(19) United States
(12) Patent Application Publication
(10) Pub. No.: US 2023/0312627 A1
(43) Pub. Date: Oct. 5, 2023

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Ming Sang, Beijing (CN); Bin Tang, Beijing (CN); Hongbo Li, Beijing (CN); Wei Cai, Beijing (CN); Zhen Wang, Beijing (CN); Zheng Wang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/126,645

(22) Filed: Mar. 27, 2023

(30) Foreign Application Priority Data
Mar. 29, 2022 (CN) 202210309910.2

(51) Int. Cl. C07F 15/00; H10K 85/30; H10K 50/11

(52) U.S. Cl. CPC C07F 15/0033; H10K 85/342; H10K 50/11; C07B 2200/05

(57) ABSTRACT

Provided are an organic electroluminescent material and device. The organic electroluminescent material is a series of metal complexes each comprising a ligand Lₐ having a structure of Formula 1, wherein the ligand Lₐ has an aza six-membered ring-(6-5-6)-fused ring skeleton structure, and has a fluorine substitution at a particular position of the aza six-membered ring, and has a particular Ar substitution and a fluorine or cyano substitution in the (6-5-6)-fused ring structure. The metal complexes may be used as light-emitting materials in electroluminescent devices. These novel compounds may be applied to electroluminescent devices and can improve the luminescence performance, driving voltages and efficiency (CE, PE and EQE) of the devices, exhibit more saturated luminescence and significantly improve the overall performance of the devices. Further provided are an organic electroluminescent device comprising the metal complex and a compound combination comprising the metal complex.

### CROSS-REFERENCE TO RELATED APPLICATION(S)

This application claims priority to Chinese Patent Application No. 202210309910.2 filed on Mar. 29, 2022, the disclosure of which is incorporated herein by reference in its entirety.

### TECHNICAL FIELD

The present disclosure relates to compounds for organic electronic devices such as organic light-emitting devices. More particularly, the present disclosure relates to a metal complex comprising a ligand Lₐ having a structure of Formula 1 and an electroluminescent device and compound combination comprising the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

CN111875640A discloses a metal complex having the following structure:

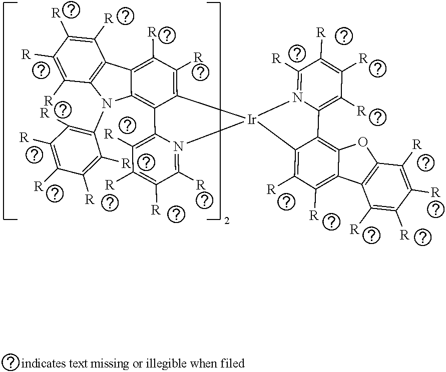

and further discloses the following iridium complex:

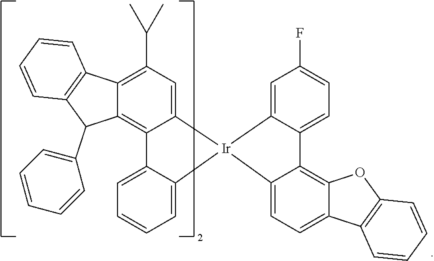

This application discloses a metal complex with a fluorine atom joined at position 5 of pyridine in a pyridine-DBX skeleton ligand. This application has neither disclosed nor taught a metal complex with a particular fluorine substitution joined at a particular position of pyridine in a pyridine-(6-5-6)-fused ring skeleton ligand and having a particular substituent on the (6-5-6)-fused ring structure and effects of the metal complex on device performance.

US20210054010A1 discloses a metal complex having the following ligand structure:

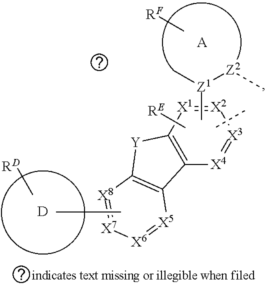

wherein the rings A and D are independent five-membered or six-membered carbocyclic or heterocyclic rings, and at least one R^{D} is a carbocyclic or heterocyclic ring. The following iridium complex is further disclosed:

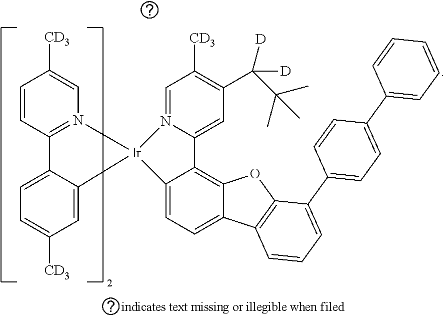

However, this application has neither disclosed nor taught a metal complex with a particular fluorine substitution joined at a particular position of the aza six-membered ring in an aza six-membered ring-(6-5-6)-fused ring skeleton ligand and having a particular substituent on the (6-5-6)-fused ring structure and effects of the metal complex on device performance.

US20200251666A1 discloses a metal complex comprising the following ligand structure:

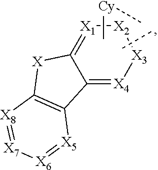

wherein at least one of X₁ to X₈ is selected from C—CN. The metal complex having the following structure is further disclosed:

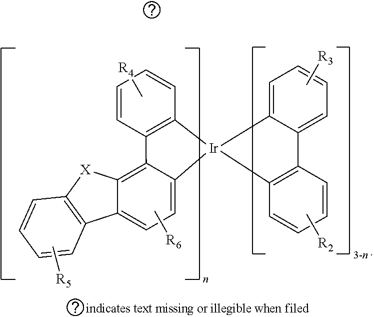

When applied to an organic electroluminescent device, the metal complex can improve device performance and color saturation, which are still to be improved though they have reached a relatively high level in the industry. Meanwhile, this application has neither disclosed nor taught a metal complex with a particular fluorine substitution joined at a particular position of the aza six-membered ring in an aza six-membered ring-(6-5-6)-fused ring skeleton ligand and having a particular substituent on the (6-5-6)-fused ring structure and effects of the metal complex on device performance.

### SUMMARY

The present disclosure aims to provide a series of metal complexes each comprising a ligand Lₐ having a structure of Formula 1 to solve at least part of the above-mentioned problems, wherein the ligand Lₐ has an aza six-membered ring-(6-5-6)-fused ring skeleton structure, and has a fluorine substitution at a particular position of the aza six-membered ring, and has a particular Ar substitution and a fluorine or cyano substitution in the (6-5-6)-fused ring structure. The metal complexes may be used as light-emitting materials in electroluminescent devices. These novel compounds may be applied to electroluminescent devices and can improve the luminescence performance, driving voltages and efficiency (CE, PE and EQE) of the devices, exhibit more saturated luminescence and significantly improve the overall performance of the devices.

According to an embodiment of the present disclosure, disclosed is a metal complex comprising a metal M and a ligand Lₐ coordinated to the metal M, wherein Lₐ has a structure represented by Formula 1:

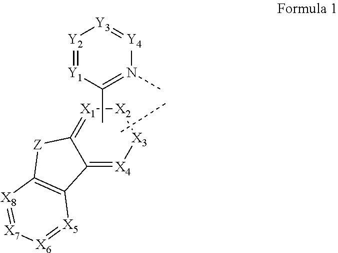

wherein
the metal M is selected from a metal with a relative atomic mass greater than 40;
Z is selected from the group consisting of O, S, Se, NR, CRR, SiRR and GeRR, wherein when two R are present at the same time, the two R are the same or different;
Y₁ to Y₄ are, at each occurrence identically or differently, selected from CR_{y} or N;
at least one of Y₂ and Y₃ is selected from CR_{y}, and the R_{y} is fluorine;
X₁ to X₈ are, at each occurrence identically or differently, selected from C, CRₓ, CAr or N;
at least two of X₁ to X₄ are C, wherein one C is joined to the nitrogen-containing six-membered ring shown in Formula 1 and another C is joined to the metal through a metal-carbon bond;
at least one of X₁ to X₈ is selected from CRₓ, and the Rₓ is cyano or fluorine;
at least one of X₁ to X₈ is selected from CAr;
Ar has a structure represented by Formula 2:

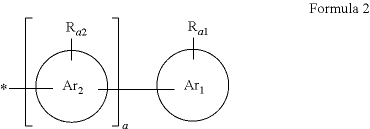

a is selected from 0, 1, 2, 3, 4 or 5;
Rₐ₁ and Rₐ₂ represent, at each occurrence identically or differently, mono-substitution, multiple substitutions or non-substitution;
the ring Ar₁ and the ring Ar₂ are, at each occurrence identically or differently, selected from an aromatic ring having 6 to 30 ring atoms, a heteroaromatic ring having 5 to 30 ring atoms or a combination thereof; and the total number of ring atoms in the ring Ar₁ and the ring Ar₂ is greater than or equal to 8;
R, Rₓ, R_{y}, Rₐ₁ and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“ [symbol] ” represents a position where Formula 2 is joined;
adjacent substituents R, Rₓ, R_{y}, Rₐ₁ and Rₐ₂ can be optionally joined to form a ring; and [symbol] “ [symbol] ” in Formula 1 represents being joined to the metal M.

According to another embodiment of the present disclosure, further disclosed is an electroluminescent device comprising an anode, a cathode and an organic layer disposed between the anode and the cathode, wherein at least one layer of the organic layer comprises the metal complex in the preceding embodiment.

According to another embodiment of the present disclosure, further disclosed is a compound combination comprising the metal complex in the preceding embodiment.

The present disclosure discloses a series of metal complexes each comprising a ligand Lₐ having a structure of Formula 1, wherein the ligand Lₐ has an aza six-membered ring-(6-5-6)-fused ring skeleton structure, and has a fluorine substitution at a particular position of the aza six-membered ring, and has a particular Ar substitution and a fluorine or cyano substitution in the (6-5-6)-fused ring structure. The metal complexes may be used as light-emitting materials in electroluminescent devices. These novel compounds may be applied to electroluminescent devices and can improve the luminescence performance, driving voltages and efficiency (CE, PE and EQE) of the devices, exhibit more saturated luminescence and significantly improve the overall performance of the devices.

### BRIEF DESCRIPTION OF DRAWINGS

FIG. 1 is a schematic diagram of an organic light-emitting apparatus that may comprise a metal complex and a compound combination disclosed herein.

FIG. 2 is a schematic diagram of another organic light-emitting apparatus that may comprise a metal complex and a compound combination disclosed herein.

### DETAILED DESCRIPTION

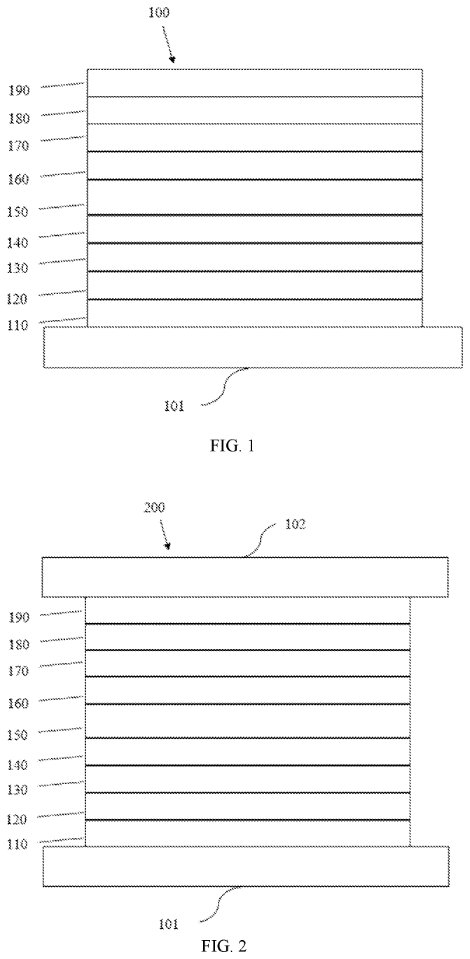

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitutions refer to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

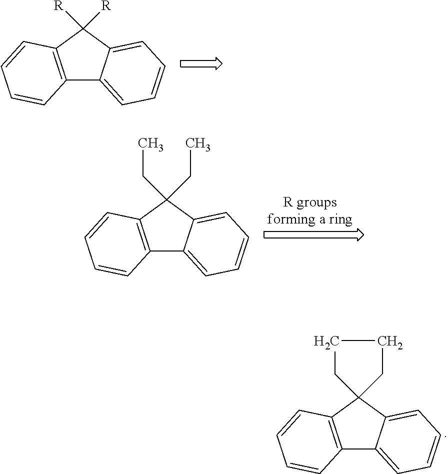

The expression that adjacent substituents can be optionally joined to form a ring is also intended to mean that two substituents bonded to carbon atoms which are directly bonded to each other are joined to each other via a chemical bond to form a ring, which can be exemplified by the following formula:

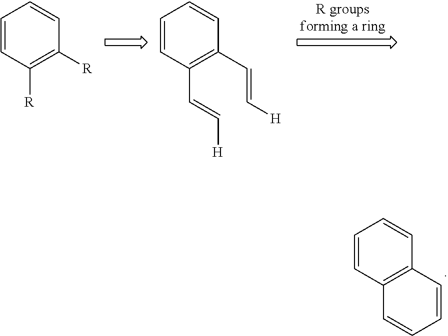

The expression that adjacent substituents can be optionally joined to form a ring is also intended to mean that two substituents bonded to a further distant carbon atom are joined to each other via a chemical bond to form a ring, which can be exemplified by the following formula:

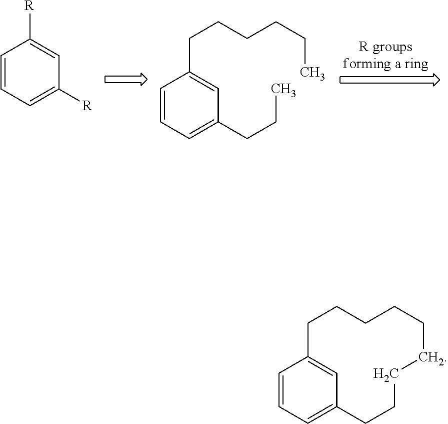

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

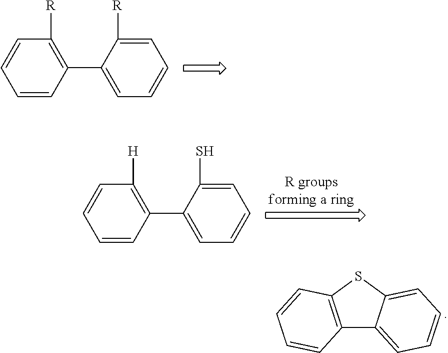

According to an embodiment of the present disclosure, disclosed is a metal complex comprising a metal M and a ligand Lₐ coordinated to the metal M, wherein La has a structure represented by Formula 1:

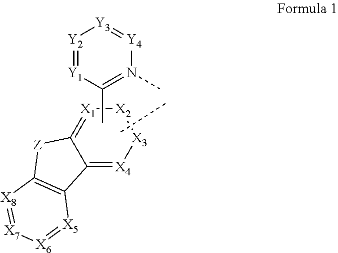

wherein
the metal M is selected from a metal with a relative atomic mass greater than 40;
Z is selected from the group consisting of O, S, Se, NR, CRR, SiRR and GeRR, wherein when two R are present at the same time, the two R are the same or different;
Y₁ to Y₄ are, at each occurrence identically or differently, selected from CR_{y} or N;
at least one of Y₂ and Y₃ is selected from CR_{y}, and the R_{y} is fluorine;
X₁ to X₈ are, at each occurrence identically or differently, selected from C, CRₓ, CAr or N;
at least two of X₁ to X₄ are C, wherein one C is joined to the nitrogen-containing six-membered ring shown in Formula 1 (that is, joined to

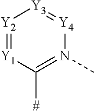

through “#”) and another C is joined to the metal through a metal-carbon bond;
at least one of X₁ to X₈ is selected from CRₓ, and the Rₓ is cyano or fluorine;
at least one of X₁ to X₈ is selected from CAr;
Ar has a structure represented by Formula 2:

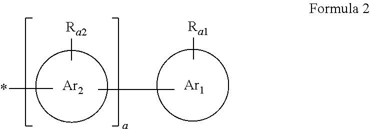

a is selected from 0, 1, 2, 3, 4 or 5;
Rₐ₁ and Rₐ₂ represent, at each occurrence identically or differently, mono-substitution, multiple substitutions or non-substitution;
the ring Ar₁ and the ring Ar₂ are, at each occurrence identically or differently, selected from an aromatic ring having 6 to 30 ring atoms, a heteroaromatic ring having 5 to 30 ring atoms or a combination thereof; and the total number of ring atoms in the ring Ar₁ and the ring Ar₂ is greater than or equal to 8;
R, Rₓ, R_{y}, Rₐ₁ and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“ [symbol] ” represents a position where Formula 2 is joined;
adjacent substituents R, Rₓ, R_{y}, Rₐ₁ and Rₐ₂ can be optionally joined to form a ring; and
“ [symbol] ” in Formula 1 represents being joined to the metal M.

In the present disclosure, the expression that “adjacent substituents R, Rₓ, R_{y}, Rₐ₁ and Rₐ₂ can be optionally joined to form a ring” is intended to mean that any one or more of groups of adjacent substituents, such as two substituents R, two substituents Rₓ, two substituents R_{y}, two substituents Rₐ₁, two substituents Rₐ₂, substituents R and Rₓ, substituents Rₐ₁ and Rₐ₂, substituents Rₐ₁ and Rₓ and substituents Rₐ₂ and Rₓ, can be joined to form a ring. Obviously, it is also possible that none of these substituents are joined to form a ring.

According to an embodiment of the present disclosure, Lₐ has a structure represented by one of Formulas 1a to 1f:

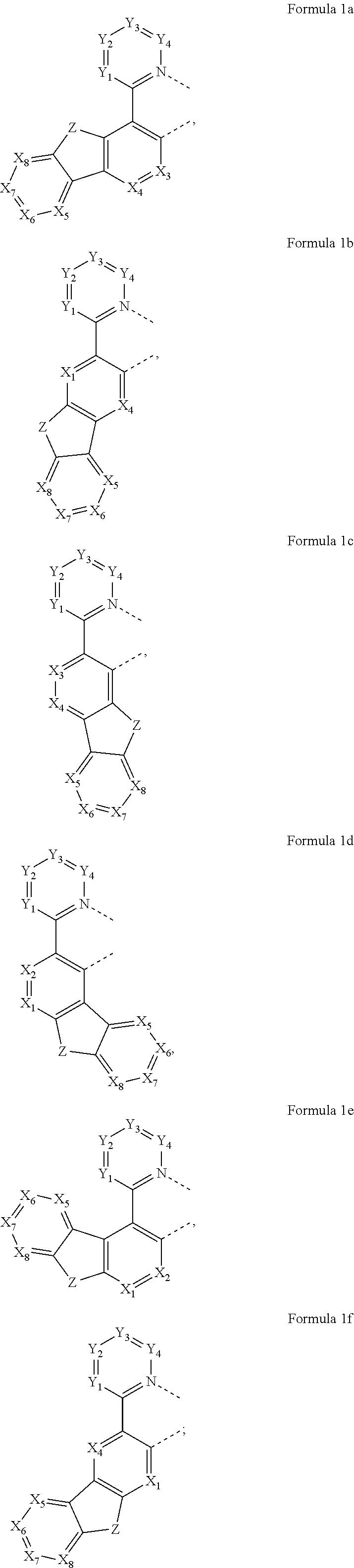

wherein
Z is selected from the group consisting of O, S, Se, NR, CRR, SiRR and GeRR, wherein when two R are present at the same time, the two R are the same or different;
Y₁ to Y₄ are, at each occurrence identically or differently, selected from CR_{y} or N;
at least one of Y₂ and Y₃ is selected from CR_{y}, and the R_{y} is fluorine;
in Formula 1a and Formula 1c, X₃ to X₈ are, at each occurrence identically or differently, selected from CRₓ, CAr or N;
in Formula 1b and Formula 1f, X₁ and X₄ to X₈ are, at each occurrence identically or differently, selected from CRₓ, CAr or N;
in Formula 1d and Formula 1e, X₁ to X₂ and X₅ to X₈ are, at each occurrence identically or differently, selected from CRₓ, CAr or N;
at least one of X₁ to X₈ is selected from CRₓ, and the Rₓ is cyano or fluorine;
at least one of X₁ to X₈ is selected from CAr;
Ar has a structure represented by Formula 2:

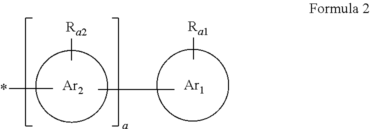

a is selected from 0, 1, 2, 3, 4 or 5;
Rₐ₁ and Rₐ₂ represent, at each occurrence identically or differently, mono-substitution, multiple substitutions or non-substitution;
the ring Ar₁ and the ring Ar₂ are, at each occurrence identically or differently, selected from an aromatic ring having 6 to 30 ring atoms, a heteroaromatic ring having 5 to 30 ring atoms or a combination thereof; and the total number of ring atoms in the ring Ar₁ and the ring Ar₂ is greater than or equal to 8;
R, Rₓ, R_{y}, Rₐ₁ and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“ [symbol] ” represents a position where Formula 2 is joined;
adjacent substituents R, Rₓ, R_{y}, Rₐ₁ and Rₐ₂ can be optionally joined to form a ring; and
“ [symbol] ” in Formulas 1a to if represents being joined to the metal M.

In the present disclosure, “ring atoms” in an aromatic ring and a heteroaromatic ring refer to those atoms that are bonded to form an aromatic cyclic structure (such as a monocyclic (hetero)aromatic or fused (hetero)aromatic ring). Carbon atoms and heteroatoms (including, but not limited to, O, S, N, Se or Si, etc.) in the ring are counted as the ring atoms. When the ring is substituted by a substituent, atoms included in the substituent are not included in the number of ring atoms. For example, the number of ring atoms in each of phenyl, pyridyl and triazinyl is 6; the number of ring atoms in each of dithiophene and difuran is 8; the number of ring atoms in each of benzothienyl and benzofuryl is 9; the number of ring atoms in each of naphthyl, quinolinyl, isoquinolyl, quinazolinyl and quinoxalinyl is 10; the number of ring atoms in each of dibenzothiophene, dibenzofuran, fluorene, aza-dibenzothiophene, azadibenzofuran and azafluorene is 13. Various examples described here are only examples, and the same applies to other cases. When a in Formula 2 is 0, it means that Ar has a structure represented by

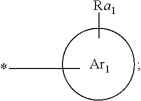

in this case, the expression that “the total number of ring atoms in the ring Ar₁ and the ring Ar₂ is greater than or equal to 8” means that the ring Ar₁ is an aromatic or heteroaromatic ring with the total number of ring atoms being greater than or equal to 8; when a in Formula 2 is 1, it means that Ar has a structure represented by

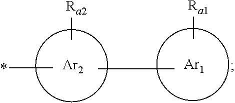

for example, when both the ring Ar₁ and the ring Ar₂ are phenyl and both Rₐ₁ and Rₐ₂ are hydrogen, the total number of ring atoms in the ring Ar₁ and the ring Ar₂ is equal to 12; for another example, when both the ring Ar₁ and the ring Ar₂ are phenyl, Rₐ₁ is hydrogen, and Rₐ₂ represents mono-substitution and is phenyl, the total number of ring atoms in the ring Ar₁ and the ring Ar₂ is equal to 12. When a in Formula 2 is 2, it means that Ar has a structure represented by

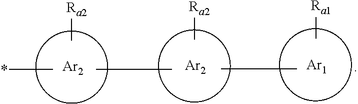

The same applies to other cases.

According to an embodiment of the present disclosure, the metal complex has a general formula of M(Lₐ)ₘ(L_{b})ₙ(L_{c})_{q};
wherein
the metal M is selected from a metal with a relative atomic mass greater than 40; preferably, M is, at each occurrence identically or differently, selected from the group consisting of Cu, Ag, Au, Ru, Rh, Pd, Os, Ir and Pt; more preferably, M is, at each occurrence identically or differently, selected from Pt or Ir;
Lₐ, L_{b} and L_{c} are a first ligand, a second ligand and a third ligand coordinated to the metal M, respectively, and Lₐ, L_{b} and L_{c} are the same or different; wherein Lₐ, L_{b} and L_{c} can be optionally joined to form a multidentate ligand; for example, any two of Lₐ, L_{b} and L_{c} can be joined to form a tetradentate ligand, Lₐ, L_{b} and L_{c} are joined to form a hexadentate ligand, or none of Lₐ, L_{b} and L_{c} are joined so that no multidentate ligand is formed;
m is selected from 1, 2 or 3, n is selected from 0, 1 or 2, q is selected from 0, 1 or 2, and m+n+q equals the oxidation state of the metal M; when m is greater than or equal to 2, multiple Lₐ are the same or different; when n is equal to 2, two L_{b} are the same or different; when q is equal to 2, two L_{c} are the same or different;
L_{b} and L_{c} are, at each occurrence identically or differently, selected from a structure represented by any one of the group consisting of:

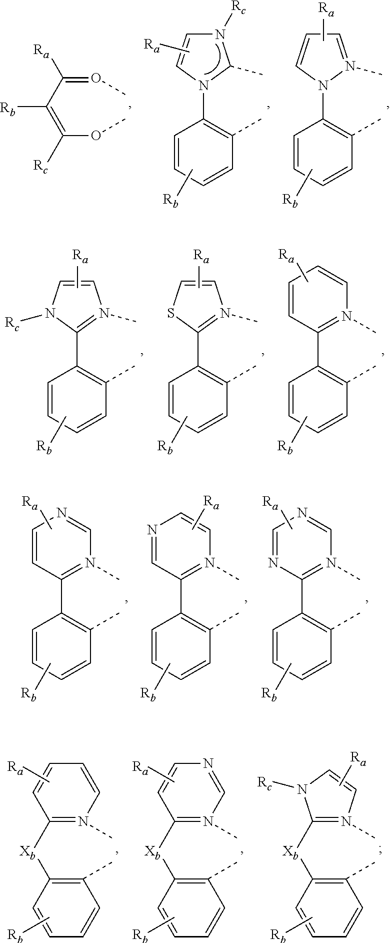

wherein
Rₐ and R_{b} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents Rₐ, R_{b}, R_{c}, R_{N1}, R_{C1} and R_{C2} can be optionally joined to form a ring; and
“ [symbol] ” in L_{b} and L_{c} represents being joined to the metal M.

In the present disclosure, the expression that “adjacent substituents Rₐ, R_{b}, R_{c}, R_{N1}, R_{C1} and R_{C2} can be optionally joined to form a ring” is intended to mean that any one or more of groups of adjacent substituents, such as two substituents Rₐ, two substituents R_{b}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2} and substituents R_{C1} and R_{C2}, can be joined to form a ring. Obviously, it is also possible that none of these substituents are joined to form a ring. For example, with Formula

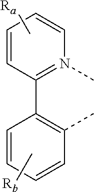

as an example, two substituents Rₐ are joined to form a ring so that the following structure can be formed:

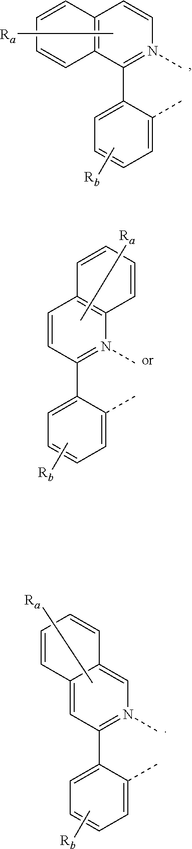

According to an embodiment of the present disclosure, the metal complex Ir(Lₐ)ₘ(L_{b})₃₋ₘ has a structure represented by Formula 3:

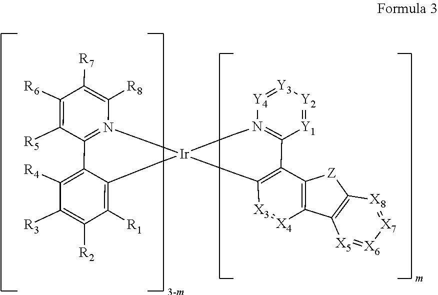

wherein
m is selected from 1, 2 or 3; when m is 1, two L_{b} are the same or different; when m is 2 or 3, multiple Lₐ are the same or different;
Z is selected from the group consisting of O, S, Se, NR, CRR, SiRR and GeRR, wherein when two R are present at the same time, the two R are the same or different;
Y₁ to Y₄ are, at each occurrence identically or differently, selected from CR_{y} or N; at least one of Y₂ and Y₃ is selected from CR_{y}, and the R_{y} is fluorine;
X₃ to X₈ are, at each occurrence identically or differently, selected from CRₓ, CAr or N;
at least one of X₃ to X₈ is selected from CRₓ, and the Rₓ is cyano or fluorine;
at least one of X₃ to X₈ is selected from CAr;
Ar has a structure represented by Formula 2:

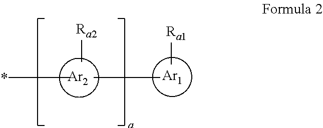

a is selected from 0, 1, 2, 3, 4 or 5;
Rₐ₁ and Rₐ₂ represent, at each occurrence identically or differently, mono-substitution, multiple substitutions or non-substitution;
the ring Ar₁ and the ring Ar₂ are, at each occurrence identically or differently, selected from an aromatic ring having 6 to 30 ring atoms, a heteroaromatic ring having 5 to 30 ring atoms or a combination thereof; and the total number of ring atoms in the ring Ar₁ and the ring Ar₂ is greater than or equal to 8;
R, Rₓ, R_{y}, Rₐ₁, Rₐ₂ and R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R, Rₓ, R_{y}, Rₐ₁ and Rₐ₂ can be optionally joined to form a ring; and
adjacent substituents R₁ to R₈ can be optionally joined to form a ring.

In the present disclosure, the expression that “adjacent R₁ to R₈ can be optionally joined to form a ring” is intended to mean that any one or more of groups of any two adjacent substituents of R₁ to R₈ can be joined to form a ring. Obviously, it is also possible that none of these substituents are joined to form a ring.

According to an embodiment of the present disclosure, the metal complex Ir(Lₐ)ₘ(L_{b})₃₋ₘ has a structure represented by Formula 3a or 3b:

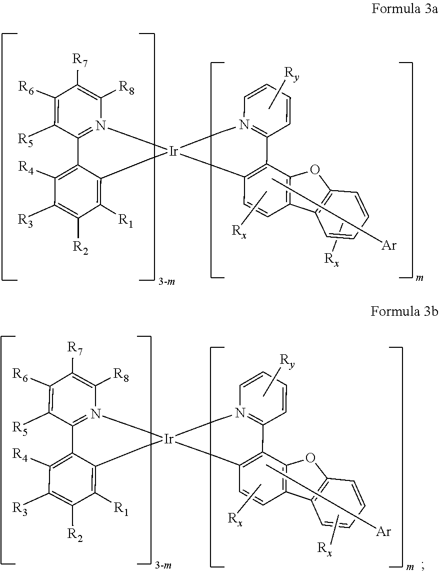

wherein
m is selected from 1, 2 or 3; when m is 1, two L_{b} are the same or different; when m is 2 or 3, multiple Lₐ are the same or different;
Rₓ, R_{y} and Ar represent, at each occurrence identically or differently, mono-substitution, multiple substitutions or non-substitution;
Ar has a structure represented by Formula 2:

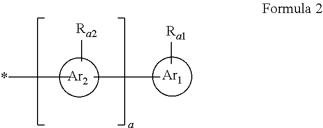

a is selected from 0, 1, 2, 3, 4 or 5;
Rₐ₁ and Rₐ₂ represent, at each occurrence identically or differently, mono-substitution, multiple substitutions or non-substitution;
the ring Ar₁ and the ring Ar₂ are, at each occurrence identically or differently, selected from an aromatic ring having 6 to 30 ring atoms, a heteroaromatic ring having 5 to 30 ring atoms or a combination thereof; and the total number of ring atoms in the ring Ar₁ and the ring Ar₂ is greater than or equal to 8;
Rₓ, R_{y}, Rₐ₁, Rₐ₂ and R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents Rₓ, R_{y}, Rₐ₁ and Rₐ₂ can be optionally joined to form a ring; and
adjacent substituents R₁ to R₈ can be optionally joined to form a ring.

In the present disclosure, the expression that “adjacent substituents Rₓ, R_{y}, Rₐ₁ and Rₐ₂ can be optionally joined to form a ring” is intended to mean that any one or more of groups of adjacent substituents, such as two substituents Rₓ, two substituents R_{y}, two substituents Rai, two substituents Rₐ₂, substituents Rₐ₁ and Rₐ₂, substituents Rₐ₁ and Rₓ and substituents Rₐ₂ and Rₓ, can be joined to form a ring. Obviously, it is also possible that none of these substituents are joined to form a ring.

According to an embodiment of the present disclosure, Z is selected from the group consisting of O and S.

According to an embodiment of the present disclosure, Z is O.

According to an embodiment of the present disclosure, a is selected from 0, 1, 2 or 3.

According to an embodiment of the present disclosure, a is 1.

According to an embodiment of the present disclosure, Y₁ to Y₄ are, at each occurrence identically or differently, selected from CR_{y}; at least one of Y₂ and Y₃ is selected from CR_{y}, and R_{y} is fluorine; and the rest of R_{y} is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

In the present disclosure, “the rest of R_{y}” refers to R_{y} of Y₁ to Y₄ when they are selected from CR_{y}, other than the exact R_{y} of Y₂ and/or Y₃ which are/is selected from CR_{y} and the R_{y} is fluorine. The following cases are included: (1) when Y₂ is selected from CR_{y} and R_{y} is fluorine, and at least one of Y₁, Y₃ and Y₄ is selected from CR_{y}, “the rest of R_{y}” refers to the R_{y} of the at least one of Y₁, Y₃ and Y₄; (2) when Y₃ is selected from CR_{y} and R_{y} is fluorine, and at least one of Y₁, Y₂ and Y₄ is selected from CR_{y}, “the rest of R_{y}” refers to the R_{y} of the at least one of Y₁, Y₂ and Y₄; (3) when Y₂ and Y₃ are selected from CR_{y} and R_{y} is fluorine, and at least one of Y₁ and Y₄ is selected from CR_{y}, “the rest of R_{y}” refers to the R_{y} of the at least one of Y₁ and Y₄.

According to an embodiment of the present disclosure, Y₁ to Y₄ are, at each occurrence identically or differently, selected from CR_{y}; at least one of Y₂ and Y₃ is selected from CR_{y}, and R_{y} is fluorine; and the rest of R_{y} is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms and combinations thereof.

According to an embodiment of the present disclosure, Y₁ to Y₄ are, at each occurrence identically or differently, selected from CR_{y}; at least one of Y₂ and Y₃ is selected from CR_{y}, and R_{y} is fluorine; and the rest of R_{y} is selected from hydrogen, deuterium, methyl, ethyl, propyl, isopropyl, butyl, t-butyl, isobutyl, pentyl, isopentyl, neopentyl, t-pentyl or a combination thereof; optionally, hydrogens in the above groups are partially or fully deuterated.

According to an embodiment of the present disclosure, at least one of Y₂ and Y₃ is CR_{y}, and R_{y} is fluorine; at least another one of Y₁ to Y₄ is selected from CR_{y}, and R_{y} is selected from the group consisting of: deuterium, halogen, substituted or unsubstituted alkyl having 1 to 10 carbon atoms, substituted or unsubstituted cycloalkyl having 3 to 10 ring carbon atoms, substituted or unsubstituted aryl having 6 to 15 carbon atoms, substituted or unsubstituted heteroaryl having 3 to 15 carbon atoms and combinations thereof.

According to an embodiment of the present disclosure, Y₂ and Y₃ are selected from CR_{y}, and one R_{y} is fluorine; and another R_{y} is selected from the group consisting of: deuterium, substituted or unsubstituted alkyl having 1 to 10 carbon atoms, substituted or unsubstituted cycloalkyl having 3 to 10 ring carbon atoms, substituted or unsubstituted aryl having 6 to 15 carbon atoms, substituted or unsubstituted heteroaryl having 3 to 15 carbon atoms and combinations thereof.

According to an embodiment of the present disclosure, Y₂ and Y₃ are selected from CR_{y}, and one R_{y} is fluorine; and another R_{y} is selected from the group consisting of: deuterium, substituted or unsubstituted alkyl having 1 to 6 carbon atoms, substituted or unsubstituted cycloalkyl having 3 to 6 ring carbon atoms and combinations thereof.

According to an embodiment of the present disclosure, Y₂ and Y₃ are selected from CR_{y}, and one R_{y} is fluorine; and another R_{y} is selected from the group consisting of: deuterium, methyl, ethyl, propyl, isopropyl, n-butyl, isobutyl, t-butyl, neopentyl, cyclopentyl, cyclohexyl, deuterated methyl, deuterated ethyl, deuterated propyl, deuterated isopropyl, deuterated n-butyl, deuterated isobutyl, deuterated t-butyl, deuterated neopentyl, deuterated cyclopentyl, deuterated cyclohexyl and trimethylsilyl.

According to an embodiment of the present disclosure, Y₁ to Y₄ are, at each occurrence identically or differently, selected from CR_{y} or N, and at least one of Y₁ to Y₄ is selected from N; for example, one of Y₁ to Y₄ is selected from N or two of Y₁ to Y₄ are selected from N.

According to an embodiment of the present disclosure, X₁ to X₈ are, at each occurrence identically or differently, selected from C, CRₓ, CAr or N, and at least one of X₁ to X₈ is selected from N; for example, one of X₁ to X₈ is selected from N or two of X₁ to X₈ are selected from N.

According to an embodiment of the present disclosure, X₃ to X₈ are, at each occurrence identically or differently, selected from CRₓ, CAr or N, and at least one of X₃ to X₈ is selected from N; for example, one of X₃ to X₈ is selected from N or two of X₃ to X₈ are selected from N.

According to an embodiment of the present disclosure, X₃ to X₈ are, at each occurrence identically or differently, selected from CRₓ or CAr, and at least one of X₃ to X₈ is selected from CAr; and at least one of Rₓ is selected from cyano or fluorine, and the rest of Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, cyano and combinations thereof.

According to an embodiment of the present disclosure, X₃ to X₈ are, at each occurrence identically or differently, selected from CRₓ or CAr, and at least one of X₃ to X₈ is selected from CAr; and at least one of Rₓ is selected from cyano or fluorine, and the rest of Rₓ is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, cyano and combinations thereof.

In the present disclosure, “the rest of Rₓ” is intended to mean that when at least one of X₃ to X₈ is selected from CAr and multiple ones of X₃ to X₈ are selected from CRₓ, at least one of Rₓ is cyano or fluorine and another Rₓ other than the Rₓ selected from cyano or fluorine is “the rest of Rₓ”. For example, when X₇ is selected from CRₓ and the Rₓ is cyano or fluorine, X₈ is selected from CAr, and at least one of X₃ to X₆ is selected from CRₓ, Rₓ in each of X₃ to X₆ selected from CRₓ is “the rest of Rₓ”.

According to an embodiment of the present disclosure, X₃ to X₈ are, at each occurrence identically or differently, selected from CRₓ or CAr, and at least one of X₃ to X₈ is selected from CAr; and at least one of Rₓ is selected from cyano or fluorine, and the rest of Rₓ is, at each occurrence identically or differently, selected from the group consisting of: hydrogen, deuterium, substituted or unsubstituted alkyl having 1 to 6 carbon atoms, substituted or unsubstituted cycloalkyl having 3 to 6 ring carbon atoms and combinations thereof.

According to an embodiment of the present disclosure, at least one of X₃ to X₈ is selected from CRₓ, and the Rₓ is cyano or fluorine; and at least one of X₃ to X₈ is selected from CAr.

According to an embodiment of the present disclosure, at least one of X₅ to X₈ is selected from CRₓ, and the Rₓ is cyano or fluorine; and at least one of X₅ to X₈ is selected from CAr.

According to an embodiment of the present disclosure, one of X₇ and X₈ is selected from CRₓ, and the Rₓ is selected from cyano or fluorine; and the other of X₇ and X₈ is selected from CAr.

According to an embodiment of the present disclosure, X₇ is selected from CRₓ, and the Rₓ is selected from cyano or fluorine; and X₈ is selected from CAr.

According to an embodiment of the present disclosure, Rₐ₁ and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, an isocyano group, a hydroxyl group, a sulfanyl group and combinations thereof.

According to an embodiment of the present disclosure, Rₐ₁ and Rₐ₂ are, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 18 carbon atoms, substituted or unsubstituted heteroaryl having 3 to 18 carbon atoms, substituted or unsubstituted alkylsilyl having 3 to 15 carbon atoms and combinations thereof.

According to an embodiment of the present disclosure, Rₐ₁ and Rₐ₂ are, at each occurrence identically or differently, selected from the group consisting of: hydrogen, deuterium, fluorine, methyl, ethyl, propyl, isopropyl, n-butyl, isobutyl, t-butyl, neopentyl, cyclopentyl, cyclohexyl, phenyl, pyridyl, trimethylsilyl and combinations thereof; optionally, hydrogens in the above groups can be partially or fully deuterated.

According to an embodiment of the present disclosure, the ring Ar₁ and the ring Ar₂ are, at each occurrence identically or differently, selected from a benzene ring, a heteroaromatic ring having 5 or 6 ring atoms or a combination thereof.

According to an embodiment of the present disclosure, the ring Ar₁ and the ring Ar₂ are, at each occurrence identically or differently, selected from a benzene ring or a heteroaromatic ring having 6 ring atoms.

According to an embodiment of the present disclosure, the ring Ar₁ and the ring Ar₂ are, at each occurrence identically or differently, selected from a benzene ring.

According to an embodiment of the present disclosure, the ring Ar₁ and the ring Ar₂ are, at each occurrence identically or differently, selected from an aromatic ring having 6 to 18 ring atoms, a heteroaromatic ring having 5 to 18 ring atoms or a combination thereof; and the total number of ring atoms in the ring Ar₁ and the ring Ar₂ is greater than or equal to 8 and less than or equal to 30.

According to an embodiment of the present disclosure, the ring Ar₁ and the ring Ar₂ are, at each occurrence identically or differently, selected from the group consisting of: a benzene ring, a pyridine ring, a pyrimidine ring, a triazine ring, a naphthalene ring, a phenanthrene ring, an anthracene ring, a fluorene ring, a silafluorene ring, a quinoline ring, an isoquinoline ring, a dithiophene ring, a difuran ring, a benzofuran ring, a benzothiophene ring, a dibenzofuran ring, a dibenzothiophene ring, a triphenylene ring, a carbazole ring, an azacarbazole ring, an azafluorene ring, an azasilafluorene ring, an azadibenzofuran ring, an aza-dibenzothiophene ring and combinations thereof; the total number of ring atoms in the ring Ar₁ and the ring Ar₂ is greater than or equal to 8 and less than or equal to 30; optionally, hydrogens in the above groups can be partially or fully deuterated.

According to an embodiment of the present disclosure, in Ar, the total number of ring atoms in the ring Ar₁ and the ring Ar₂ is greater than or equal to 8 and less than or equal to 24.

According to an embodiment of the present disclosure, in Ar, the total number of ring atoms in the ring Ar₁ and the ring Ar₂ is greater than or equal to 8 and less than or equal to 18.

According to an embodiment of the present disclosure, Ar is, at each occurrence identically or differently, selected from the group consisting of:

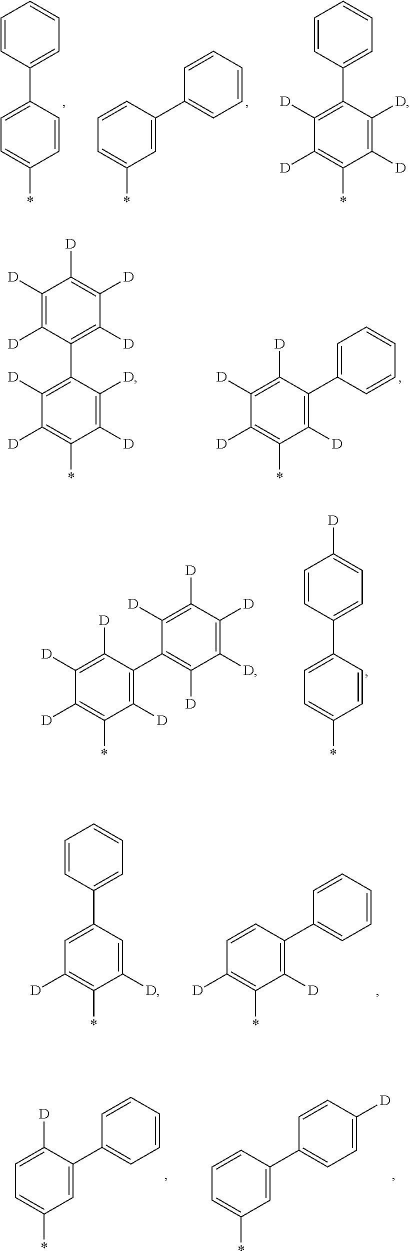

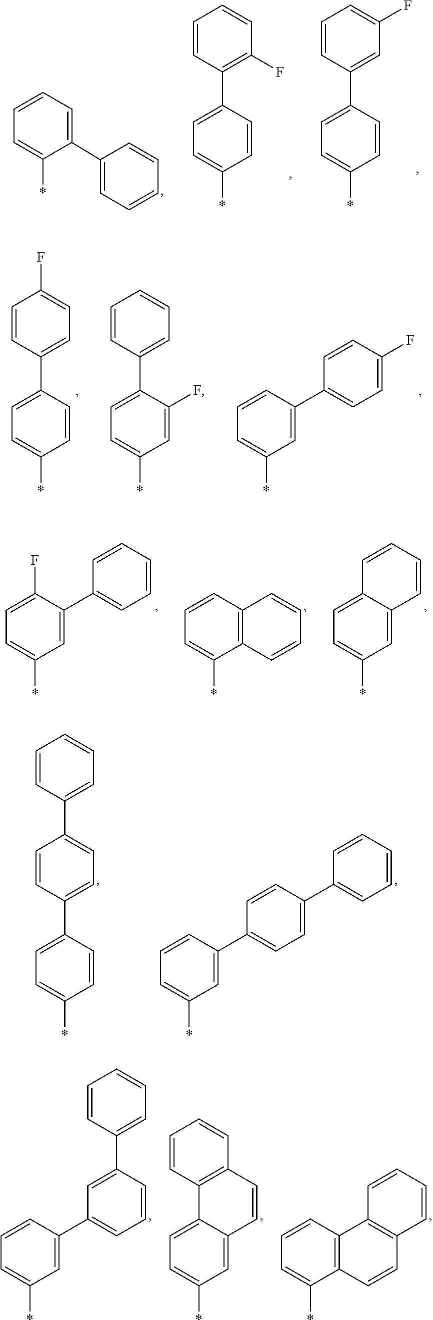

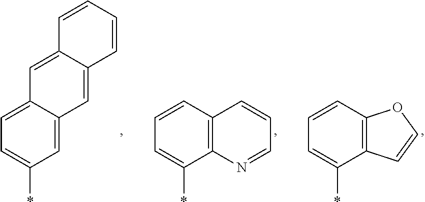

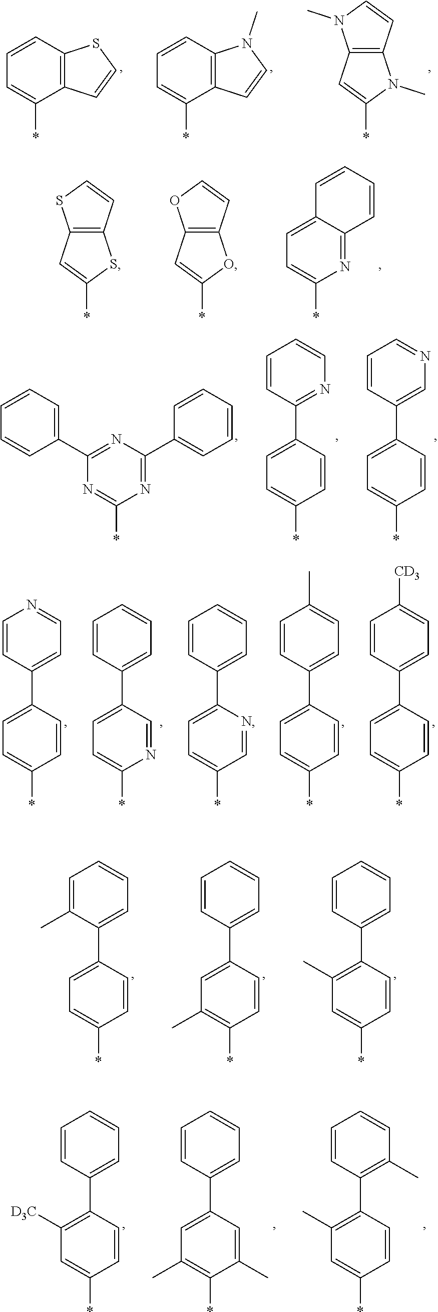

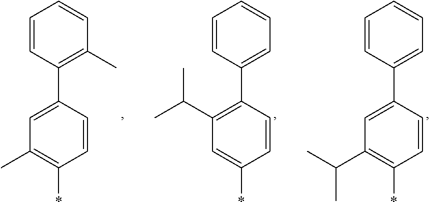

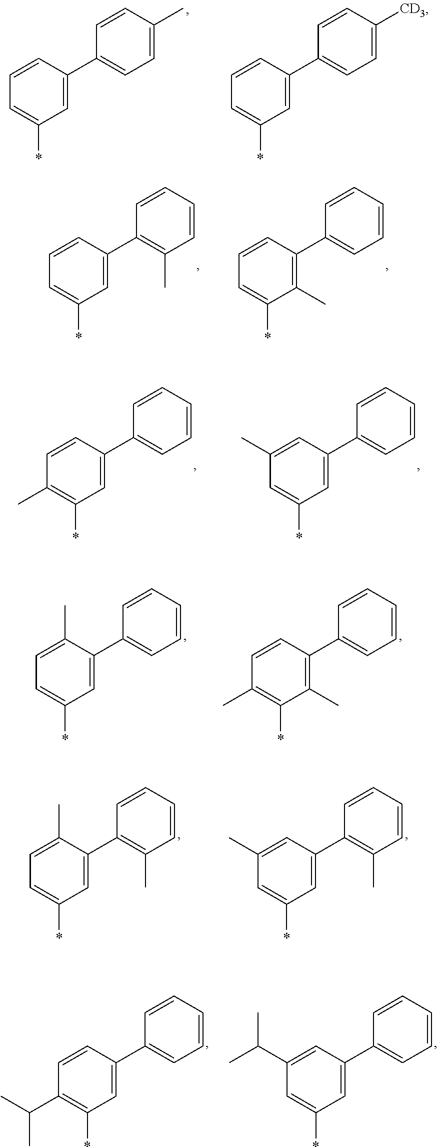

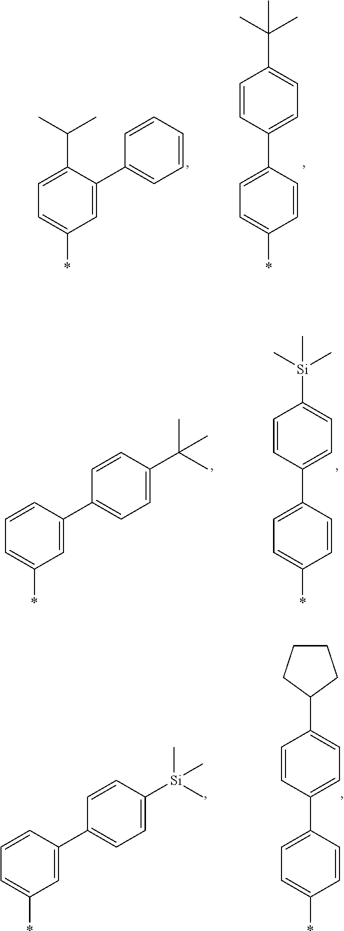

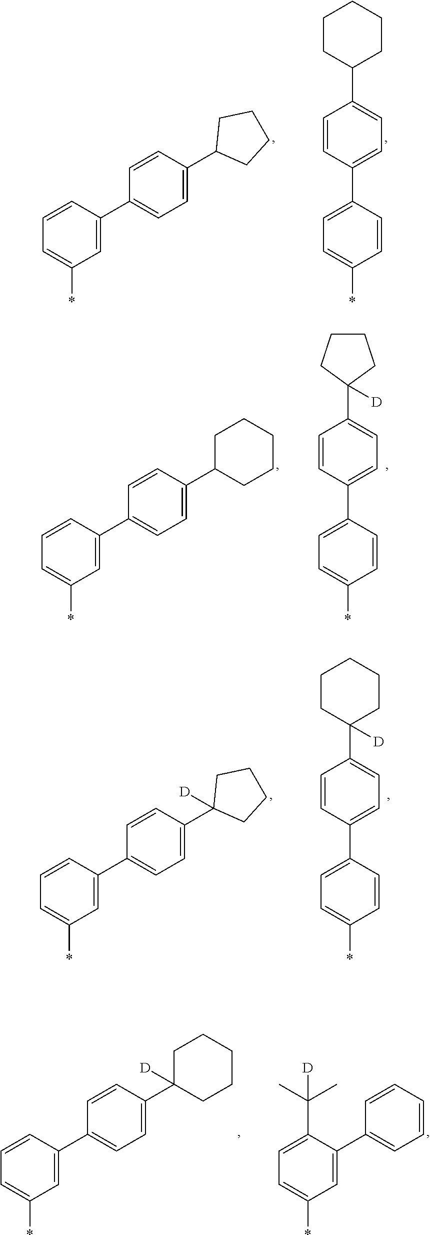

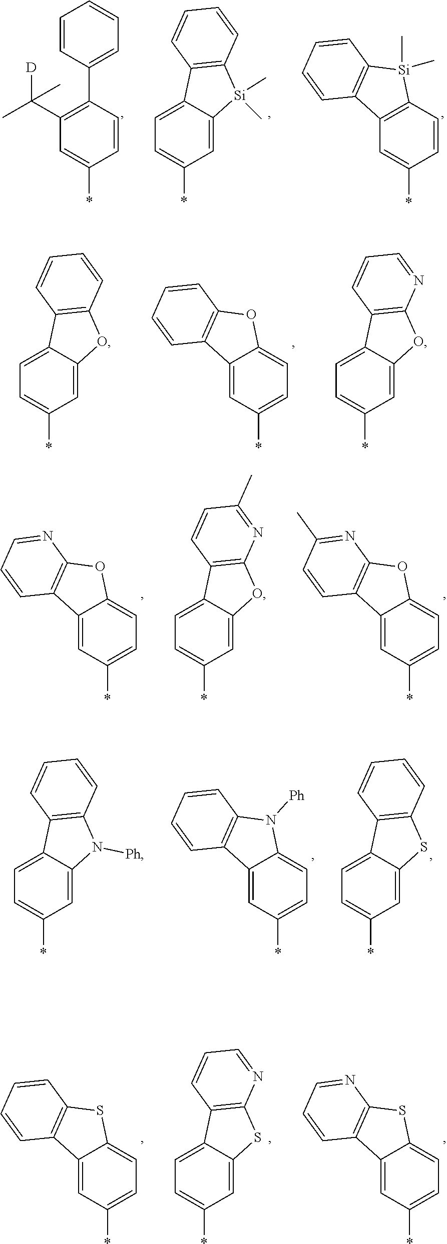

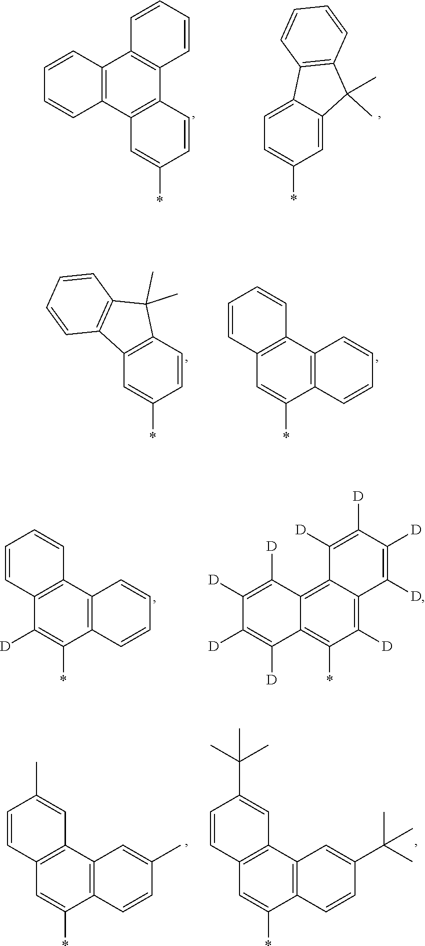

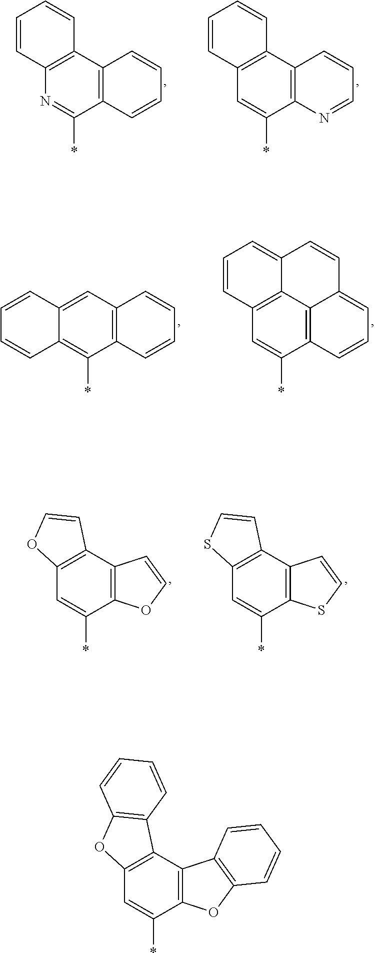

and combinations thereof;
wherein optionally, hydrogens in the above groups can be partially or fully deuterated; and “ [symbol] ” represents a position where Ar is joined.

According to an embodiment of the present disclosure, at least one or at least two of R₁ to R₈ are selected from substituted or unsubstituted alkyl having 1 to 20 carbon atoms, substituted or unsubstituted cycloalkyl having 3 to 20 ring carbon atoms or a combination thereof, and the total number of carbon atoms in all of R₁ to R₄ and/or R₅ to R₈ is at least 4.

According to an embodiment of the present disclosure, at least one or at least two of R₁ to R₄ are selected from substituted or unsubstituted alkyl having 1 to 20 carbon atoms, substituted or unsubstituted cycloalkyl having 3 to 20 ring carbon atoms or a combination thereof, and the total number of carbon atoms in all of R₁ to R₄ is at least 4.

According to an embodiment of the present disclosure, at least one or at least two of R₅ to R₈ are selected from substituted or unsubstituted alkyl having 1 to 20 carbon atoms, substituted or unsubstituted cycloalkyl having 3 to 20 ring carbon atoms or a combination thereof, and the total number of carbon atoms in all of R₅ to R₈ is at least 4.

According to an embodiment of the present disclosure, at least one, at least two, at least three or all of R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof.

According to an embodiment of the present disclosure, at least one, at least two, at least three or all of R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms and combinations thereof.

According to an embodiment of the present disclosure, at least one, at least two, at least three or all of R₂, R₃, R₆ and R₇ are selected from the group consisting of: deuterium, methyl, ethyl, propyl, isopropyl, n-butyl, isobutyl, t-butyl, cyclopentyl, cyclohexyl, neopentyl, t-pentyl and combinations thereof; optionally, hydrogens in the above groups can be partially or fully deuterated.

According to an embodiment of the present disclosure, Lₐ is, at each occurrence identically or differently, selected from the group consisting of Lₐ₁ to Lₐ₈₇₉, wherein the specific structures of Lₐ₁ to Lₐ₈₇₉ are referred to claim 17.

According to an embodiment of the present disclosure, hydrogen atoms in Lₐ₁ to Lₐ₈₇₉ can be partially or fully deuterated.

According to an embodiment of the present disclosure, L_{b} is, at each occurrence identically or differently, selected from the group consisting of L_{b1} to L_{b334}, wherein the specific structures of L_{b1} to L_{b334} are referred to claim 18.

According to an embodiment of the present disclosure, hydrogen atoms in L_{b1} to L_{b334} can be partially or fully deuterated.

According to an embodiment of the present disclosure, L_{c} is, at each occurrence identically or differently, selected from the group consisting of:

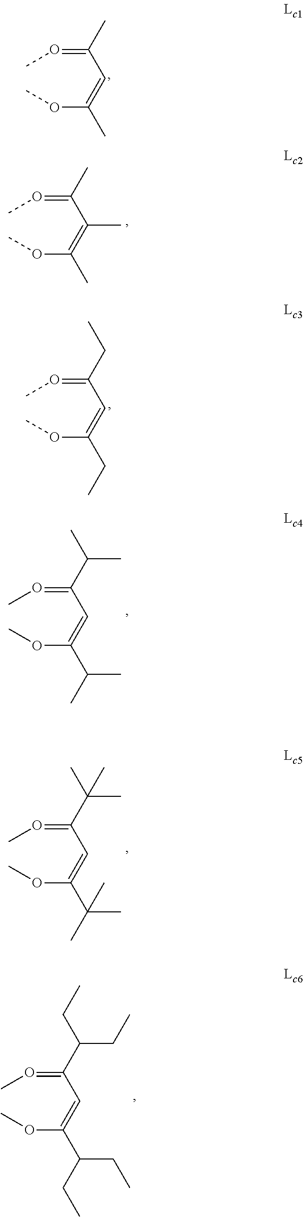

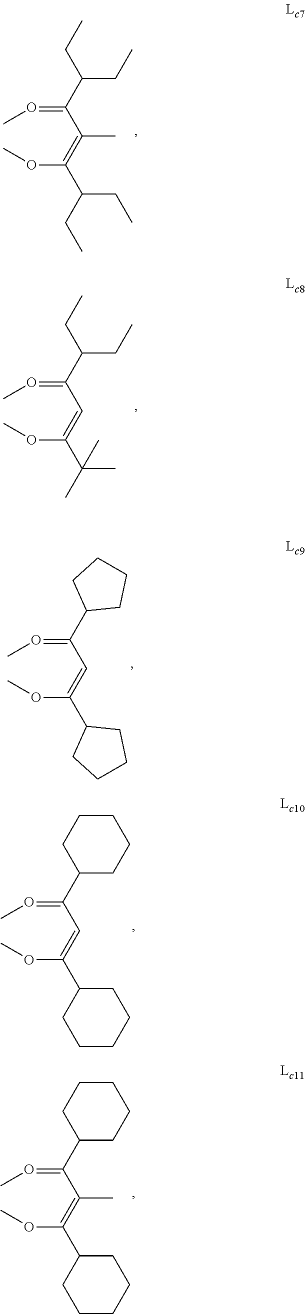

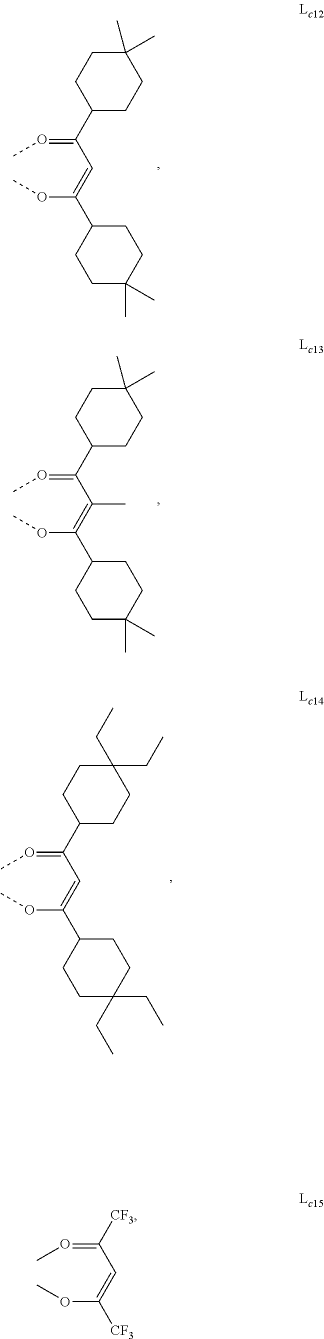

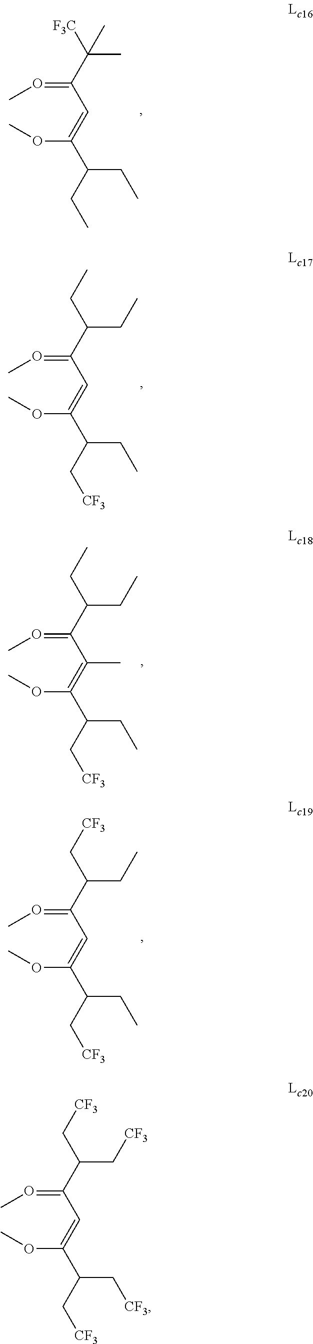

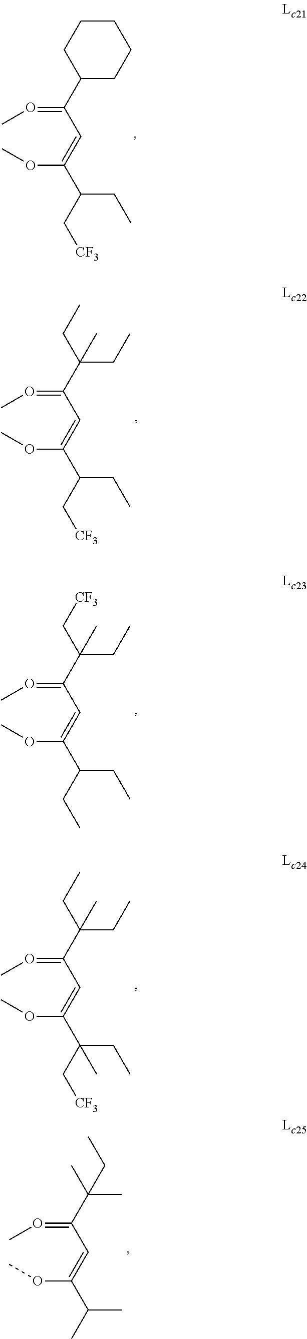

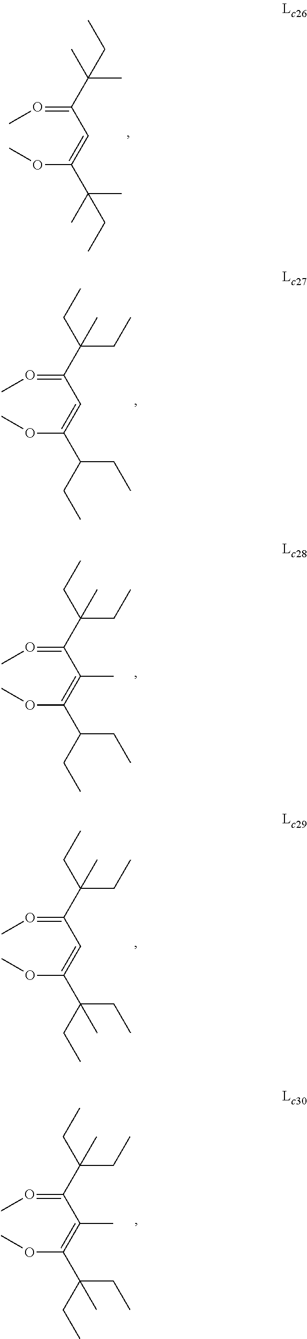

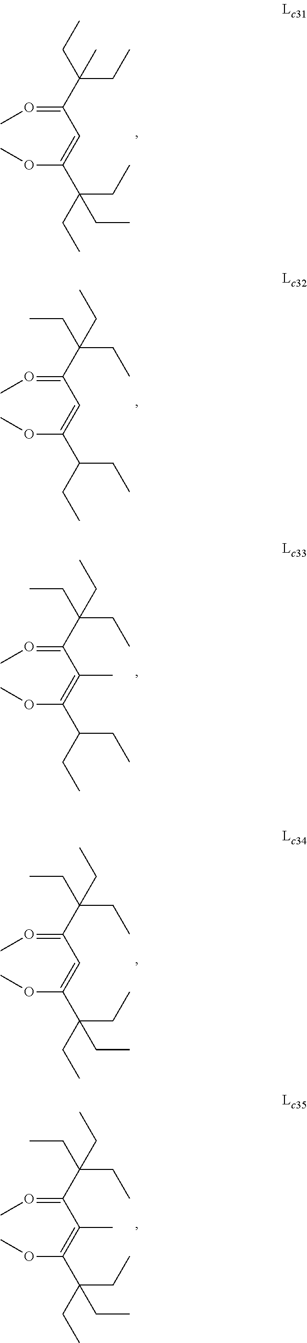

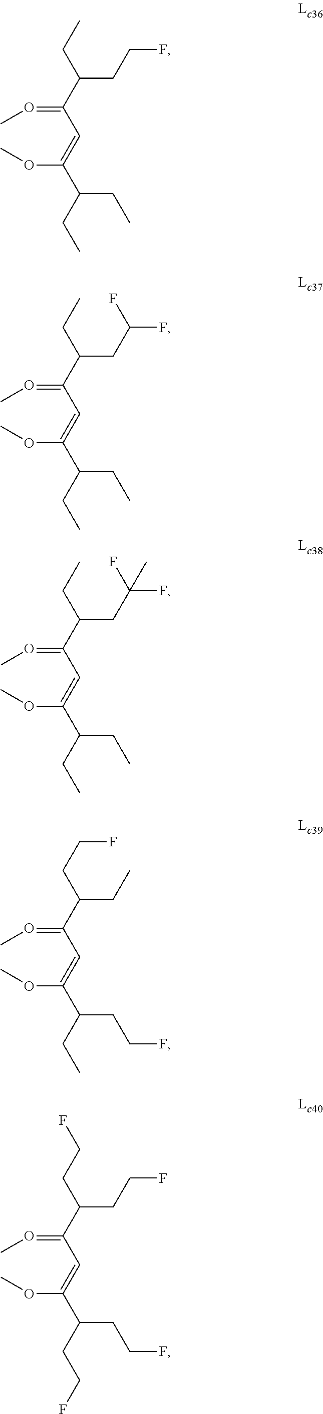

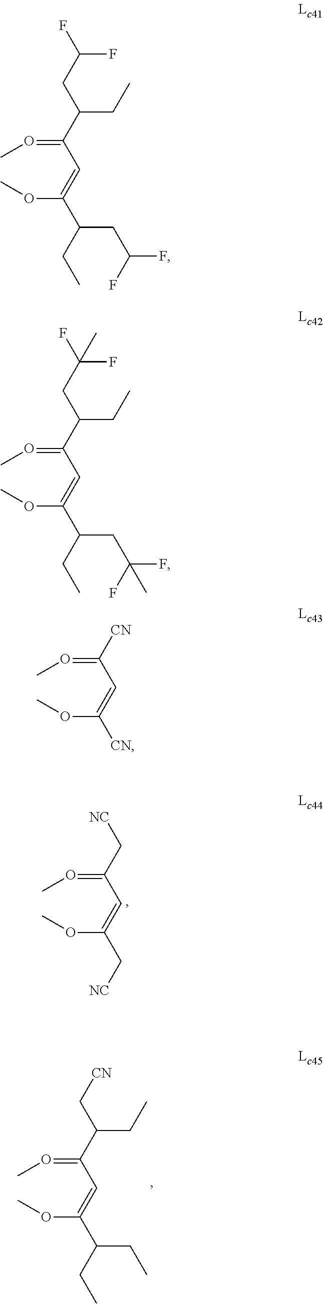

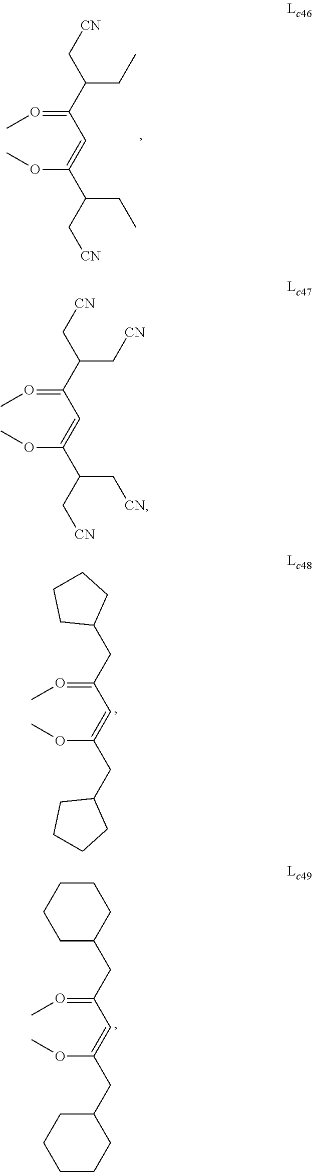

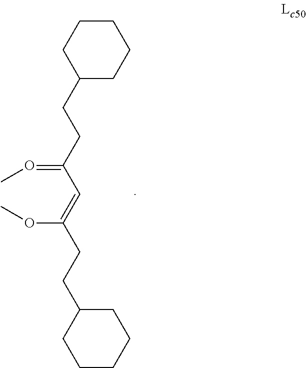

According to an embodiment of the present disclosure, the metal complex has a structure of Ir(Lₐ)₃, IrLₐ(L_{b})₂, Ir(Lₐ)₂L_{b}, Ir(Lₐ)₂L_{c}, IrLₐc)₂ or IrLₐL_{b}L_{c}, wherein the ligand Lₐ is, at each occurrence identically or differently, selected from any one, any two or any three of the group consisting of Lₐ₁ to Lₐ₈₇₉, the ligand L_{b} is, at each occurrence identically or differently, selected from any one or any two of the group consisting of L_{b1} to L_{b334}, and the ligand L_{c} is, at each occurrence identically or differently, selected from any one or any two of the group consisting of L_{c1} to L_{c50}.

According to an embodiment of the present disclosure, the metal complex has a structure of IrLₐ(L_{b})₂, wherein two L_{b} are the same or different, the ligand Lₐ is, at each occurrence identically or differently, selected from any one of the group consisting of Lₐ₁ to Lₐ₈₇₉, and the ligand L_{b} is, at each occurrence identically or differently, selected from any one or any two of the group consisting of L_{b1} to L_{b334}.

According to an embodiment of the present disclosure, the metal complex is selected from the group consisting of Metal Complex 1 to Metal Complex 396, wherein the specific structures of Metal Complex 1 to Metal Complex 396 are referred to claim 19.

According to an embodiment of the present disclosure, disclosed is an electroluminescent device comprising an anode, a cathode and an organic layer disposed between the anode and the cathode, wherein at least one layer of the organic layer comprises the metal complex in any one of the preceding embodiments.

According to an embodiment of the present disclosure, the organic layer comprising the metal complex is a light-emitting layer.

According to an embodiment of the present disclosure, the light-emitting layer further comprises a first host compound.

According to an embodiment of the present disclosure, the light-emitting layer further comprises a second host compound.

According to an embodiment of the present disclosure, at least one of the host compounds comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

According to an embodiment of the present disclosure, the first host compound has a structure represented by Formula 4:

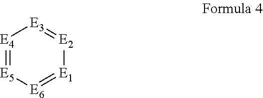

wherein
E₁ to E₆ are, at each occurrence identically or differently, selected from C, CRₑ or N, at least two of E₁ to E₆ are N, and at least one of E₁ to E₆ is C and joined to Formula 5;

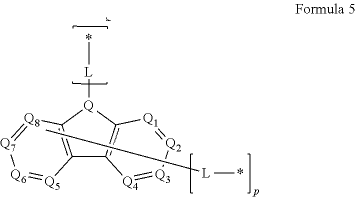

wherein
Q is, at each occurrence identically or differently, selected from the group consisting of O, S, Se, N, NR″, CR″R″, SiR″R″, GeR″R″ and R″C═CR″; when two R″ are present at the same time, the two R″ may be the same or different;
p is 0 or 1; r is 0 or 1;
when Q is selected from N, p is 0 and r is 1;
when Q is selected from the group consisting of O, S, Se, NR″, CR″R″, SiR″R″, GeR″R″ and R″C═CR″, p is 1 and r is 0;
L is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
Q₁ to Q₈ are, at each occurrence identically or differently, selected from C, CR_{q} or N;
“ [symbol] 36” represents a position where Formula 5 is joined to Formula 4;
Rₑ, R″ and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₑ, R″, R_{q} can be optionally joined to form a ring.

In the present disclosure, the expression that “adjacent substituents Rₑ, R″, R_{q} can be optionally joined to form a ring” is intended to mean that any one or more of groups of adjacent substituents, such as two substituents Rₑ, two substituents R″, two substituents R_{q} and substituents R″ and R_{q}, can be joined to form a ring. Obviously, it is also possible that none of these substituents are joined to form a ring.

According to an embodiment of the present disclosure, the first host compound has a structure represented by Formula 4a or 4b:

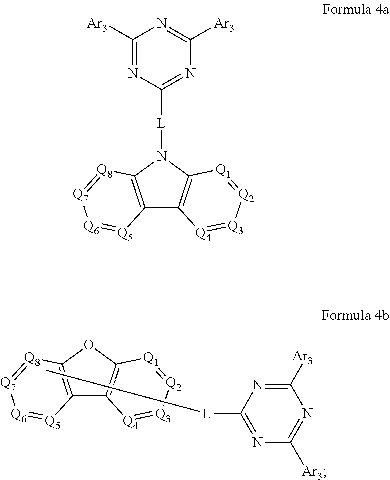

wherein in Formula 4a or Formula 4b,
Q is, at each occurrence identically or differently, selected from the group consisting of O, S, Se, NR″, CR″R″, SiR″R″, GeR″R″ and R″C═CR″; when two R″ are present at the same time, the two R″ may be the same or different;
L is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
Q₁ to Q₈ are, at each occurrence identically or differently, selected from C, CR_{q} or N;
R″ and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Ar₃ is, at each occurrence identically or differently, selected from substituted or unsubstituted aryl having 6 to 30 carbon atoms, substituted or unsubstituted heteroaryl having 3 to 30 carbon atoms or a combination thereof;
preferably, Ar₃ is selected from substituted or unsubstituted phenyl, substituted or unsubstituted biphenyl, substituted or unsubstituted terphenyl, substituted or unsubstituted naphthyl, substituted or unsubstituted phenanthryl, substituted or unsubstituted triphenylenyl, substituted or unsubstituted fluorenyl, substituted or unsubstituted dibenzofuryl, substituted or unsubstituted dibenzothienyl, substituted or unsubstituted carbazolyl or a combination thereof; and
adjacent substituents R″, R_{q} can be optionally joined to form a ring.

In the present disclosure, the expression that “adjacent substituents R″, R_{q} can be optionally joined to form a ring” is intended to mean that any one or more of groups of adjacent substituents, such as two substituents R″, two substituents R_{q} and substituents R″ and R_{q}, can be joined to form a ring. Obviously, it is also possible that none of these substituents are joined to form a ring.

According to an embodiment of the present disclosure, the second host compound has a structure represented by Formula 6 or Formula 7:

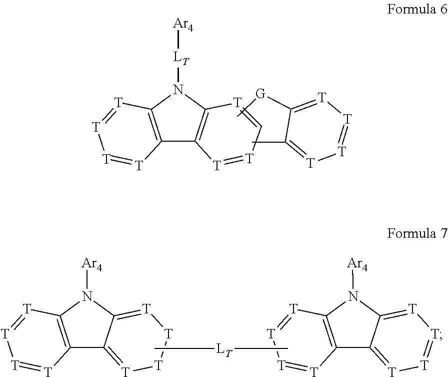

wherein
G is, at each occurrence identically or differently, selected from C(R_{g})₂, NR_{g}, O or S;
L_{T} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or a combination thereof;
T is, at each occurrence identically or differently, selected from C, CRₜ or N;
Rₜ and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a sulfanyl group, a hydroxyl group, a sulfinyl group, a sulfonyl group, a phosphino group and combinations thereof; Ar₄ is, at each occurrence identically or differently, selected from substituted or unsubstituted aryl having 6 to 30 carbon atoms, substituted or unsubstituted heteroaryl having 3 to 30 carbon atoms or a combination thereof;
in Formula 6, adjacent substituents Rₜ, R_{g} can be optionally joined to form a ring; and
in Formula 7, adjacent substituents Rₜ can be optionally joined to form a ring.

According to an embodiment of the present disclosure, the second host compound has a structure represented by one of Formula 6-a to Formula 6-f and Formula 7-a to Formula 7-j:

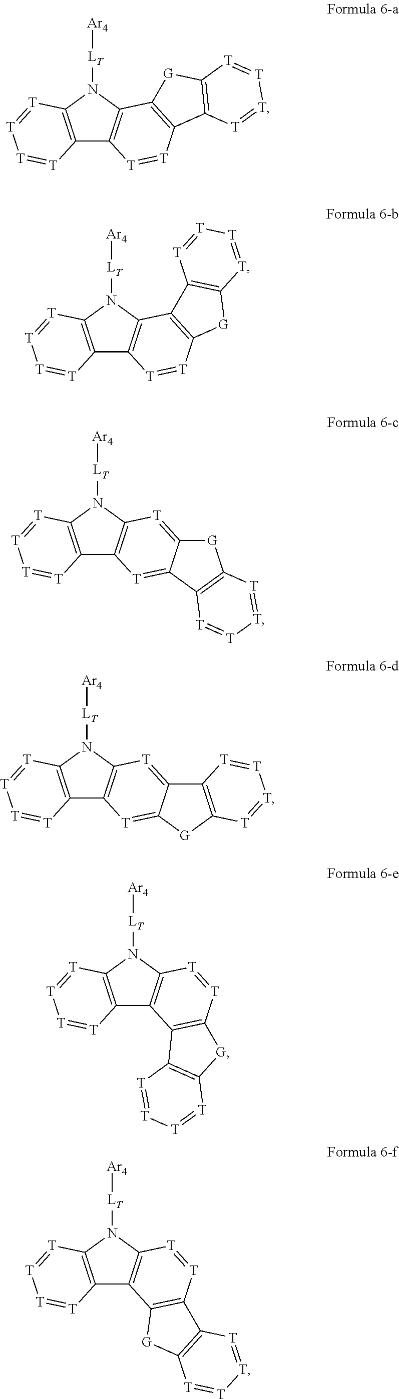

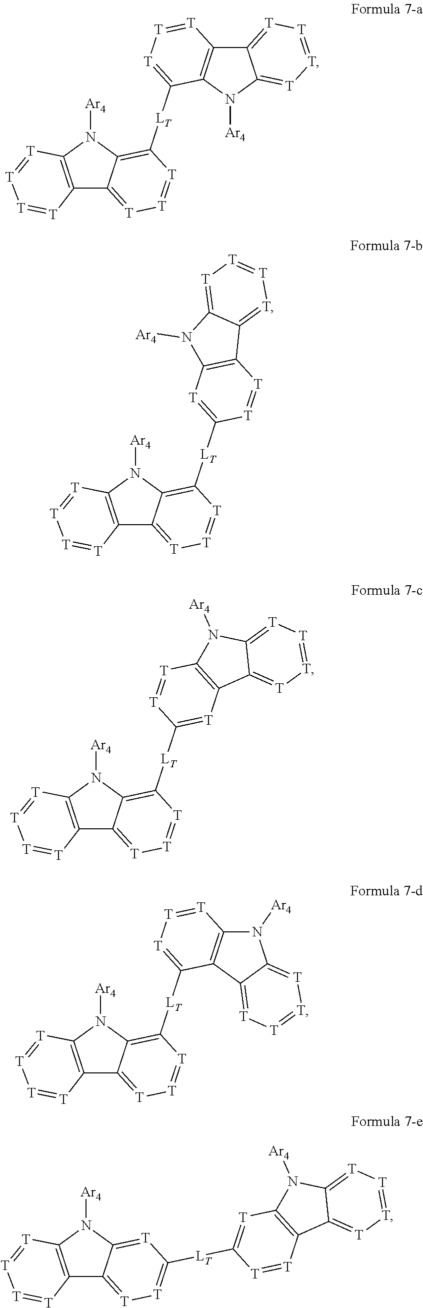

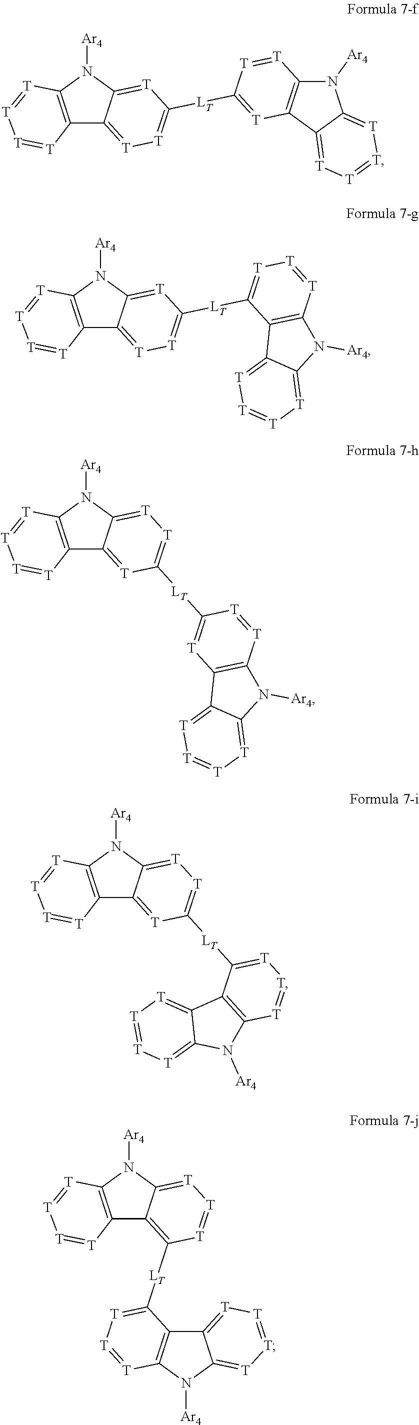

wherein in Formula 6-a to Formula 6-f, T, G, L_{T} and Ar₄ are defined the same as in Formula 6; and
wherein in Formula 7-a to Formula 7-j, T, L_{T} and Ar₄ are defined the same as in Formula 7.

In the present disclosure, the expression that “adjacent substituents Rₜ can be optionally joined to form a ring” is intended to mean that any one or more of groups of any two adjacent substituents Rₜ can be joined to form a ring. Obviously, it is also possible that none of these substituents are joined to form a ring.

In the present disclosure, the expression that “adjacent substituents Rₜ, R_{g} can be optionally joined to form a ring” is intended to mean that any one or more of groups of adjacent substituents, such as two substituents Rₜ, two substituents R_{g} and substituents Rₜ and R_{g}, can be joined to form a ring. Obviously, it is also possible that none of these substituents are joined to form a ring.

According to an embodiment of the present disclosure, in the electroluminescent device, the metal complex is doped in the first host compound and the second host compound, and the weight of the metal complex accounts for 1% to 30% of the total weight of the light-emitting layer.

According to an embodiment of the present disclosure, in the electroluminescent device, the metal complex is doped in the first host compound and the second host compound, and the weight of the metal complex accounts for 3% to 13% of the total weight of the light-emitting layer.

According to another embodiment of the present disclosure, further disclosed is a compound combination comprising a metal complex whose specific structure is described in any one of the preceding embodiments.

Combination with Other Materials

The materials described in the present disclosure for a particular layer in an organic light-emitting device can be used in combination with various other materials present in the device. The combinations of these materials are described in more detail in U.S. Pat. App. No. 20160359122 at paragraphs 0132-0161, which is incorporated by reference herein in its entirety.

The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art.

As the persons skilled in the art are aware of the above-mentioned equipment use, test methods and other related contents, the inherent data of the sample can be obtained with certainty and without influence, so the above related contents are not further described in this patent.

### Material Synthesis Example

The method for preparing a compound in the present disclosure is not limited herein.

Typically, the following compounds are used as examples without limitation, and synthesis routes and preparation methods thereof are described below.

### Synthesis Example 1: Synthesis of Metal Complex 134

Step 1:

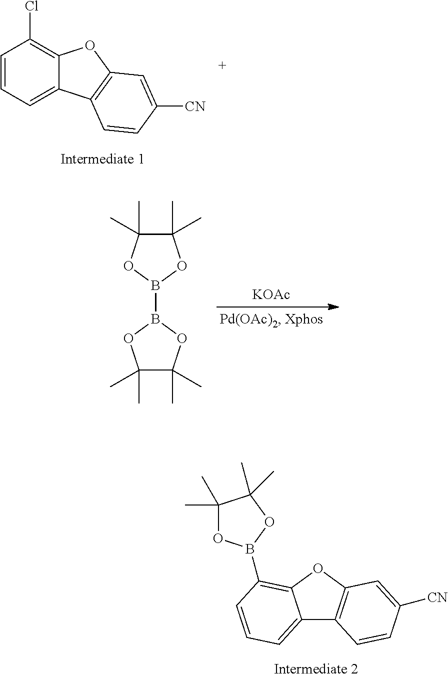

Intermediate 1 (15 g, 60.7 mmol), B₂pin₂ (16.9 g, 66.8 mmol), Pd(OAc)₂ (0.41 g, 1.8 mmol), Xphos (1.7 g, 3.6 mmol), KOAc (8.9 g, 91 mmol) and dioxane (300 mL) were added in sequence to a dry 1000 mL round-bottom flask and heated to reflux for 12 h under N₂ protection. The reaction solution was cooled to obtain the crude product of Intermediate 2, which was directly used for the subsequent reaction.

Step 2:

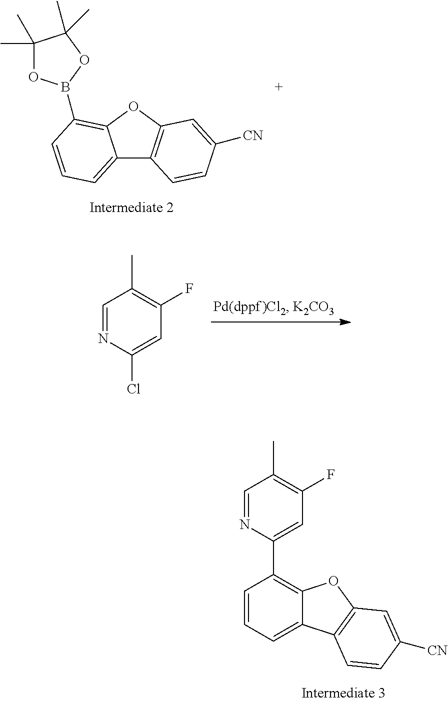

2-Chloro-4-fluoro-5-methylpyridine (9.9 g, 67.9 mmol), Pd(dppf)Cl₂ (1.78 g, 2.4 mmol), K₂CO₃ (12.6 g, 91 mmol) and water (100 mL) were added to the crude product in step 1. The reaction solution was heated to reflux for 12 h under N₂ protection. The reaction solution was cooled and extracted with DCM. The organic phases were collected, subjected to rotary evaporation under reduced pressure to remove the solvent, and purified through column chromatography to obtain Intermediate 3 (15.7 g, with a yield of 85.8%).

Step 3:

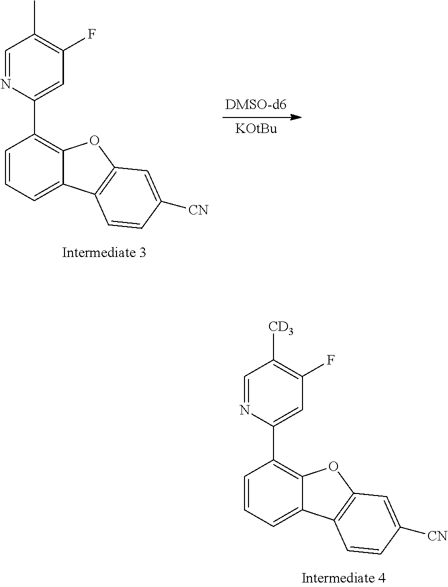 [SMILES: Cc1cnc(-c2cccc3c2oc2cc(C#N)ccc23)cc1F ; [2H]C([2H])([2H])c1cnc(-c2cccc3c2oc2cc(C#N)ccc23)cc1F ; "KOtBu"]

Intermediate 3 (15.7 g, 51 mmol), potassium t-butoxide (0.58 g, 5.2 mmol) and DMSO-d6 (90 mL) were added in sequence to a dry 250 mL round-bottom flask and heated to react overnight at 100° C. under N₂ protection. After the reaction was completed, the reaction solution was cooled and extracted with DCM and saturated brine. The organic phases were collected, subjected to rotary evaporation under reduced pressure to remove the solvent, and purified through column chromatography to obtain Intermediate 4 (8.2 g, with a yield of 52.6%).

Step 4:

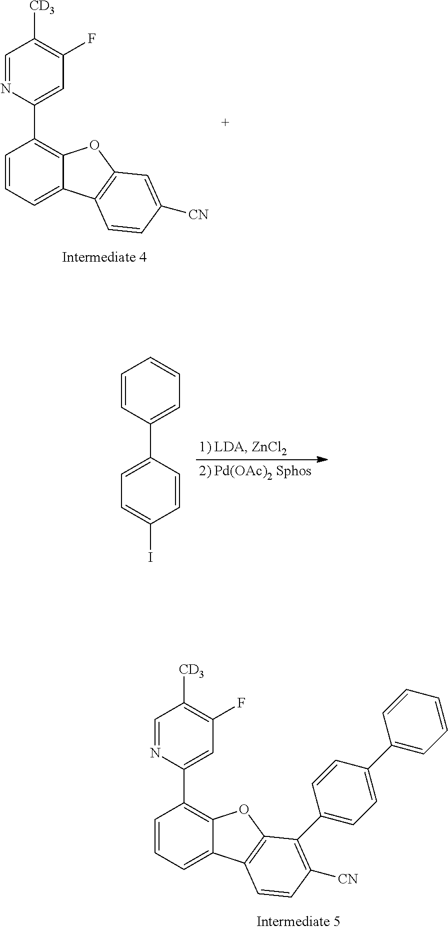

Intermediate 4 (4.4 g, 14.4 mmol) was added in sequence to a dry 500 mL round-bottom flask, dissolved in 150 mL of THF, cooled to −78° C., added with LDA (8.7 mL, 17.3 mmol), reacted for 1.5 h, and then added with ZnCl₂ (10.8 mL, 10.8 mmol), and reacted for 0.5 h. Pd(OAc)₂ (0.13 g, 0.58 mmol), Sphos (0.47 g, 1.1 mmol) and 4-iodo-1,1′-biphenyl (3.82 g, 18.7 mmol) were added. The reaction was heated to room temperature and performed overnight. After the reaction was completed, the reaction was quenched with a saturated ammonium chloride solution, and extracted with EA. The organic phases were collected, subjected to rotary evaporation under reduced pressure to remove the solvent, and purified through column chromatography to obtain Intermediate 5 (3.0 g, with a yield of 45.6%).

Step 5:

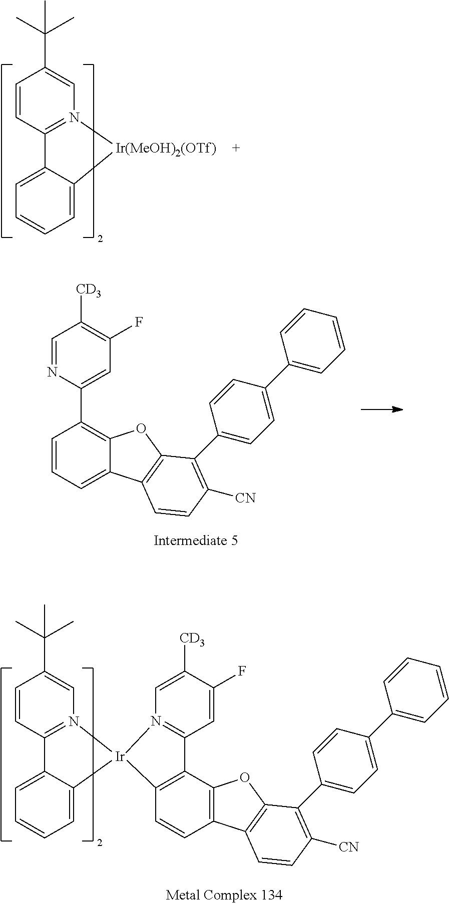

Intermediate 5 (2.2 g, 4.8 mmol), an iridium complex (3.0 g, 3.7 mmol), 2-ethoxyethanol (30 mL) and DMF (30 mL) were added in sequence to a dry 250 mL round-bottom flask and heated to react for 144 h at 95° C. under N₂ protection. The reaction was cooled and filtered through Celite. The yellow solids on the Celite were washed twice with methanol and n-hexane respectively and dissolved with dichloromethane. The organic phases were collected, subjected to rotary evaporation under reduced pressure to remove the solvent, and purified through column chromatography to obtain Metal Complex 134 as a yellow solid (0.64 g, with a yield of 16.2%). The product structure was confirmed as the target product with a molecular weight of 1069.4.

### Synthesis Example 2: Synthesis of Metal Complex 150

Step 1:

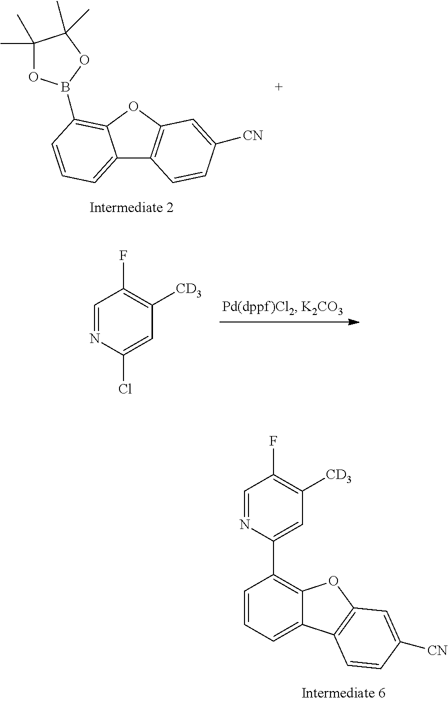 [SMILES: CC1(C)OB(c2cccc3c2oc2cc(C#N)ccc23)OC1(C)C ; [2H]C([2H])([2H])c1cc(Cl)ncc1F ; [2H]C([2H])([2H])c1cc(-c2cccc3c2oc2cc(C#N)ccc23)ncc1F]

2-Chloro-4-deuteromethyl-5-fluoropyridine (2.6 g, 17.8 mmol), Pd(dppf)Cl₂ (0.47 g, 0.6 mmol), K₂CO₃ (3.4 g, 24.3 mmol) and water (20 mL) were added to the crude product of Intermediate 2. The reaction solution was heated to reflux for 12 h under N₂ protection. The reaction solution was cooled and extracted with DCM. The organic phases were collected, subjected to rotary evaporation under reduced pressure to remove the solvent, and purified through column chromatography to obtain Intermediate 6 (3.44 g, with a yield of 69.6%).

Step 2:

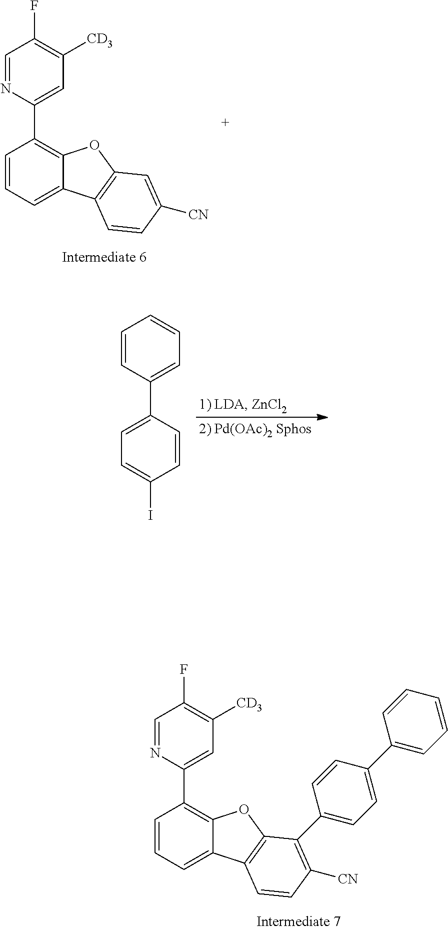

Intermediate 6 (3.44 g, 11.3 mmol) was added in sequence to a dry 500 mL round-bottom flask, dissolved in 200 mL of THF, cooled to −78° C., added with LDA (8.5 mL, 8.5 mmol), reacted for 1.5 h, and then added with ZnCl₂ (6.8 mL, 13.5 mmol), and reacted for 0.5 h. Pd(OAc)₂ (0.10 g, 0.45 mmol), Sphos (0.37 g, 0.90 mmol) and 4-iodo-1,1′-biphenyl (4.1 g, 14.7 mmol) were added. The reaction was heated to room temperature and performed overnight. After the reaction was completed, the reaction was quenched with a saturated ammonium chloride solution, and extracted with EA. The organic phases were collected, subjected to rotary evaporation under reduced pressure to remove the solvent, and purified through column chromatography to obtain Intermediate 7 (2.1 g, with a yield of 41.10%).

Step 3:

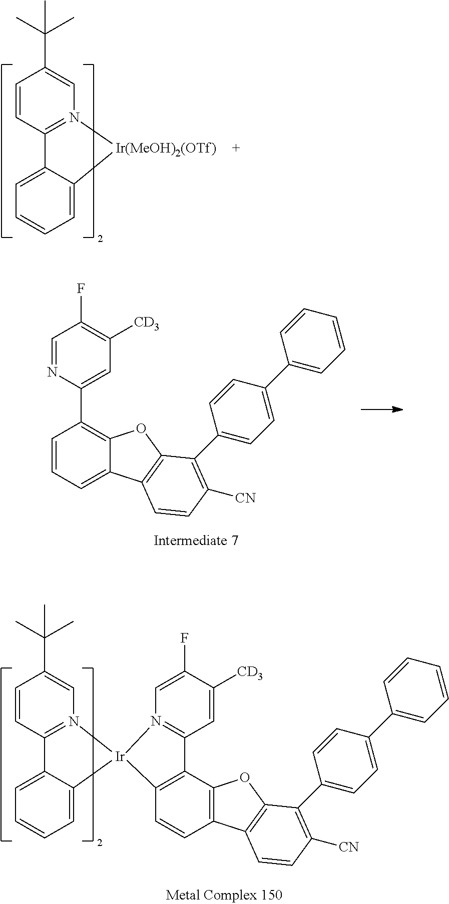

Intermediate 7 (1.2 g, 2.6 mmol), an iridium complex (2.0 g, 2.4 mmol), 2-ethoxyethanol (30 mL) and DMF (30 mL) were added in sequence to a dry 250 mL round-bottom flask and heated to react for 144 h at 95° C. under N₂ protection. The reaction was cooled and filtered through Celite. The yellow solids on the Celite were washed twice with methanol and n-hexane respectively and dissolved with dichloromethane. The organic phases were collected, subjected to rotary evaporation under reduced pressure to remove the solvent, and purified through column chromatography to obtain Metal Complex 150 as a yellow solid (0.21 g, with a yield of 8.2%). The product structure was confirmed as the target product with a molecular weight of 1069.4.

Those skilled in the art will appreciate that the above preparation methods are merely exemplary. Those skilled in the art can obtain other compound structures of the present disclosure through the modifications of the preparation methods.

### Device Example 1

Firstly, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. The organic layers specified below were sequentially deposited through vacuum thermal evaporation on the ITO anode at a rate of 0.2 to 2 Angstroms per second and a vacuum degree of about 10⁻⁸ Torr. Compound HI was used as a hole injection layer (HIL). Compound HT was used as a hole transporting layer (HTL). Compound H1 was used as an electron blocking layer (EBL). Then, Metal Complex 134 of the present disclosure was doped in Compound H1 and Compound H2, and was codeposited for use as an emissive layer (EML). On the EML, Compound H3 was used as a hole blocking layer (HBL). Then, Compound ET and 8-hydroxyquinolinolato-lithium (Liq) were co-deposited for use as an electron transporting layer (ETL). Finally, 8-hydroxyquinolinolato-lithium (Liq) was deposited as an electron injection layer with a thickness of 1 nm and Al was deposited as a cathode with a thickness of 120 nm. The device was transferred back to the glovebox and encapsulated with a glass lid to complete the device.

### Device Example 2

The implementation mode in Device Example 2 was the same as that in Device Example 1, except that in the EML, Metal Complex 134 of the present disclosure was replaced with Metal Complex 150.

### Device Comparative Example 1

The implementation mode in Device Comparative Example 1 was the same as that in Device Example 1, except that in the EML, Metal Complex 134 of the present disclosure was replaced with Compound GD1.

### Device Comparative Example 2

The implementation mode in Device Comparative Example 2 was the same as that in Device Example 1, except that in the EML, Metal Complex 134 of the present disclosure was replaced with Compound GD2.

### Device Comparative Example 3

The implementation mode in Device Comparative Example 3 was the same as that in Device Example 1, except that in the EML, Metal Complex 134 of the present disclosure was replaced with Compound GD3.

Detailed structures and thicknesses of layers of the devices are shown in the following table. A layer using more than one material is obtained by doping different compounds at their weight ratio as recorded.

TABLE 1
Device structures of Device Examples 1 and 2 and Comparative Examples 1 to 3

| Device ID | HIL | HTL | EBL | EML | HBL | ETL |
|---|---|---|---|---|---|---|
| Example 1 | Compound | Compound | Compound | Compound | Compound | Compound |
| | HI (100 Å) | HT (350 Å) | H1 (50 Å) | H1:Compound | H3 (50 Å) | ET:Liq |
| | | | | H2:Metal | | (40:60) |
| | | | | Complex 134 | | (350 Å) |
| | | | | (47:47:6) | | |
| | | | | (400 Å) | | |
| Example 2 | Compound | Compound | Compound | Compound | Compound | Compound |
| | HI (100 Å) | HT (350 Å) | H1 (50 Å) | H1:Compound | H3 (50 Å) | ET:Liq |
| | | | | H2:Metal | | (40:60) |
| | | | | Complex 150 | | (350 Å) |
| | | | | (47:47:6) | | |
| | | | | (400 Å) | | |
| Comparative | Compound | Compound | Compound | Compound | Compound | Compound |
| Example 1 | HI (100 Å) | HT (350 Å) | H1 (50 Å) | H1:Compound | H3 (50 Å) | ET:Liq |
| | | | | H2:Compound | | (40:60) |
| | | | | GD1 (47:47:6) | | (350 Å) |
| | | | | (400 Å) | | |
| Comparative | Compound | Compound | Compound | Compound | Compound | Compound |
| Example 2 | HI (100 Å) | HT (350 Å) | H1 (50 Å) | H1:Compound | H3 (50 Å) | ET:Liq |
| | | | | H2:Compound | | (40:60) |
| | | | | GD2 (47:47:6) | | (350 Å) |
| | | | | (400 Å) | | |
| Comparative | Compound | Compound | Compound | Compound | Compound | Compound |
| Example 3 | HI (100 Å) | HT (350 Å) | H1 (50 Å) | H1:Compound | H3 (50 Å) | ET:Liq |
| | | | | H2:Compound | | (40:60) |
| | | | | GD3 (47:47:6) | | (350 Å) |
| | | | | (400 Å) | | |

The materials used in the devices have the following structures:

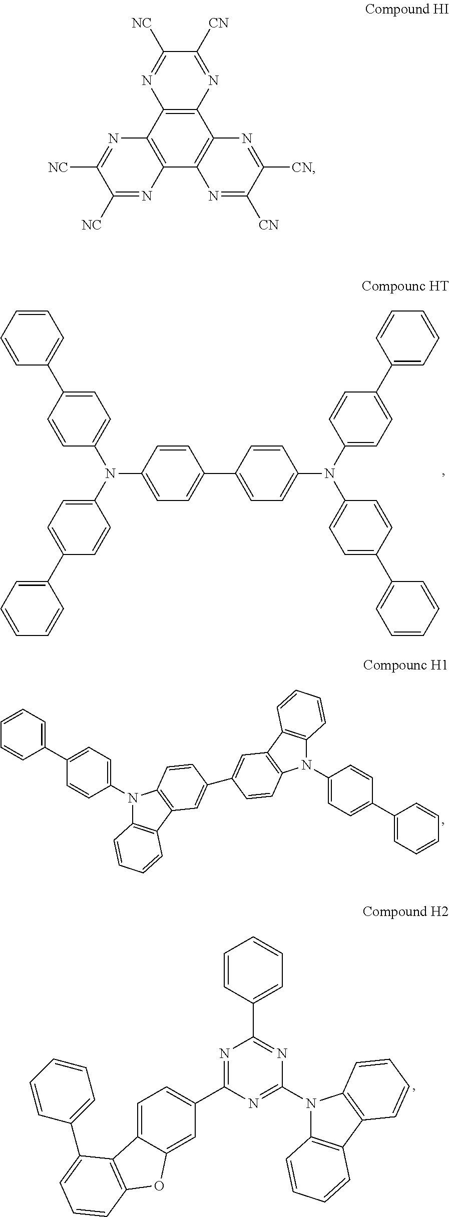 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-c3ccc4c(c3)oc3cccc(-c5ccccc5)c34)nc(-n3c4ccccc4c4ccccc43)n2)cc1]

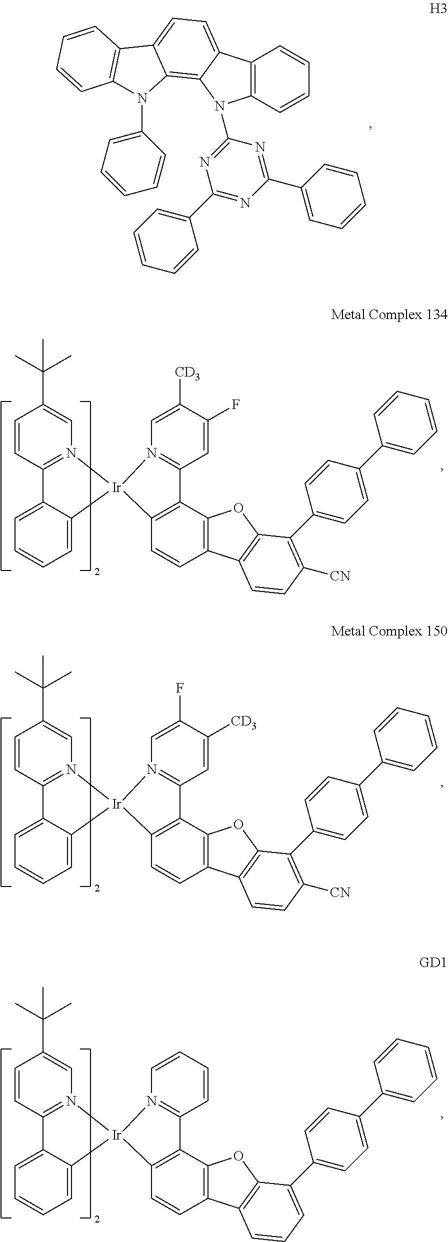

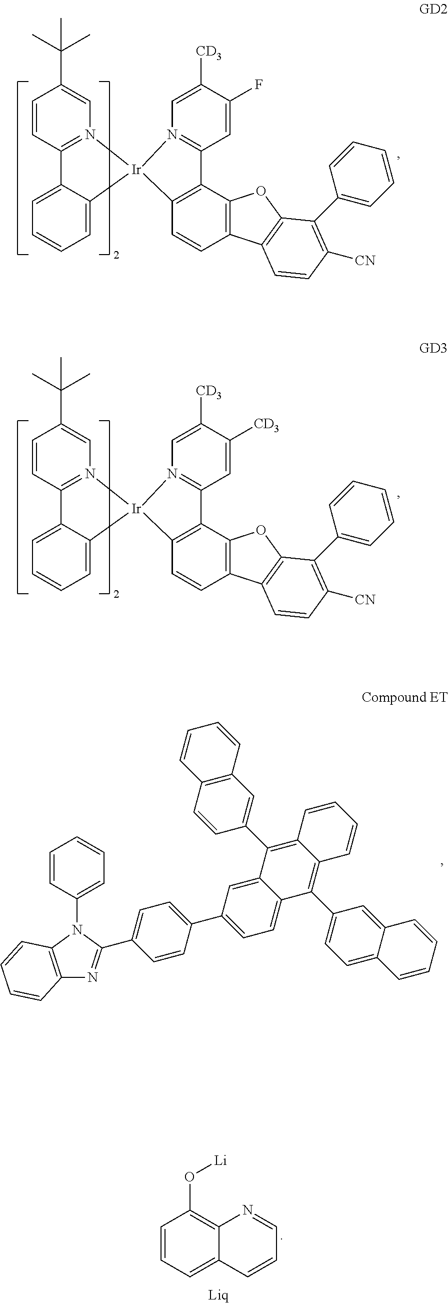

The current-voltage-luminance (IVL) characteristics of the devices were measured. The CIE data, maximum emission wavelength (λₘₐₓ), full width at half maximum (FWHM), voltage (V), current efficiency (CE), power efficiency (PE) and external quantum efficiency (EQE) of each device were measured at 1000 cd/m². The data was recorded and shown in Table 2.

TABLE 2
Device data of Device Examples 1 and
2 and Comparative Examples 1 to 3

| | | | | Vol- | | | |
|---|---|---|---|---|---|---|---|
| | CIE | λₘₐₓ | FWHM | tage | CE | PE | EQE |
| Device ID | (x, y) | (nm) | (nm) | (V) | (cd/A) | (lm/W) | (%) |
| Example 1 | (0.320, | 526 | 32.0 | 2.63 | 108 | 129 | 27.90 |
| | 0.648) | | | | | | |
| Example 2 | (0.317, | 526 | 33.2 | 2.65 | 109 | 130 | 27.99 |
| | 0.651) | | | | | | |
| Comparative | (0.357, | 530 | 60.3 | 3.13 | 98 | 98 | 25.42 |
| Example 1 | 0.620) | | | | | | |
| Comparative | (0.318, | 525 | 32.3 | 2.80 | 104 | 116 | 26.52 |
| Example 2 | 0.649) | | | | | | |
| Comparative | (0.303, | 524 | 29.9 | 2.80 | 93 | 104 | 23.88 |
| Example 3 | 0.657) | | | | | | |

### DISCUSSION

Table 2 shows the device performance of the metal complexes of the present disclosure and comparative metal complexes. The light-emitting materials used in the devices in Example 1, Example 2 and Comparative Example 1 are Metal Complex 134 of the present disclosure, Metal Complex 150 of the present disclosure and Metal Complex GD1 not provided in the present disclosure, respectively, and their differences mainly lie in different substituents on the pyridine group of the ligand Lₐ and whether a cyano substituent exists on the dibenzofuran group. Compared with Comparative Example 1, Example 1 and Example 2 have the FWHM narrowed by 28.3 nm and 27.1 nm respectively, the driving voltages reduced by 0.5 V and 0.48 V respectively, the CE increased by 10.2% and 11.2% respectively, the PE increased by 31.6% and 32.6% respectively, the EQE increased by 9.7% and 10.1% respectively and the maximum emission wavelengths blue-shifted by 4 nm. The above indicates that the metal complex of the present disclosure comprising the ligand Lₐ having an aza six-membered ring-(6-5-6)-fused ring skeleton structure with a fluorine substitution at a particular position of the aza six-membered ring and a cyano substitution in the (6-5-6)-fused ring structure, when applied to the device, can greatly improve the performance of the device, for example, reduce the driving voltage and improve the device efficiency (CE, PE and EQE) and can greatly improve the luminescence saturation of the device and significantly improve the overall performance of the device.

The light-emitting materials used in the devices in Example 1 and Comparative Example 2 are Metal Complex 134 of the present disclosure and Metal Complex GD2 not provided in the present disclosure, respectively, and their difference only lies in different substituents Ar in the dibenzofuran group of the ligand Lₐ. Compared with Comparative Example 2, Example 1 has similar CE and FWHM, the driving voltage reduced by 0.17 V and the PE and EQE increased by 11.2% and 5.2% respectively. The above indicates that the metal complex of the present disclosure comprising the ligand Lₐ having the aza six-membered ring-(6-5-6)-fused ring skeleton structure with an Ar substitution of the present disclosure in the (6-5-6)-fused ring structure, when applied to the device, can reduce the driving voltage of the device, greatly improve the device efficiency (PE and EQE) and significantly improve the overall performance of the device.

The light-emitting materials used in the devices in Example 1, Example 2 and Comparative Example 3 are Metal Complex 134 of the present disclosure, Metal Complex 150 of the present disclosure and Metal Complex GD3 not provided in the present disclosure, respectively, and their differences mainly lie in the replacement of a substituent F on the pyridine group of the ligand Lₐ with CD₃ and different substituents Ar on the benzofuran group. Compared with Comparative Example 3, Example 1 and Example 2 have the driving voltages reduced by 0.17 V and 0.15 V respectively, the CE increased by 16.1% and 17.2% respectively, the PE increased by 24% and 25% respectively and the EQE increased by 16.8% and 17.2% respectively though the FWHM is 2.1 nm and 3.3 nm wider. The above indicates that the metal complex of the present disclosure comprising the ligand Lₐ having the aza six-membered ring-(6-5-6)-fused ring skeleton structure with the fluorine substitution at the particular position of the aza six-membered ring and the Ar substitution of the present disclosure in the (6-5-6)-fused ring structure, when applied to the device, can greatly improve the performance of the device, for example, reduce the driving voltage and improve the device efficiency (CE, PE and EQE) and significantly improve the overall performance of the device.

The above indicates that the metal complex of the present disclosure comprising the ligand Lₐ having the aza six-membered ring-(6-5-6)-fused ring skeleton structure with the fluorine substitution at the particular position of the aza six-membered ring and the Ar and specific substitutions in the (6-5-6)-fused ring structure of the present disclosure, when applied to the device, can greatly improve the performance of the device, for example, reduce the driving voltage and improve the device efficiency (CE, PE and EQE) and significantly improve the overall performance of the device.

Geometric optimization calculations were performed by using Gaussian 09 software and the following calculation methods: a B3LYP hybrid functional method and a CEP-31G basis set including effective nuclear potential so that the HOMO energy levels and LUMO energy levels of Metal Complex 133, Metal Complex 149, and Metal Complexes GD4 and GD5 not provided in the present disclosure were calculated separately, and their HOMO-LUMO energy level differences E_{g} were calculated. Their differences only lie in different positions of the F substitution on the pyridine group of the ligand Lₐ.

DFT calculation results are recorded and shown in Table 3.

TABLE 3
DFT results of Metal Complexes 133, 149, GD4 and GD5

| Compound No. | HOMO (eV) | LUMO (eV) | E_{g} (eV) |
|---|---|---|---|
| Metal Complex | −5.11 | −1.91 | 3.20 |
| 133 | | | |
| Metal Complex | −5.11 | −1.93 | 3.18 |
| 149 | | | |
| GD4 | −5.09 | −1.98 | 3.11 |
| GD5 | −5.01 | −1.97 | 3.04 |

The metal complexes subjected to DFT calculations have the following structures:

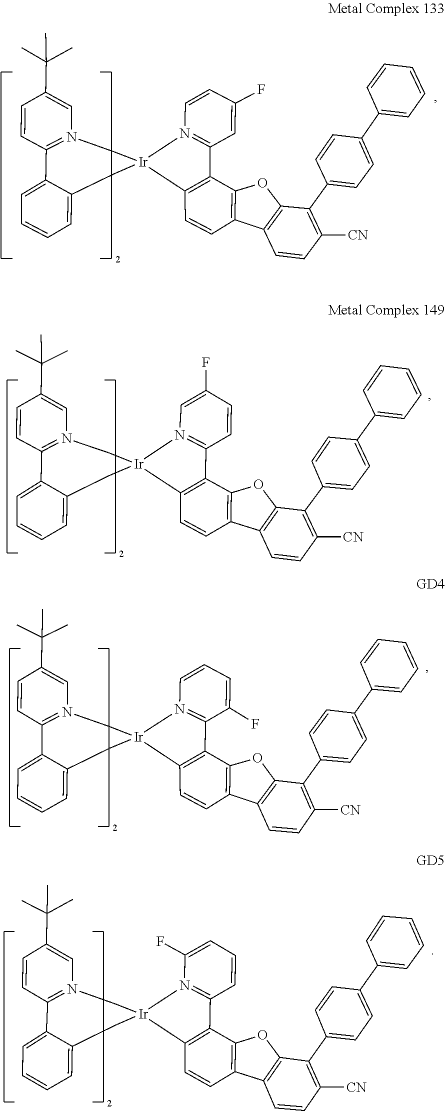

### DISCUSSION

Table 3 shows the DFT calculation results of the metal complexes of the present disclosure and comparative metal complexes. The HOMO-LUMO energy level differences of Metal Complex 133 and Metal Complex 149 of the present disclosure are 3.20 eV and 3.18 eV, respectively. The HOMO-LUMO energy level differences of Metal Complexes GD4 and GD5 not provided in the present disclosure are only 3.11 eV and 3.04 eV, respectively. A higher energy level difference indicates that the excitons generated by the electroluminescent device can return to a ground state in the form of higher energy to achieve a more blue-shifted emission spectrum, which is conducive to achieving more saturated green light emission and is of great significance for us to achieve BT2020 wide color gamut. The above results indicate that the metal complex of the present disclosure comprising the ligand Lₐ may be used as the light-emitting material in the light-emitting layer of the electroluminescent device and the metal complex of the present disclosure can provide the higher luminescence efficiency, the narrower FWHM and the more saturated green light spectrum and can significantly improve the overall performance of the device.

It is to be understood that various embodiments described herein are merely examples and not intended to limit the scope of the present disclosure. Therefore, it is apparent to the persons skilled in the art that the present disclosure as claimed may include variations of specific embodiments and preferred embodiments described herein. Many of materials and structures described herein may be substituted with other materials and structures without departing from the spirit of the present disclosure. It is to be understood that various theories as to why the present disclosure works are not intended to be limitative.

What is claimed is:

1. A metal complex, comprising a metal M and a ligand Lₐ coordinated to the metal M, wherein Lₐ has a structure represented by Formula 1: 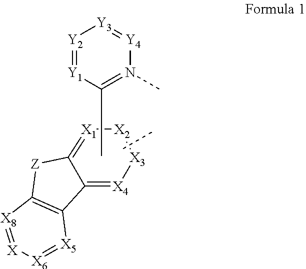
wherein
the metal M is selected from a metal with a relative atomic mass greater than 40;
Z is selected from the group consisting of O, S, Se, NR, CRR, SiRR and GeRR, wherein when two R are present at the same time, the two R are the same or different;
Y₁ to Y₄ are, at each occurrence identically or differently, selected from CR_{y} or N;
Y₂ and/or Y₃ are selected from CR_{y}, and the R_{y} is fluorine;
X₁ to X₈ are, at each occurrence identically or differently, selected from C, CRₓ, CAr or N;
at least two of X₁ to X₄ are C, wherein one C is joined to the nitrogen-containing six-membered ring shown in Formula 1 and another C is joined to the metal through a metal-carbon bond;
at least one of X₁ to X₈ is selected from CRₓ, and the Rₓ is cyano or fluorine;
at least one of X₁ to X₈ is selected from CAr;
Ar has a structure represented by Formula 2: 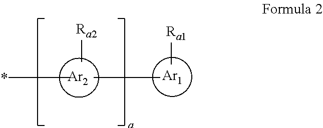
a is selected from 0, 1, 2, 3, 4 or 5;
Rₐ₁ and Rₐ₂ represent, at each occurrence identically or differently, mono-substitution, multiple substitutions or non-substitution;
the ring Ar₁ and the ring Ar₂ are, at each occurrence identically or differently, selected from an aromatic ring having 6 to 30 ring atoms, a heteroaromatic ring having 5 to 30 ring atoms or a combination thereof; and the total number of ring atoms in the ring Ar₁ and the ring Ar₂ is greater than or equal to 8;
R, Rₓ, R_{y}, Rₐ₁ and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“ [symbol] ” represents a position where Formula 2 is joined;
adjacent substituents R, Rₓ, R_{y}, Rₐ₁ and Rₐ₂ can be optionally joined to form a ring; and
“ [symbol] ” in Formula 1 represents being joined to the metal M.

2. The metal complex according to claim 1, wherein Lₐ has a structure represented by one of Formulas 1a to 1f: 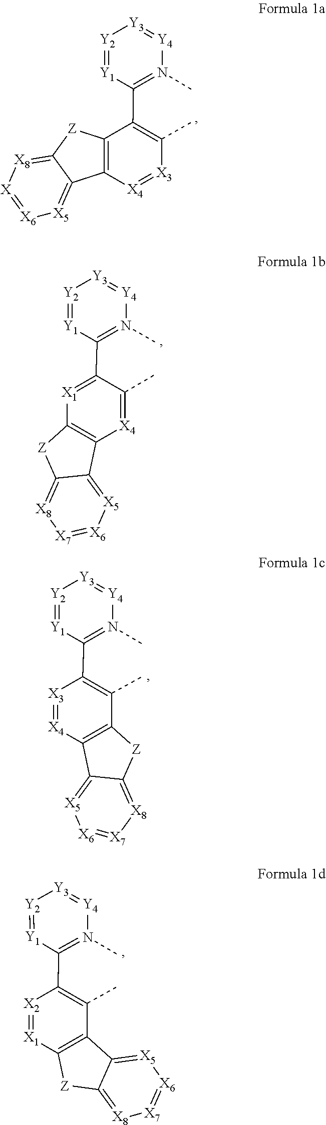 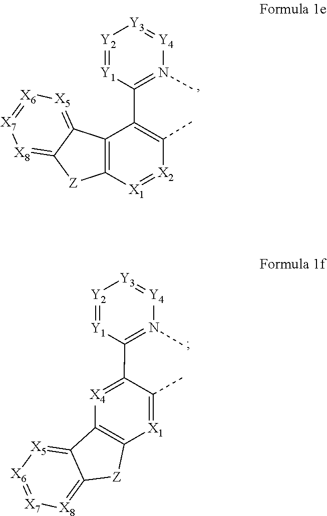
wherein
Z is selected from the group consisting of O, S, Se, NR, CRR, SiRR and GeRR, wherein when two R are present at the same time, the two R are the same or different;
Y₁ to Y₄ are, at each occurrence identically or differently, selected from CR_{y} or N;
at least one of Y₂ and Y₃ is selected from CR_{y}, and R_{y} is fluorine;
X₁ to X₈ are, at each occurrence identically or differently, selected from CRₓ, CAr or N;
at least one of X₁ to X₈ is selected from CRₓ, and Rₓ is cyano or fluorine;
at least one of X₁ to X₈ is selected from CAr;
Ar has a structure represented by Formula 2: 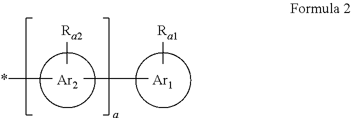
a is selected from 0, 1, 2, 3, 4 or 5;
Rₐ₁ and Rₐ₂ represent, at each occurrence identically or differently, mono-substitution, multiple substitutions or non-substitution;
the ring Ar₁ and the ring Ar₂ are, at each occurrence identically or differently, selected from an aromatic ring having 6 to 30 ring atoms, a heteroaromatic ring having 5 to 30 ring atoms or a combination thereof; and the total number of ring atoms in the ring Ar₁ and the ring Ar₂ is greater than or equal to 8;
R, Rₓ, R_{y}, Rₐ₁ and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
“ [symbol] ” represents a position where Formula 2 is joined;
adjacent substituents R, Rₓ, R_{y}, Rₐ₁ and Rₐ₂ can be optionally joined to form a ring; and
“ [symbol] ” in Formulas 1a to 1f represents being joined to the metal M.

3. The metal complex according to claim 1, wherein the metal complex has a general formula of M(Lₐ)ₘ(L)ₙ(L_{c})_{q};
wherein
the metal M is selected from a metal with a relative atomic mass greater than 40; preferably, M is, at each occurrence identically or differently, selected from the group consisting of Cu, Ag, Au, Ru, Rh, Pd, Os, Ir and Pt; more preferably, M is, at each occurrence identically or differently, selected from Pt or Ir;
Lₐ, L_{b} and L_{c} are a first ligand, a second ligand and a third ligand coordinated to the metal M, respectively, and Lₐ, L_{b} and L_{c} are the same or different; wherein Lₐ, L_{b} and L_{c} can be optionally joined to form a multidentate ligand;
m is selected from 1, 2 or 3, n is selected from 0, 1 or 2, q is selected from 0, 1 or 2, and m+n+q equals the oxidation state of the metal M; when m is greater than or equal to 2, multiple Lₐ are the same or different; when n is equal to 2, two L_{b} are the same or different; when q is equal to 2, two L_{c} are the same or different;
L_{b} and L_{c} are, at each occurrence identically or differently, selected from a structure represented by any one of the group consisting of: 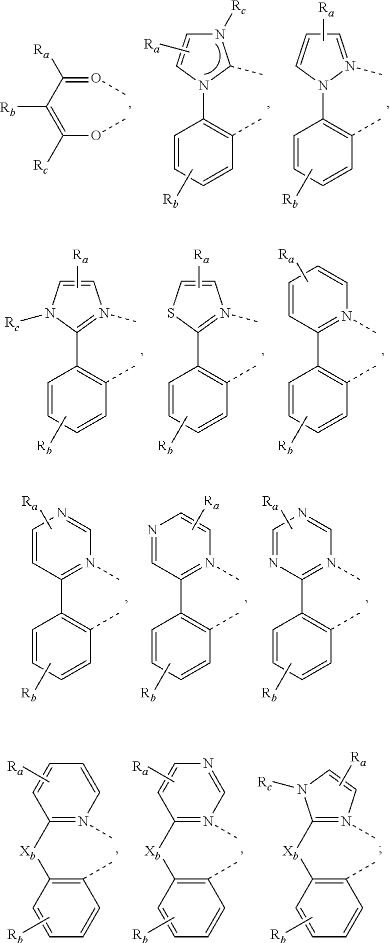
wherein
Rₐ and R_{b} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
Rₐ, R_{b}, R_{c}, R_{N1}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents Rₐ, R_{b}, R_{c}, R_{N1}, R_{C1} and R_{C2} can be optionally joined to form a ring; and
“ [symbol] ” in Le and L_{c} represents being joined to the metal M.

4. The metal complex according to claim 1, wherein the metal complex Ir(Lₐ)ₘ(L_{b})₃₋ₘ has a structure represented by Formula 3: 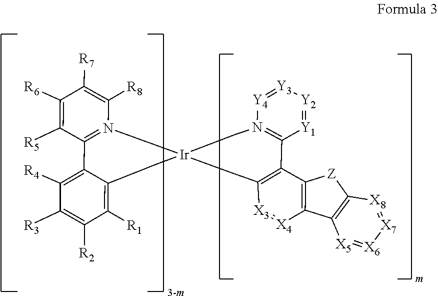
wherein
m is selected from 1, 2 or 3; when m is 1, two Le are the same or different; when m is 2 or 3, multiple Lₐ are the same or different;
Z is selected from the group consisting of O, S, Se, NR, CRR, SiRR and GeRR, wherein when two R are present at the same time, the two R are the same or different;
Y₁ to Y₄ are, at each occurrence identically or differently, selected from CR_{y} or N;
at least one of Y₂ and Y₃ is selected from CR_{y}, and the R_{y} is fluorine;
X₃ to X₈ are, at each occurrence identically or differently, selected from CRₓ, CAr or N;
at least one of X₃ to X₈ is selected from CRₓ, and the Rₓ is cyano or fluorine;
at least one of X₃ to X₈ is selected from CAr;
Ar has a structure represented by Formula 2: 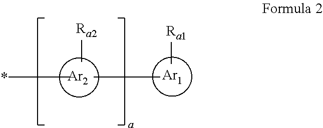
a is selected from 0, 1, 2, 3, 4 or 5;
Rₐ₁ and Rₐ₂ represent, at each occurrence identically or differently, mono-substitution, multiple substitutions or non-substitution;
the ring Ar₁ and the ring Ar₂ are, at each occurrence identically or differently, selected from an aromatic ring having 6 to 30 ring atoms, a heteroaromatic ring having 5 to 30 ring atoms or a combination thereof; and the total number of ring atoms in the ring Ar₁ and the ring Ar₂ is greater than or equal to 8;
R, Rₓ, R_{y}, Rₐ₁, Rₐ₂ and R₁ to R₈ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R, Rₓ, R_{y}, Rₐ₁ and Rₐ₂ can be optionally joined to form a ring; and
adjacent substituents R₁ to R₈ can be optionally joined to form a ring.

5. The metal complex according to claim 1, wherein Z is selected from the group consisting of O and S; preferably, Z is O.

6. The metal complex according to claim 1, wherein a is selected from 0, 1, 2 or 3; preferably, a is 1.

7. The metal complex according to claim 1, wherein Y₁ to Y₄ are, at each occurrence identically or differently, selected from CR_{y}; at least one of Y₂ and Y₃ is selected from CR_{Y}, and the R_{y} is fluorine; and the rest of R_{y} is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof;
preferably, the rest of R_{y} is, at each occurrence identically or differently, selected from the group consisting of: hydrogen, deuterium, substituted or unsubstituted alkyl having 1 to 20 carbon atoms, substituted or unsubstituted cycloalkyl having 3 to 20 ring carbon atoms and combinations thereof;
more preferably, the rest of R_{y} is selected from hydrogen, deuterium, methyl, ethyl, propyl, isopropyl, butyl, t-butyl, isobutyl, pentyl, isopentyl, neopentyl, t-pentyl or a combination thereof; optionally, hydrogens in the above groups are partially or fully deuterated.

8. The metal complex according to claim 1, wherein at least one of Y₂ and Y₃ is CR_{y}, and the R_{y} is fluorine; at least another one of Y₁ to Y₄ is selected from CR_{y}, and the R_{y} is selected from the group consisting of: deuterium, halogen, substituted or unsubstituted alkyl having 1 to 10 carbon atoms, substituted or unsubstituted cycloalkyl having 3 to 10 ring carbon atoms, substituted or unsubstituted aryl having 6 to 15 carbon atoms, substituted or unsubstituted heteroaryl having 3 to 15 carbon atoms and combinations thereof;
preferably, Y₂ and Y₃ are selected from CR_{y}, and one R_{y} is fluorine; and another R_{y} is selected from the group consisting of: deuterium, substituted or unsubstituted alkyl having 1 to 10 carbon atoms, substituted or unsubstituted cycloalkyl having 3 to 10 ring carbon atoms, substituted or unsubstituted aryl having 6 to 15 carbon atoms, substituted or unsubstituted heteroaryl having 3 to 15 carbon atoms and combinations thereof.

9. The metal complex according to claim 4, wherein at least one of X₃ to X₈ is selected from CRₓ, and the Rₓ is cyano or fluorine; and at least one of X₃ to X₈ is selected from CAr;
preferably, at least one of X₅ to X₈ is selected from CRₓ, and the Rₓ is cyano or fluorine; and at least one of X₅ to X₈ is selected from CAr;
more preferably, one of X₇ and X₈ is selected from CRₓ, and the Rₓ is selected from cyano or fluorine; and the other of X₇ and X₈ is selected from CAr.

10. The metal complex according to claim 4, wherein X₃ to X₈ are, at each occurrence identically or differently, selected from CRₓ or CAr, and at least one of X₃ to X₈ is selected from CAr; and at least one of Rₓ is selected from cyano or fluorine, and the rest of Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, cyano and combinations thereof;
preferably, at least one of Rₓ is selected from cyano or fluorine, and the rest of Rₓ is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, substituted or unsubstituted alkylsilyl having 3 to 6 carbon atoms, cyano and combinations thereof;
more preferably, at least one of Rₓ is selected from cyano or fluorine, and the rest of Rₓ is, at each occurrence identically or differently, selected from the group consisting of: hydrogen, deuterium, substituted or unsubstituted alkyl having 1 to 6 carbon atoms, substituted or unsubstituted cycloalkyl having 3 to 6 ring carbon atoms and combinations thereof.

11. The metal complex according to claim 1, wherein Rₐ₁ and Rₐ₂ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, an isocyano group, a hydroxyl group, a sulfanyl group and combinations thereof;
preferably, Rₐ₁ and Rₐ₂ are, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 18 carbon atoms, substituted or unsubstituted heteroaryl having 3 to 18 carbon atoms, substituted or unsubstituted alkylsilyl having 3 to 15 carbon atoms and combinations thereof;
more preferably, Rₐ₁ and Rₐ₂ are, at each occurrence identically or differently, selected from the group consisting of: hydrogen, deuterium, fluorine, methyl, ethyl, propyl, isopropyl, n-butyl, isobutyl, t-butyl, neopentyl, cyclopentyl, cyclohexyl, phenyl, pyridyl, trimethylsilyl and combinations thereof; optionally, hydrogens in the above groups can be partially or fully deuterated.

12. The metal complex according to claim 1, wherein the ring Ar₁ and the ring Ar₂ are, at each occurrence identically or differently, selected from an aromatic ring having 6 to 18 ring atoms, a heteroaromatic ring having 5 to 18 ring atoms or a combination thereof; and the total number of ring atoms in the ring Ar₁ and the ring Ar₂ is greater than or equal to 8 and less than or equal to 30;
preferably, the ring Ar₁ and the ring Ar₂ are, at each occurrence identically or differently, selected from the group consisting of: a benzene ring, a pyridine ring, a pyrimidine ring, a triazine ring, a naphthalene ring, a phenanthrene ring, an anthracene ring, a fluorene ring, a silafluorene ring, a quinoline ring, an isoquinoline ring, a dithiophene ring, a difuran ring, a benzofuran ring, a benzothiophene ring, a dibenzofuran ring, a dibenzothiophene ring, a triphenylene ring, a carbazole ring, an azacarbazole ring, an azafluorene ring, an azasilafluorene ring, an azadibenzofuran ring, an aza-dibenzothiophene ring and combinations thereof; the total number of ring atoms in the ring Ar₁ and the ring Ar₂ is greater than or equal to 8 and less than or equal to 24; optionally, hydrogens in the above groups can be partially or fully deuterated.

13. The metal complex according to claim 1, wherein the ring Ar₁ and the ring Ar₂ are, at each occurrence identically or differently, selected from a benzene ring, a heteroaromatic ring having 5 or 6 ring atoms or a combination thereof;
preferably, the ring Ar₁ and the ring Ar₂ are, at each occurrence identically or differently, selected from a benzene ring or a heteroaromatic ring having 6 ring atoms;
more preferably, the ring Ar₁ and the ring Ar₂ are, at each occurrence identically or differently, selected from a benzene ring.

14. The metal complex according to claim 1, wherein Ar is, at each occurrence identically or differently, selected from the group consisting of: 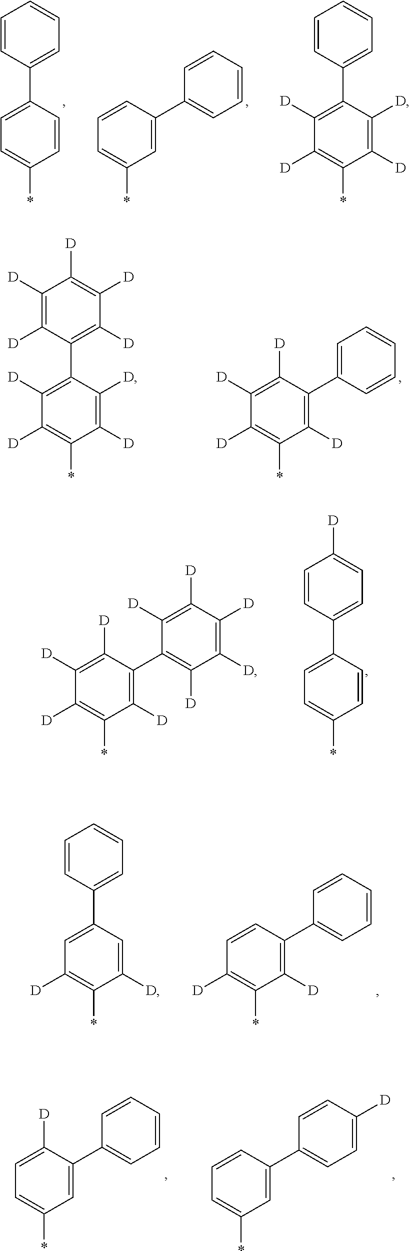 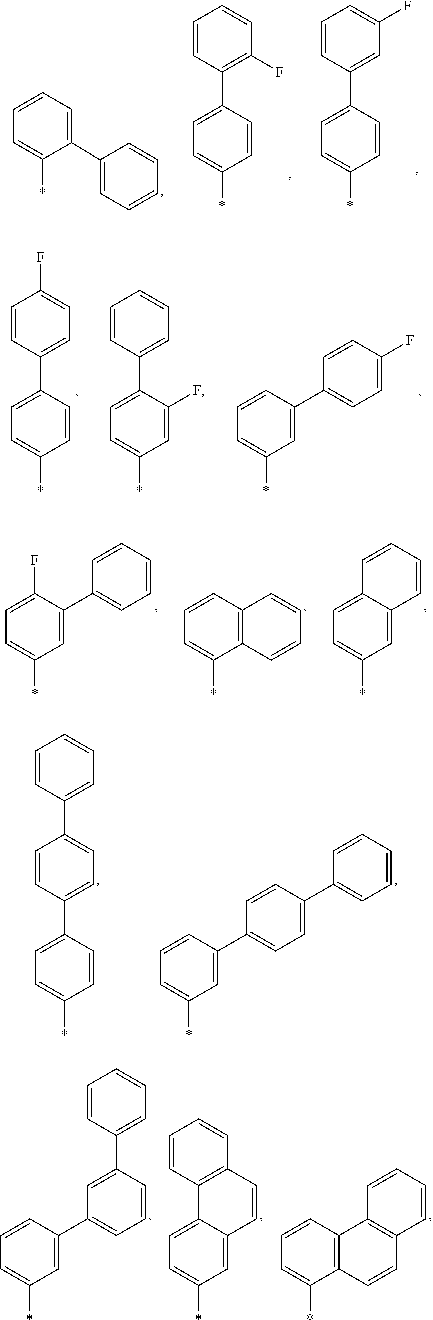 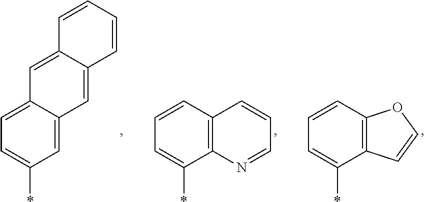 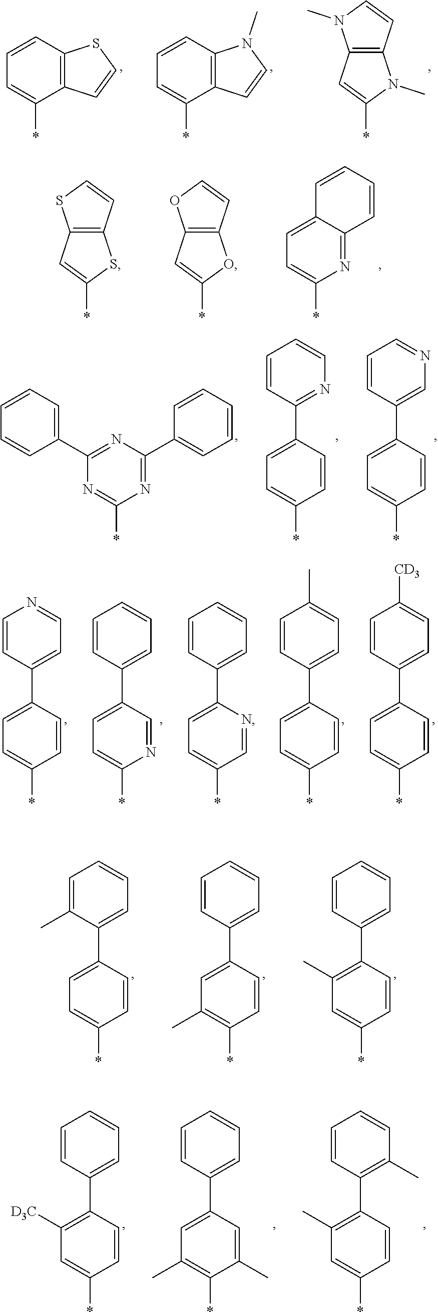 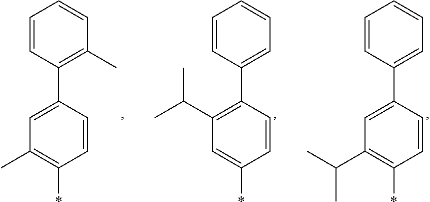 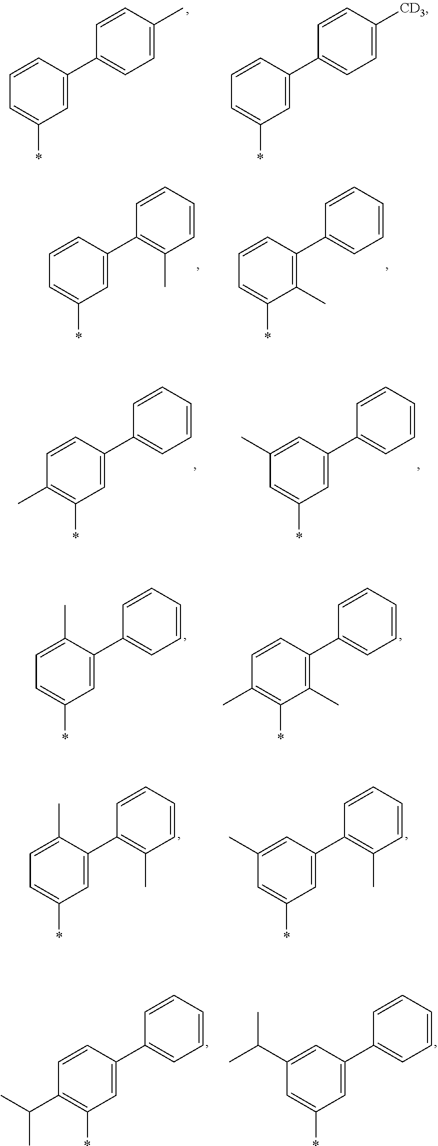 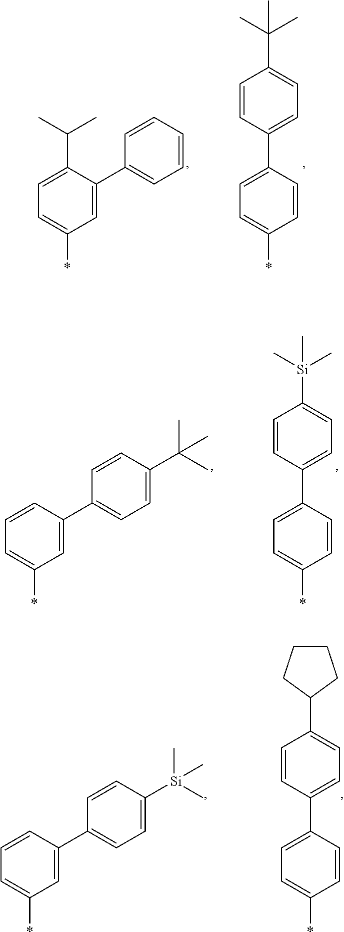 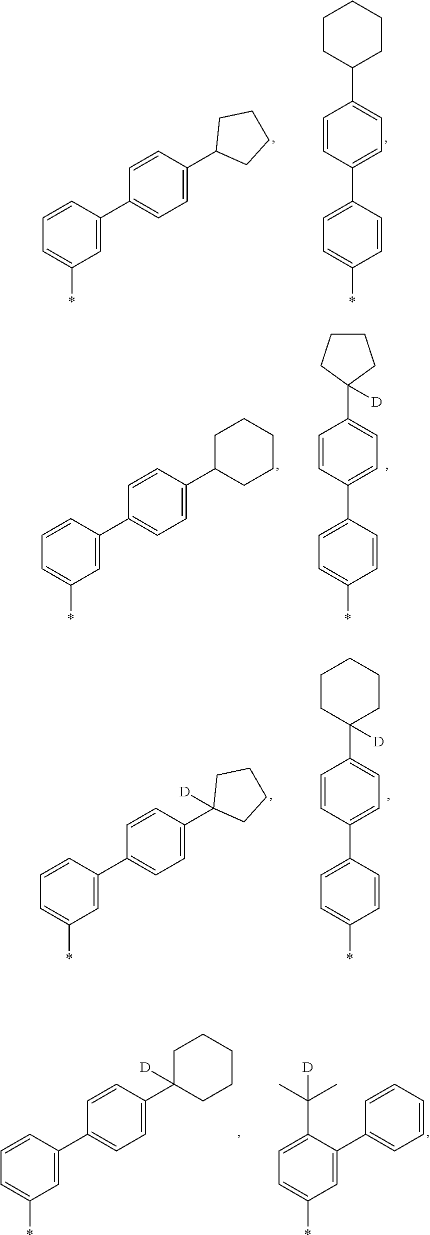 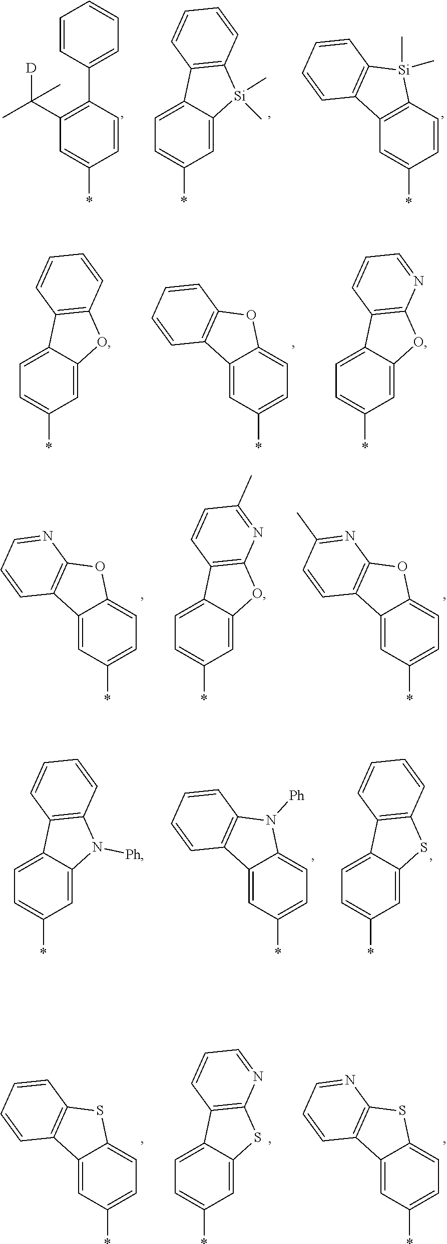 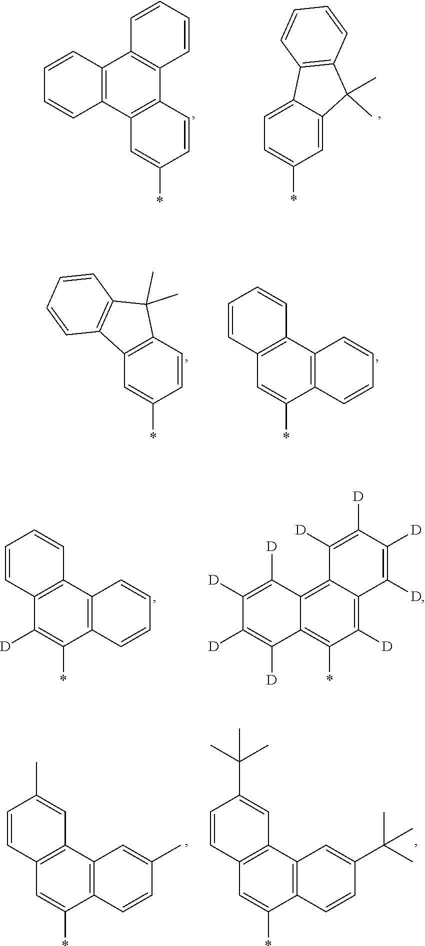 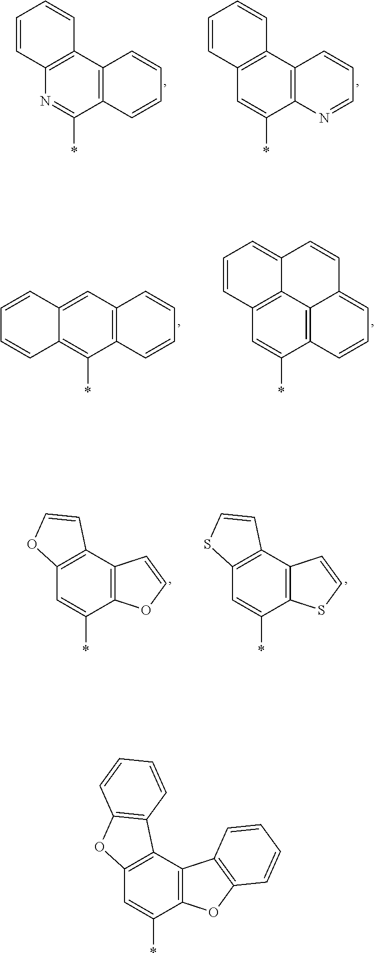
and combinations thereof;
wherein optionally, hydrogens in the above groups can be partially or fully deuterated; and
“ [symbol] ” represents a position where Ar is joined.

15. The metal complex according to claim 4, wherein at least one or at least two of R₁ to R₈ are selected from substituted or unsubstituted alkyl having 1 to 20 carbon atoms, substituted or unsubstituted cycloalkyl having 3 to 20 ring carbon atoms or a combination thereof, and the total number of carbon atoms in all of R₁ to R₄ and/or R₅ to R₈ is at least 4;
preferably, at least one or at least two of R₁ to R₄ are selected from substituted or unsubstituted alkyl having 1 to 20 carbon atoms, substituted or unsubstituted cycloalkyl having 3 to 20 ring carbon atoms or a combination thereof, and the total number of carbon atoms in all of R₁ to R₄ is at least 4; and/or at least one or at least two of R₅ to R₈ are selected from substituted or unsubstituted alkyl having 1 to 20 carbon atoms, substituted or unsubstituted cycloalkyl having 3 to 20 ring carbon atoms or a combination thereof, and the total number of carbon atoms in all of R₅ to R₈ is at least 4.

16. The metal complex according to claim 4, wherein at least one, at least two, at least three or all of R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms and combinations thereof;
preferably, at least one, at least two, at least three or all of R₂, R₃, R₆ and R₇ are selected from the group consisting of: deuterium, substituted or unsubstituted alkyl having 1 to 20 carbon atoms, substituted or unsubstituted cycloalkyl having 3 to 20 ring carbon atoms and combinations thereof;
more preferably, at least one, at least two, at least three or all of R₂, R₃, R₆ and R₇ are selected from the group consisting of: deuterium, methyl, ethyl, propyl, isopropyl, n-butyl, isobutyl, t-butyl, cyclopentyl, cyclohexyl, neopentyl, t-pentyl and combinations thereof;
optionally, hydrogens in the above groups can be partially or fully deuterated.

17. The metal complex according to claim 1, wherein Lₐ is, at each occurrence identically or differently, selected from the group consisting of: 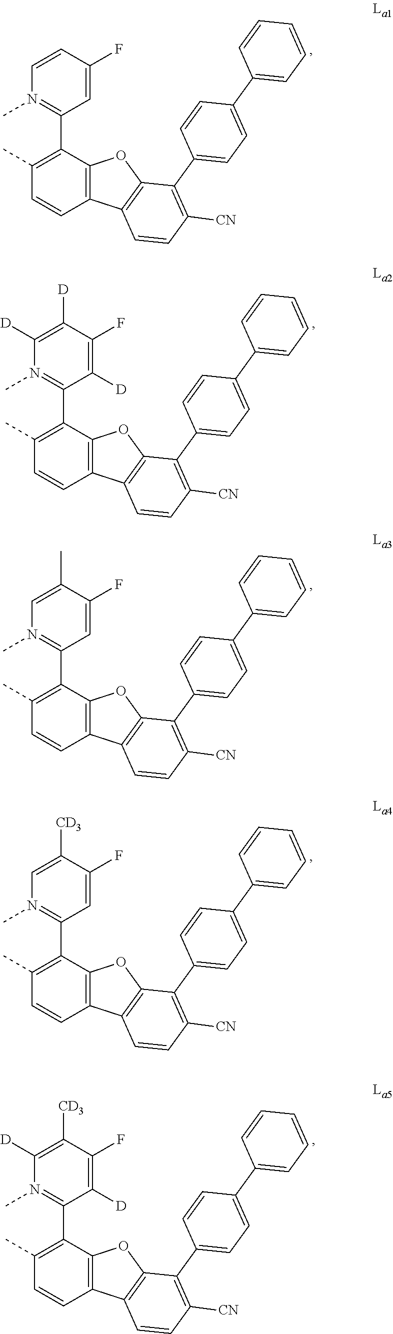 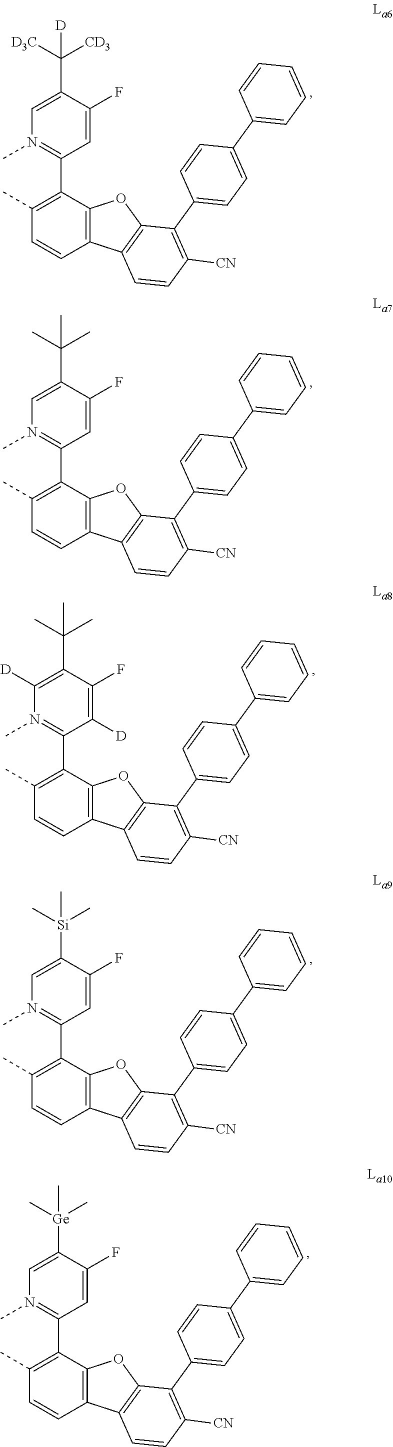 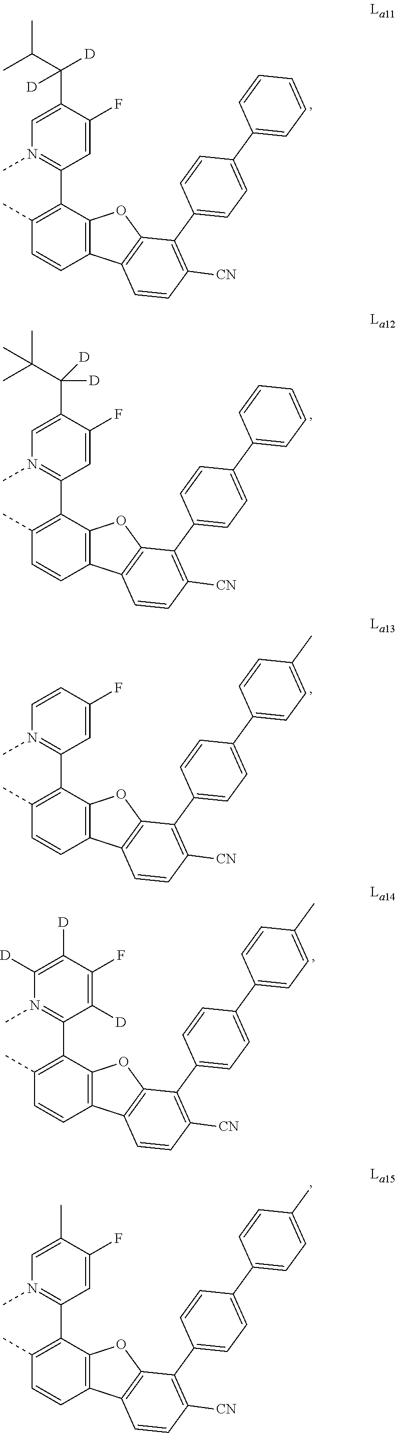 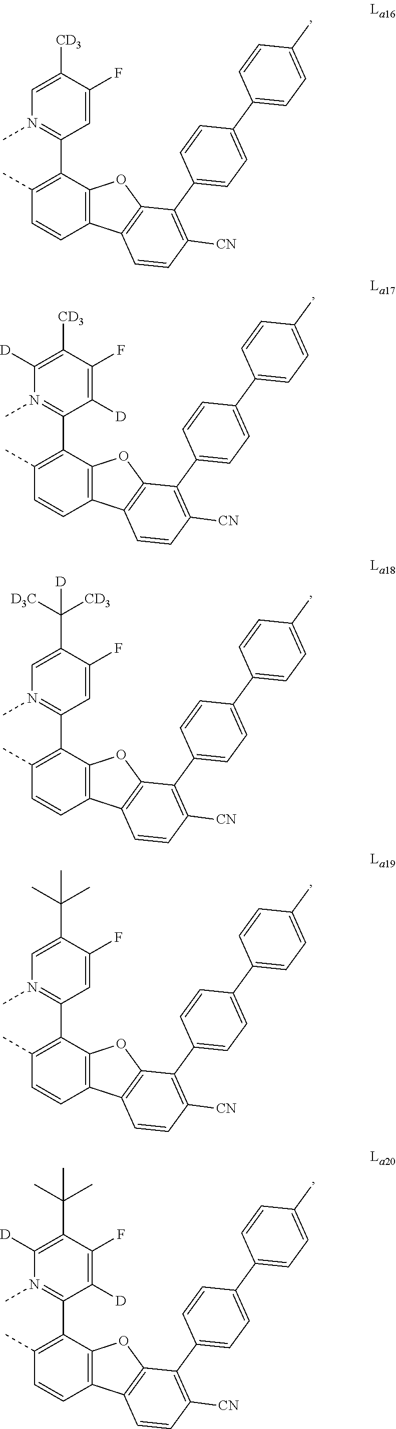 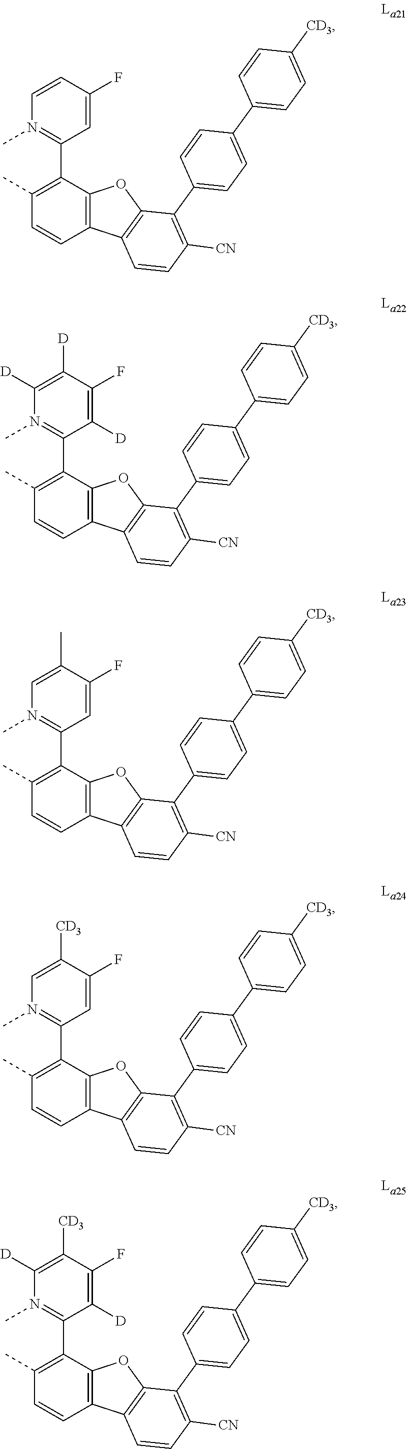 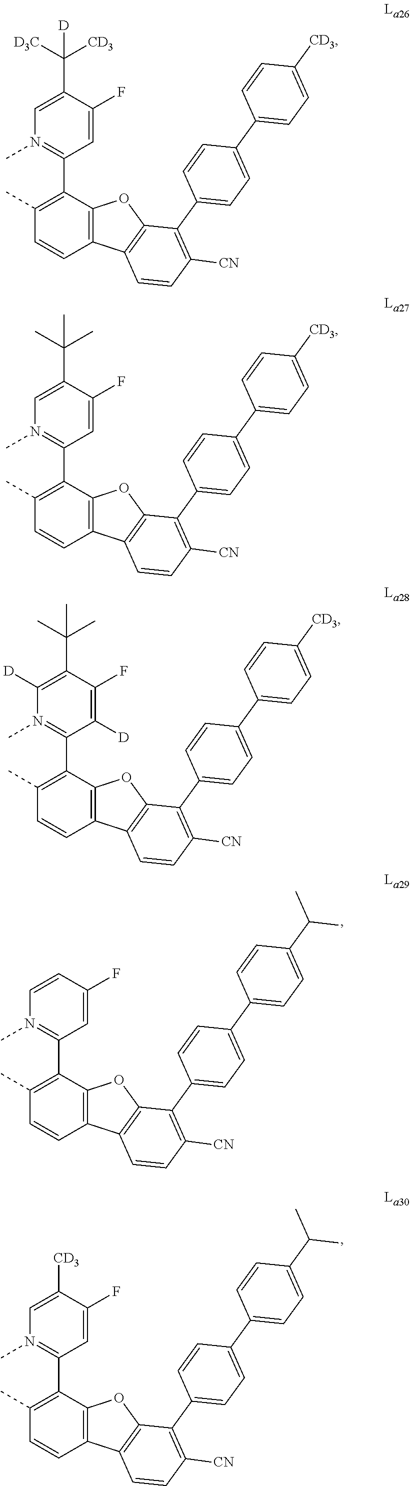 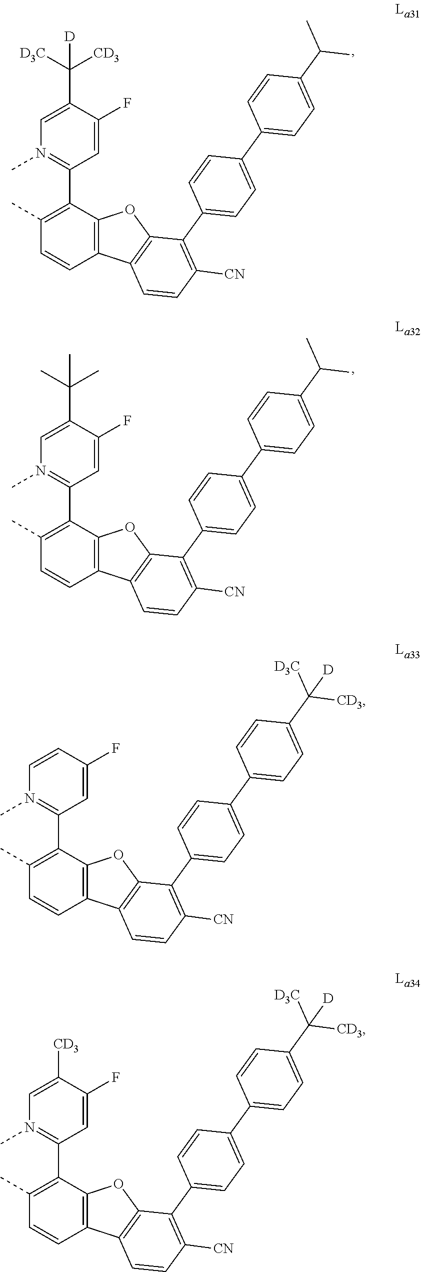 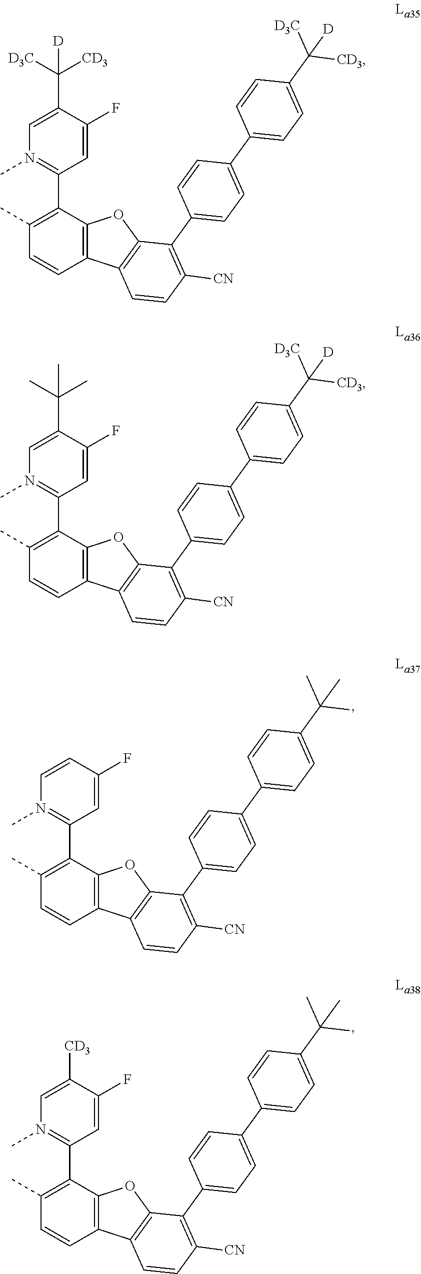 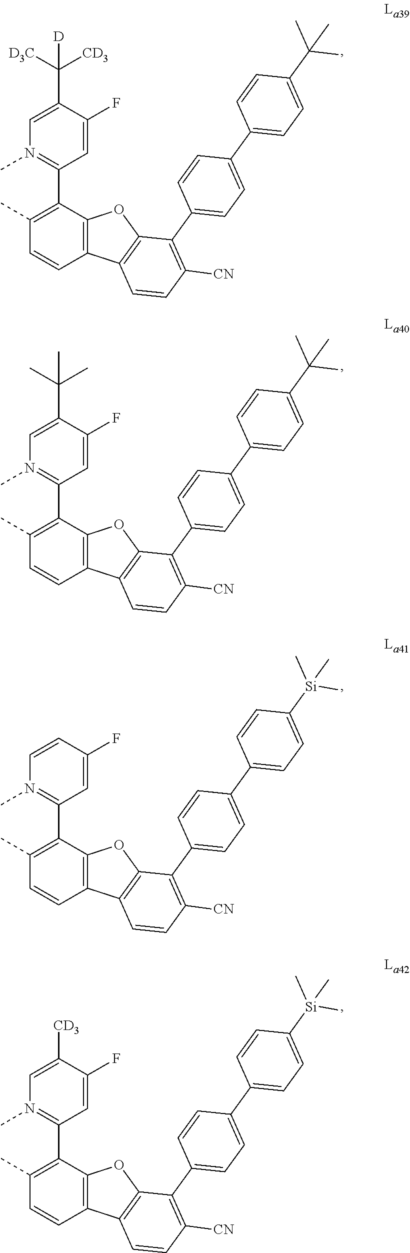 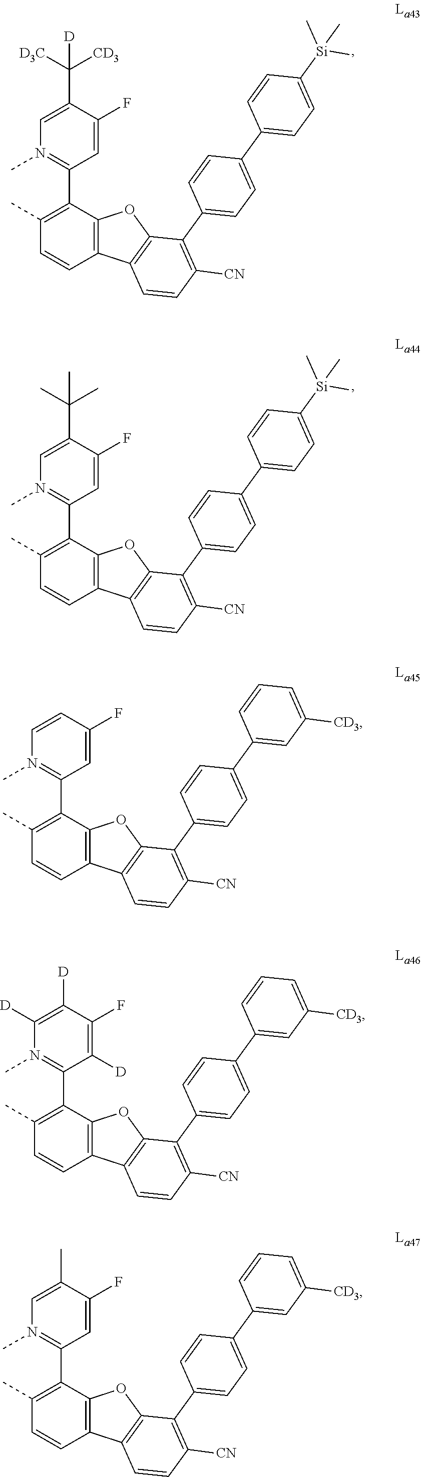 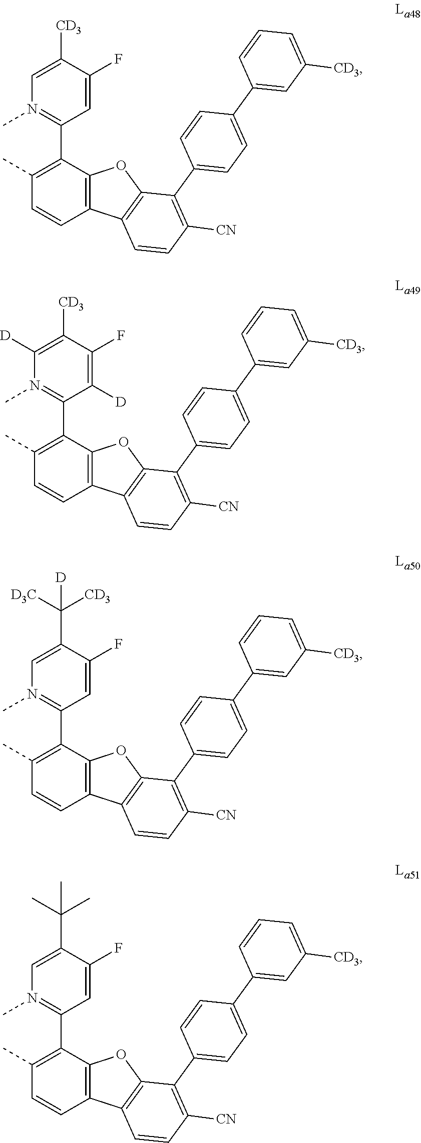 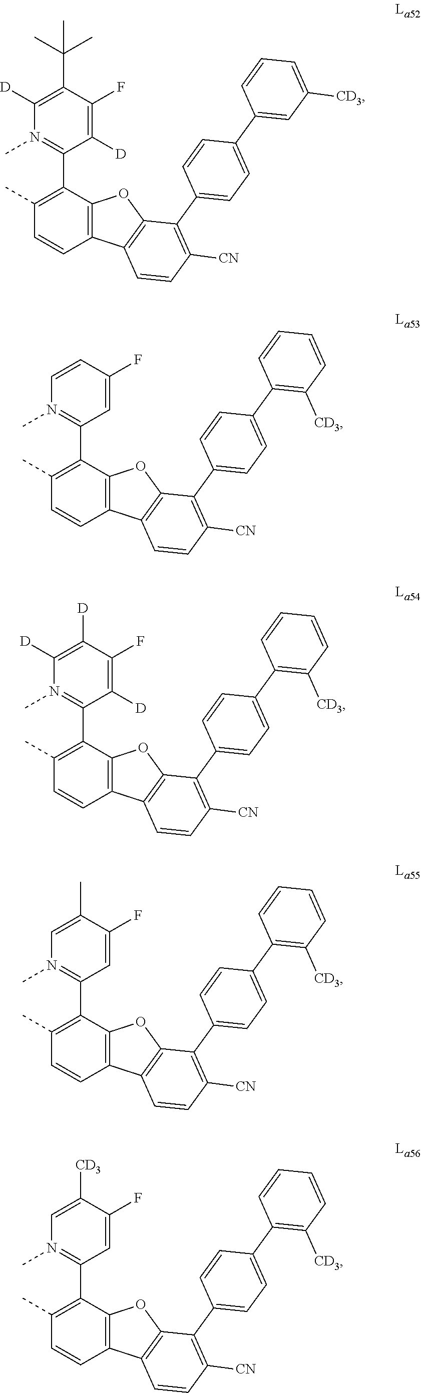 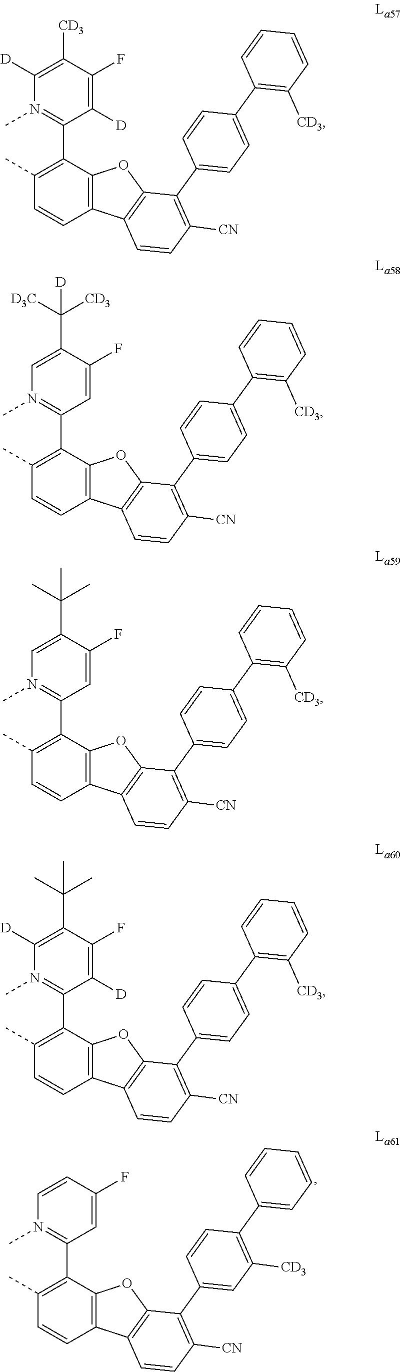 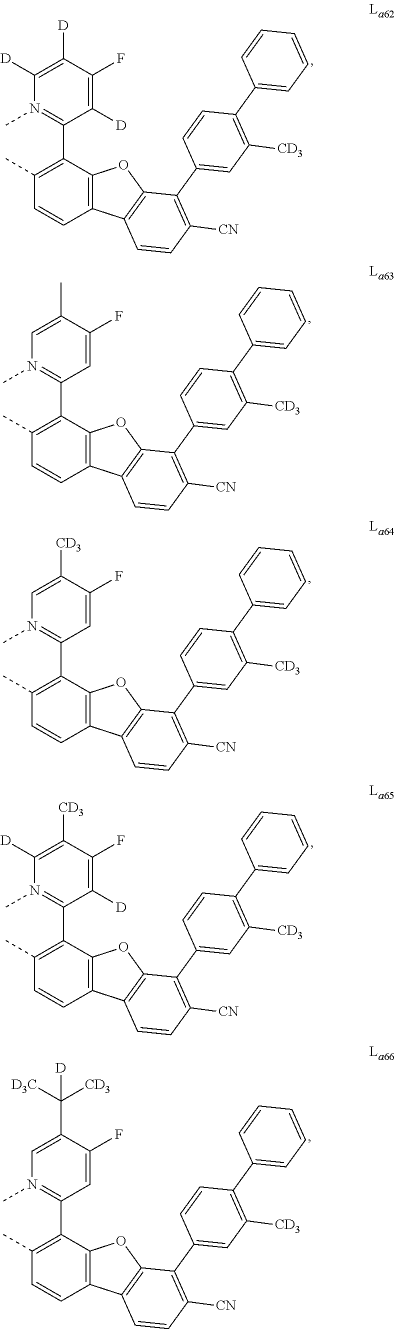 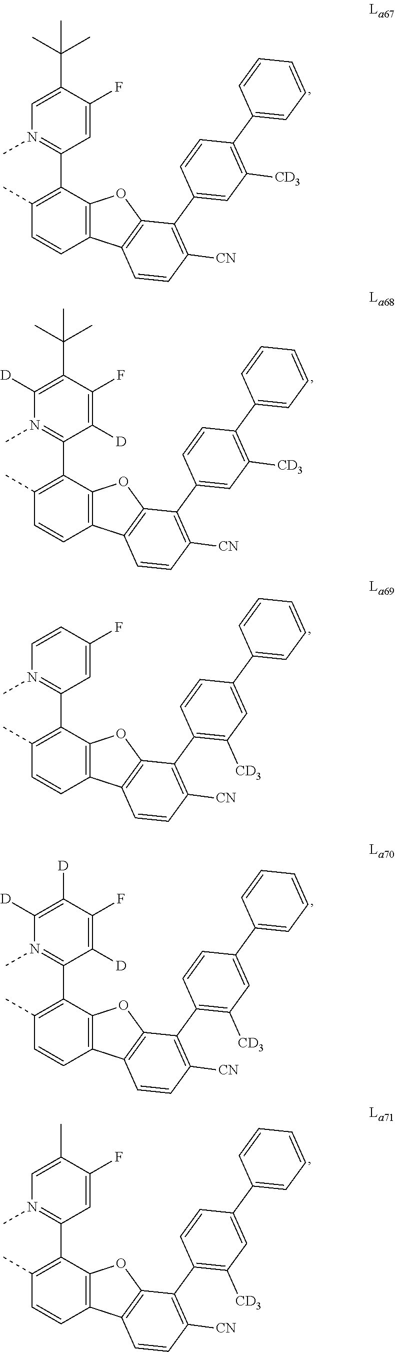 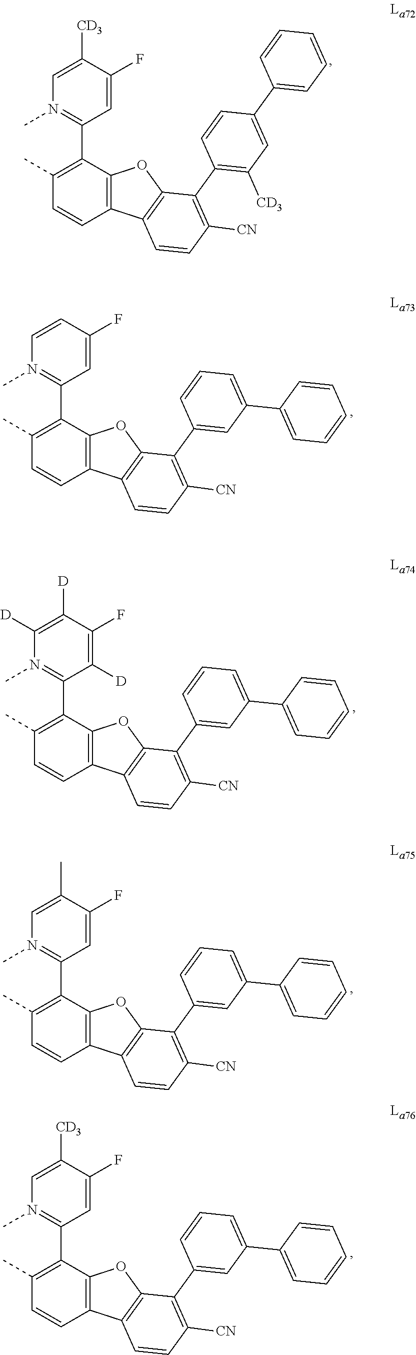 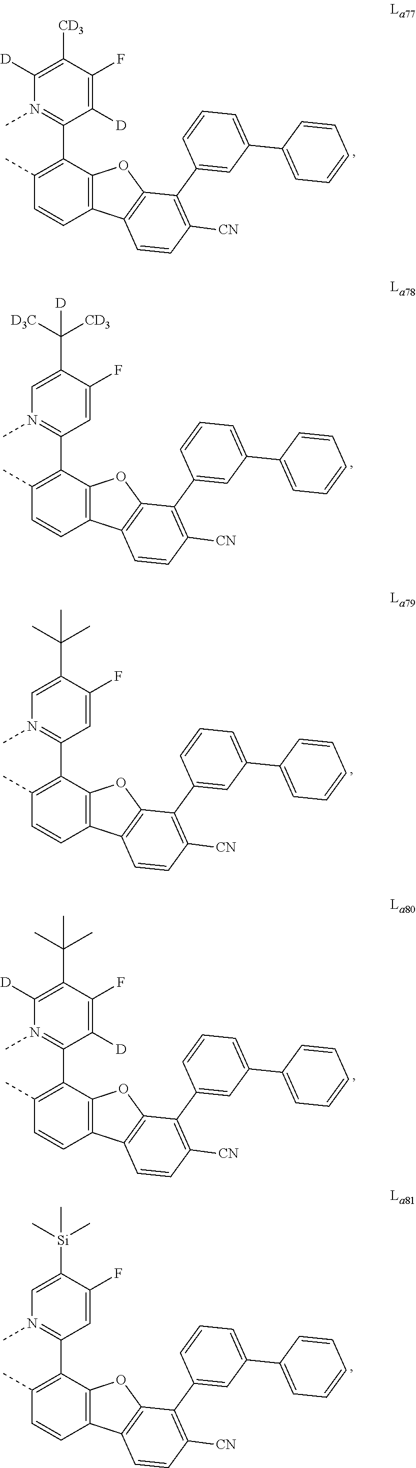 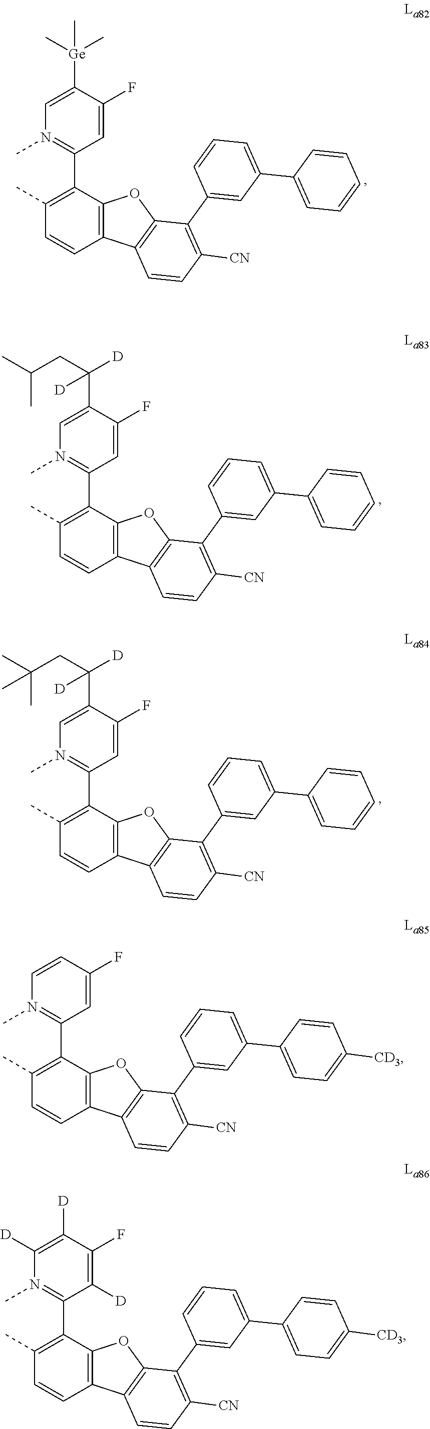 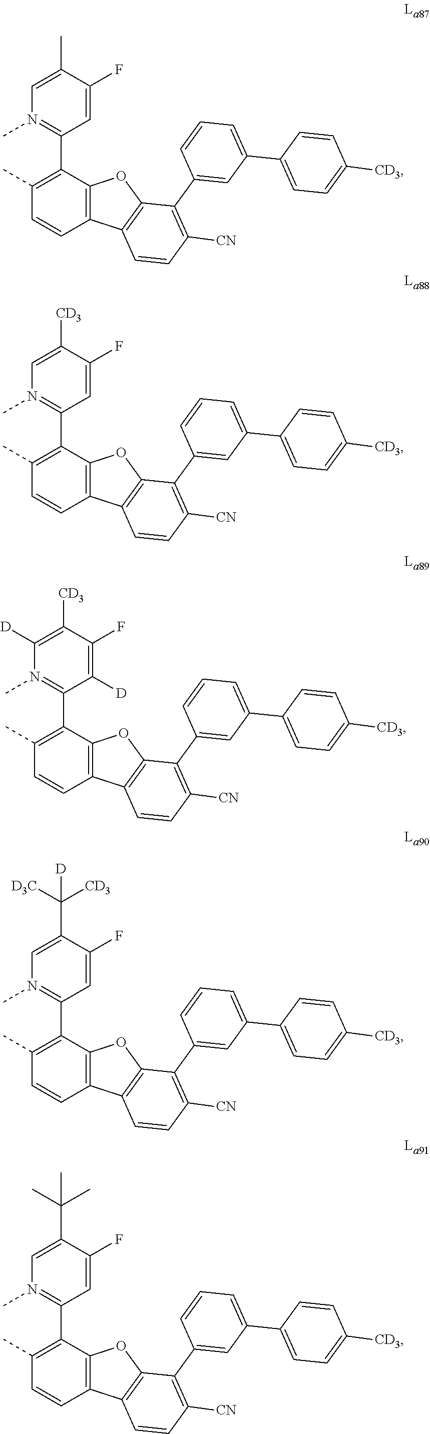 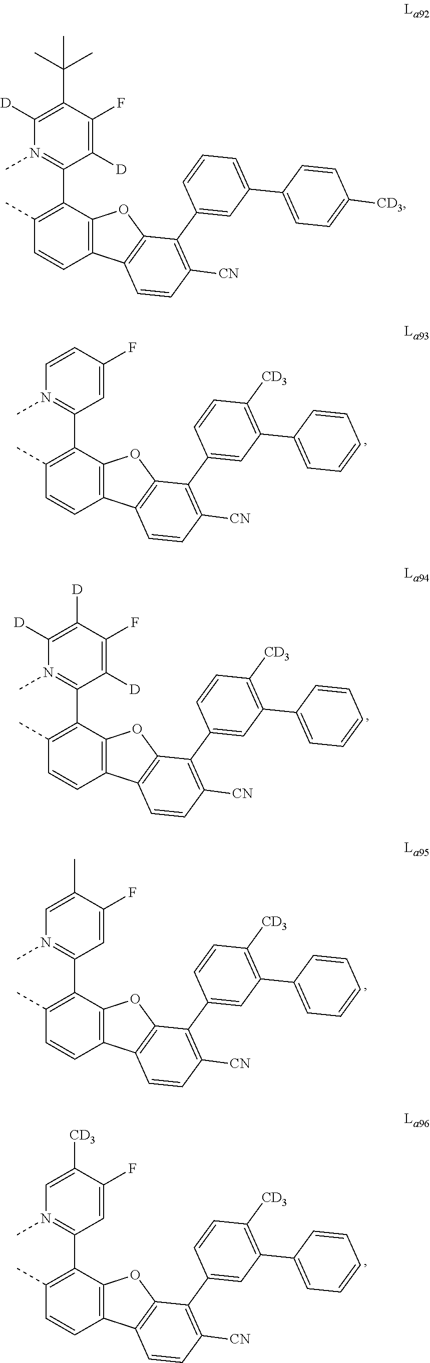 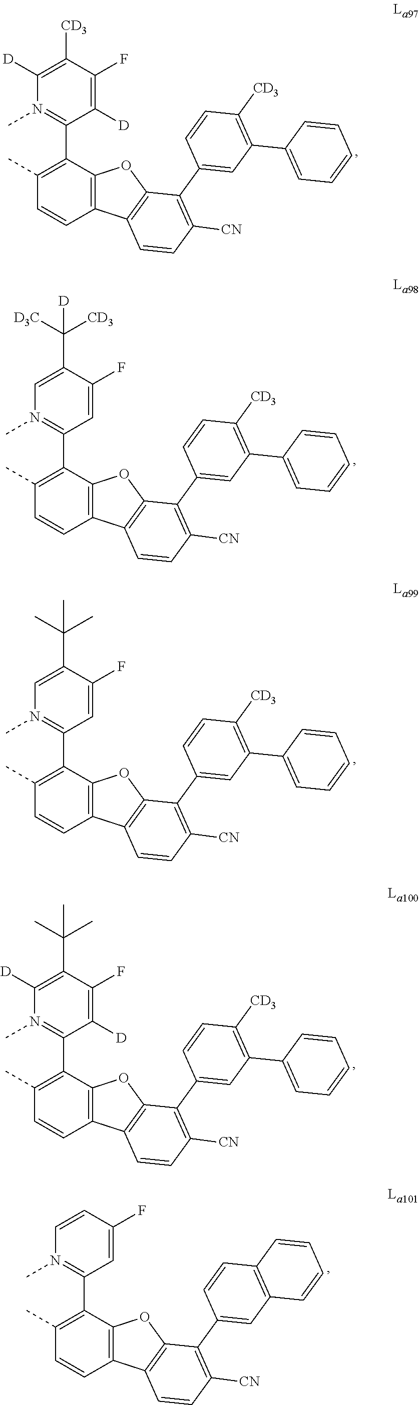 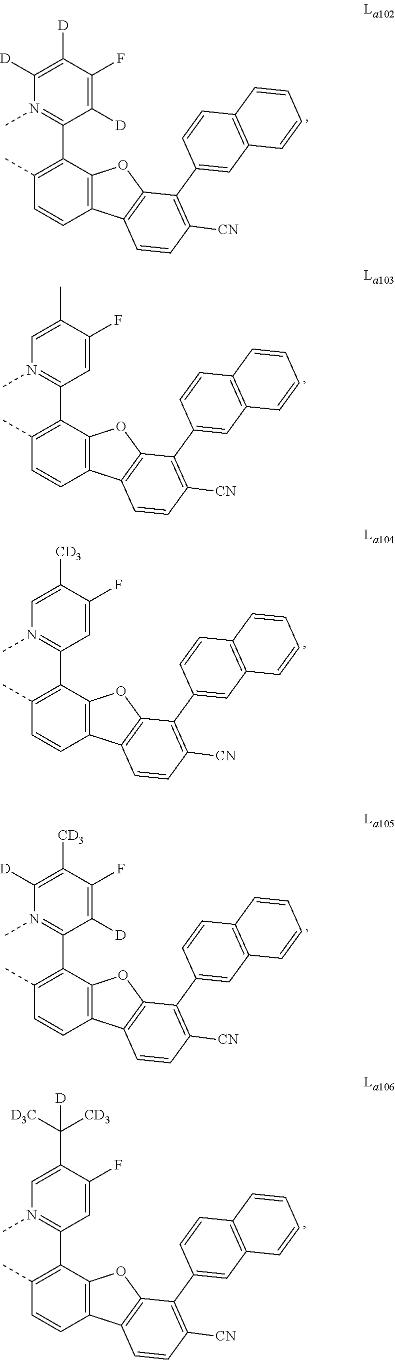 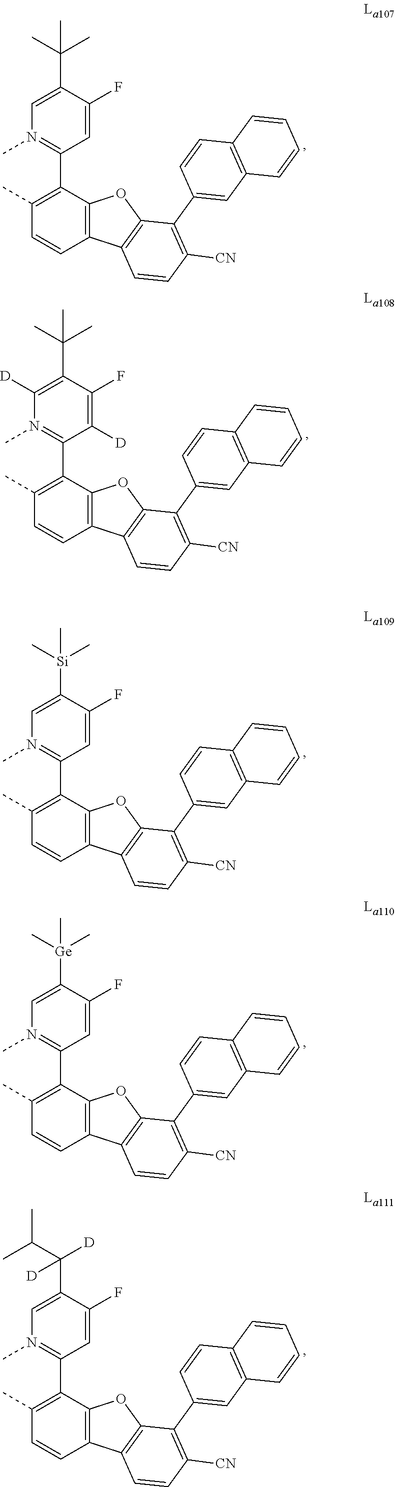 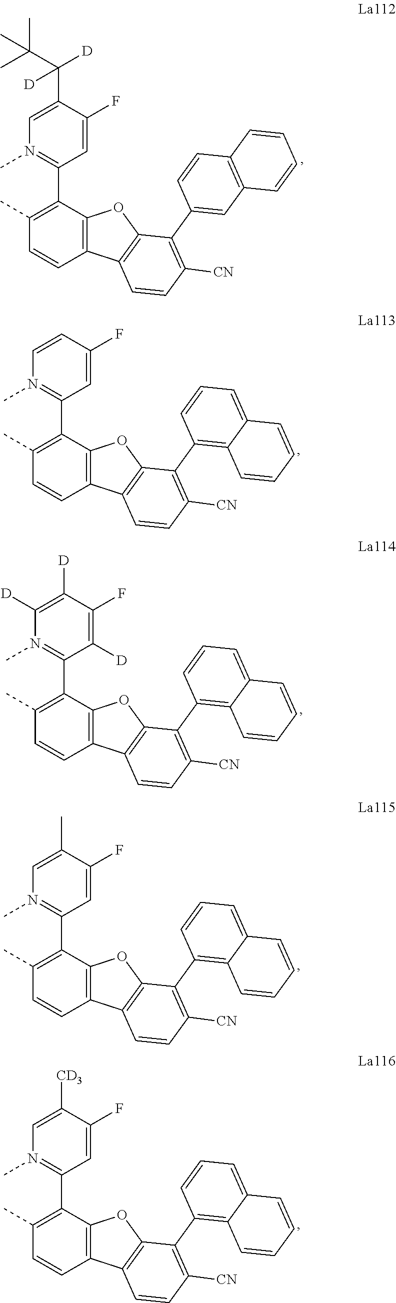 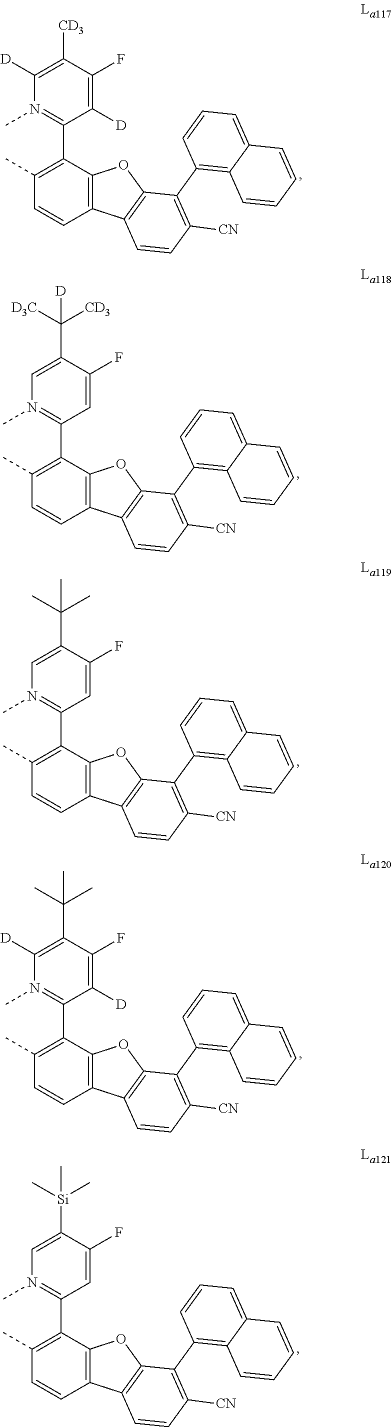 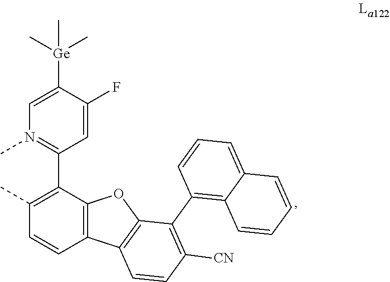 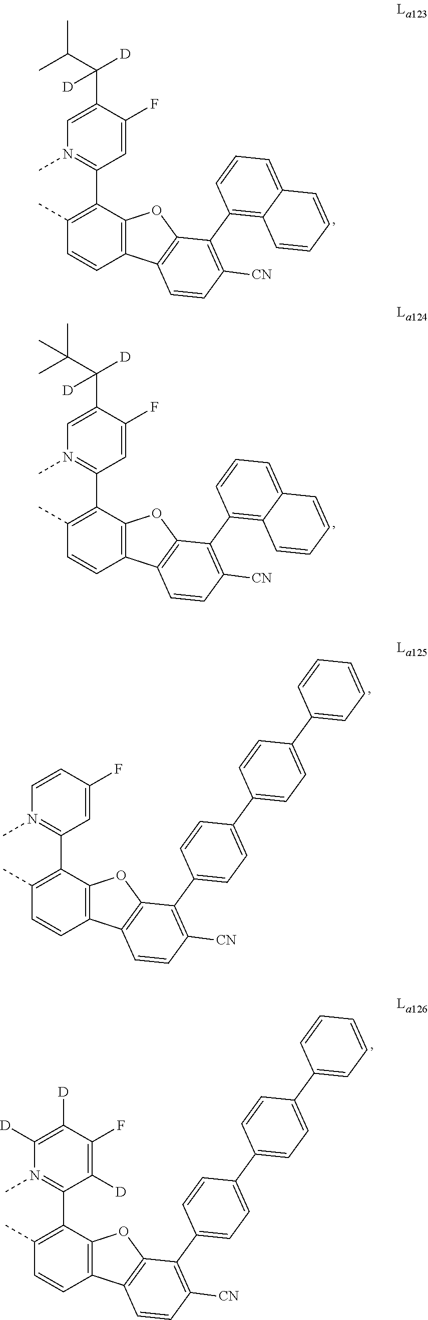 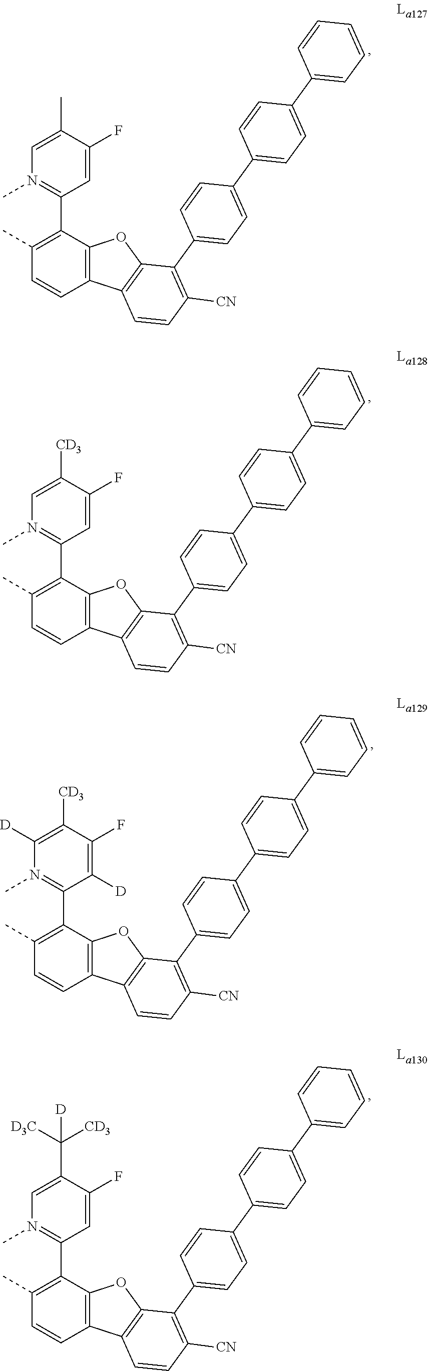 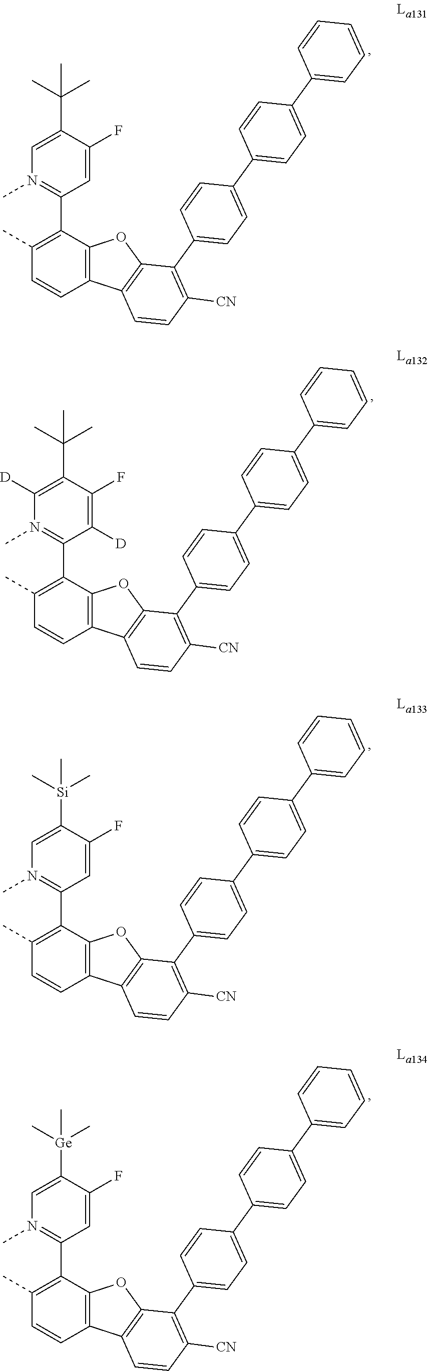 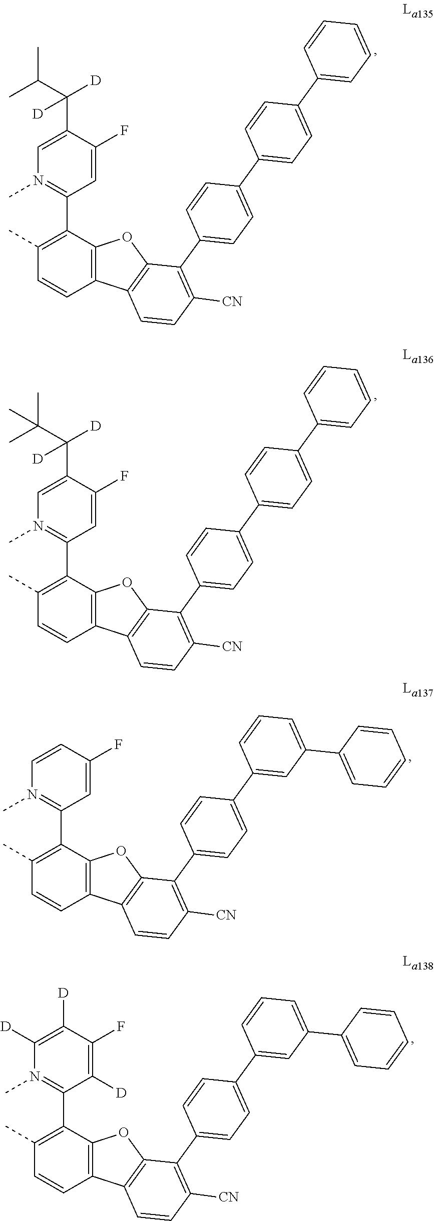 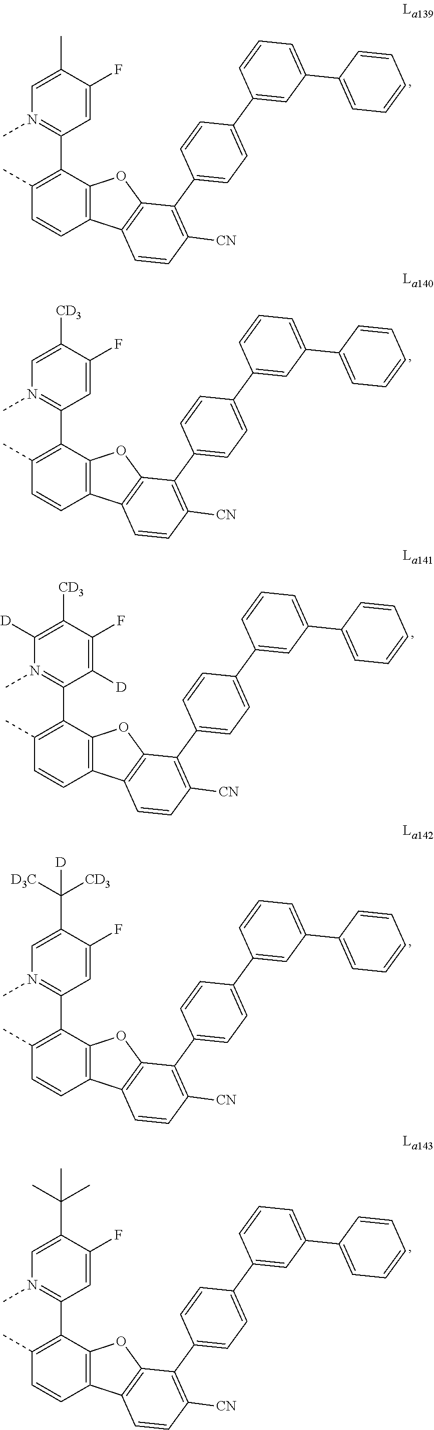 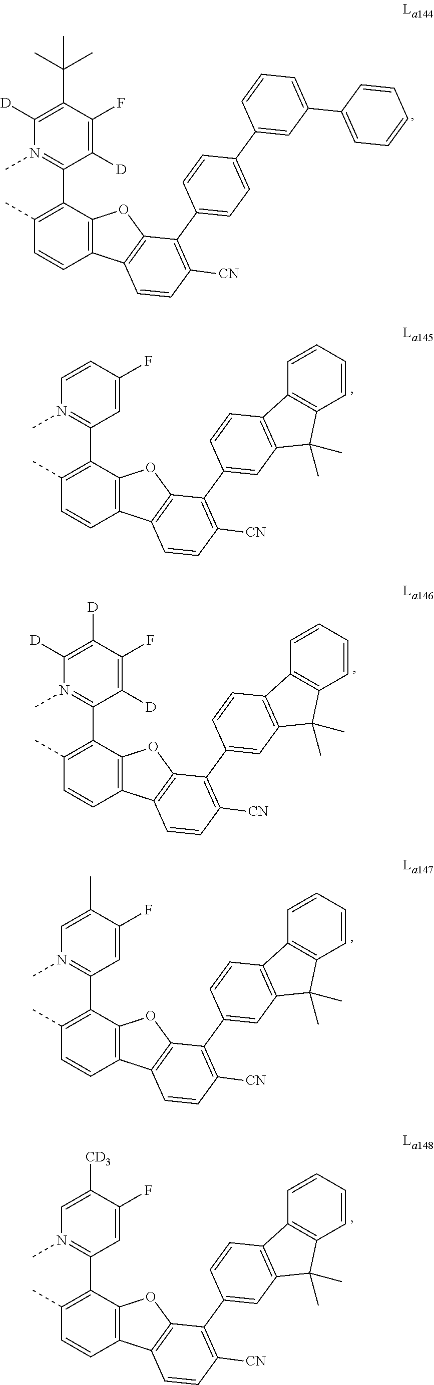 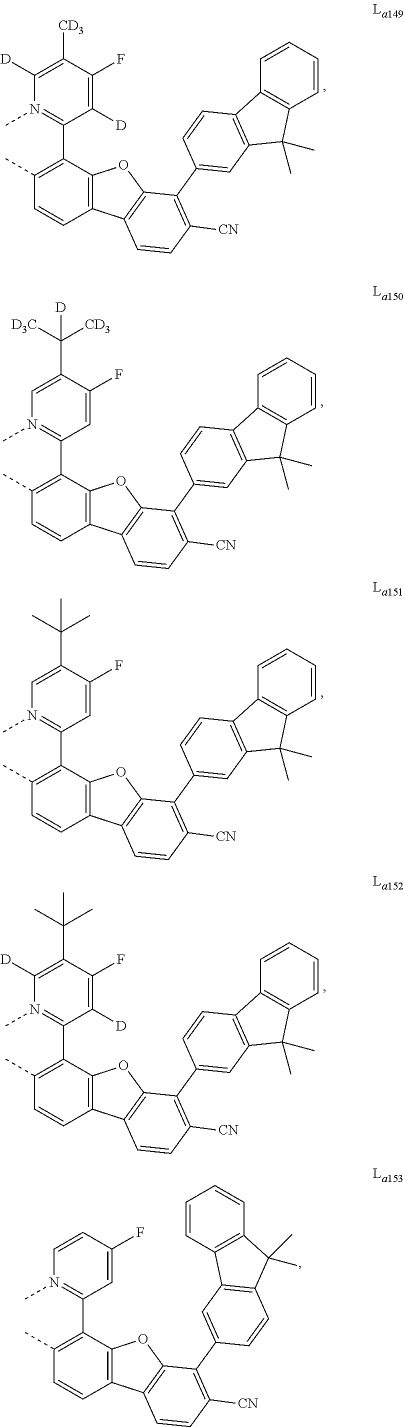 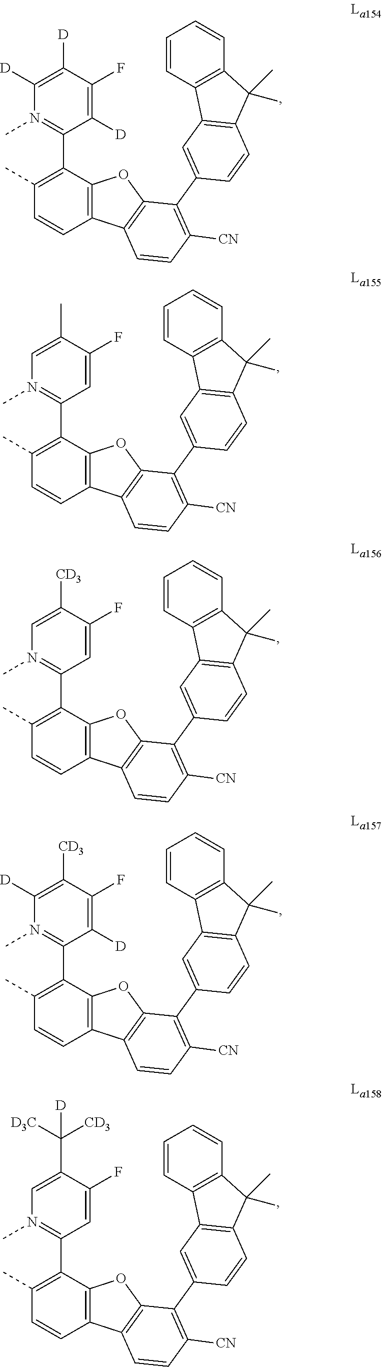 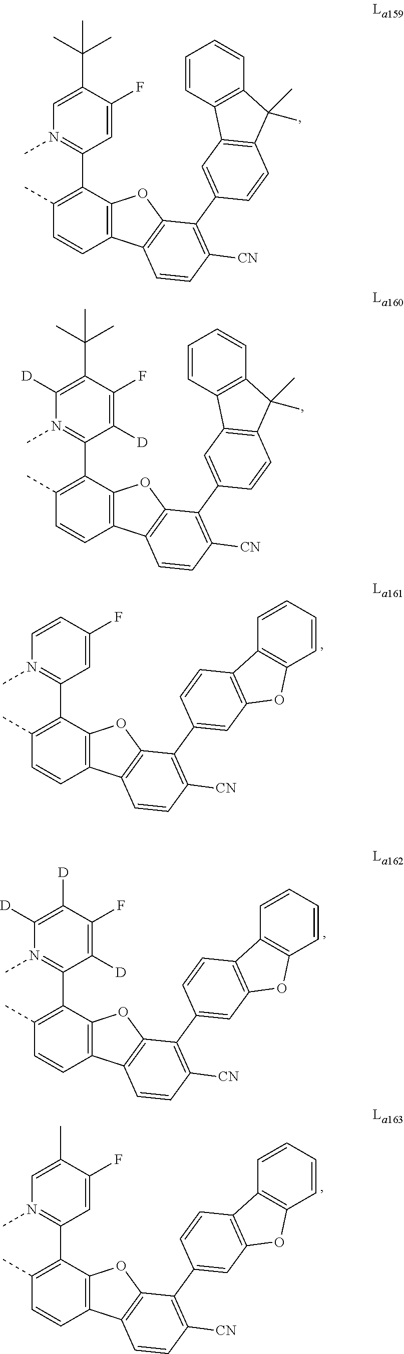 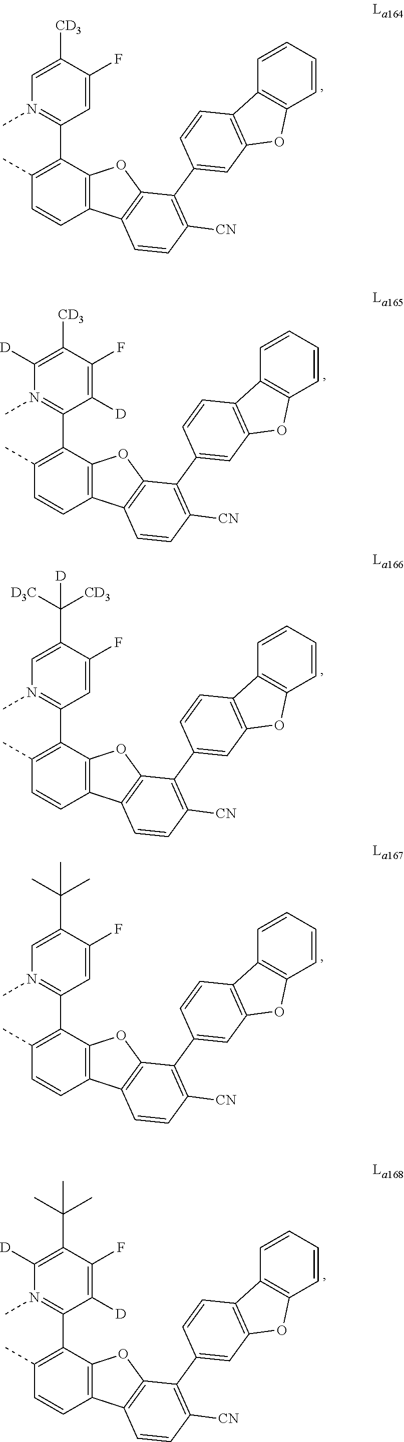 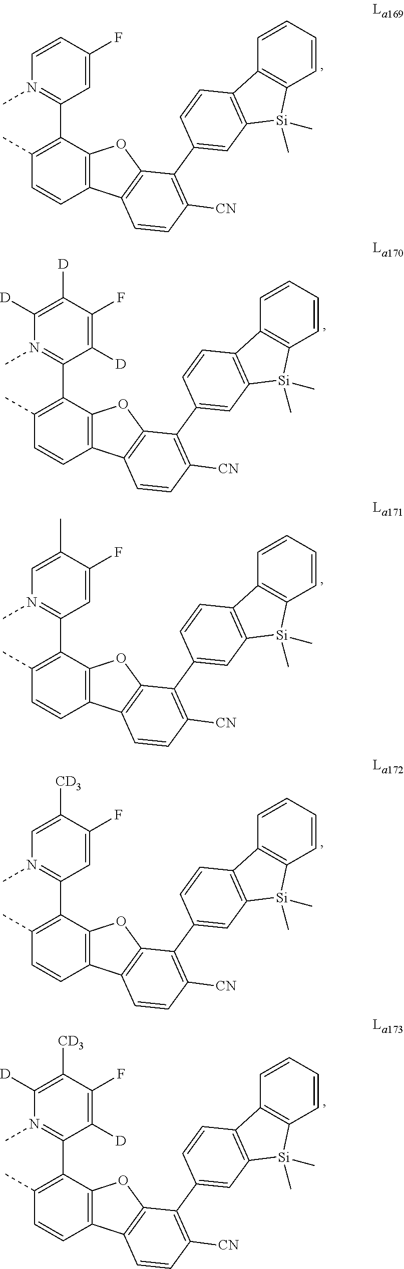 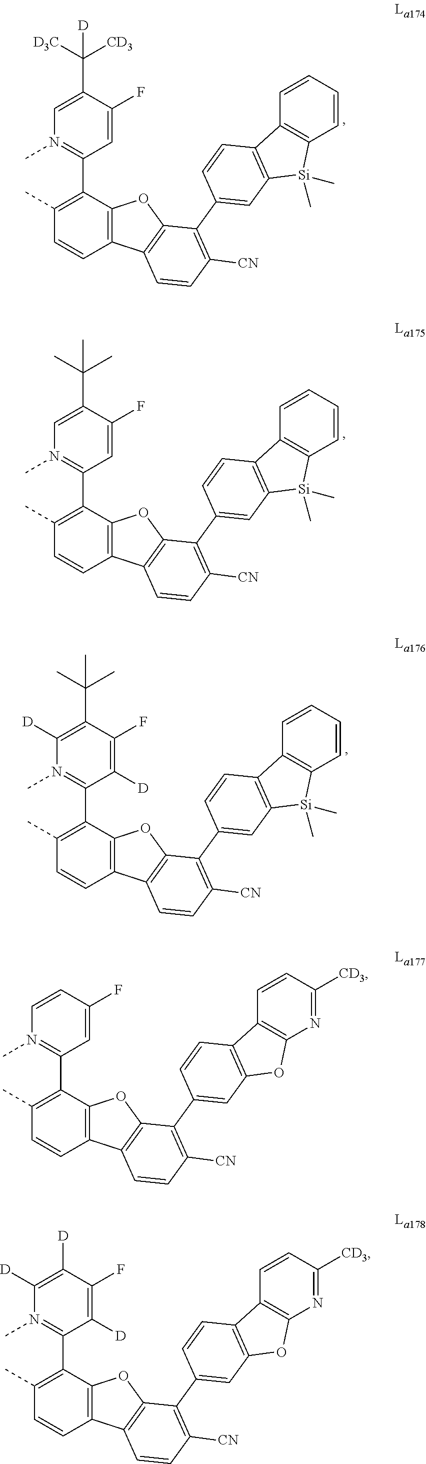 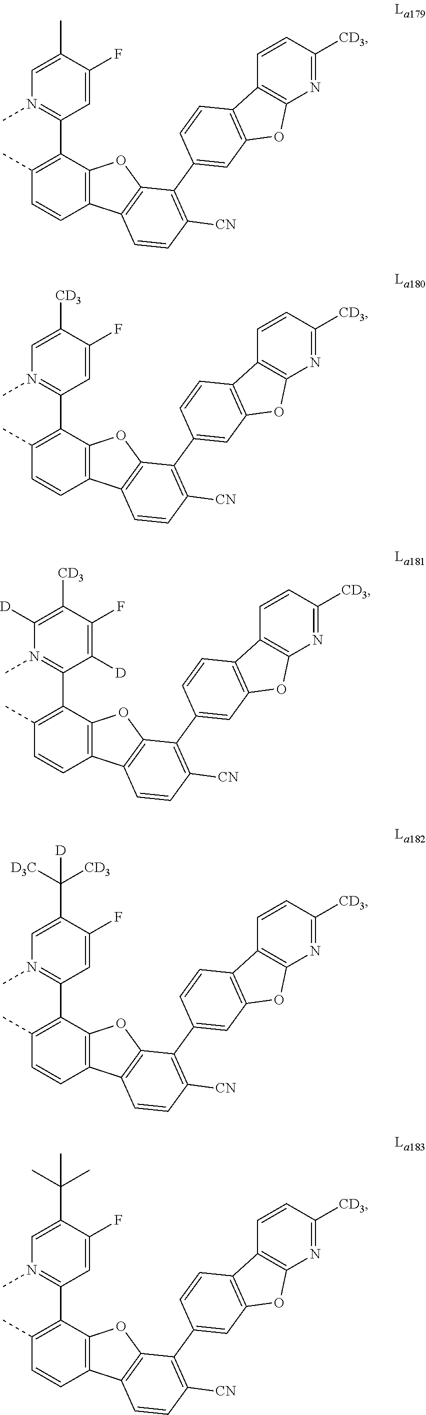 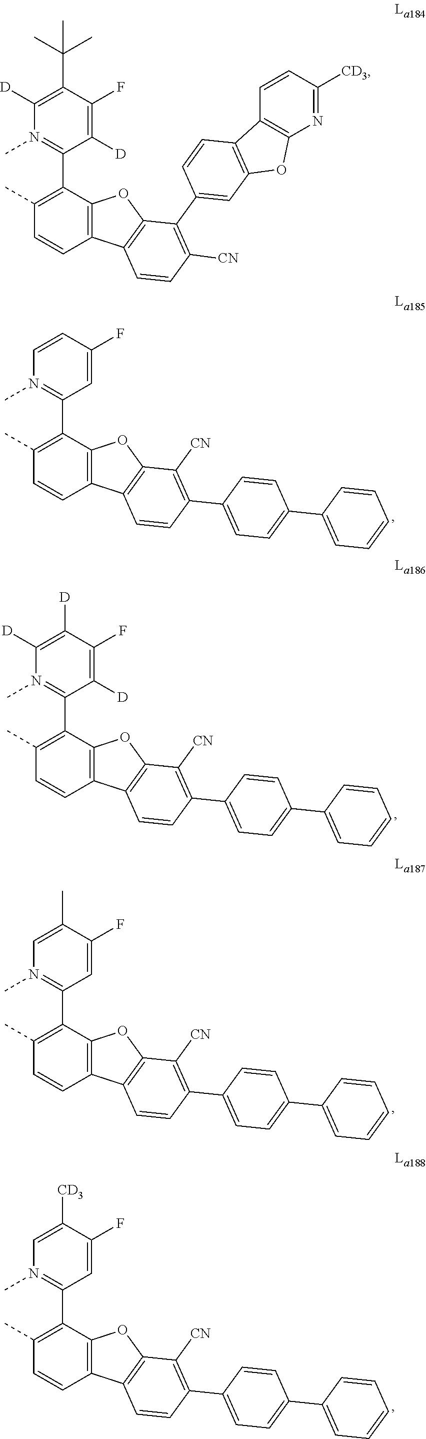 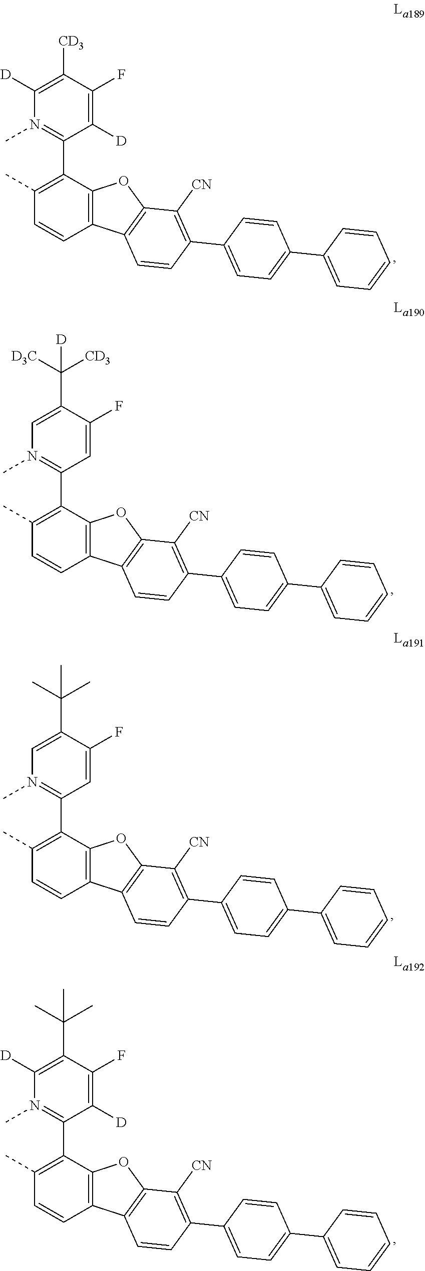 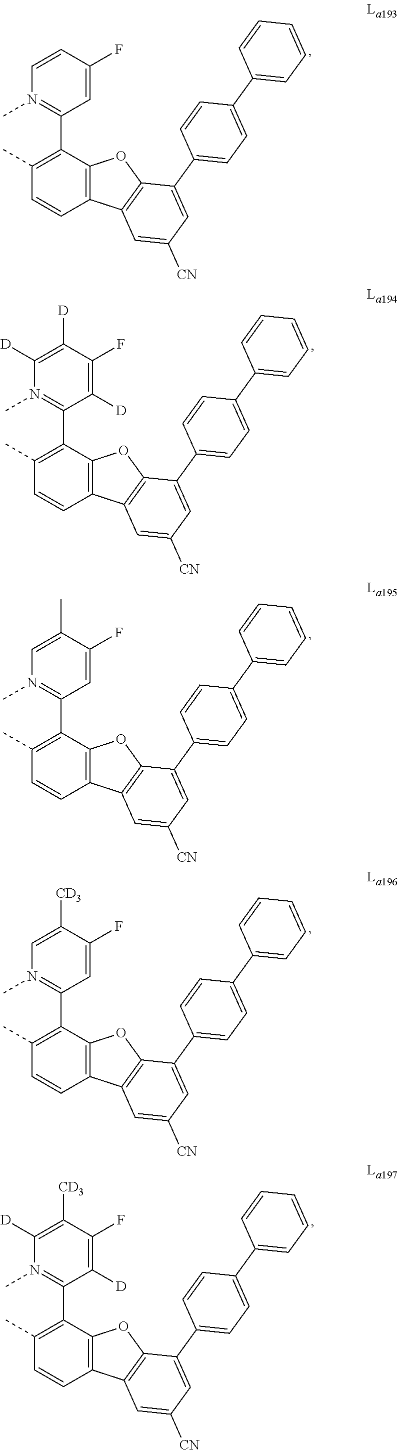 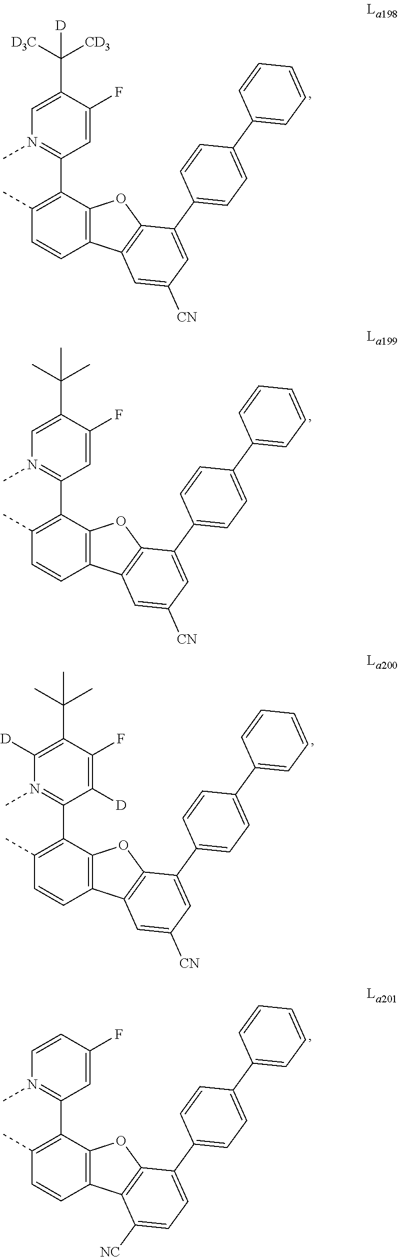 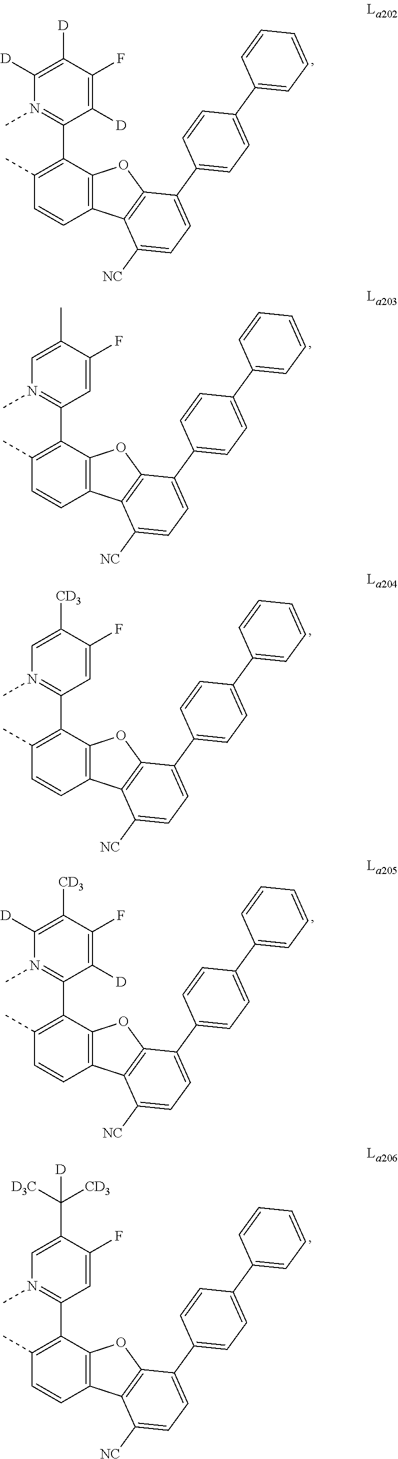 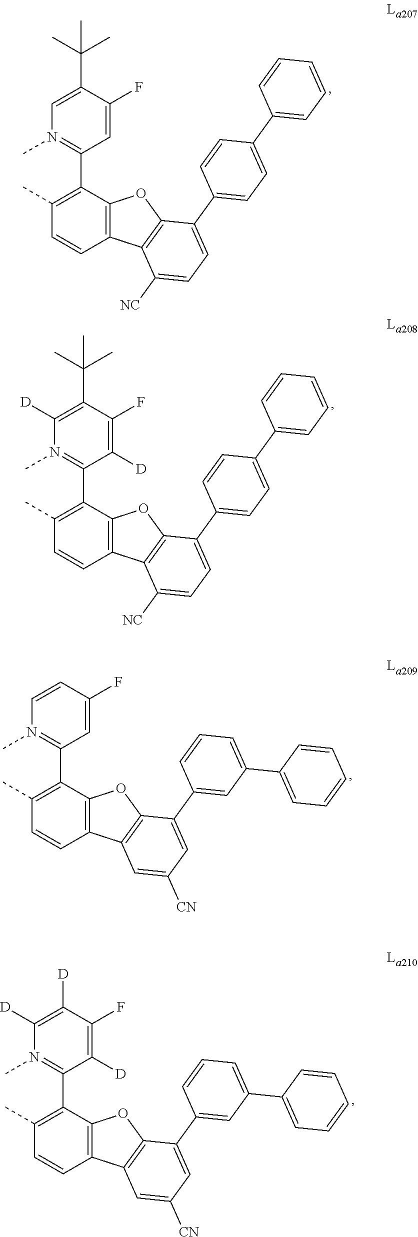 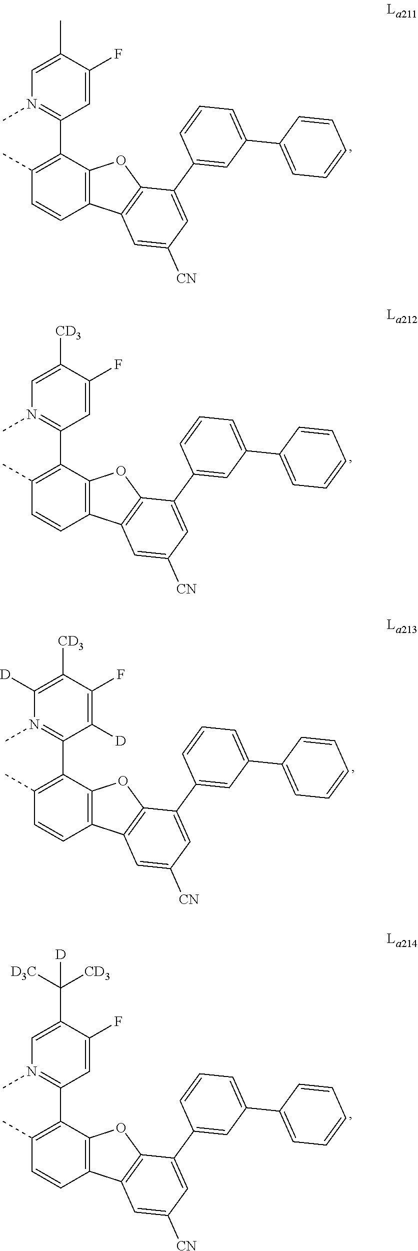 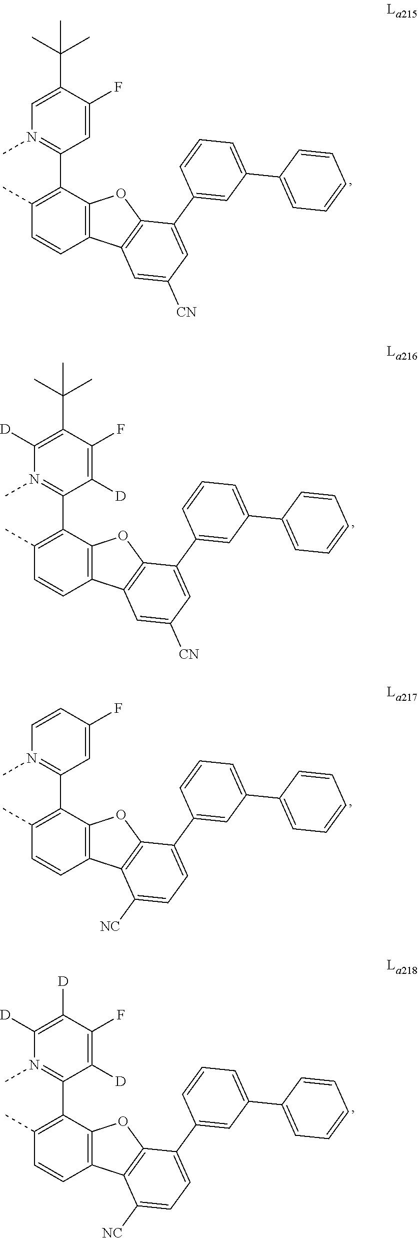 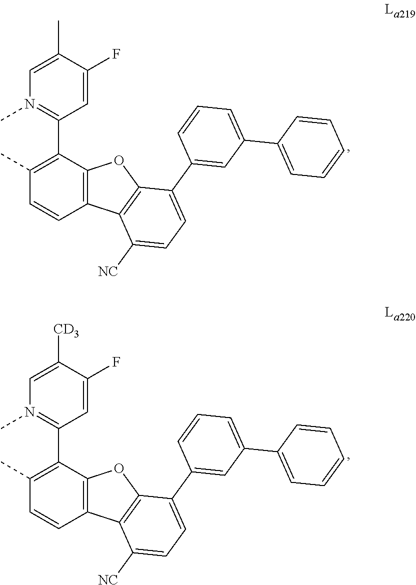 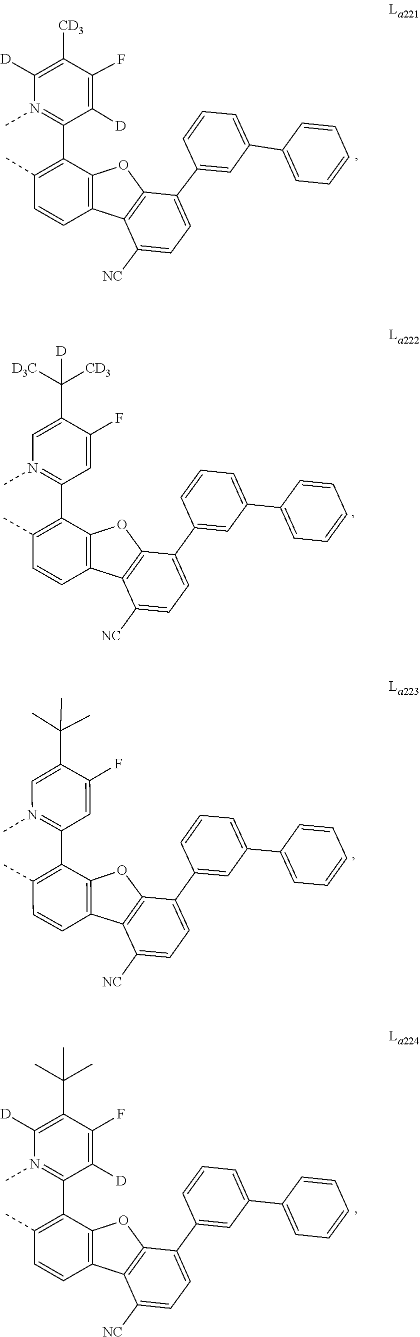 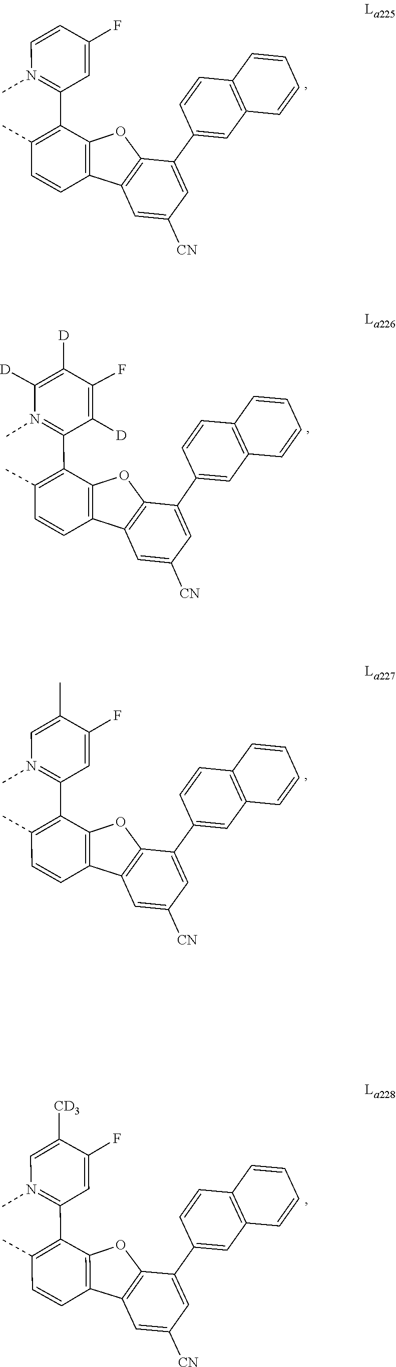 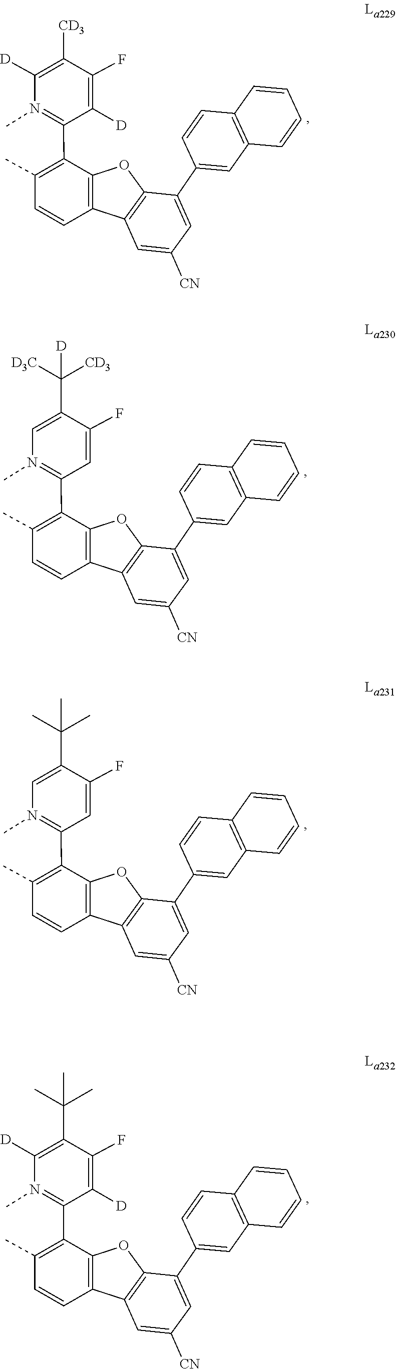 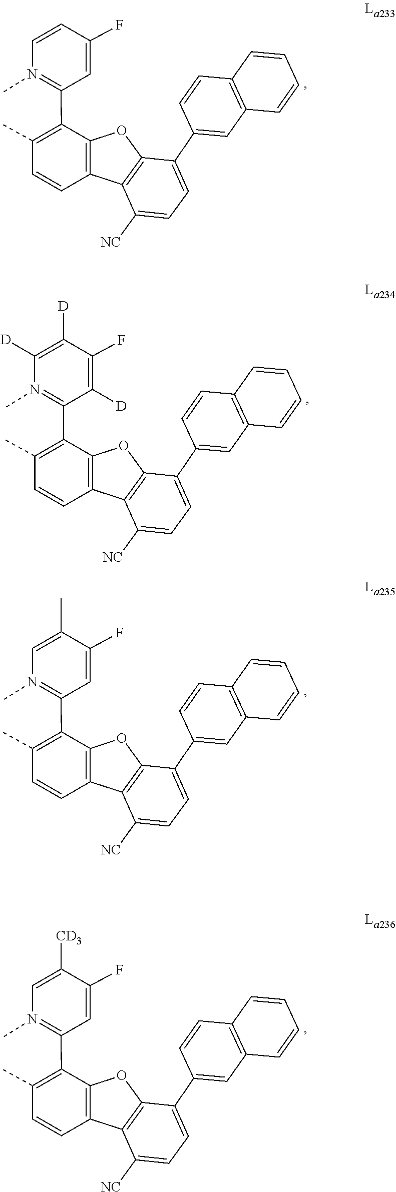 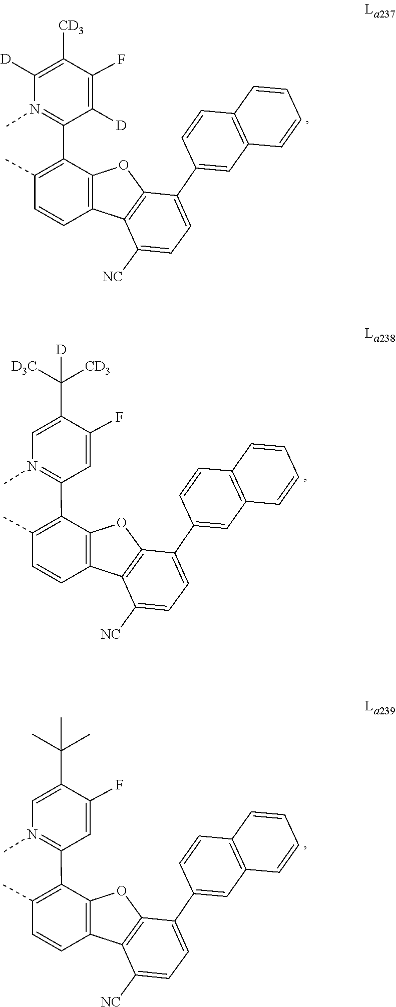 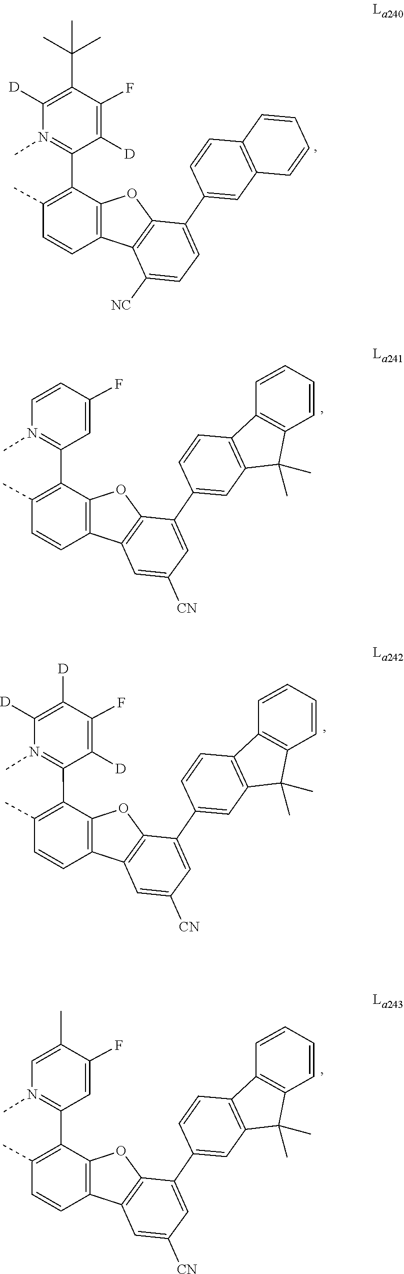 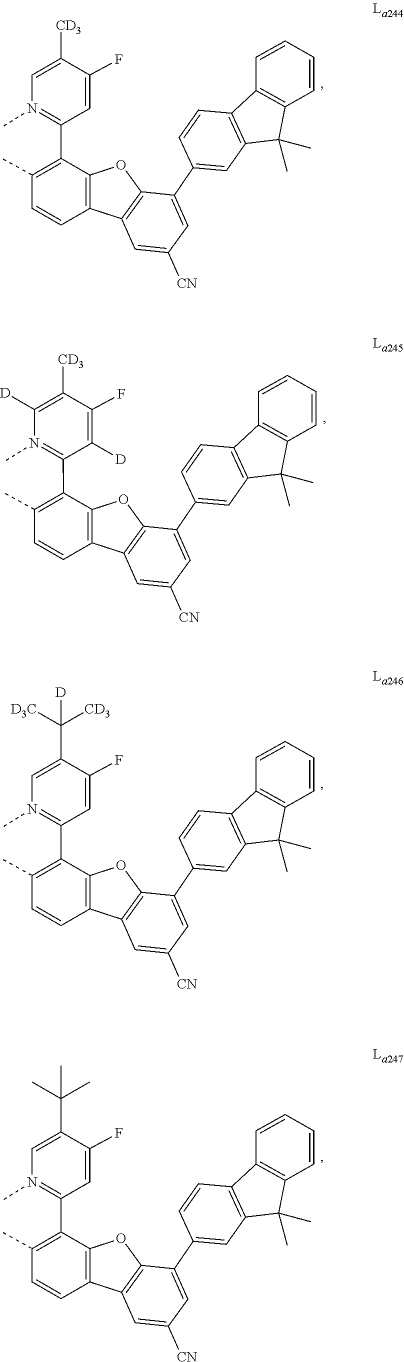 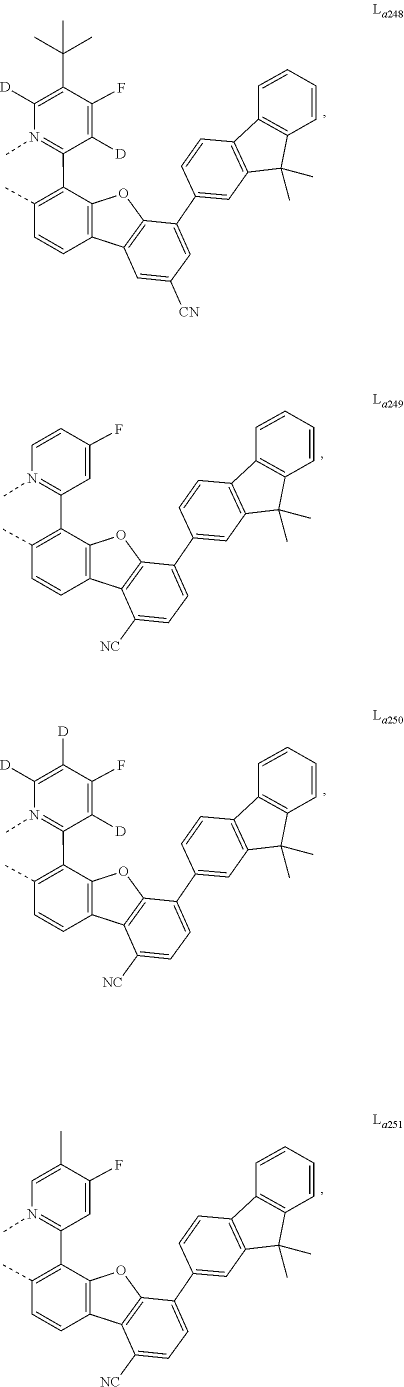 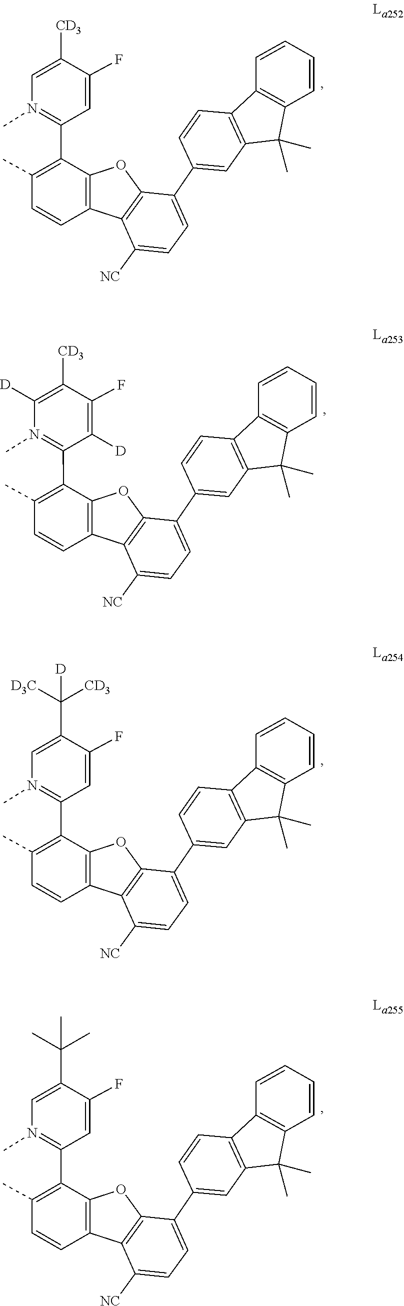 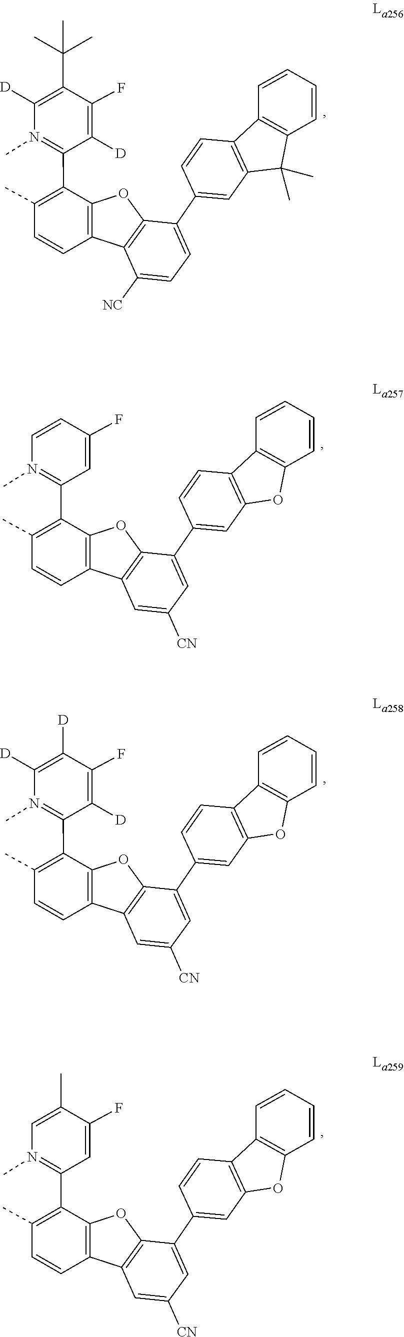 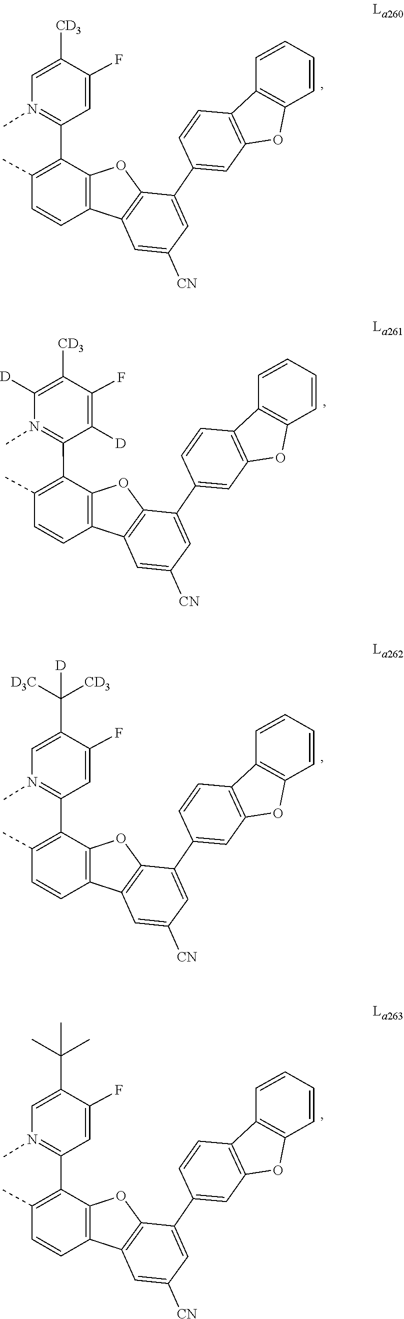 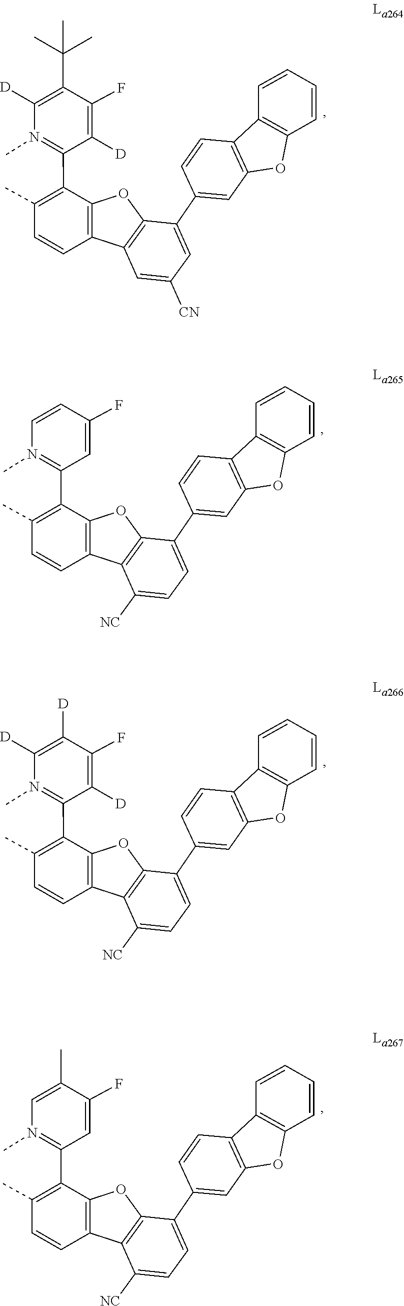 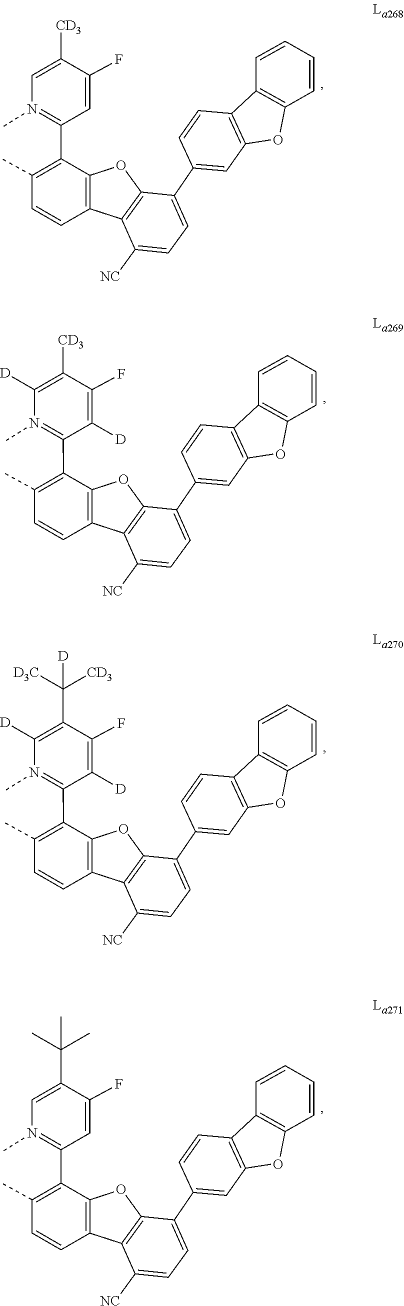 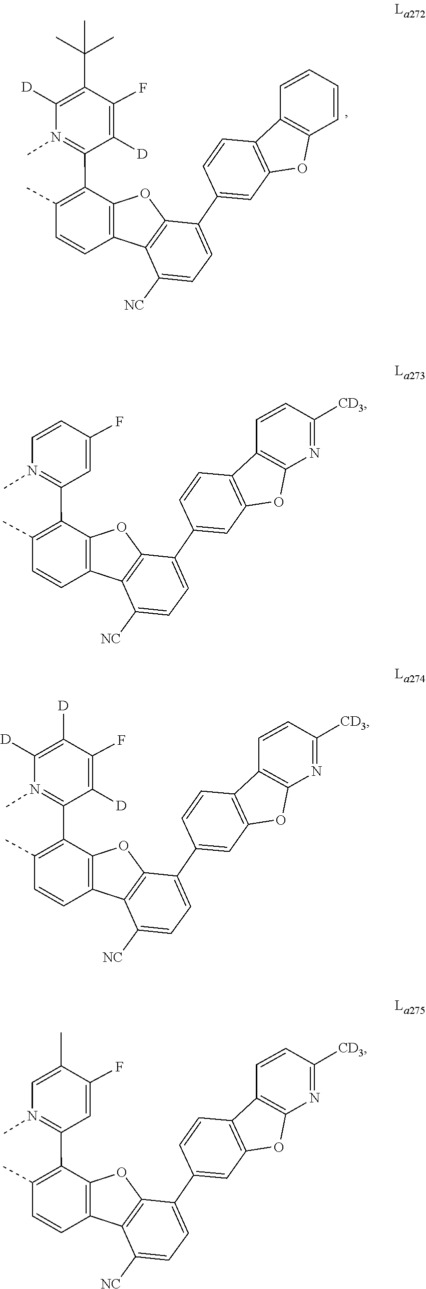 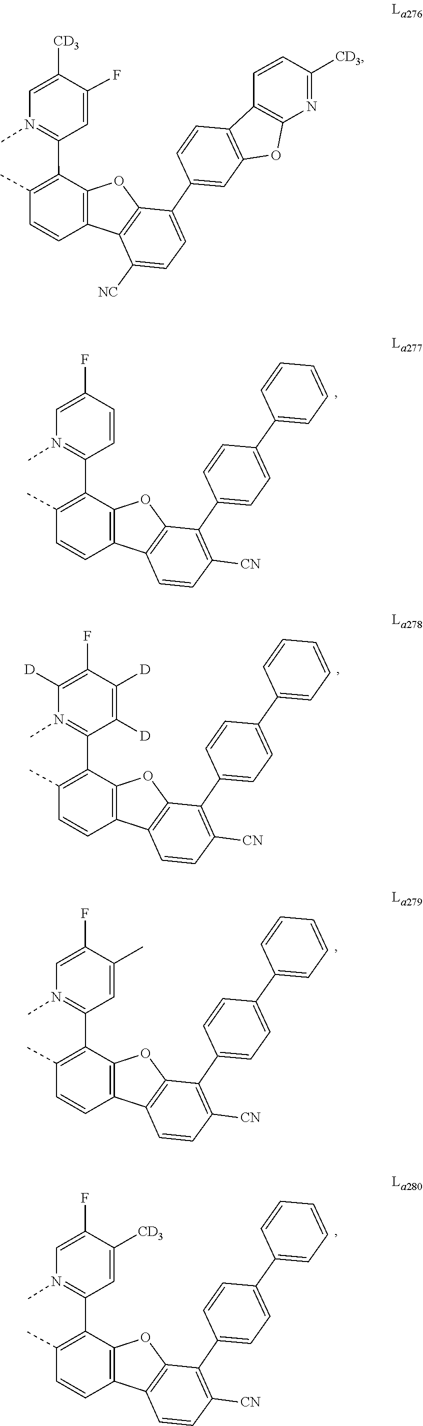 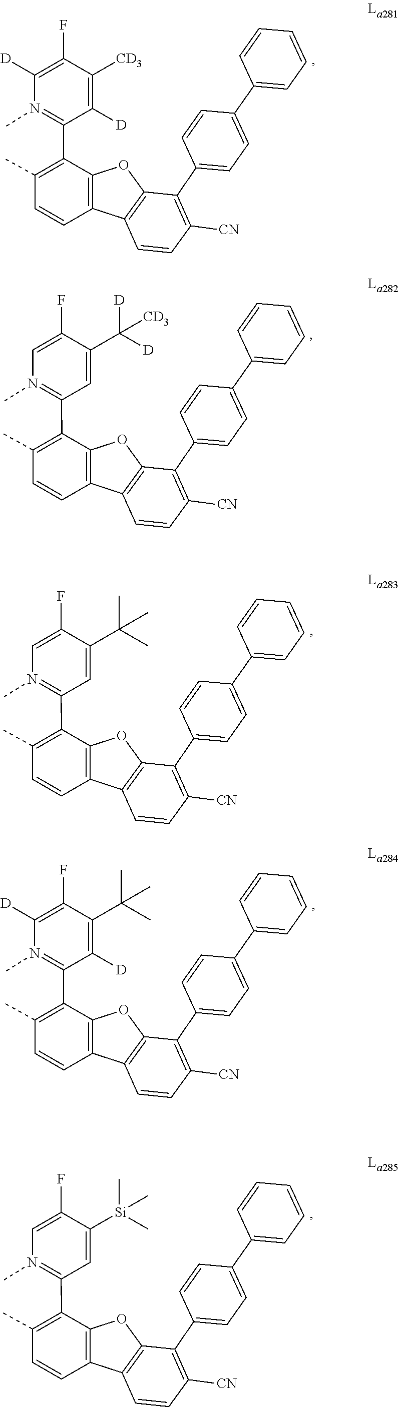 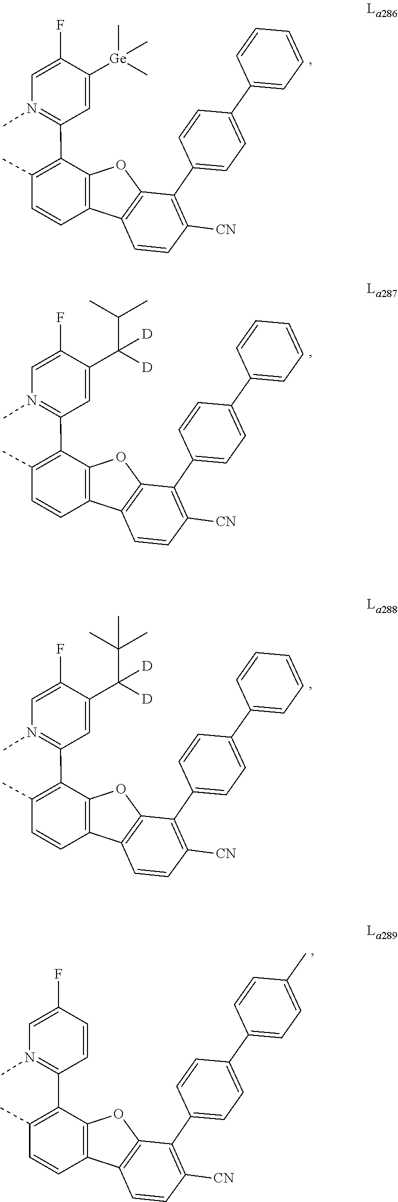 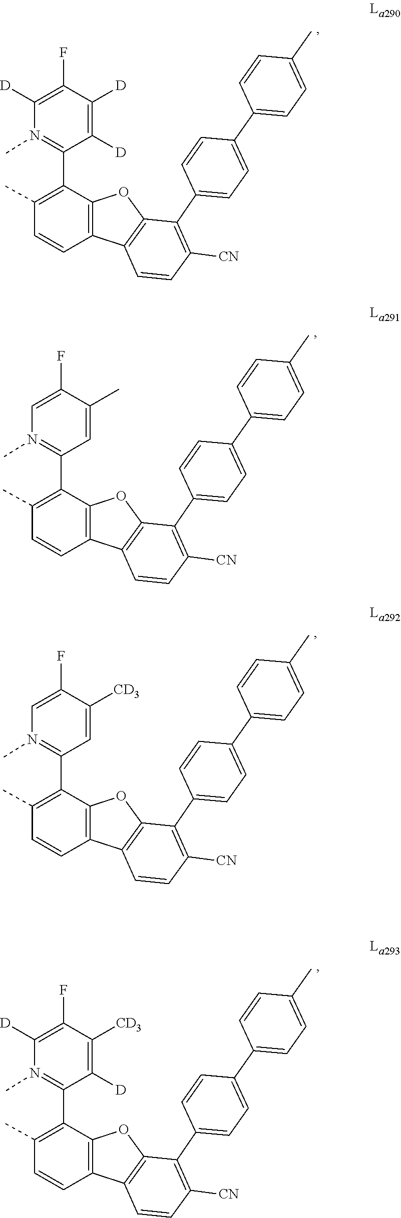 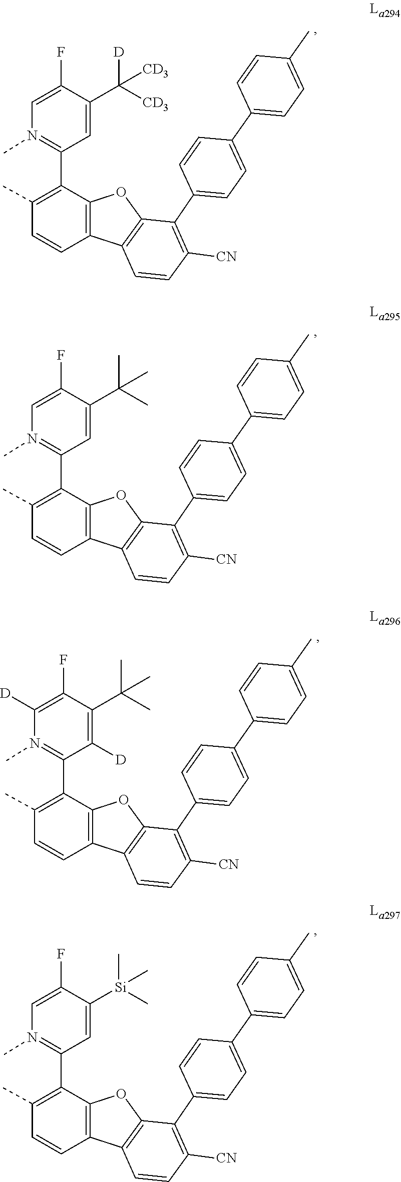 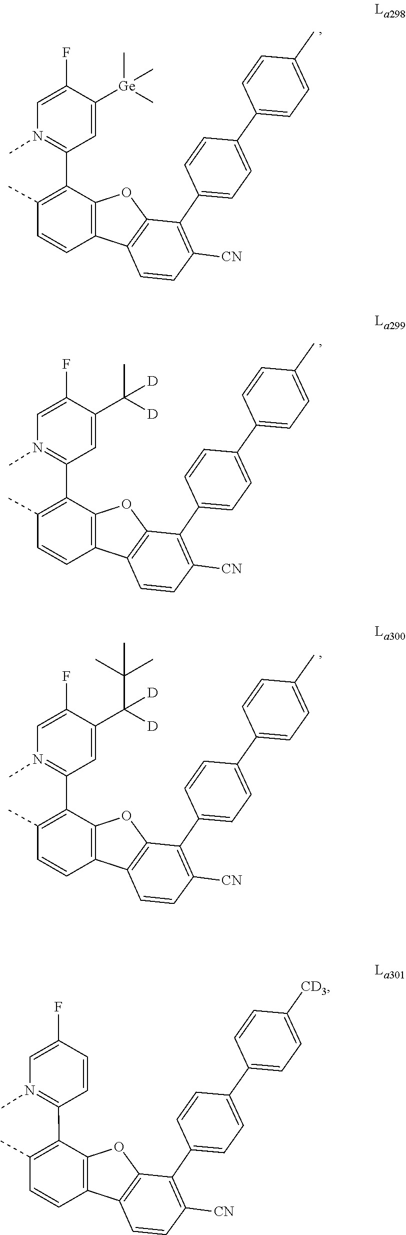 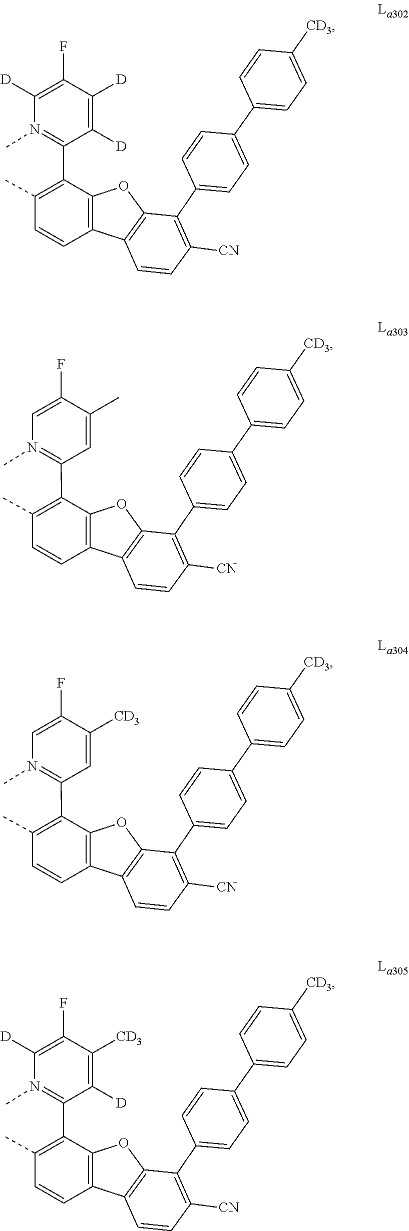 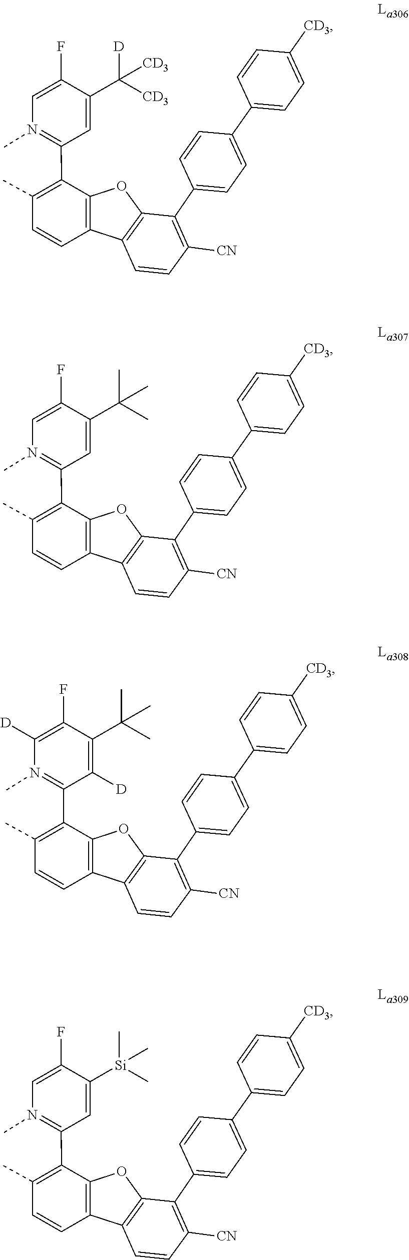 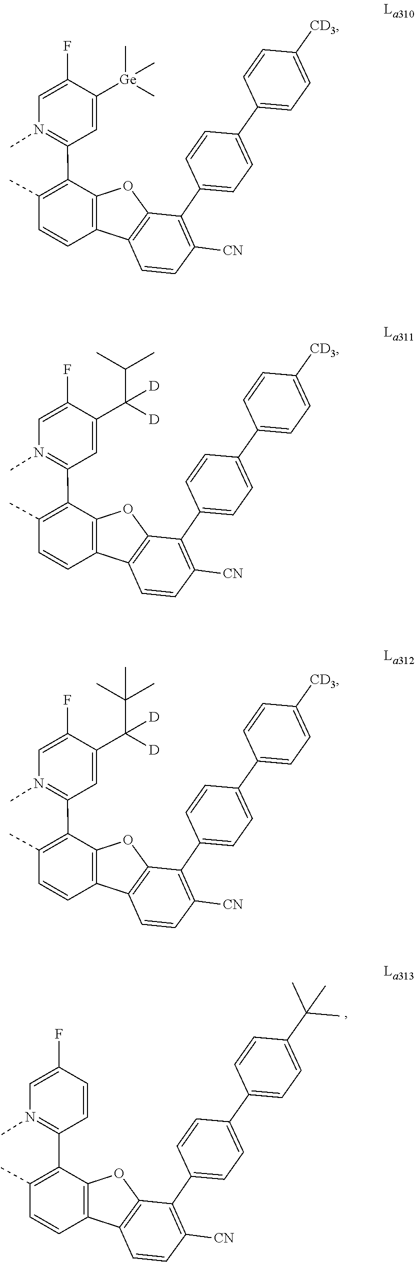 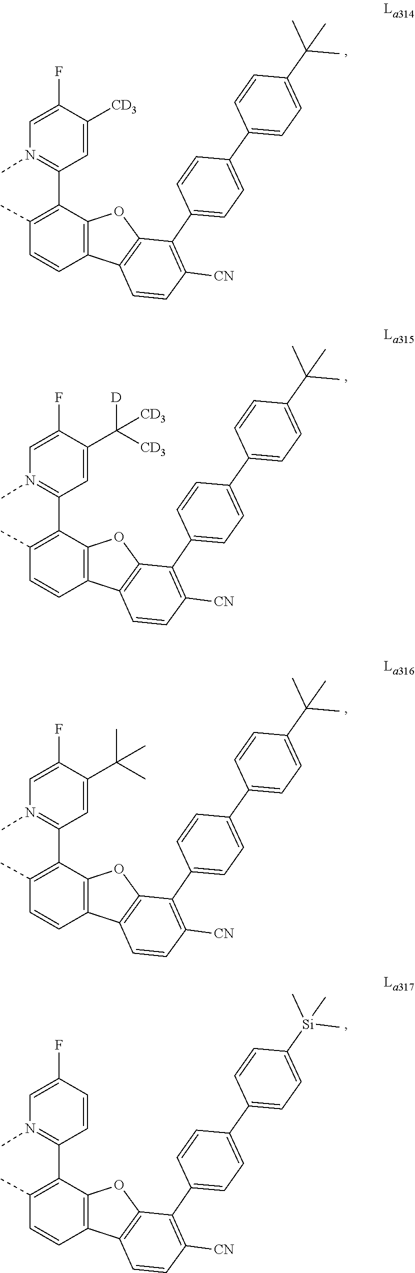 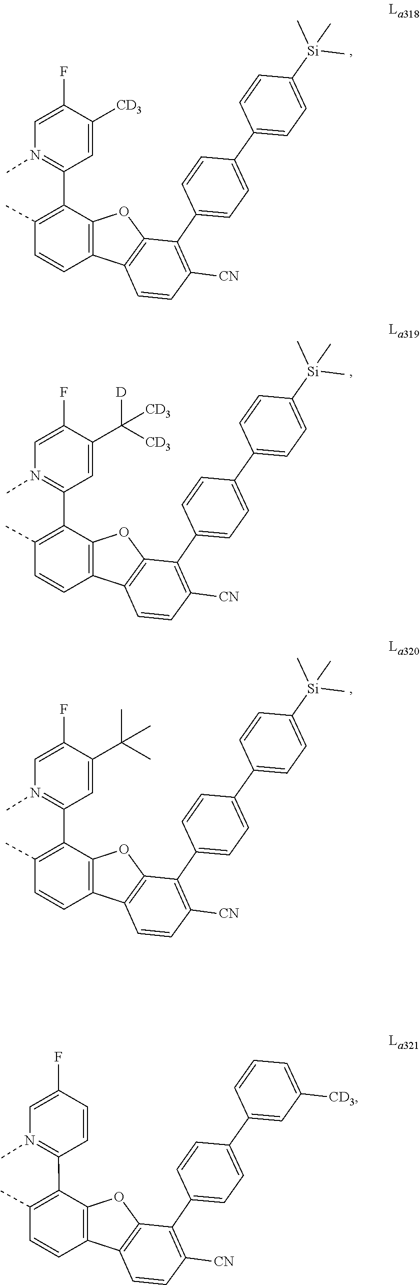 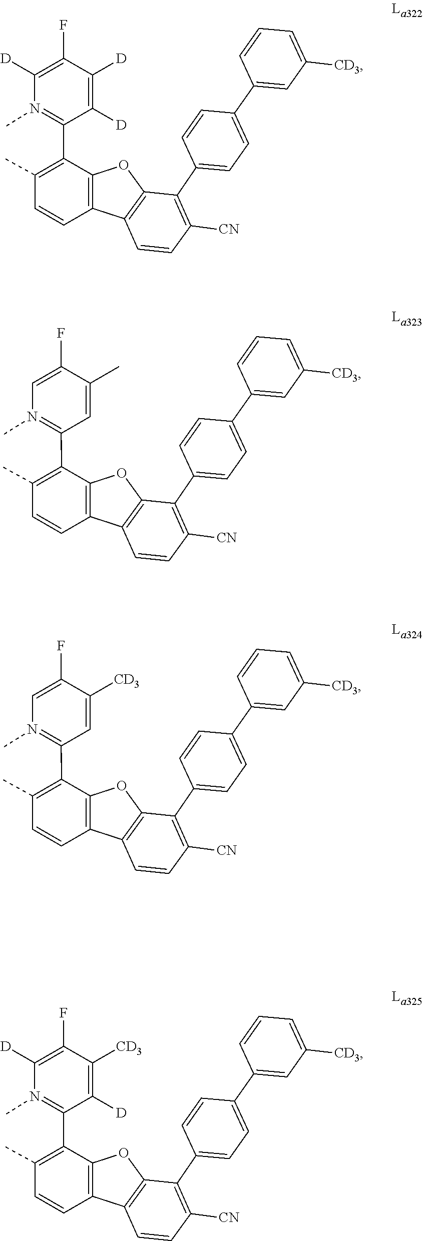 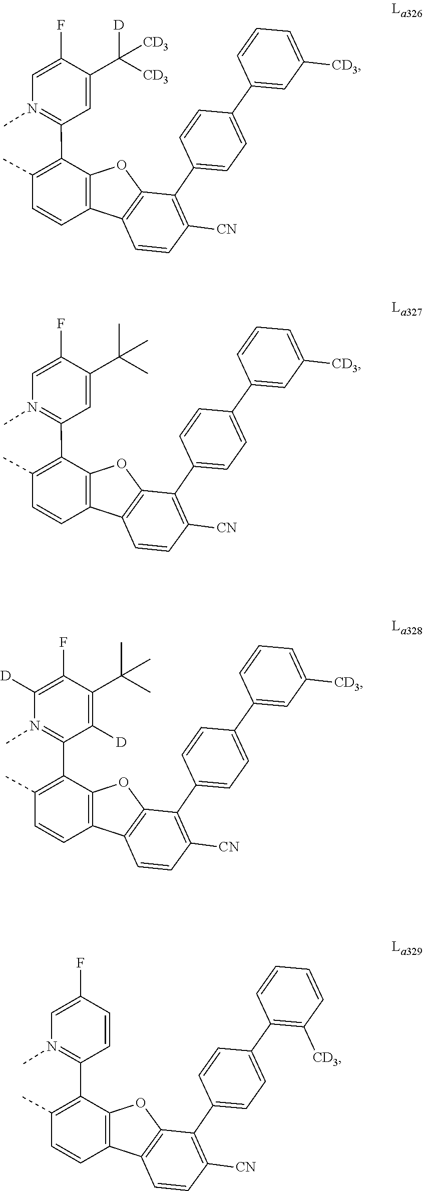 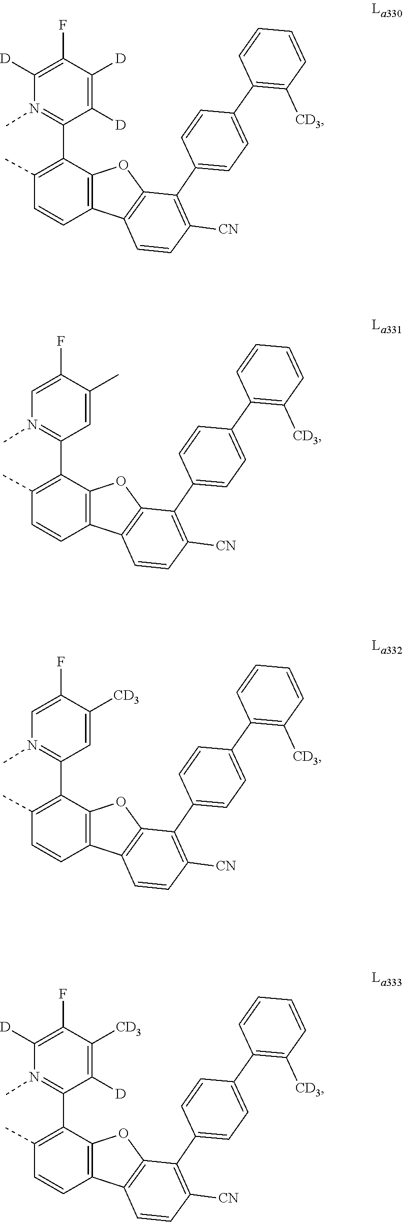 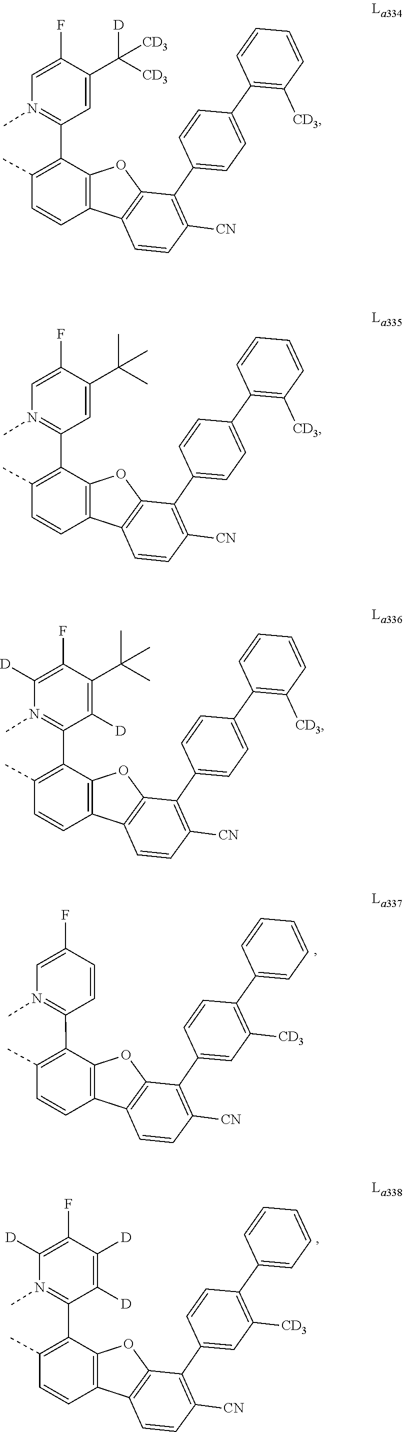 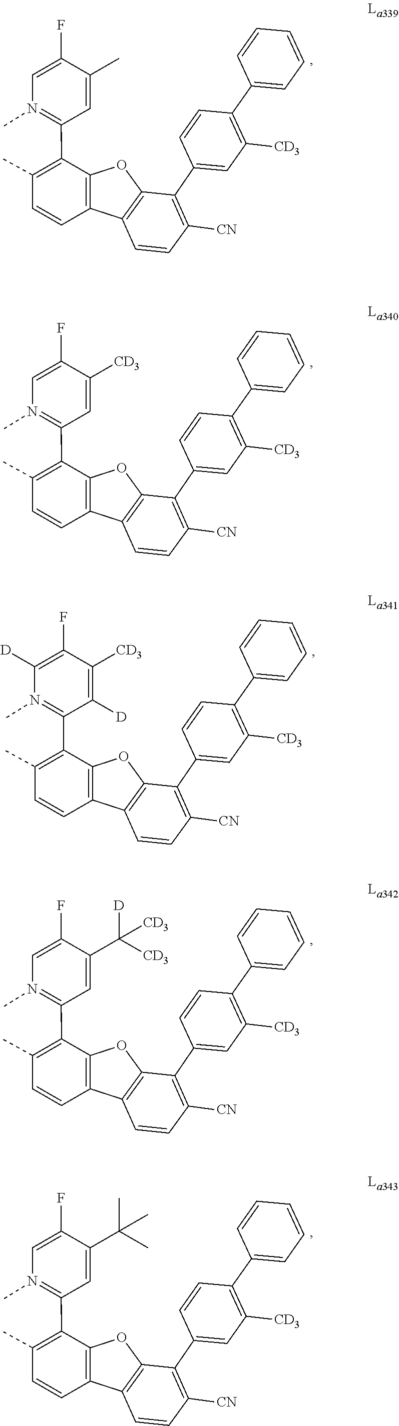 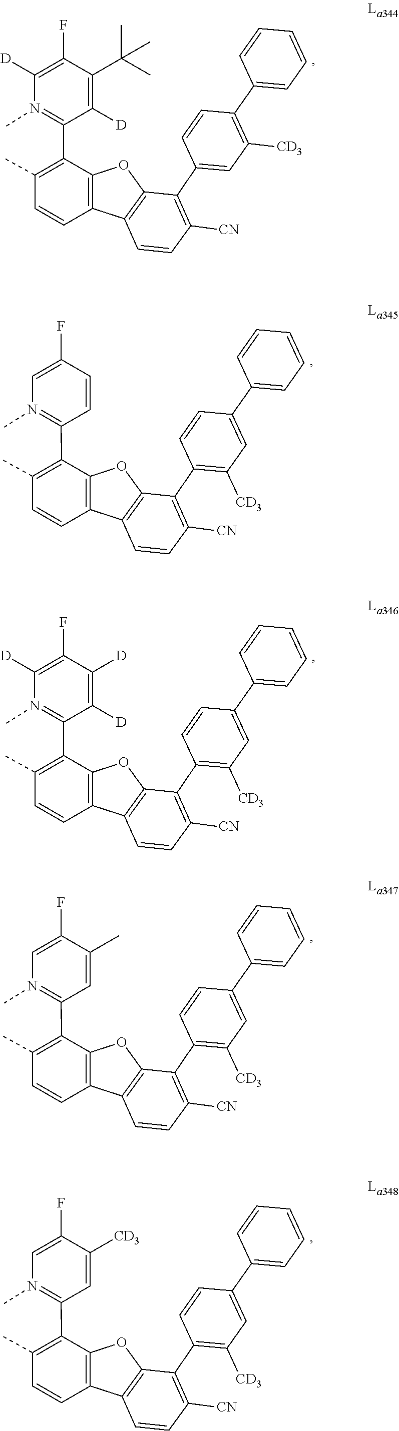 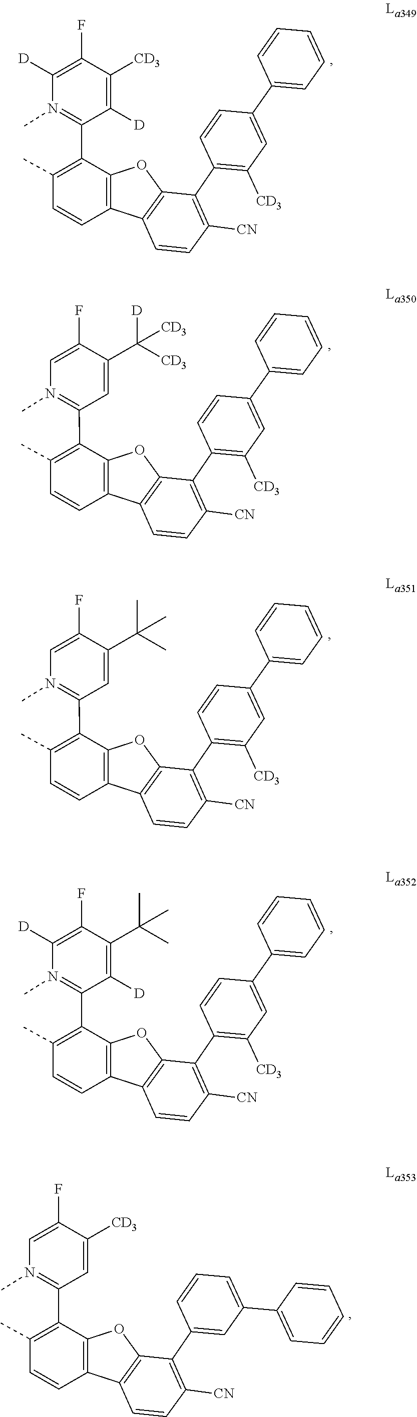 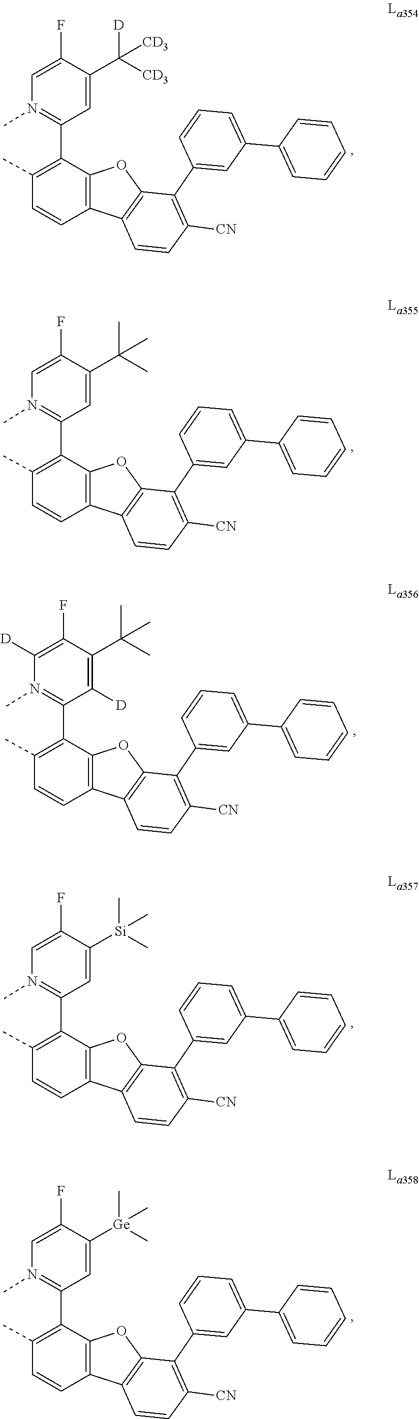 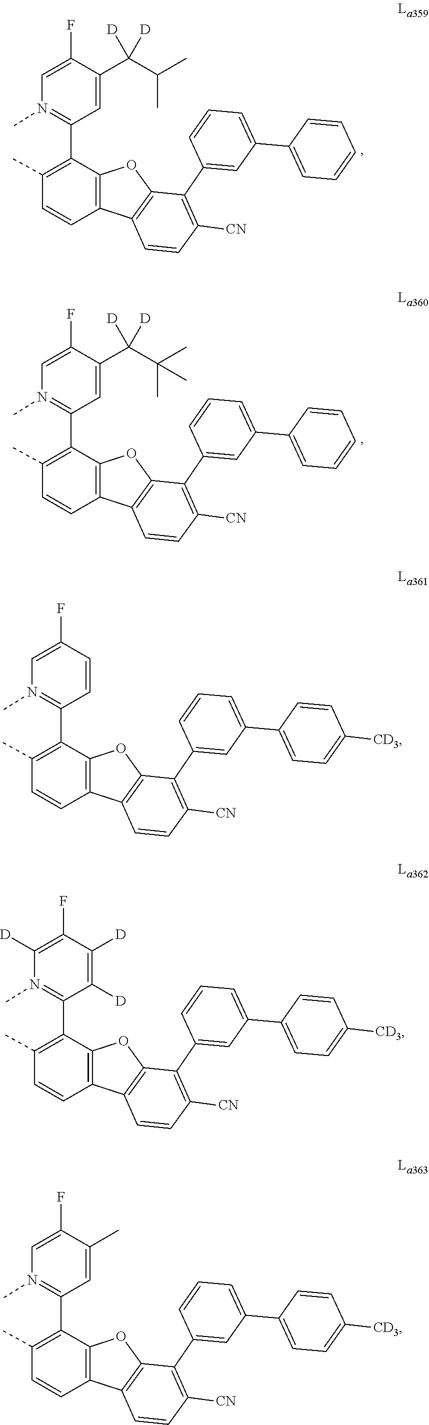 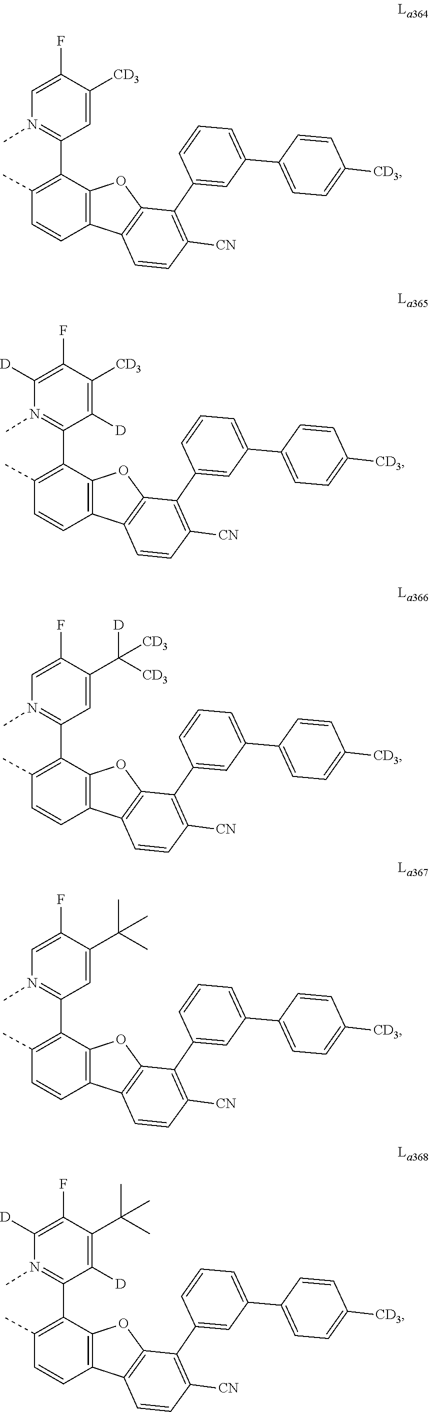 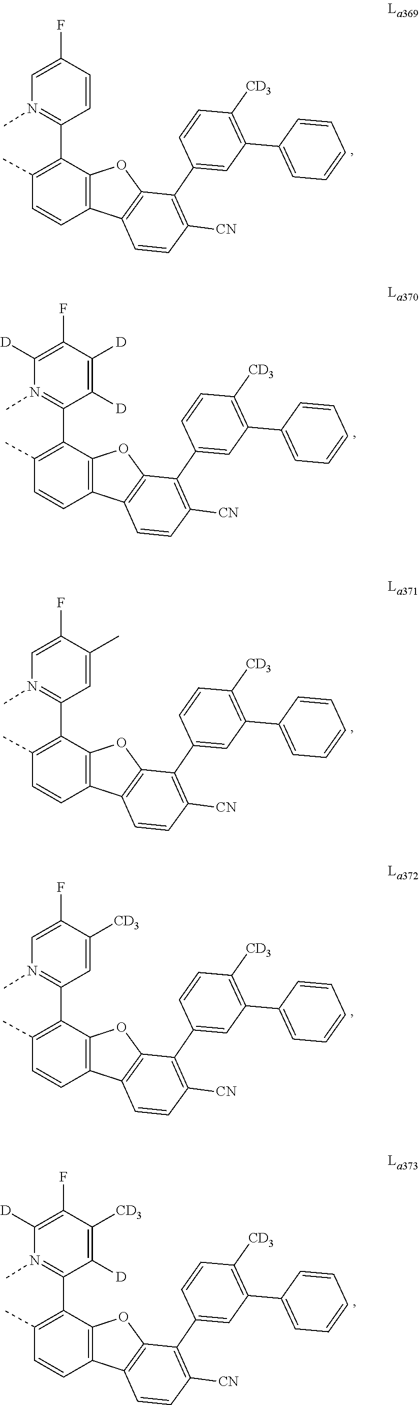 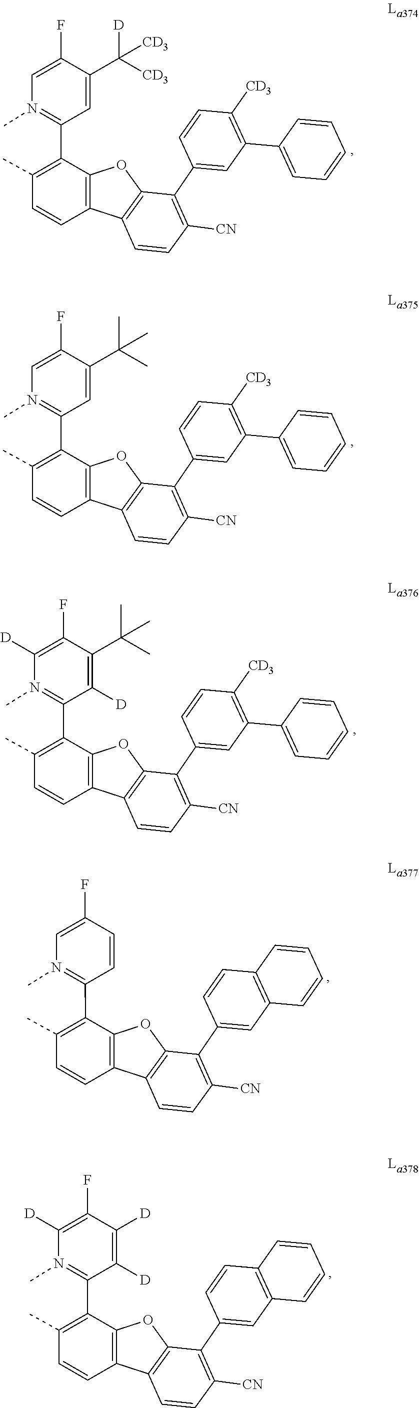 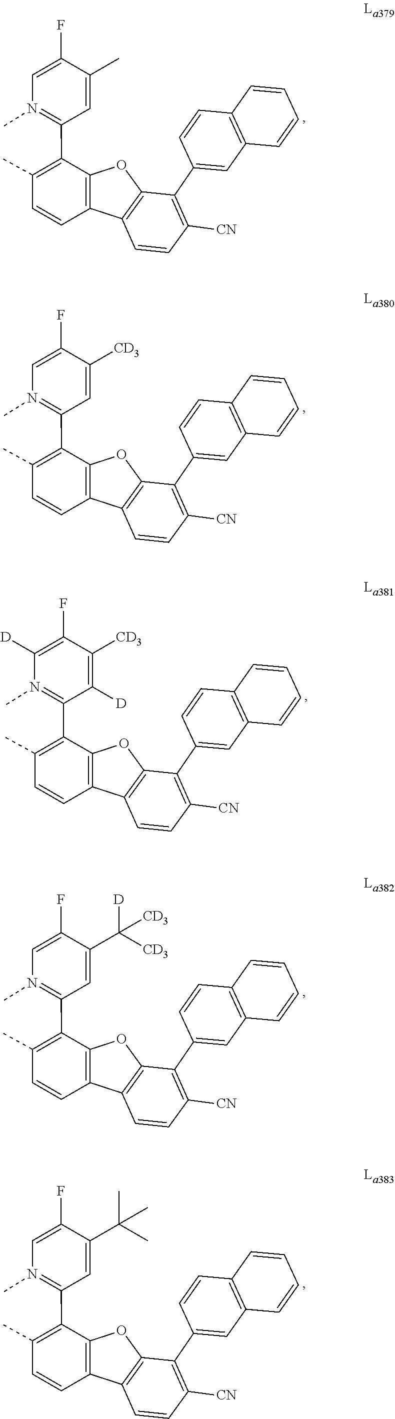 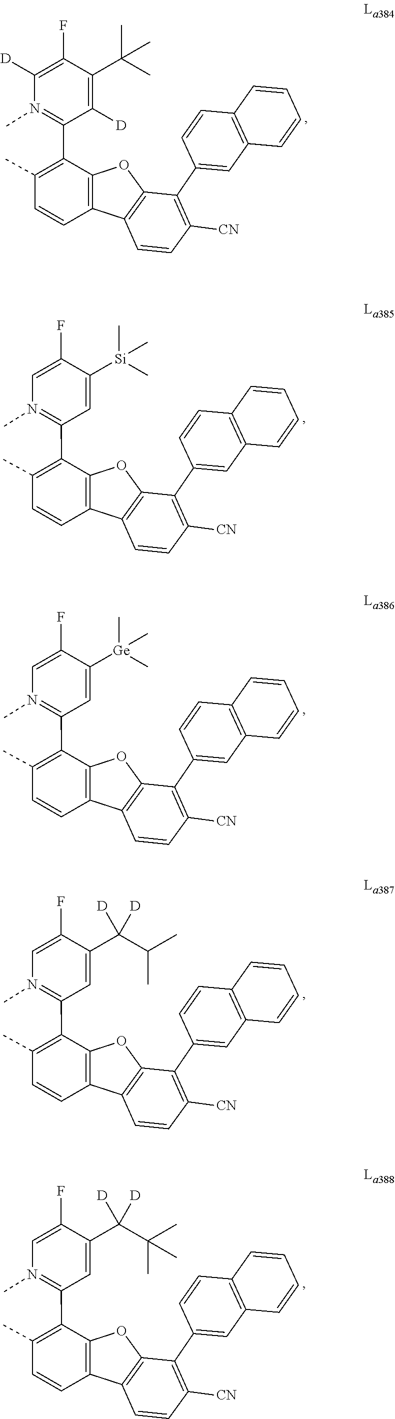 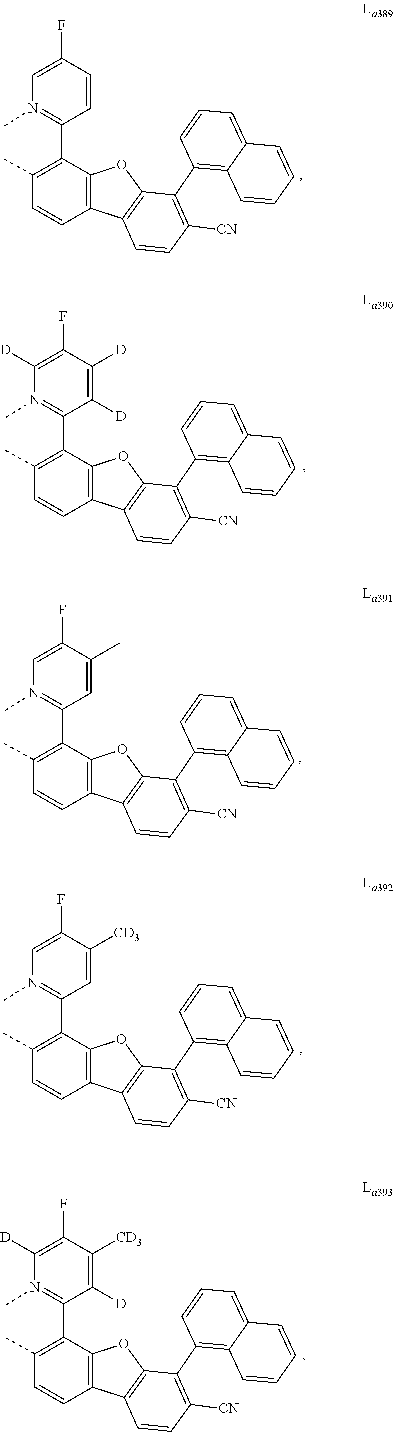 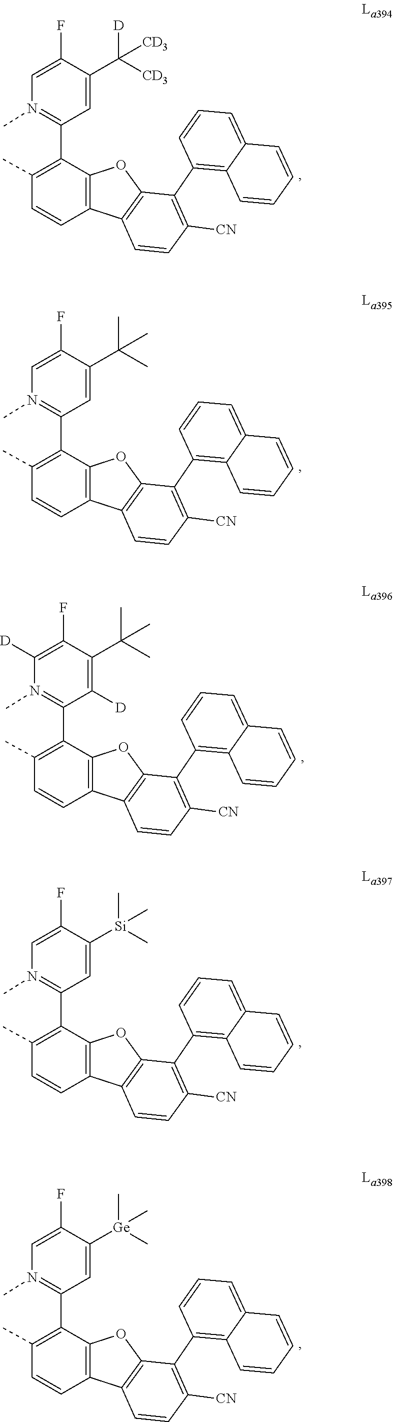 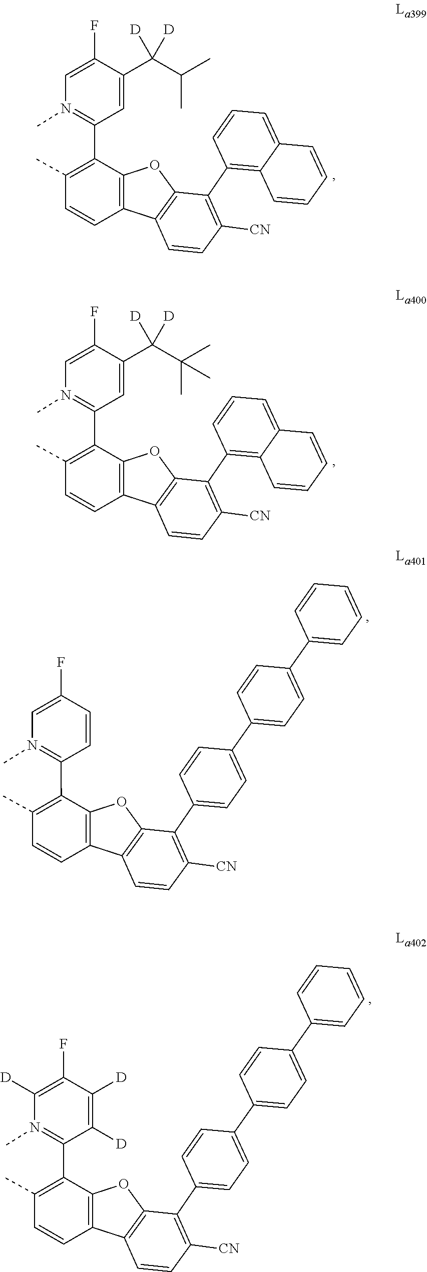 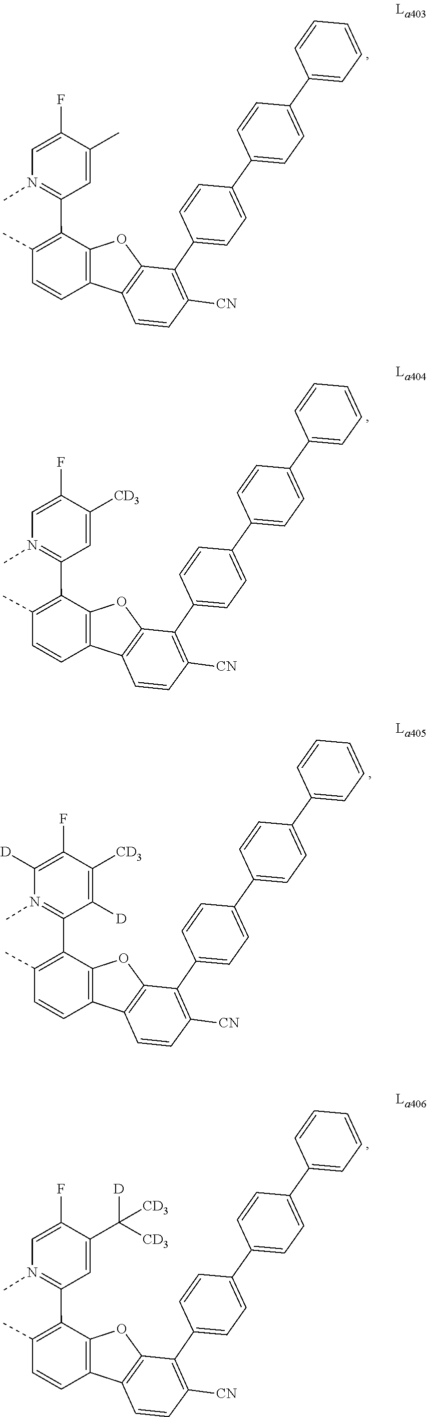 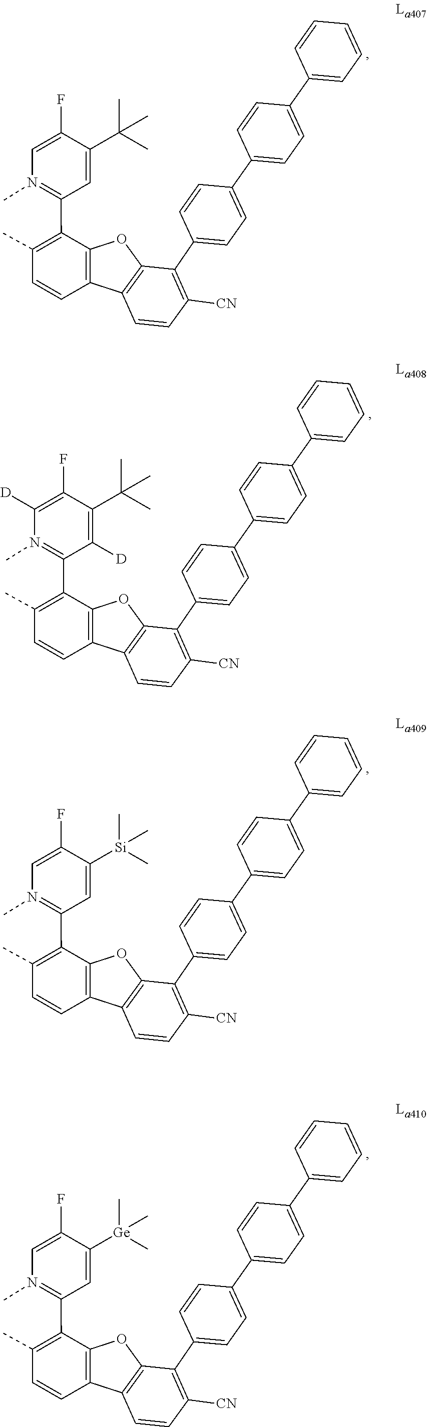 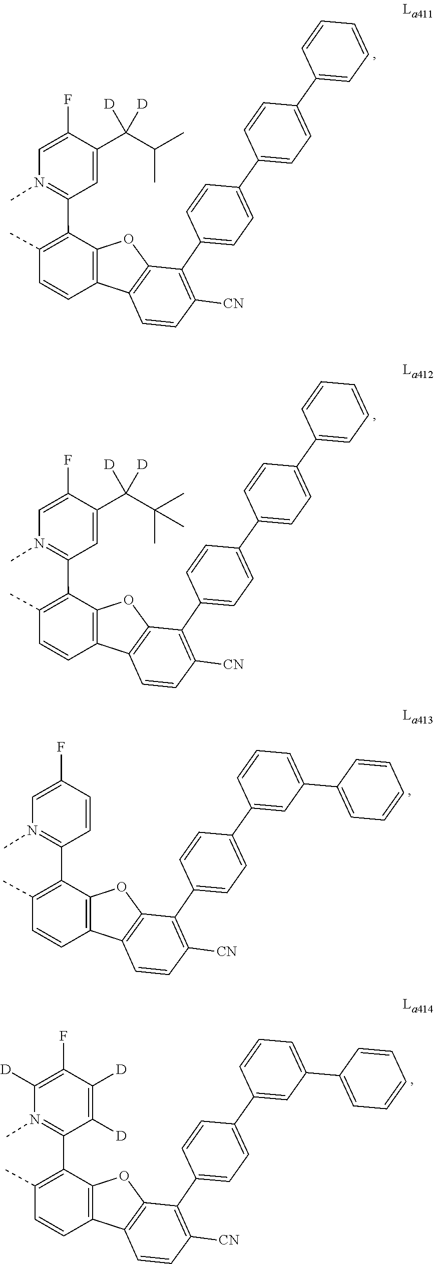 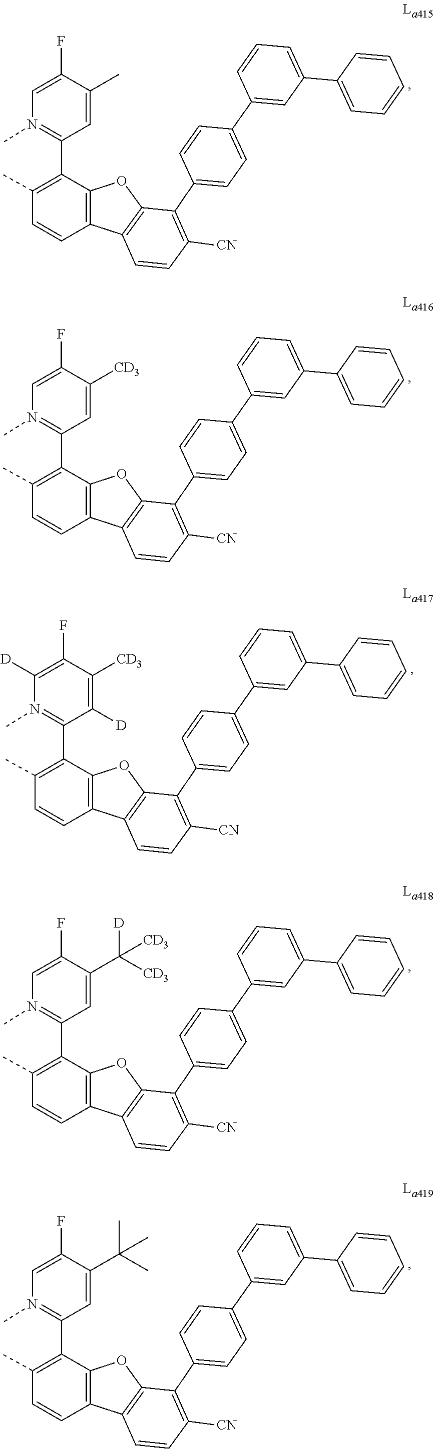 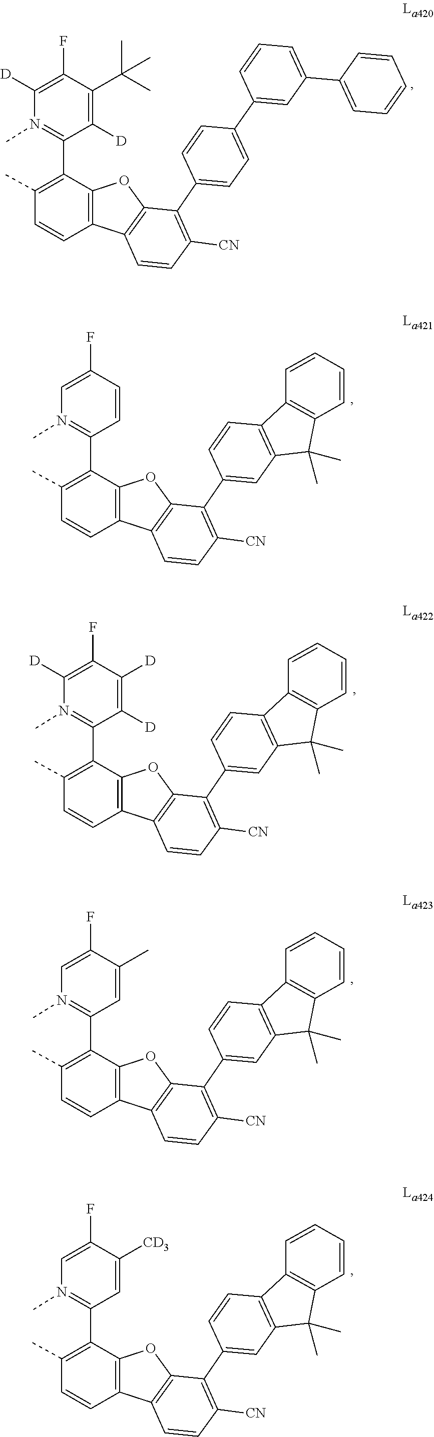 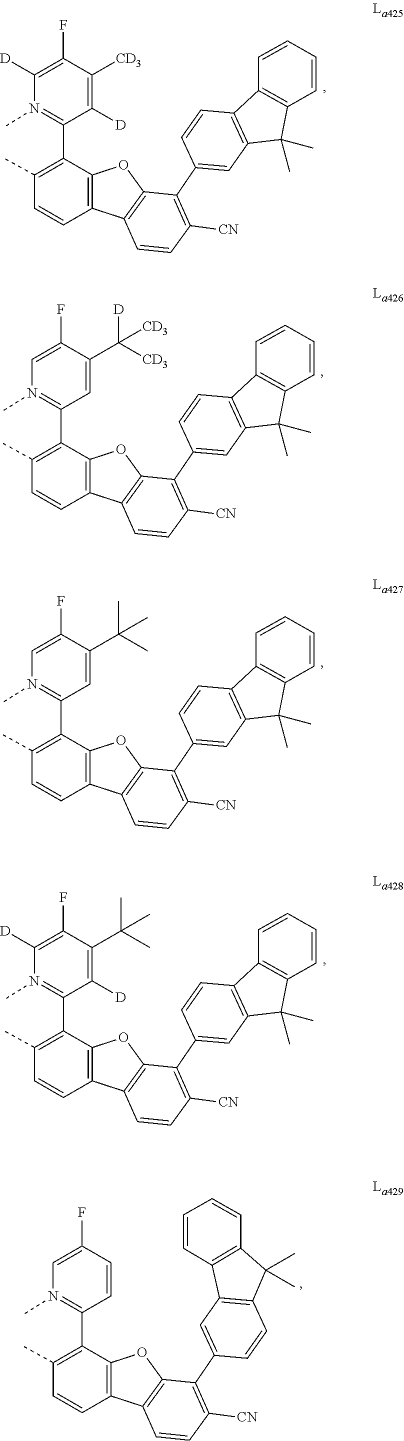 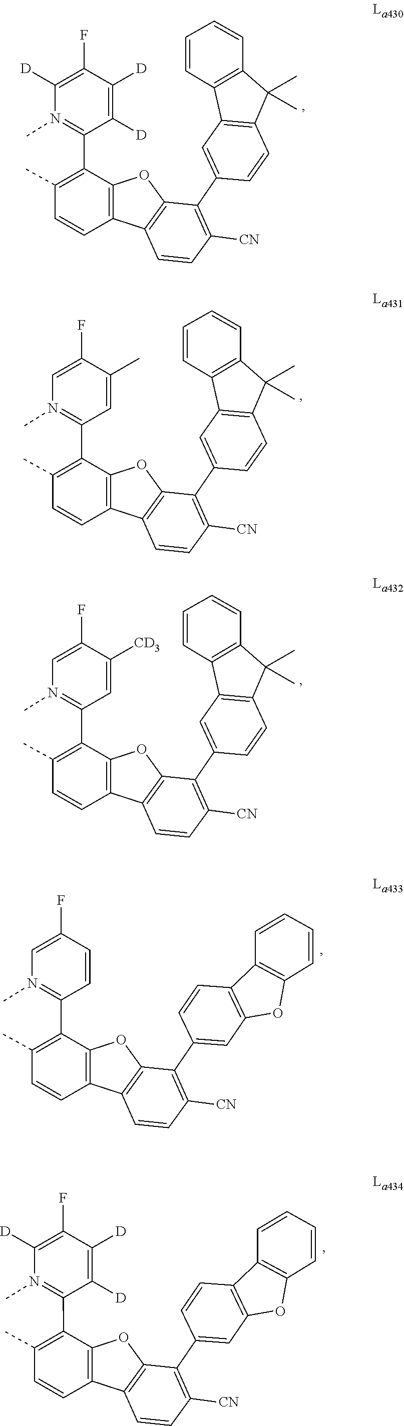 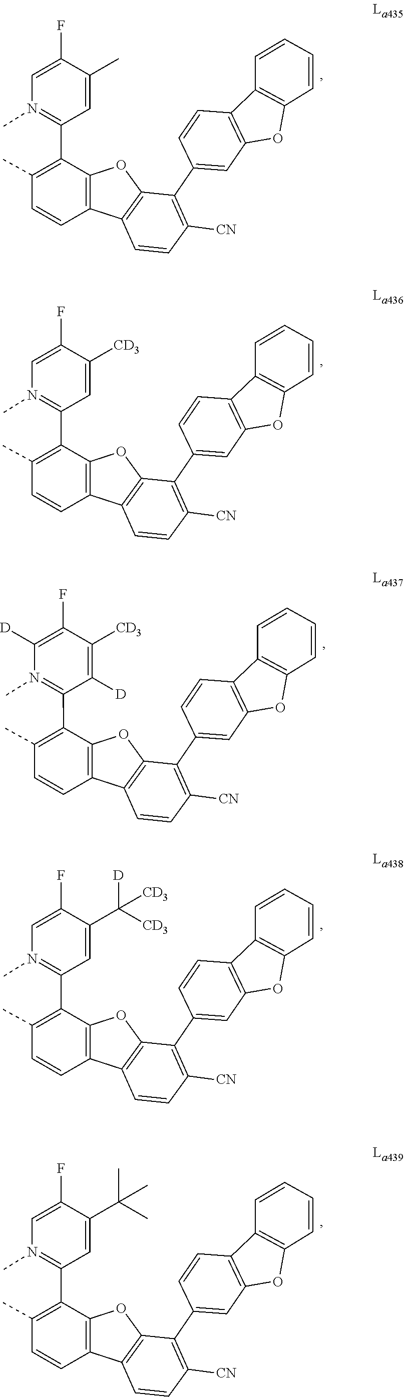 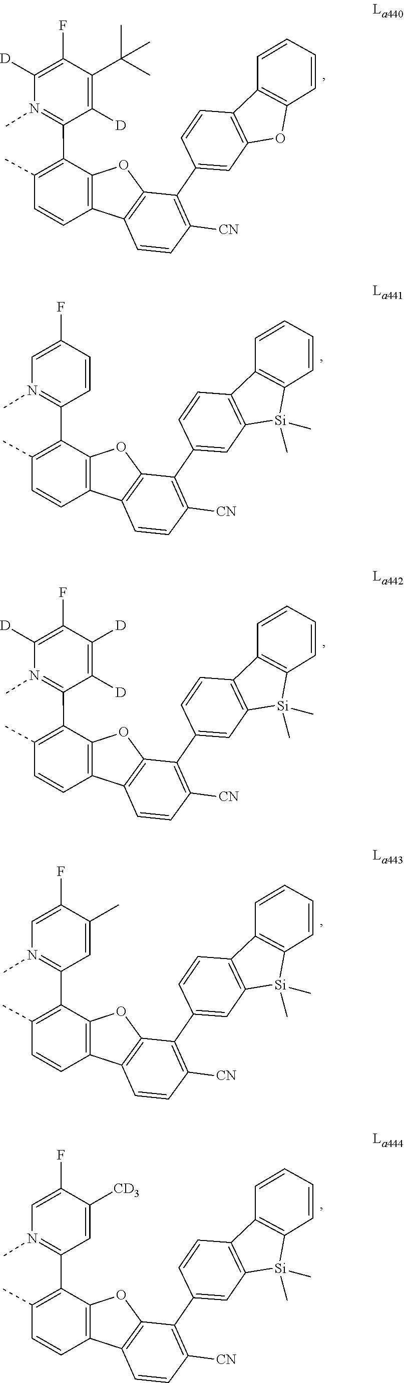 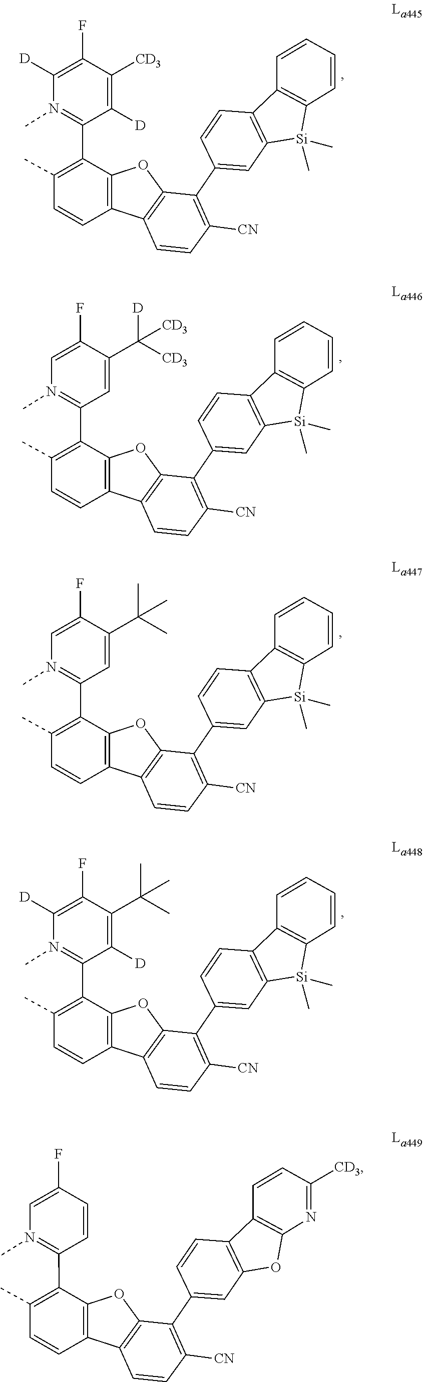 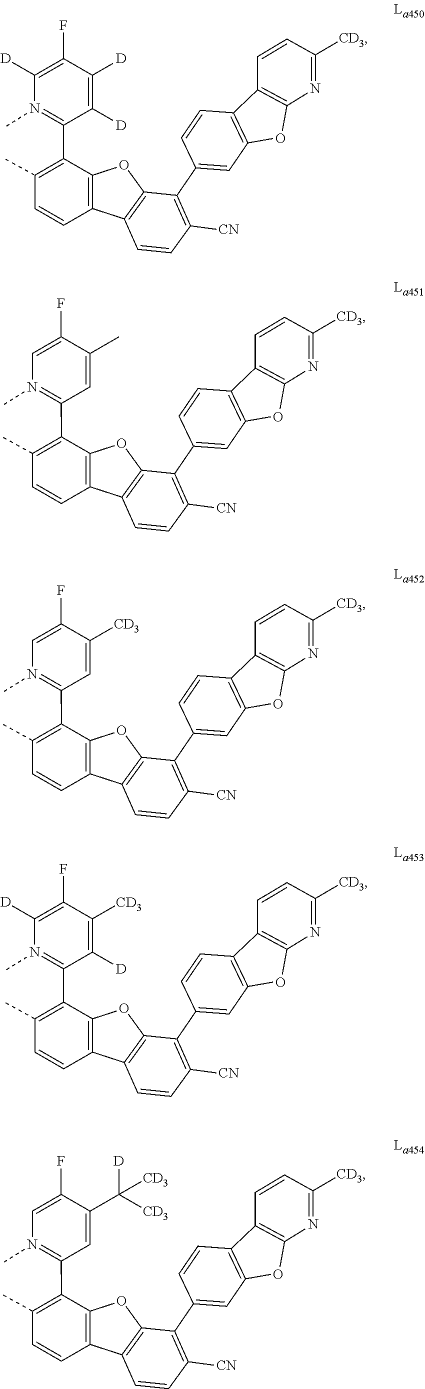 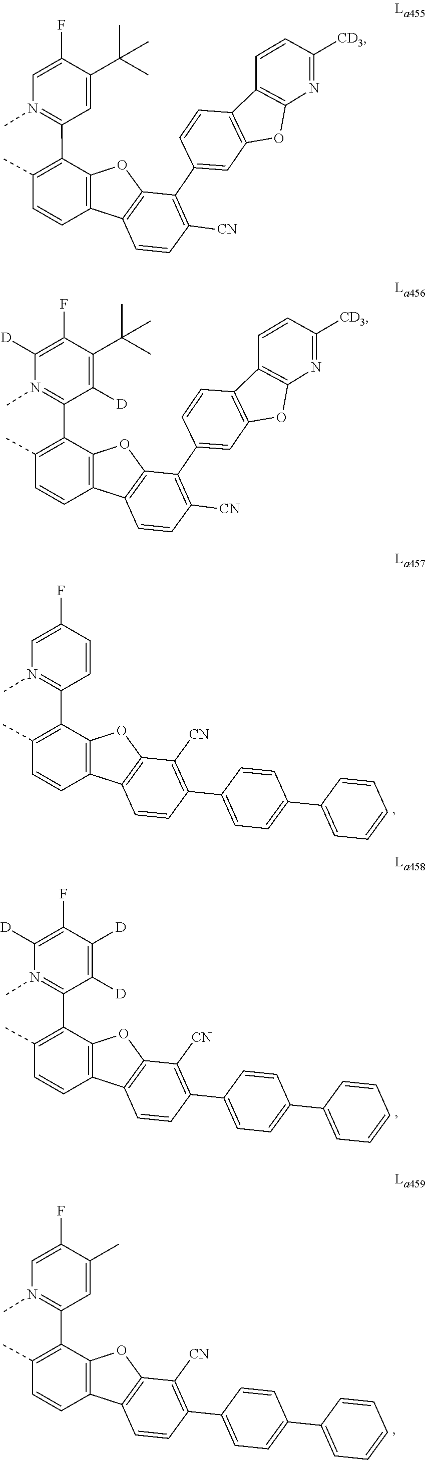 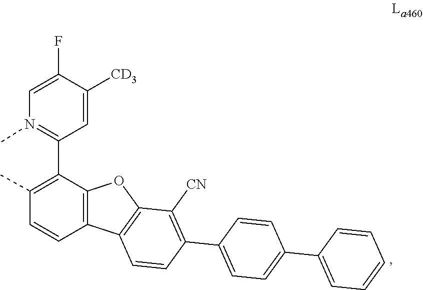 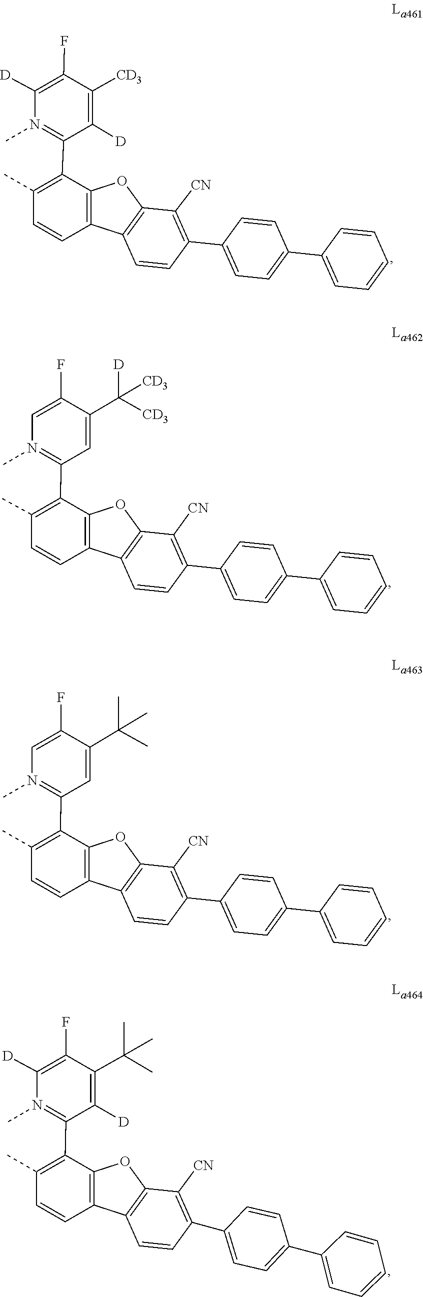 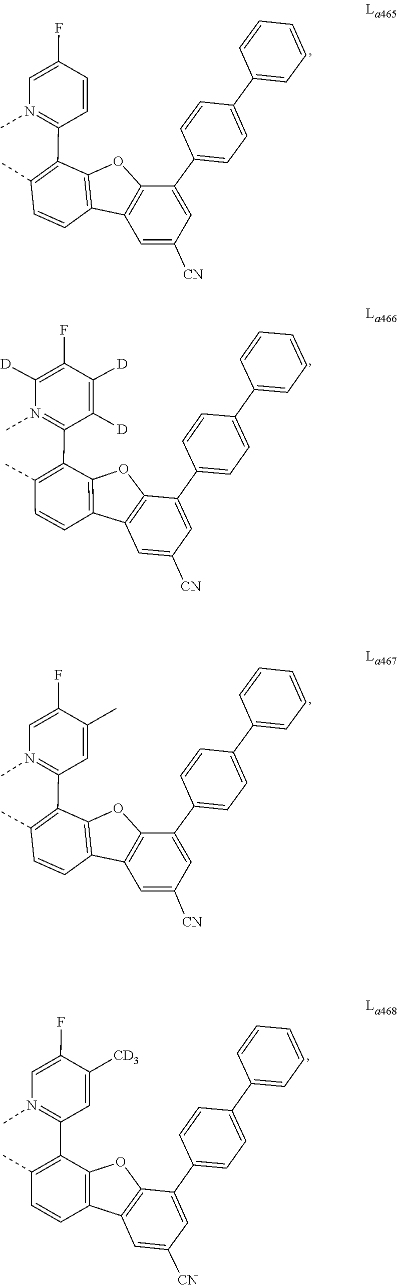 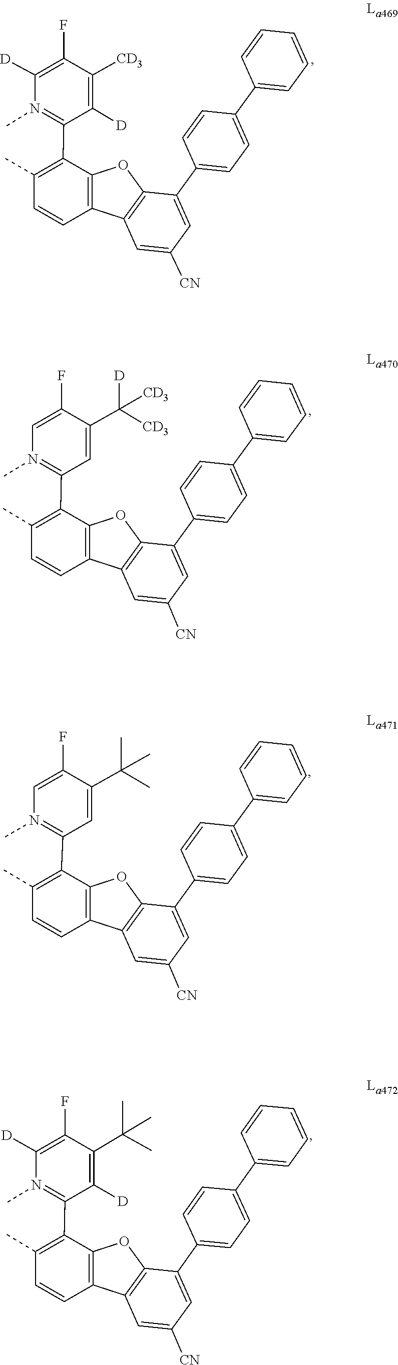 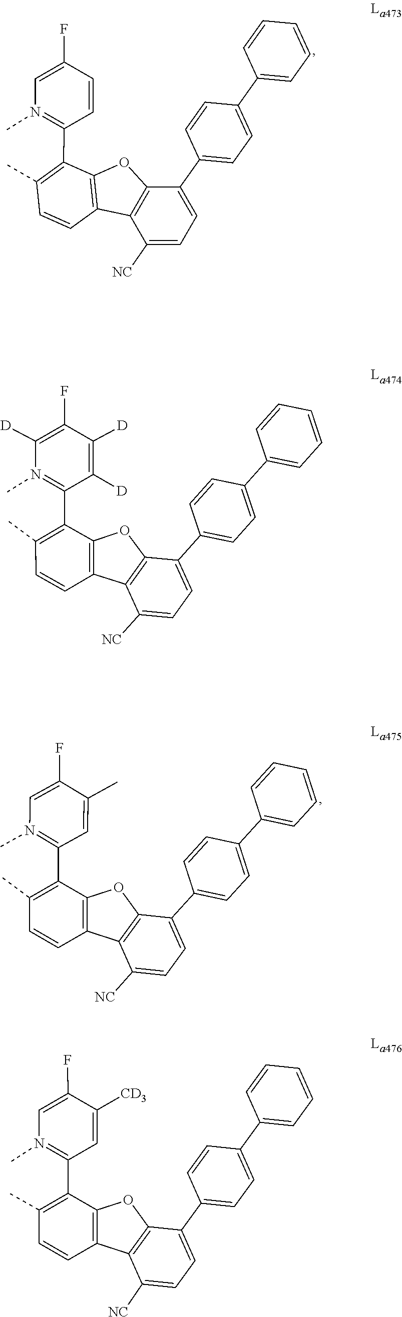 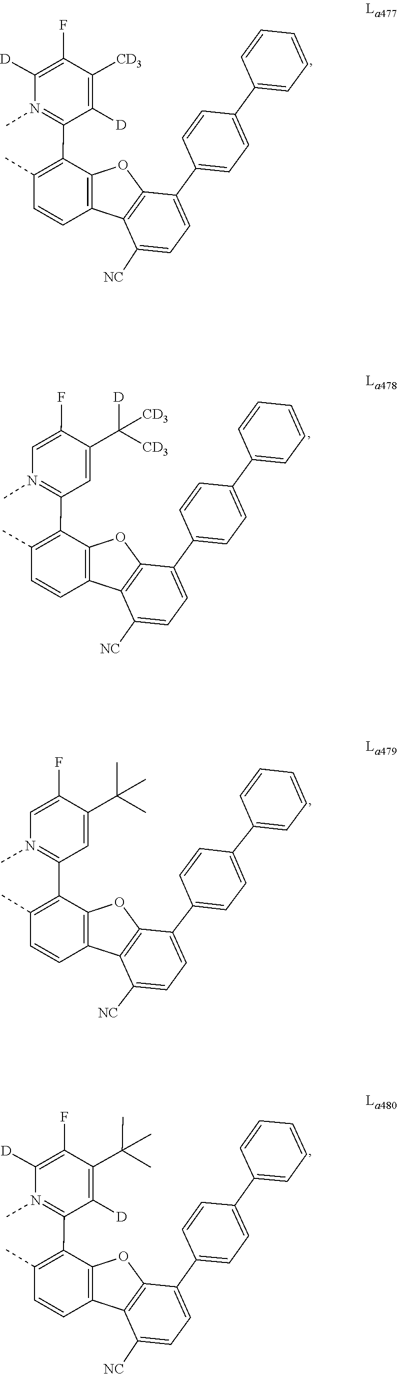 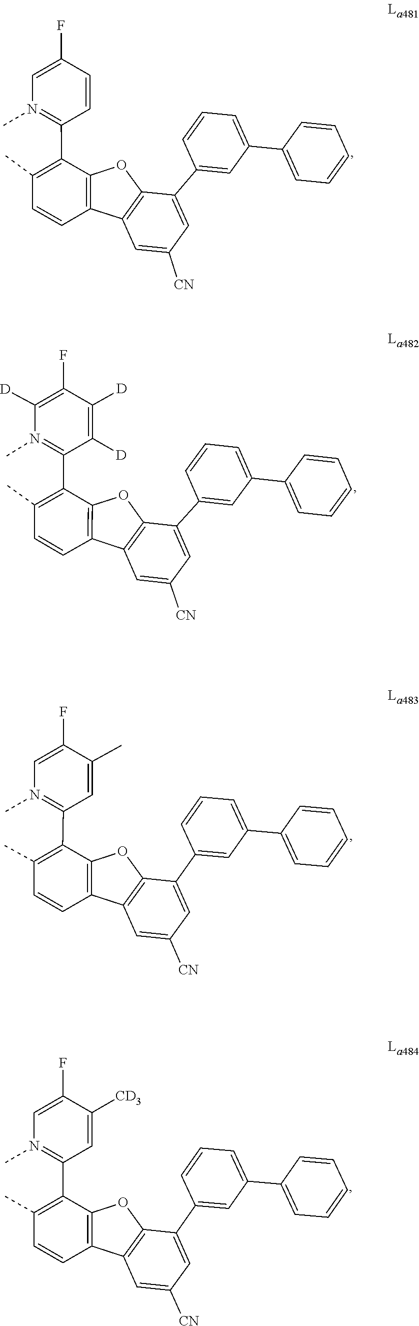 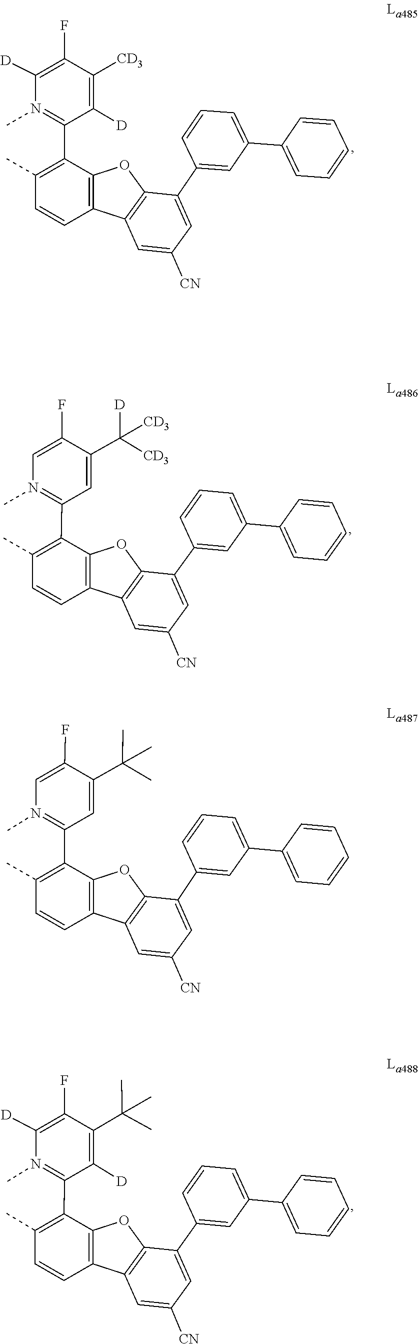 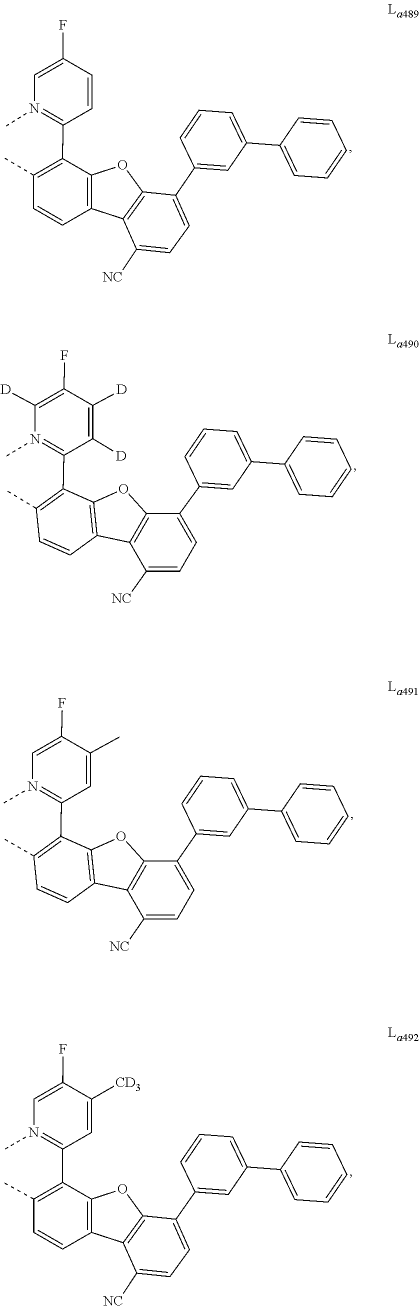 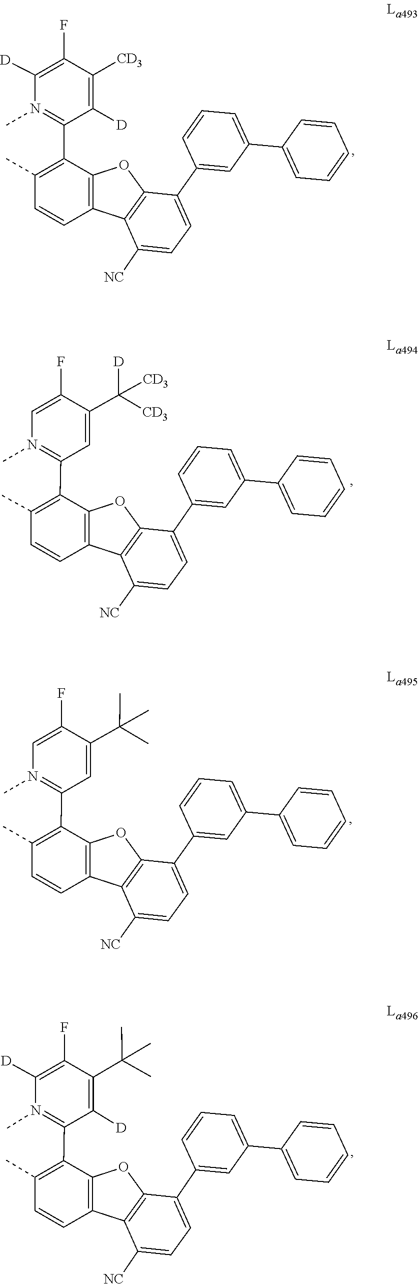 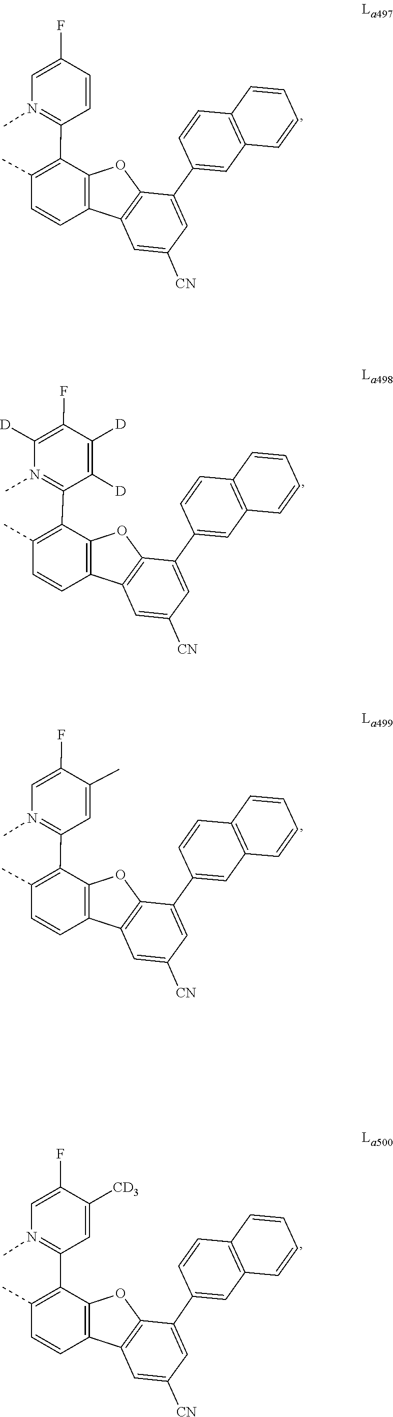 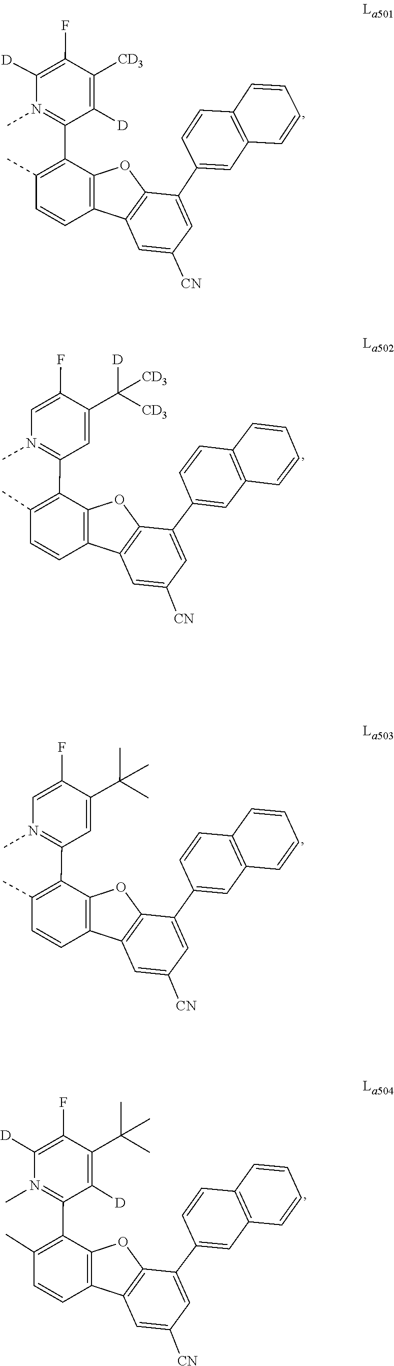 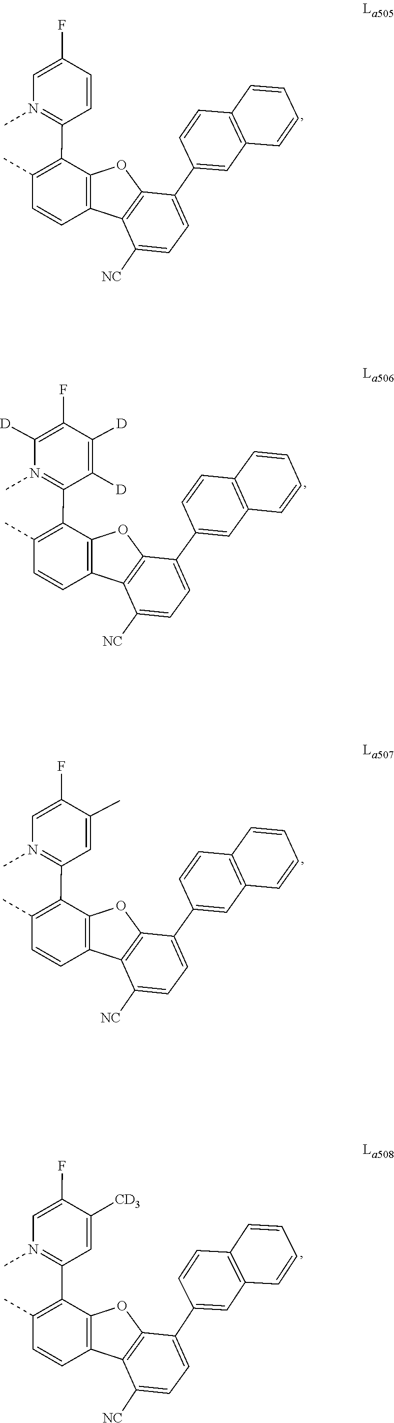 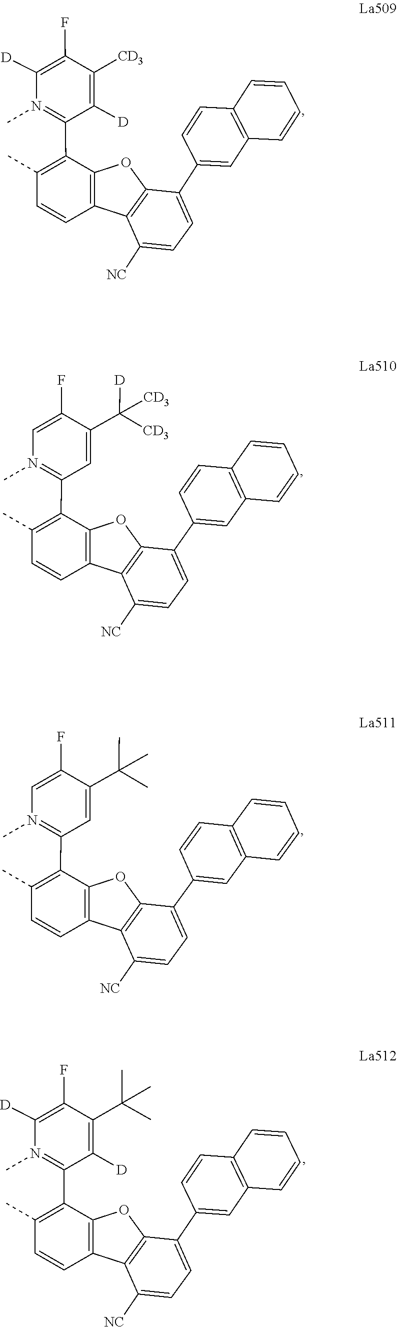 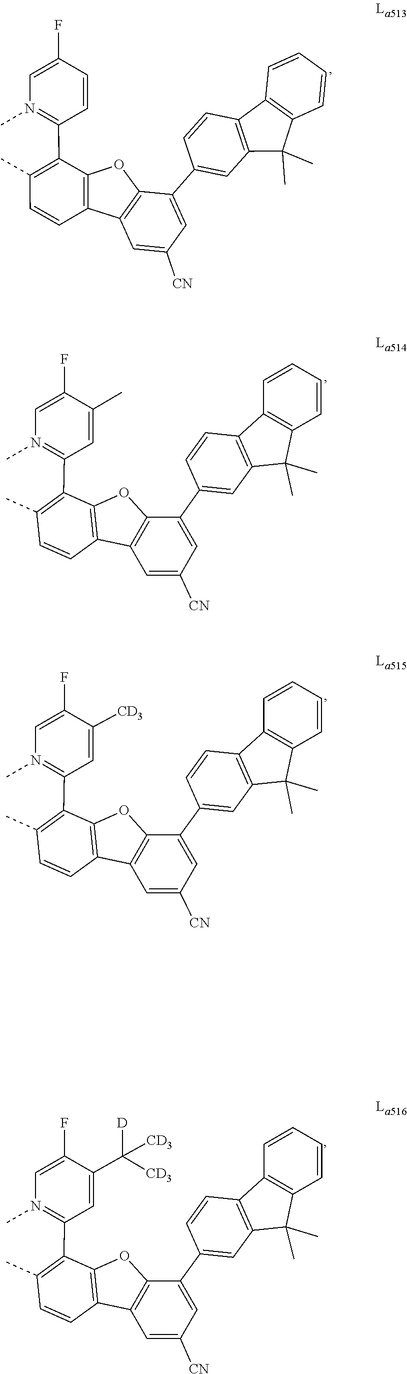 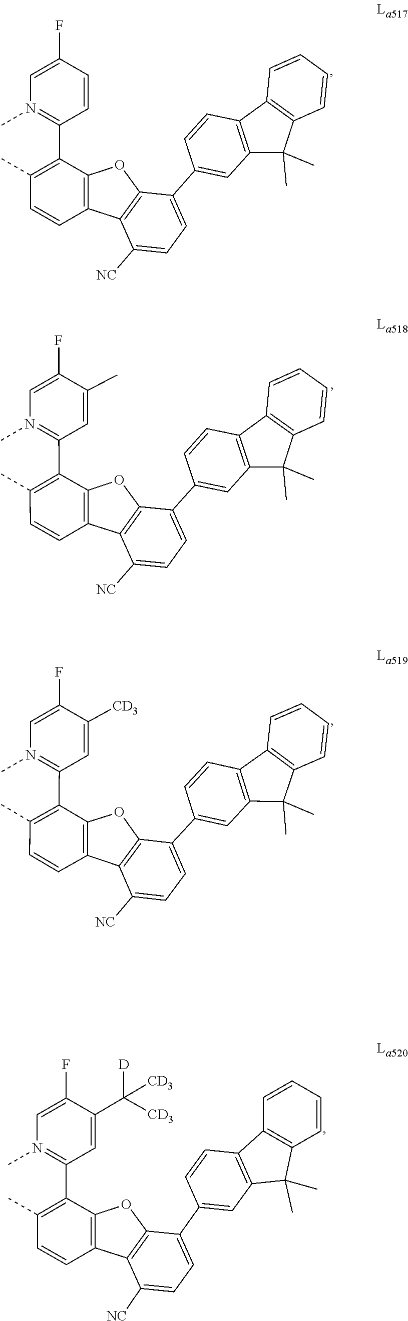 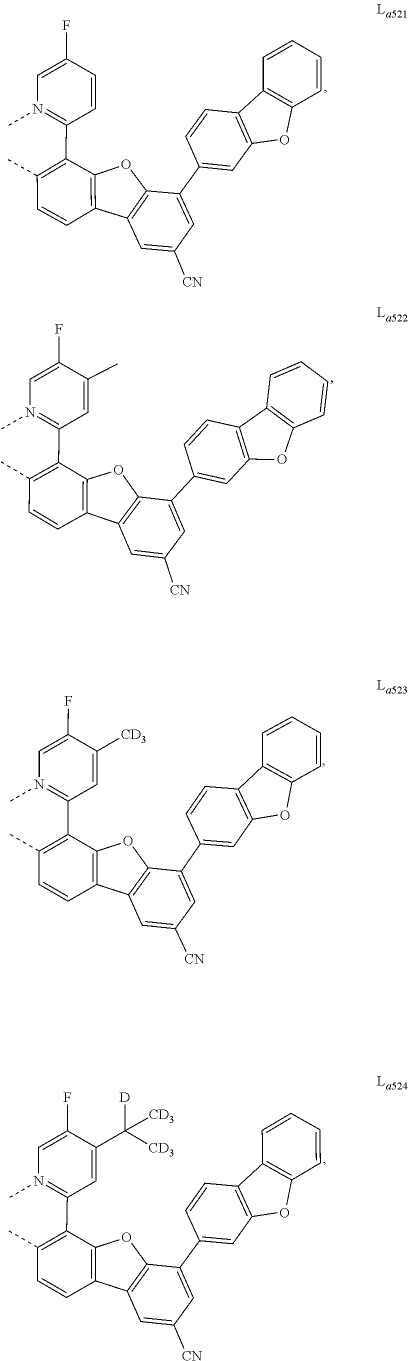 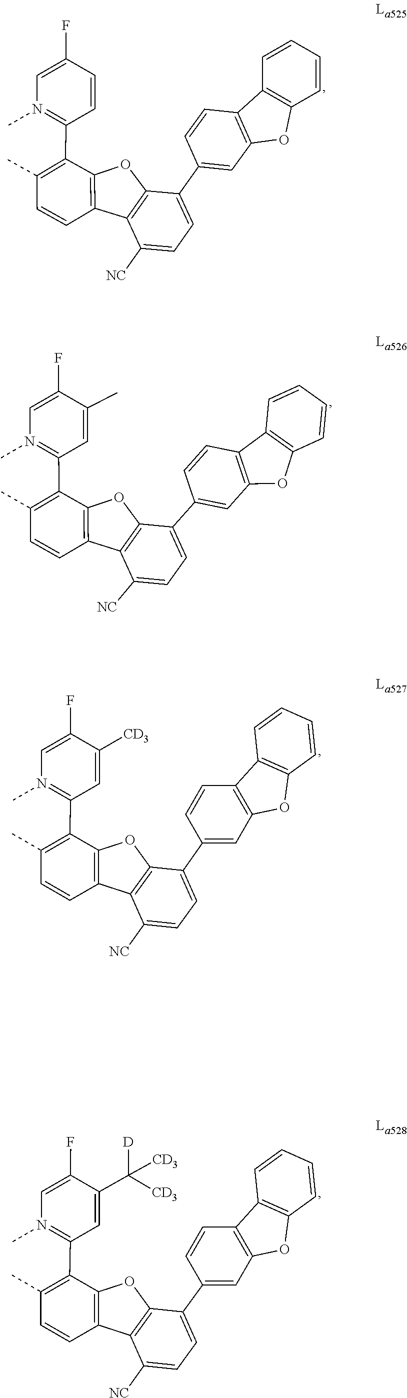 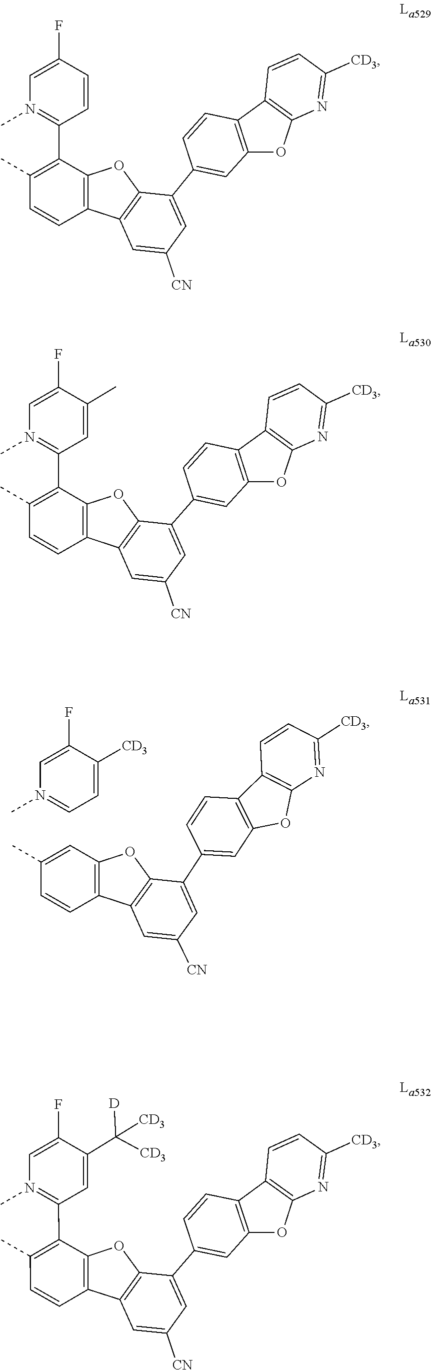 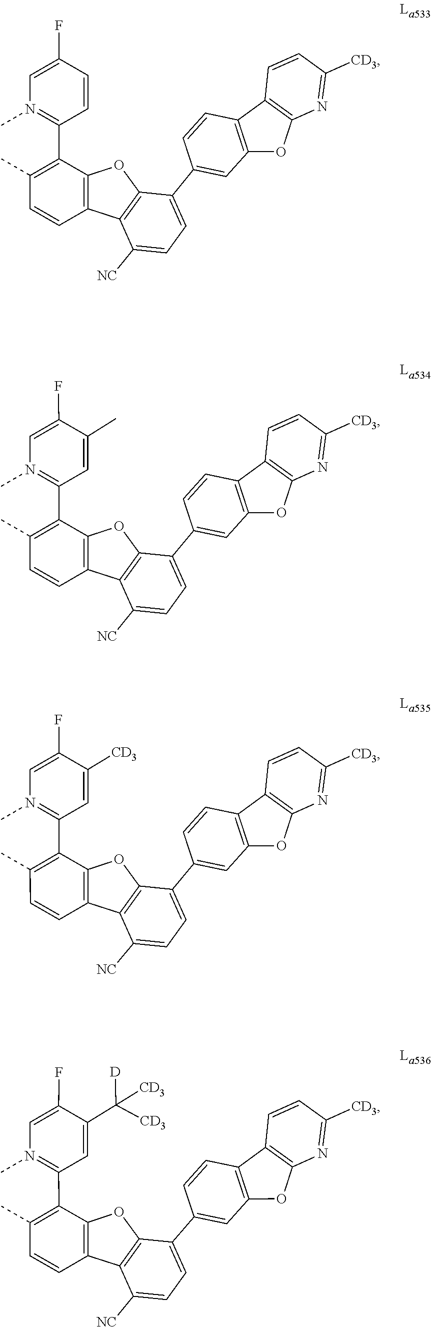 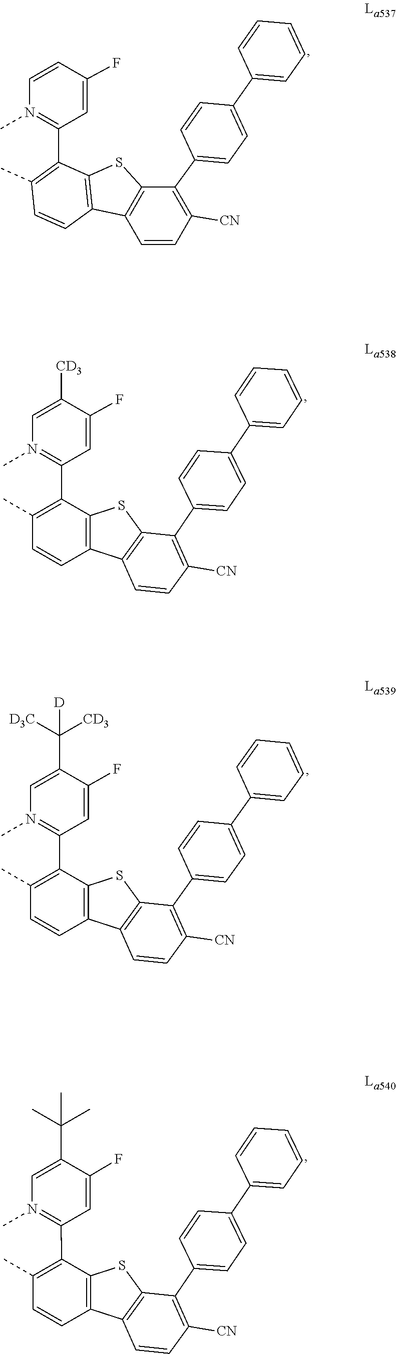 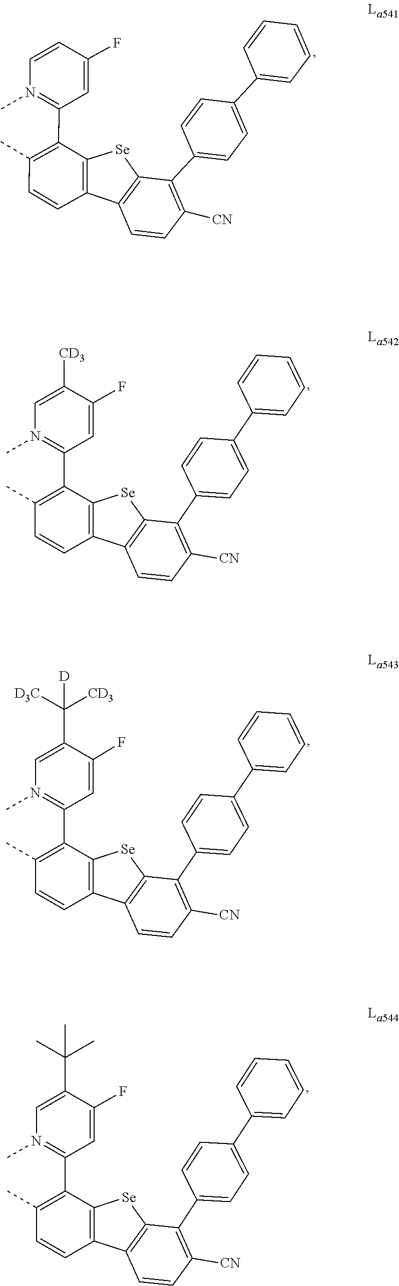 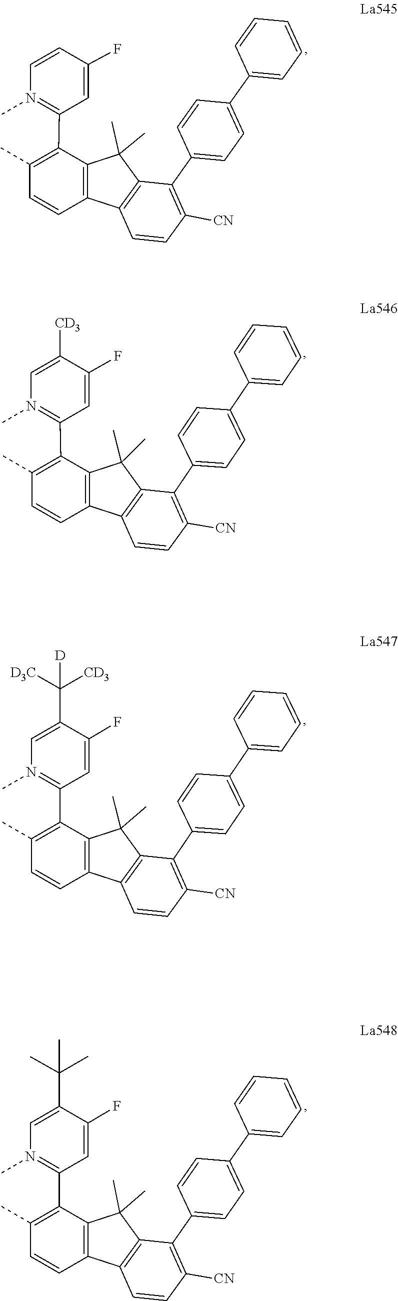 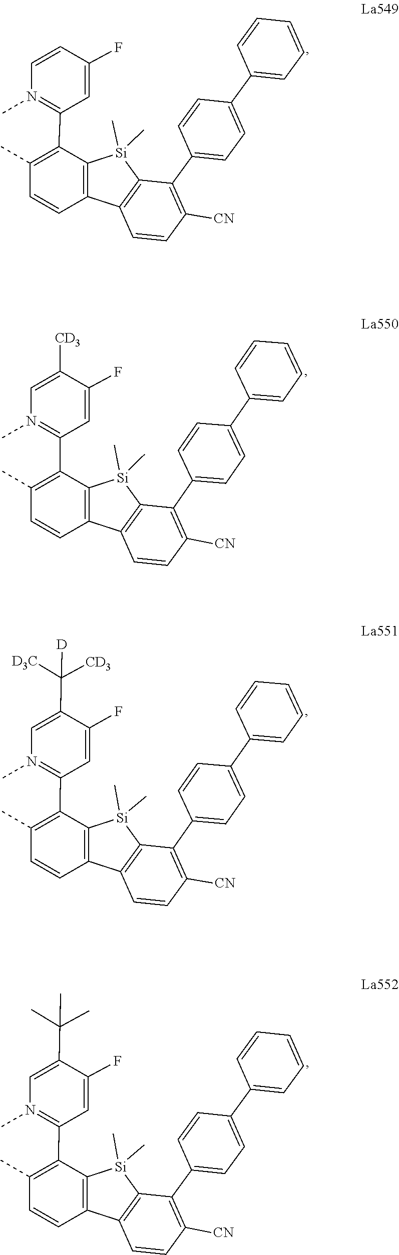 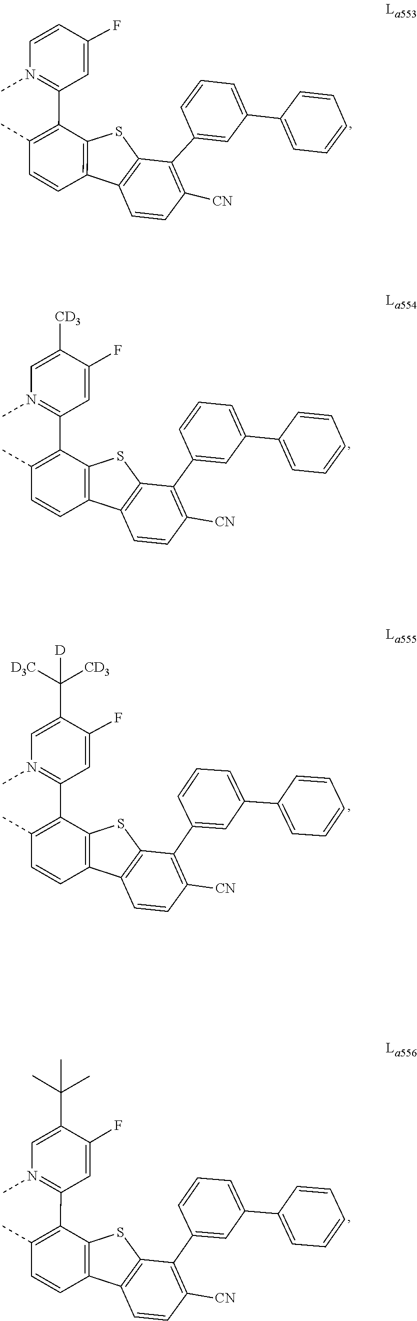 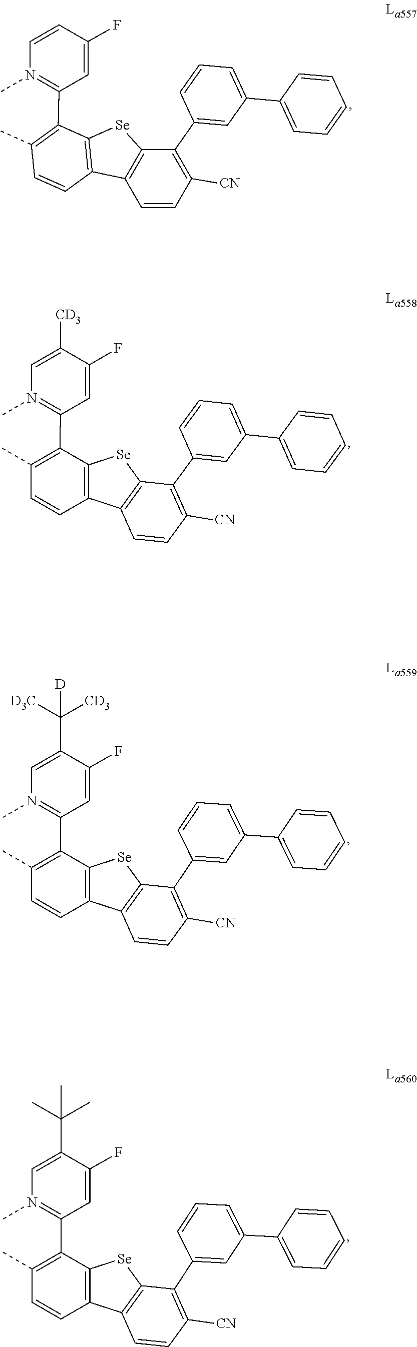 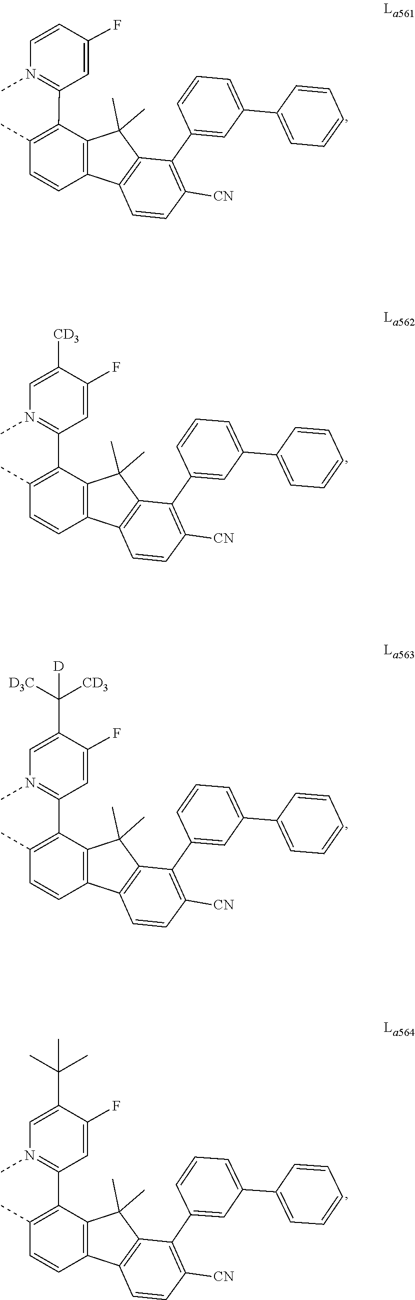 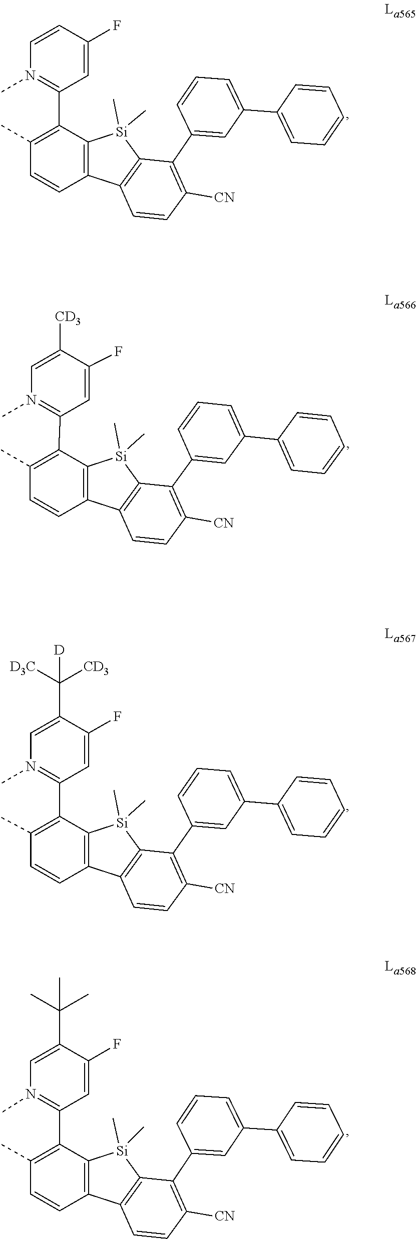 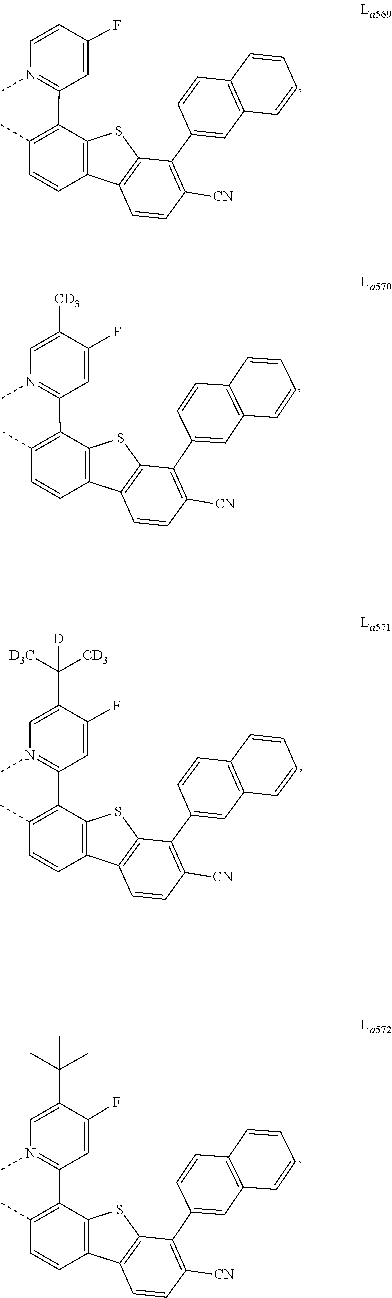 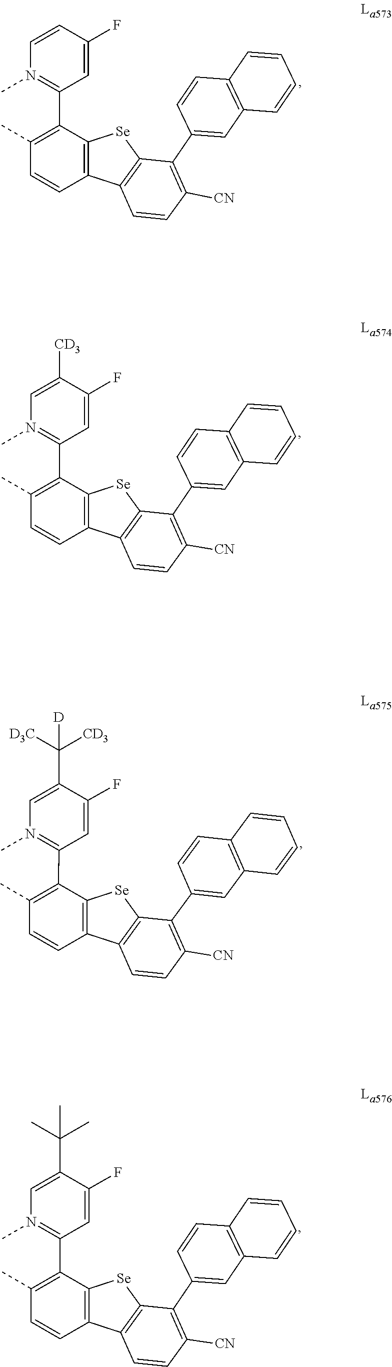 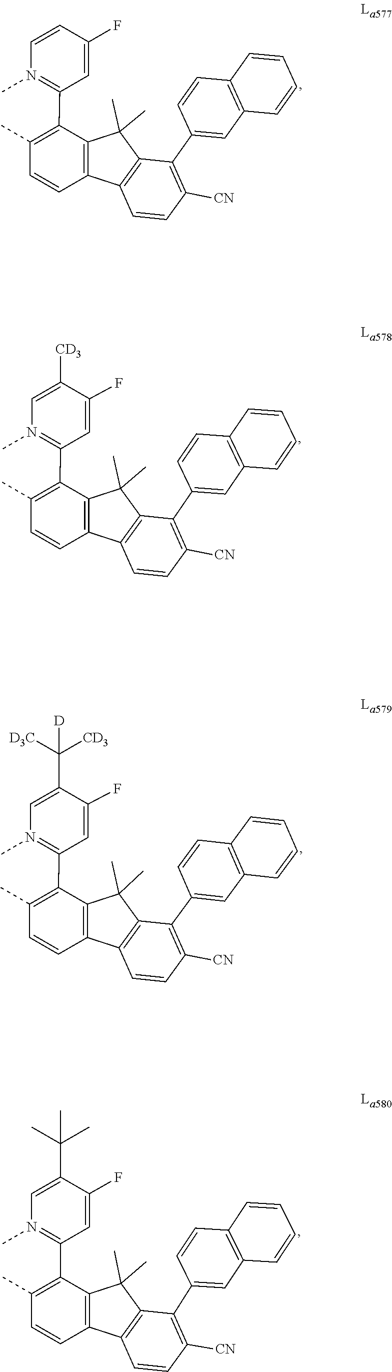 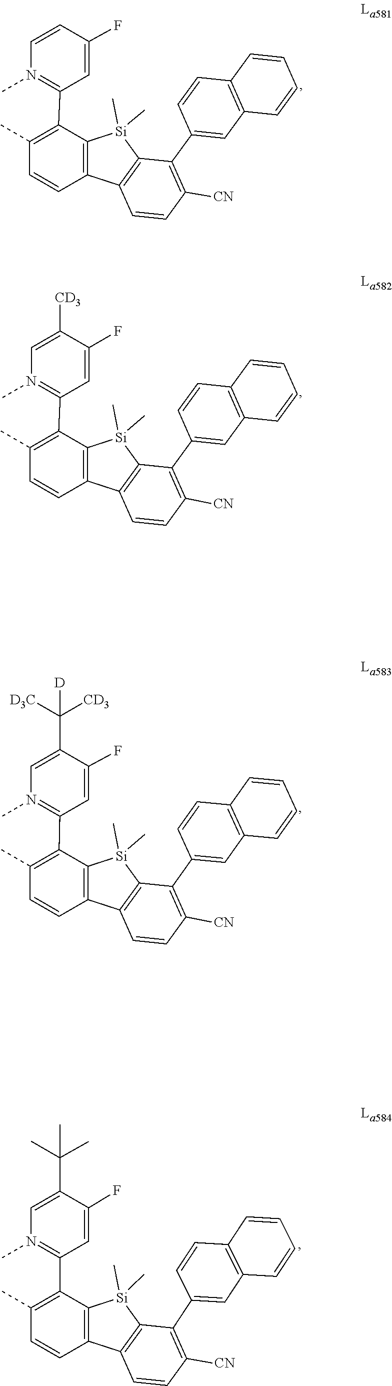 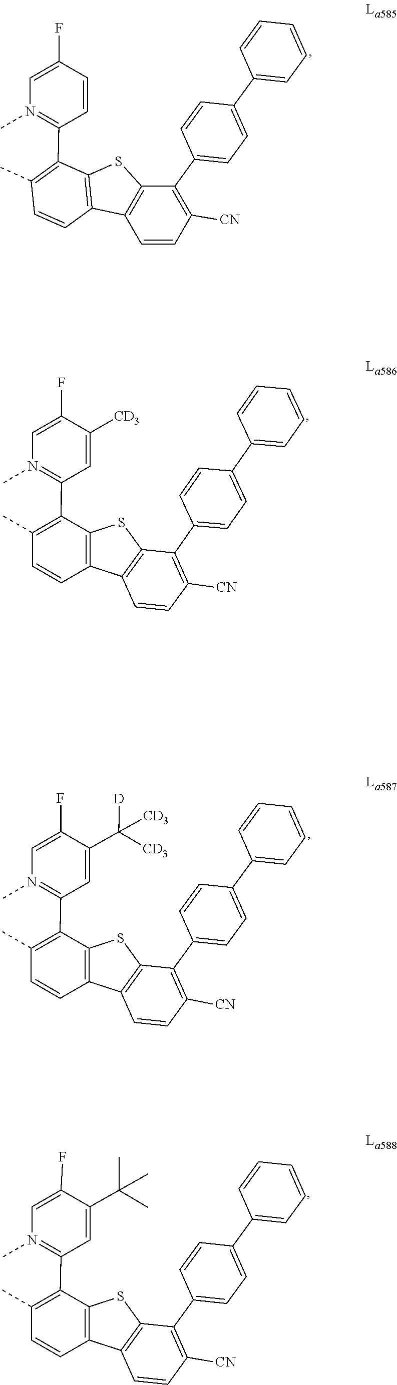 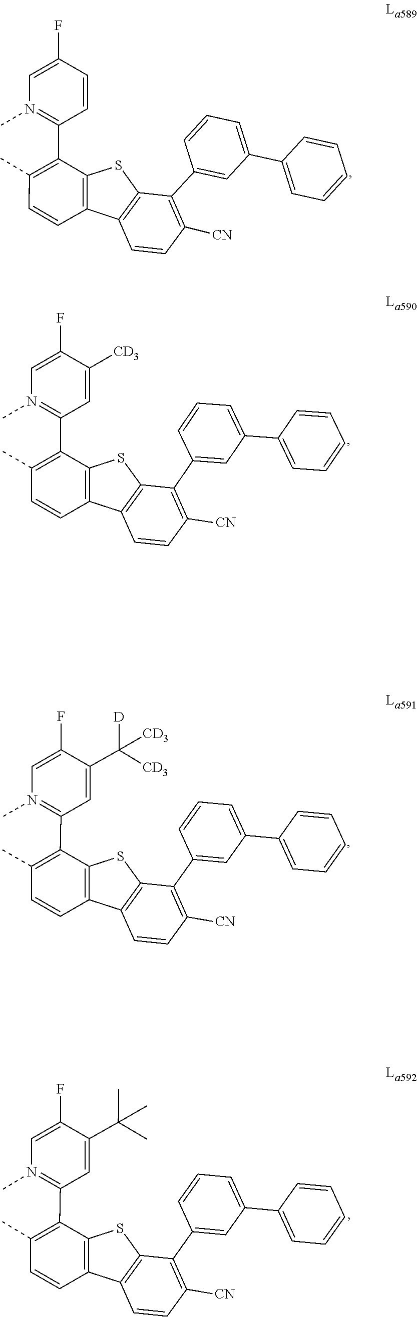 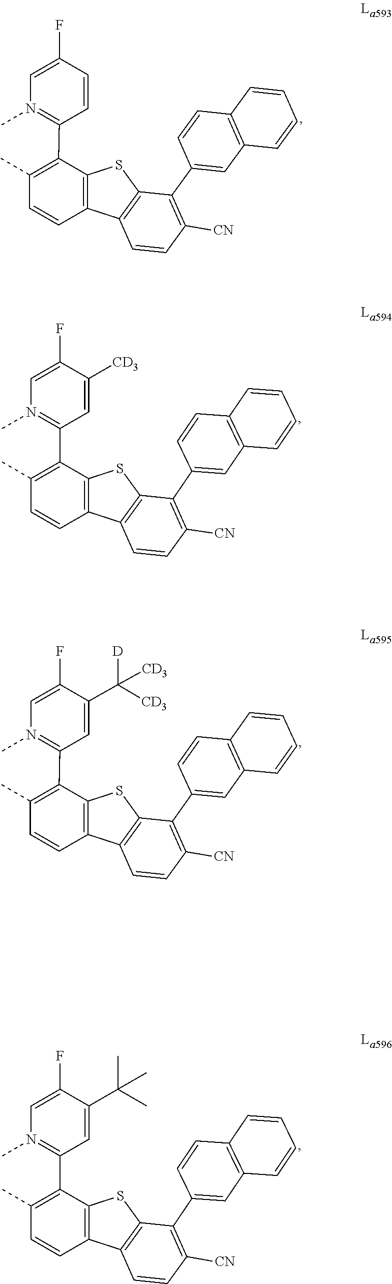 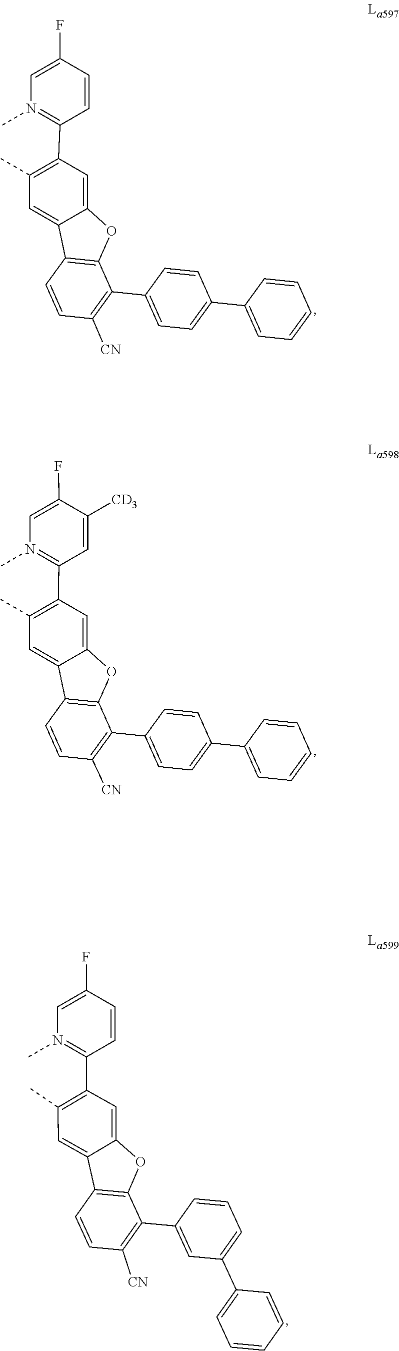 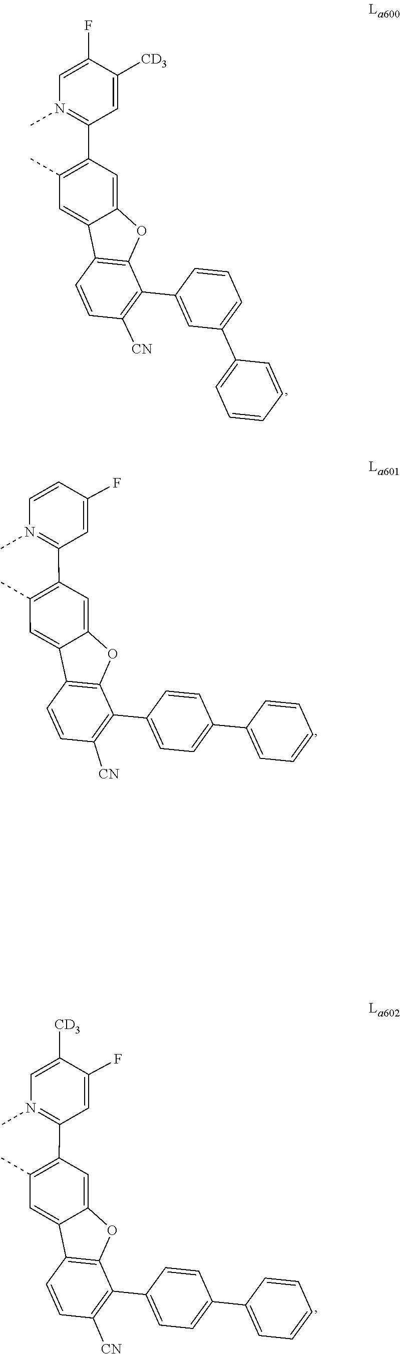 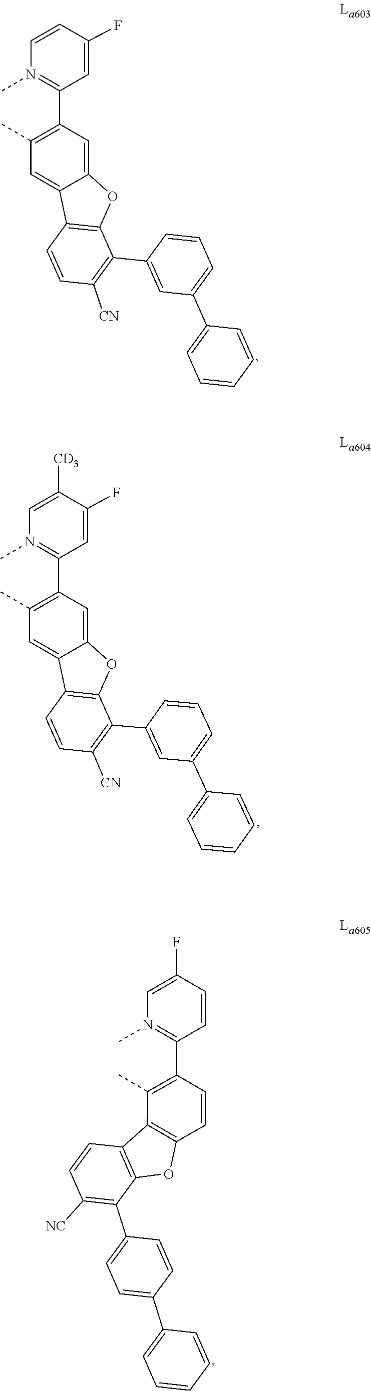 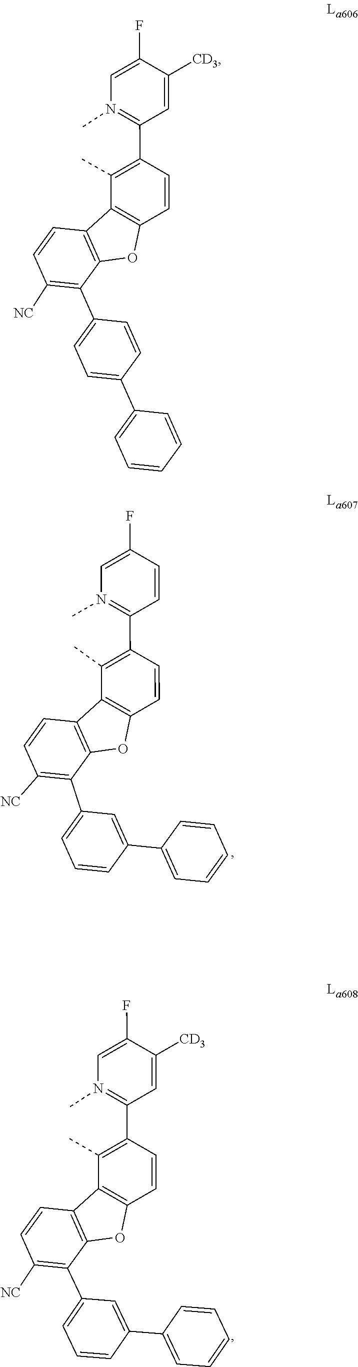 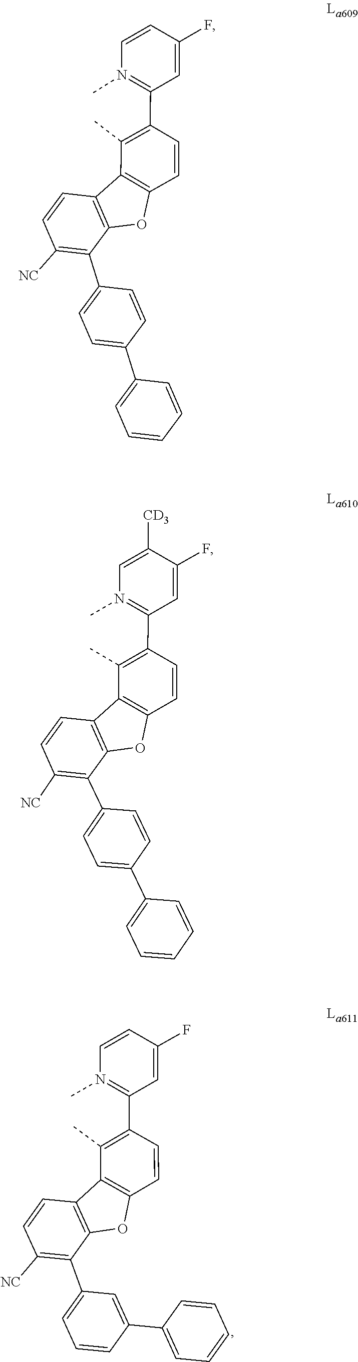 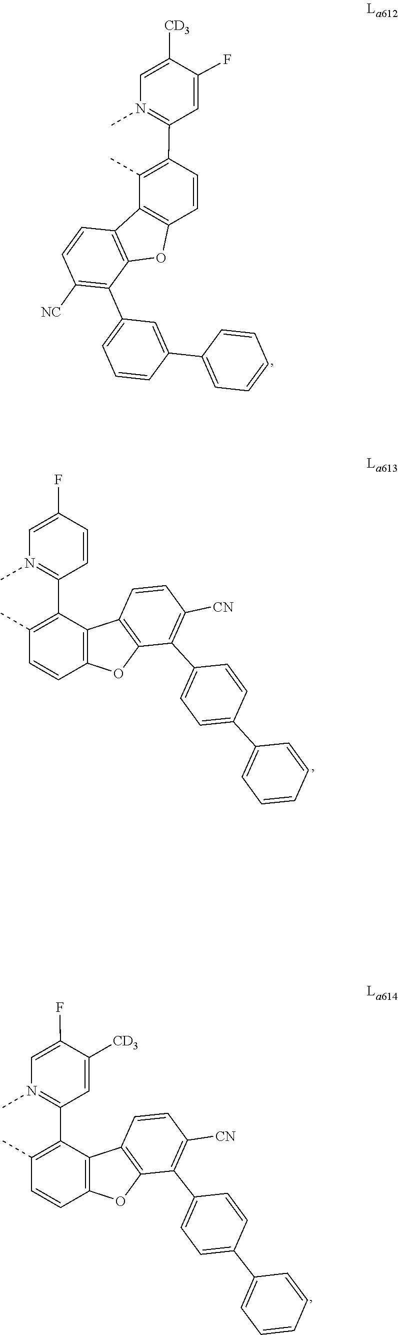 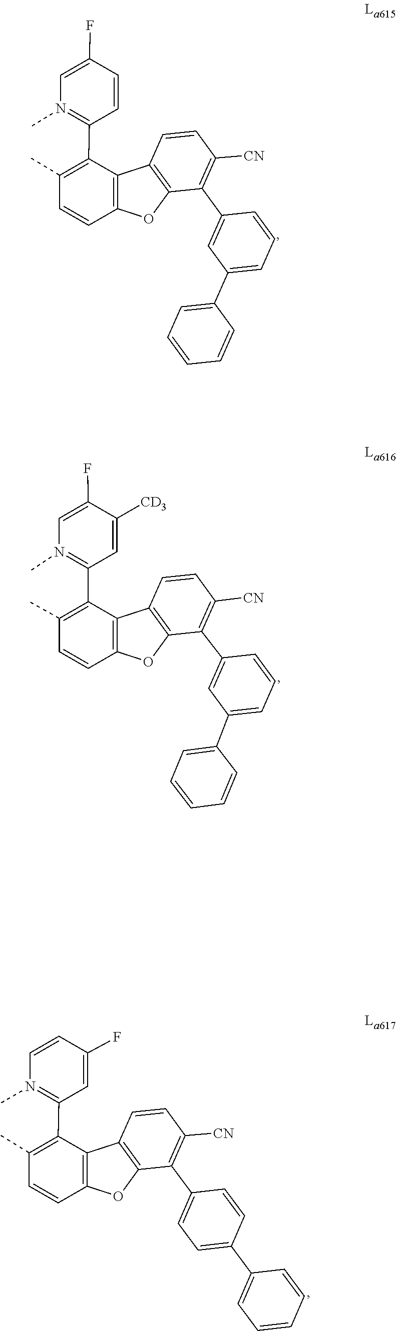 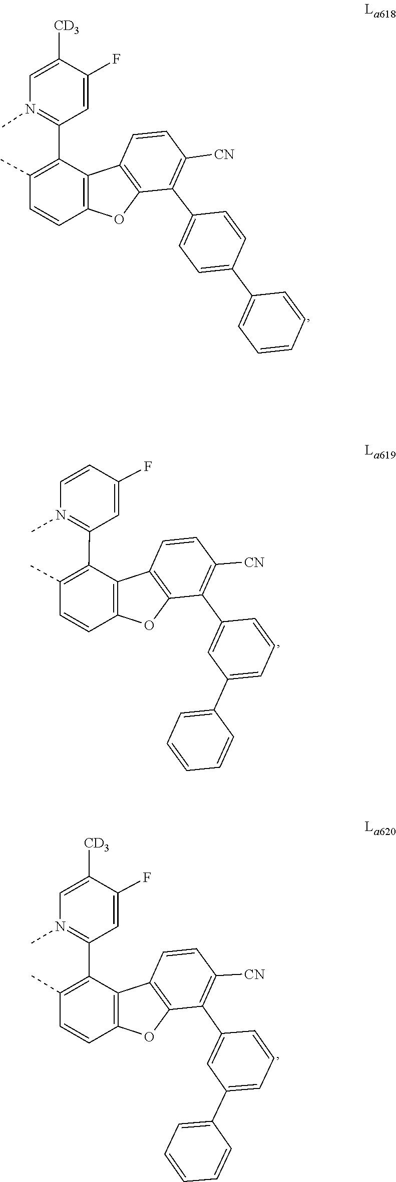 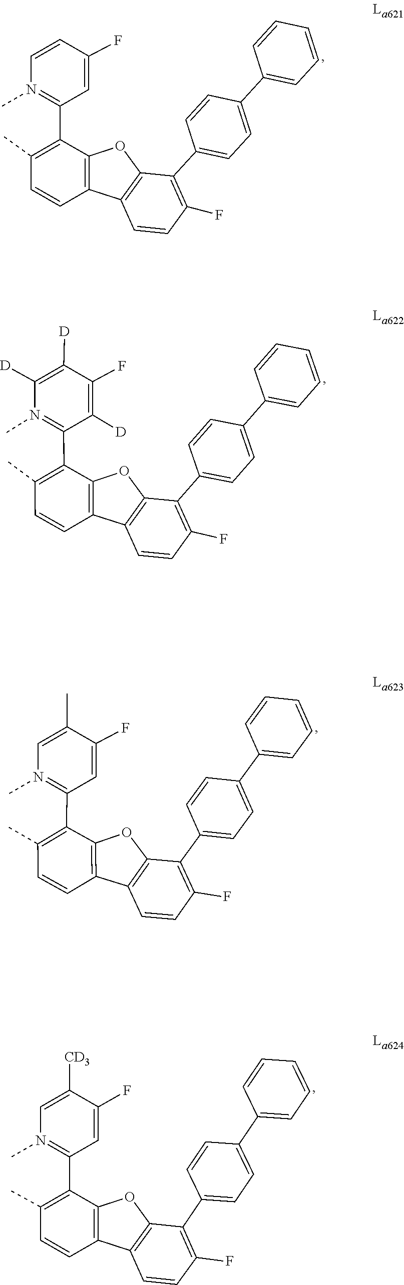 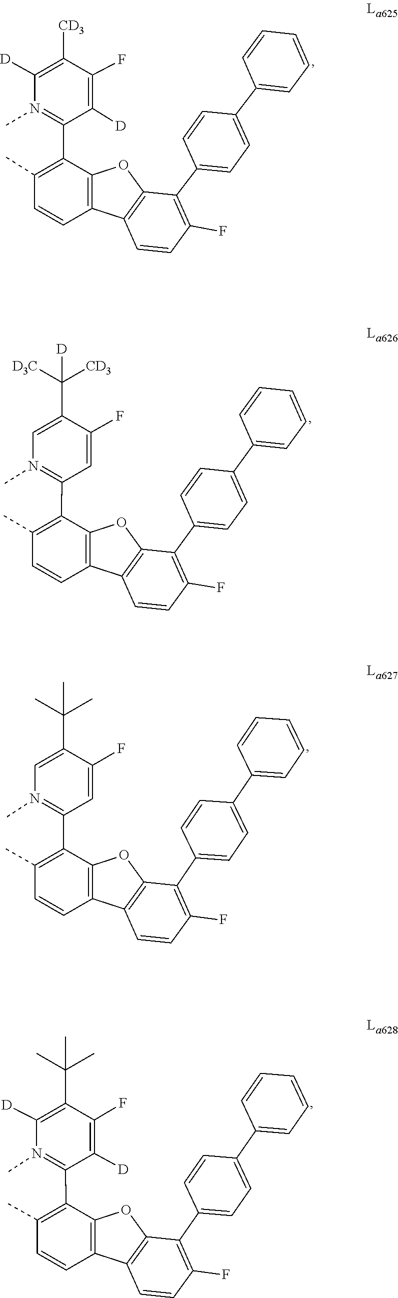 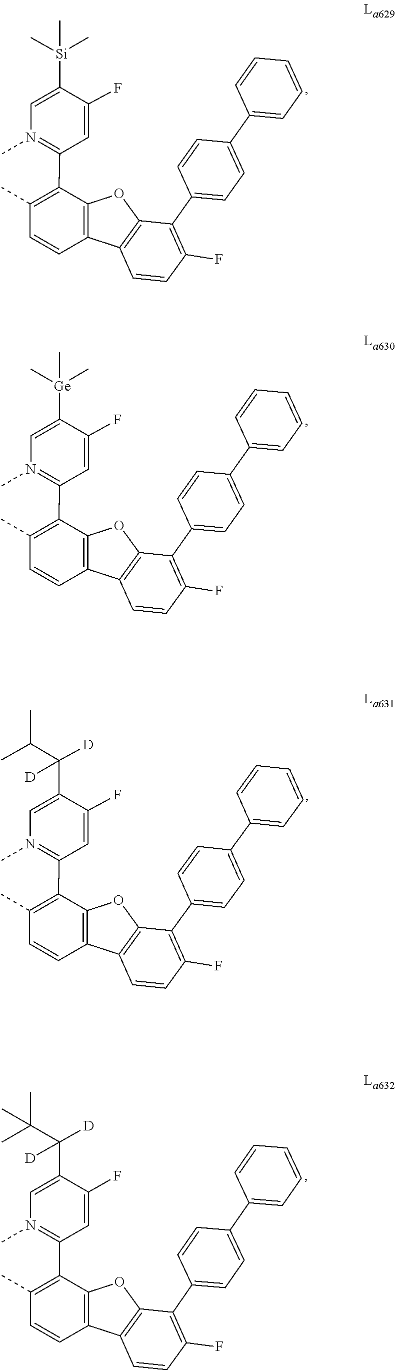 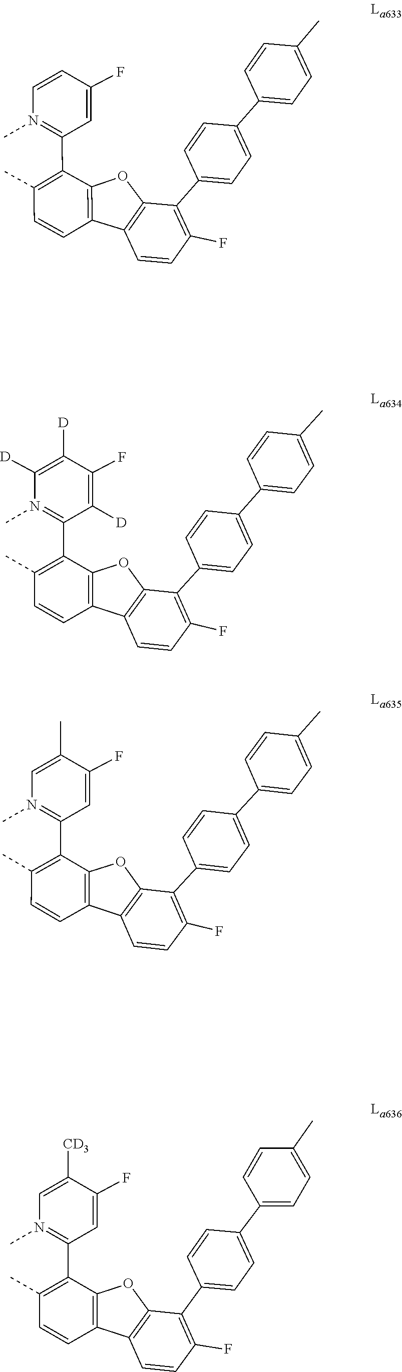 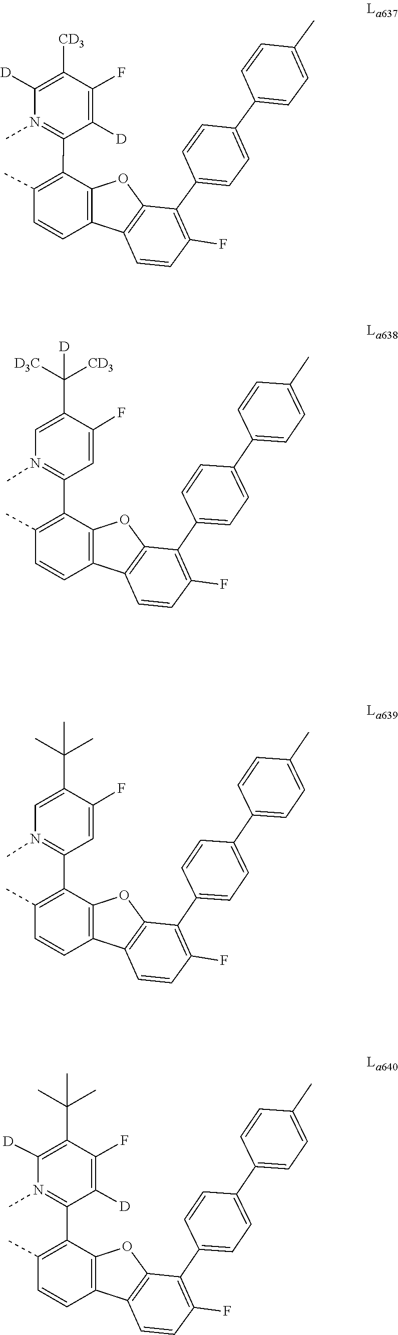 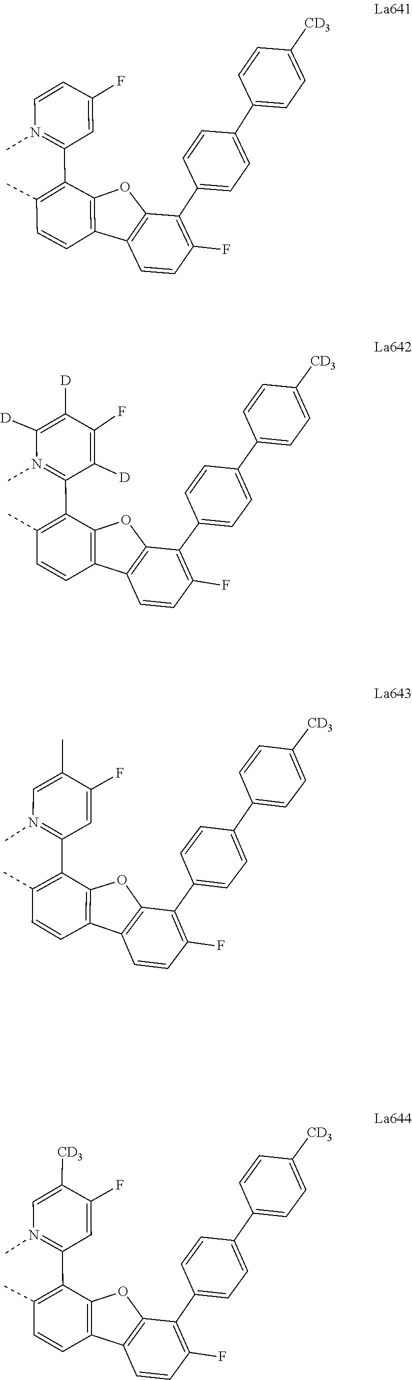 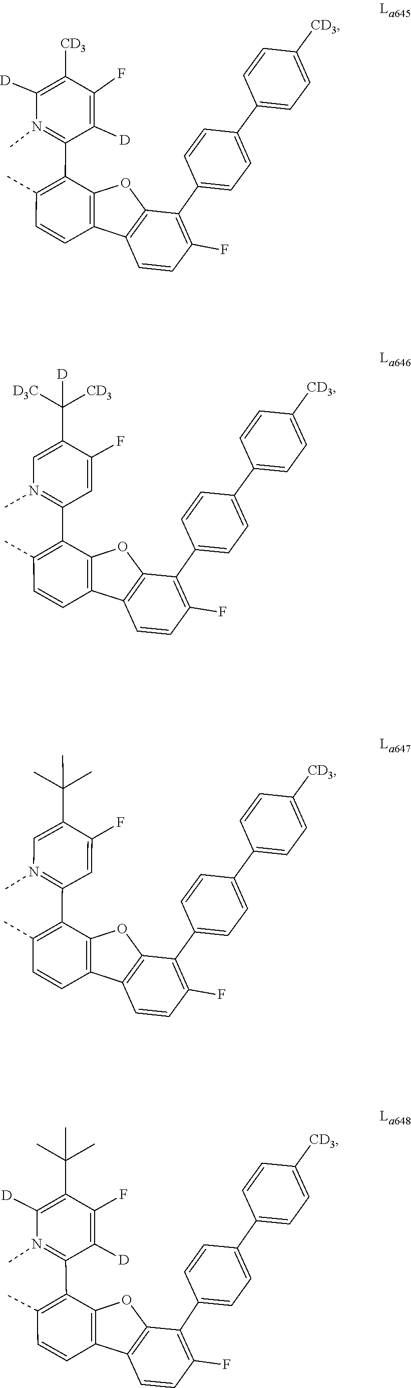 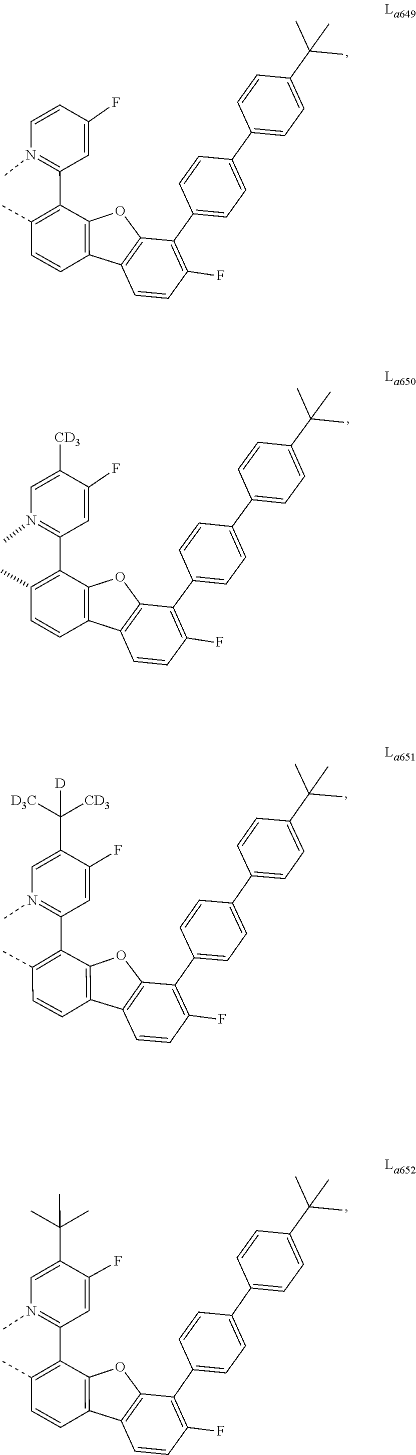 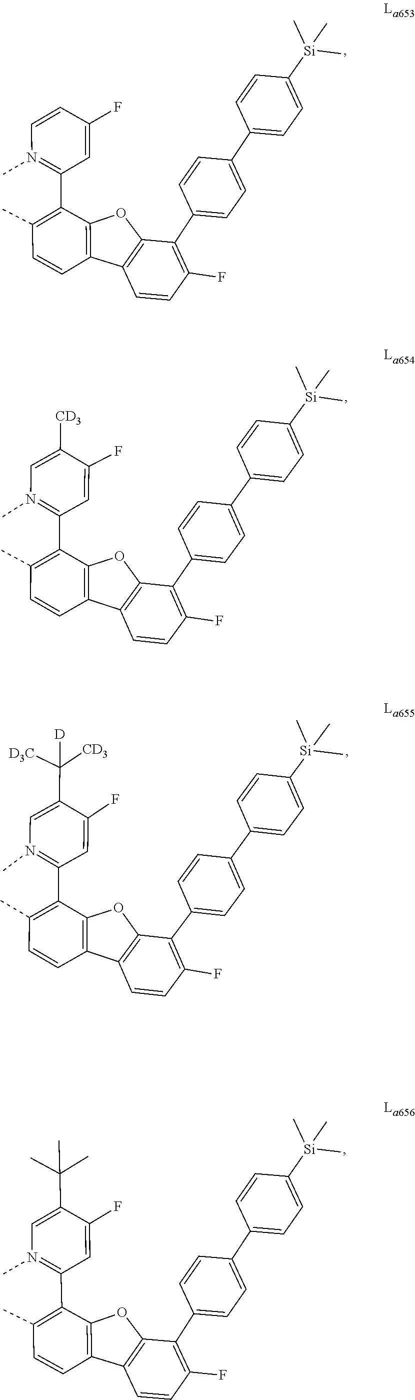 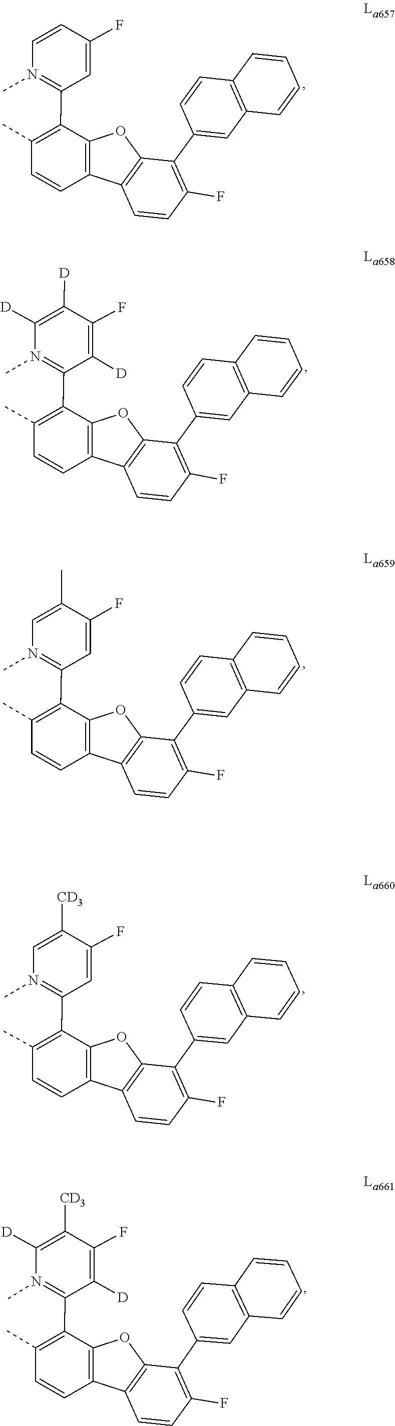 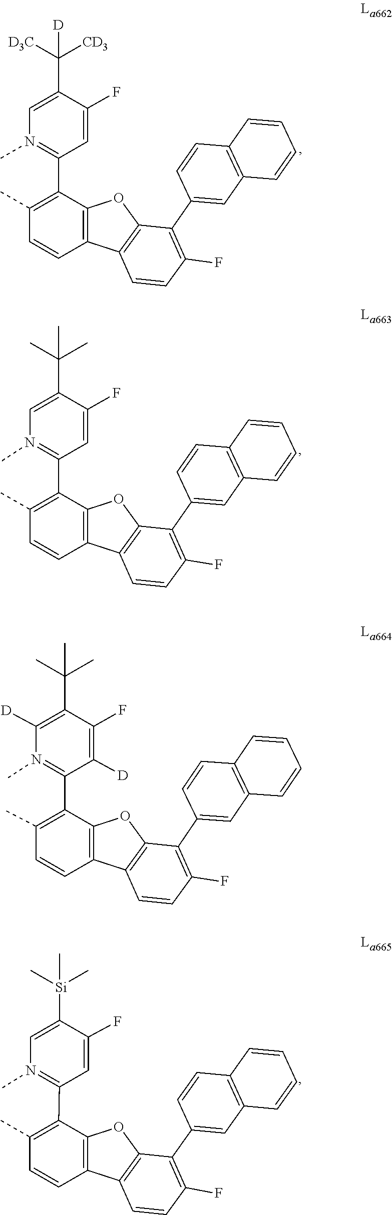 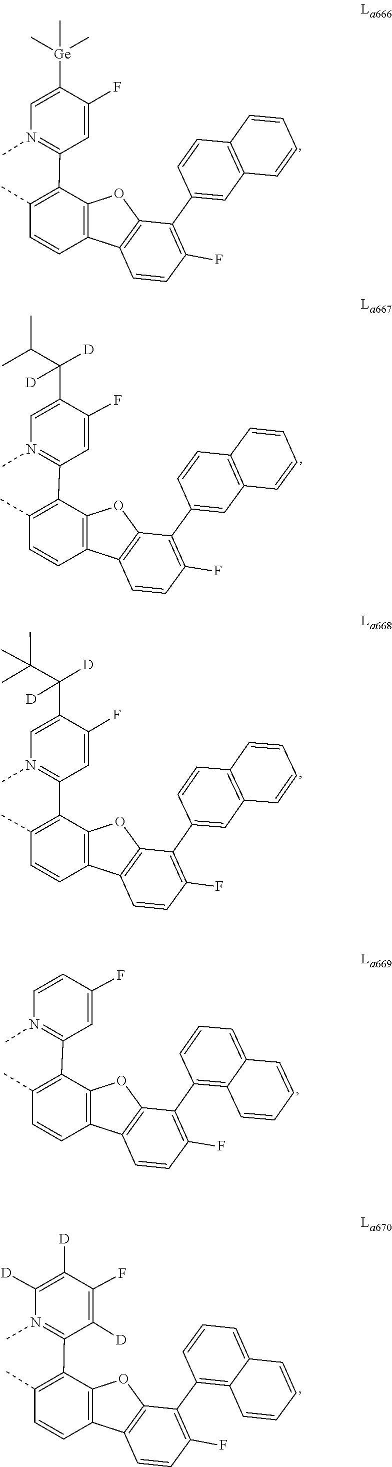 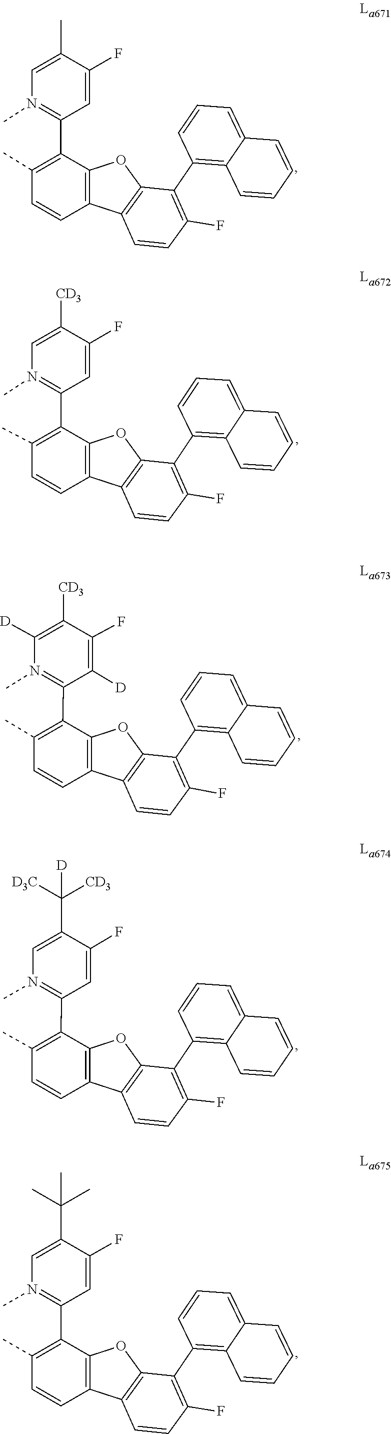 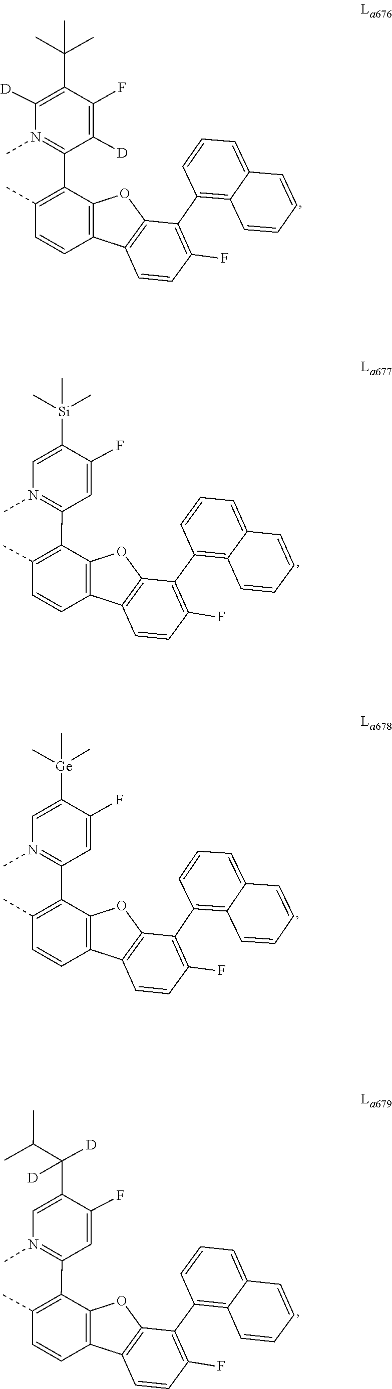 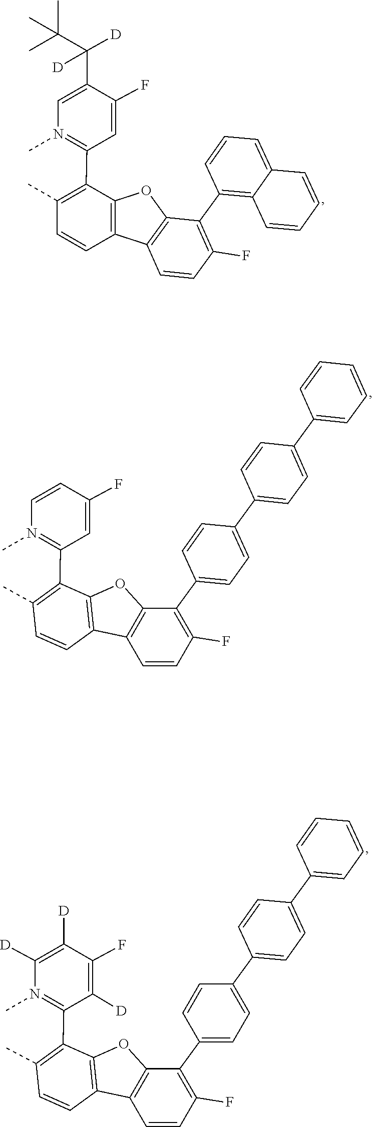 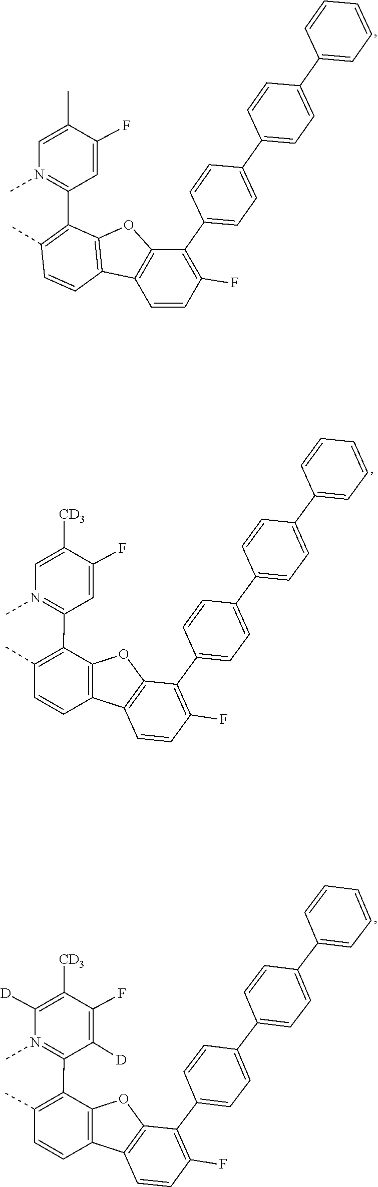 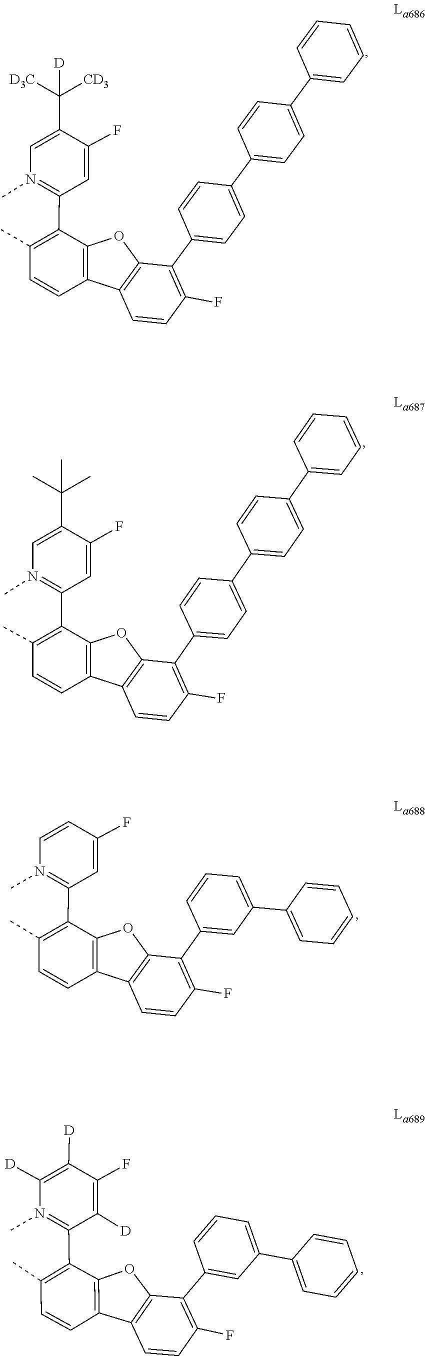 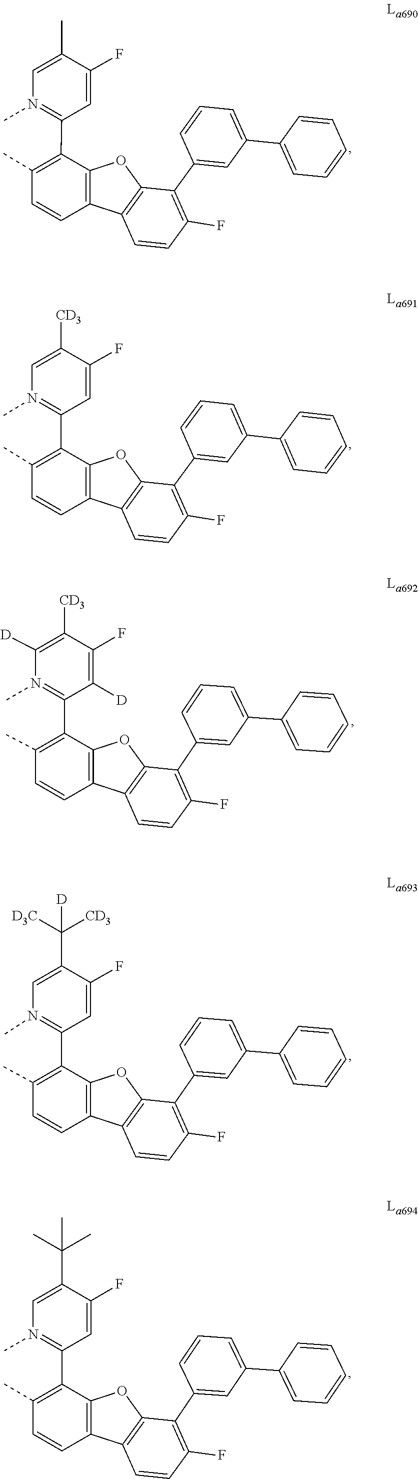 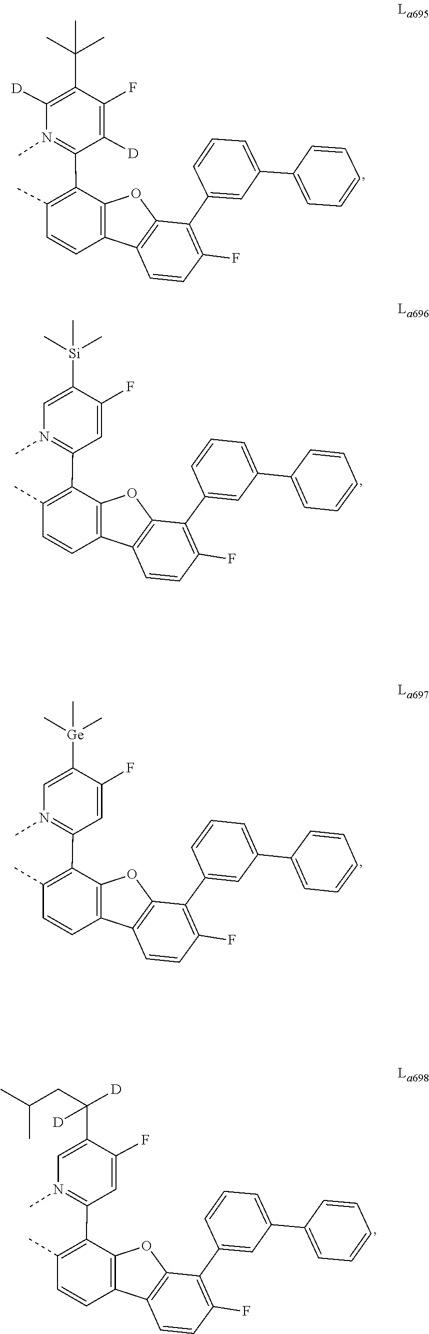 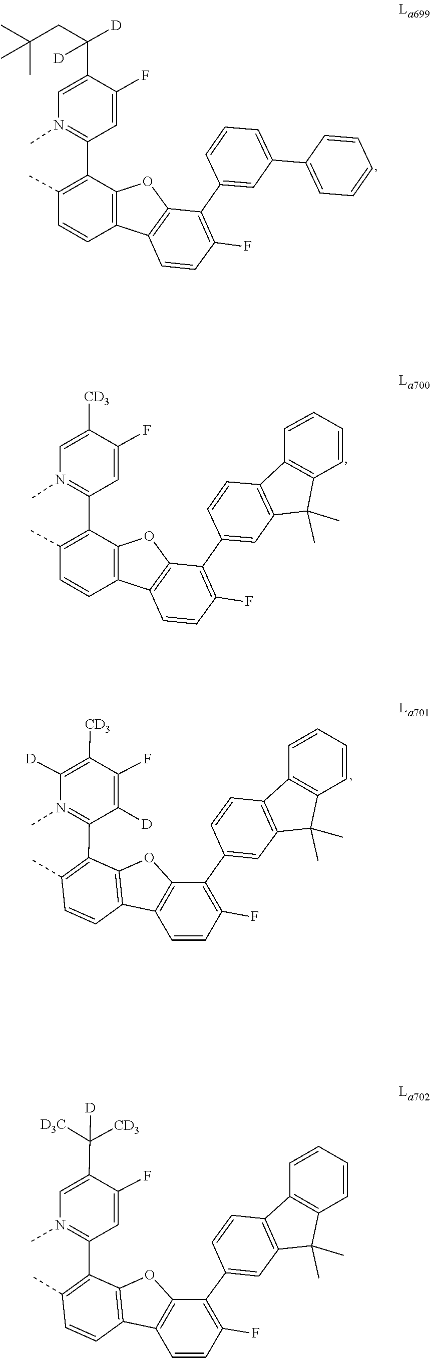 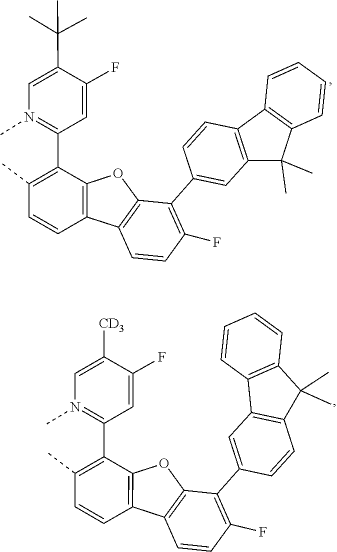 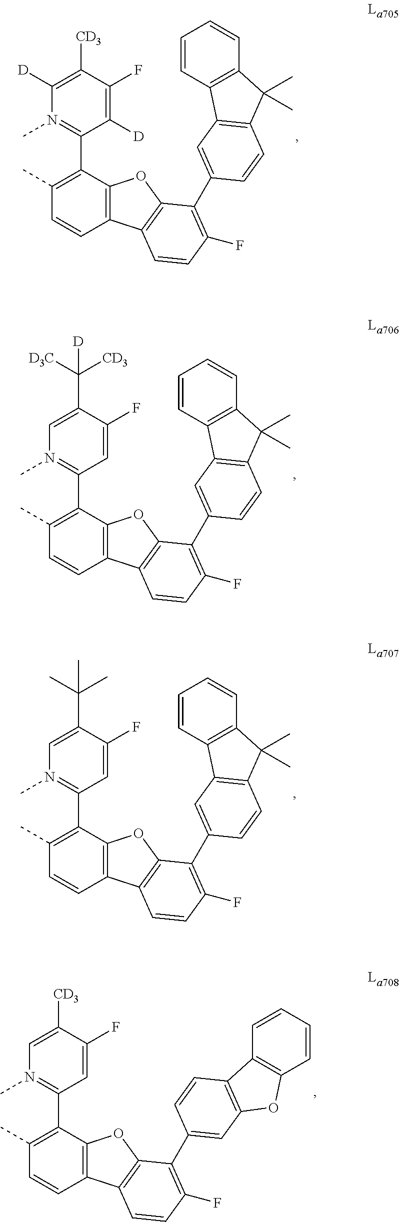 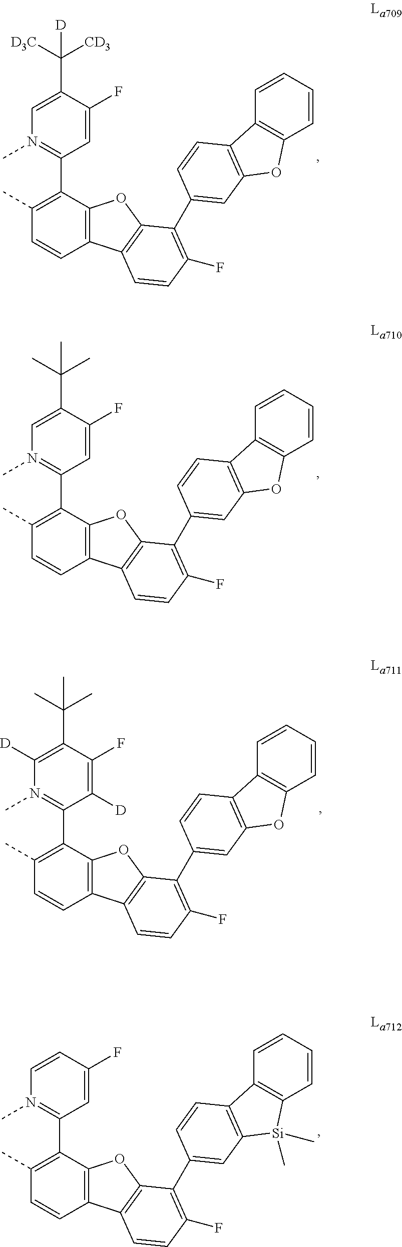 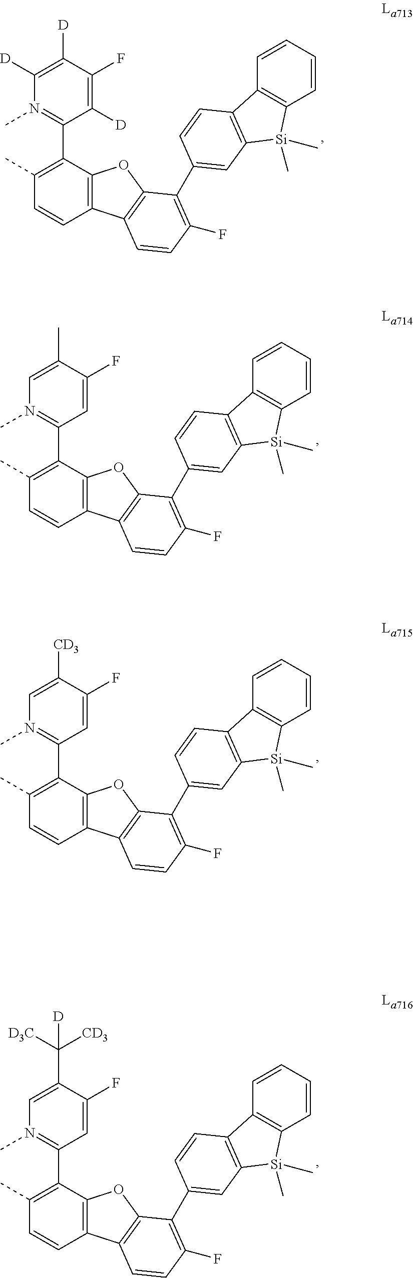 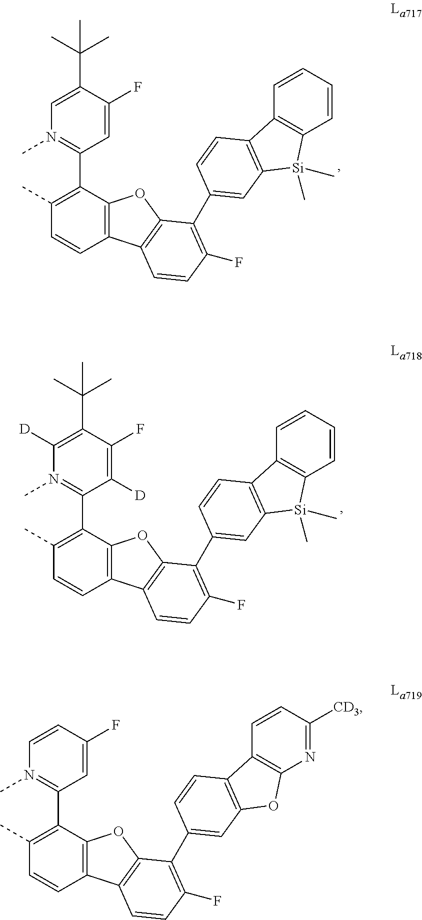 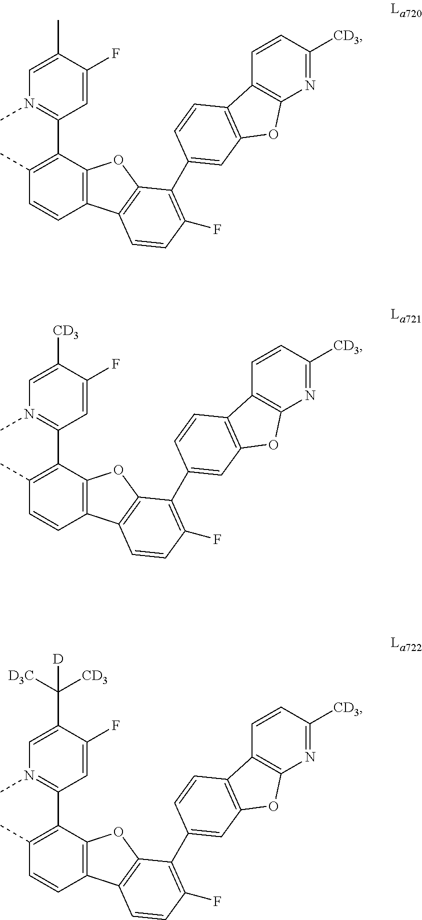 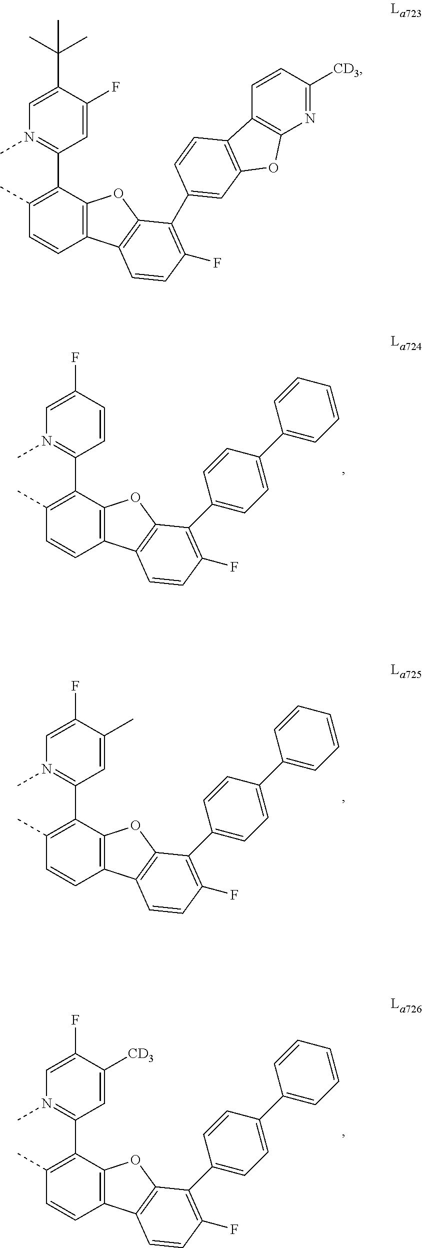 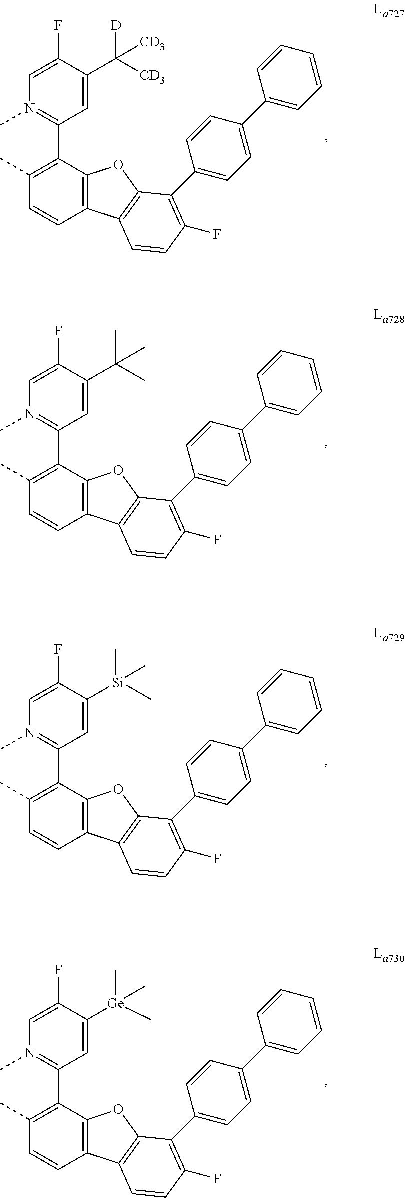 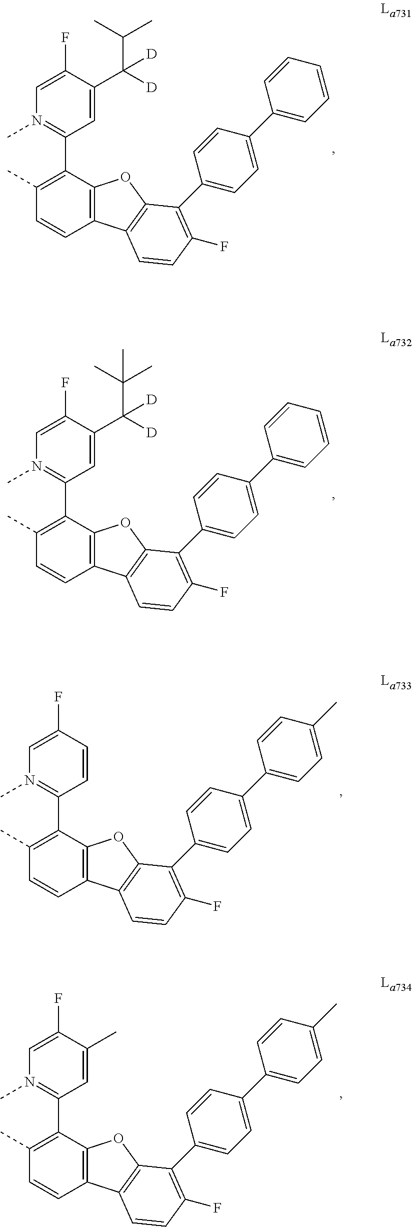 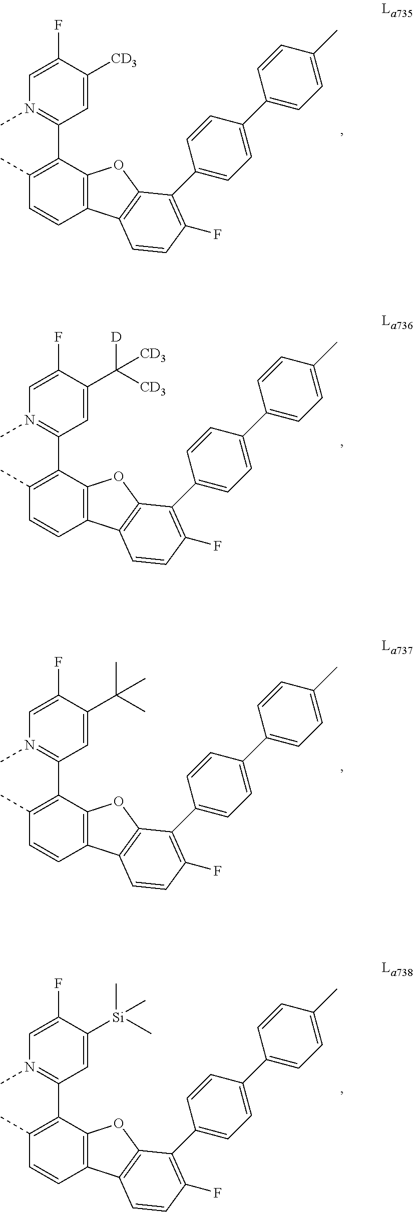 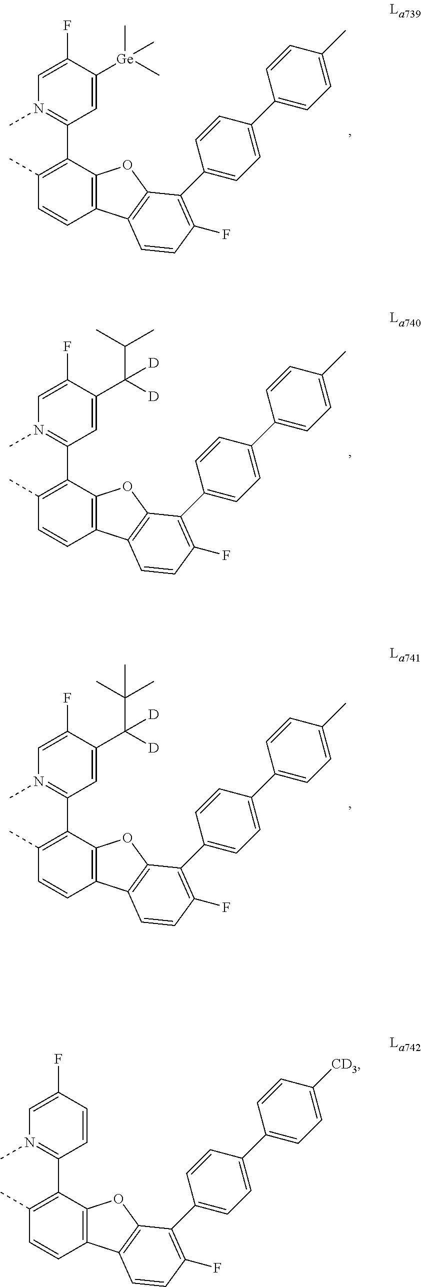 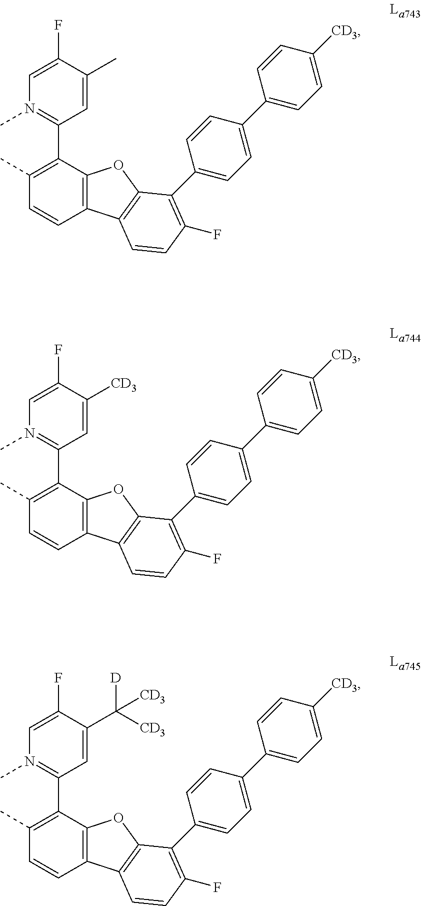 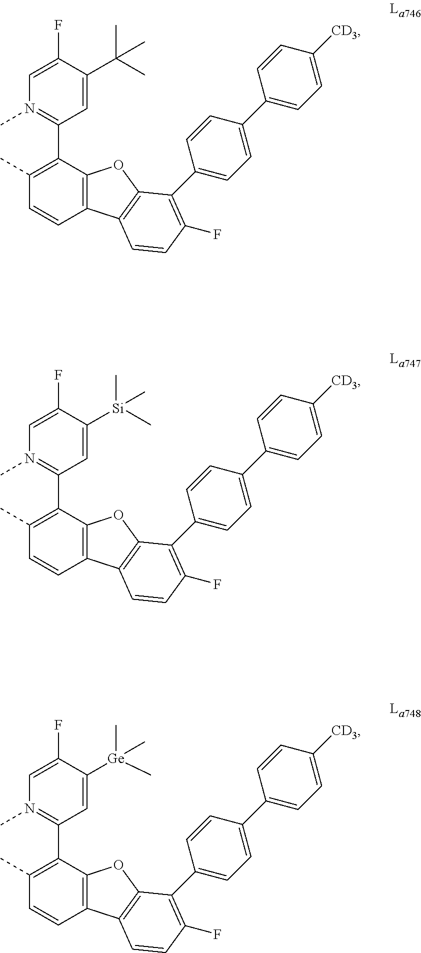 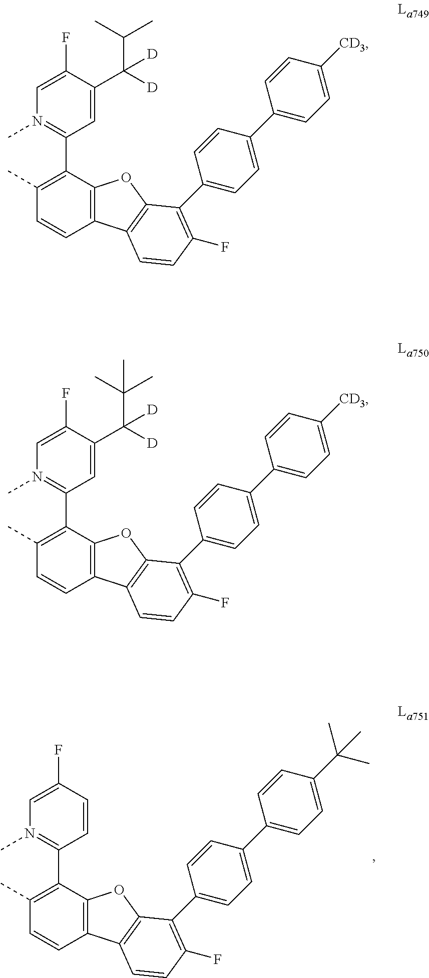 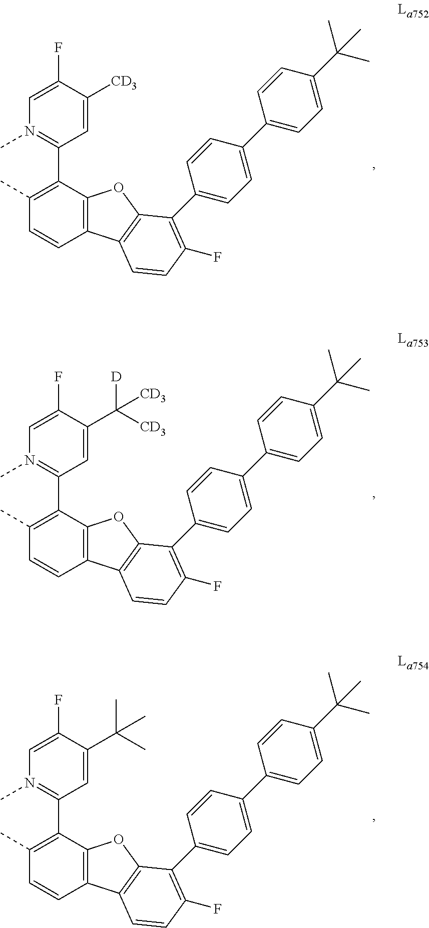 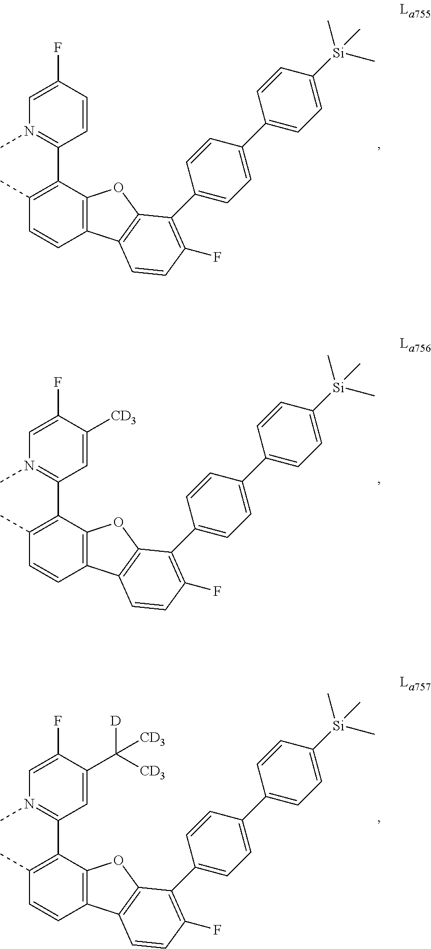 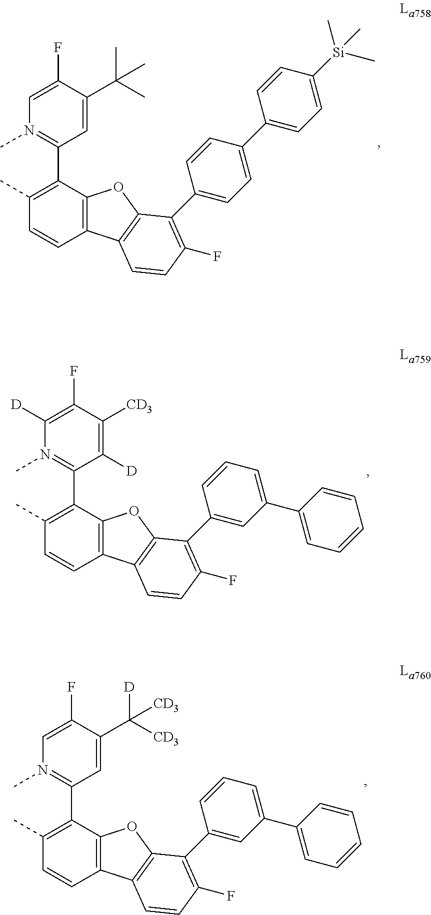 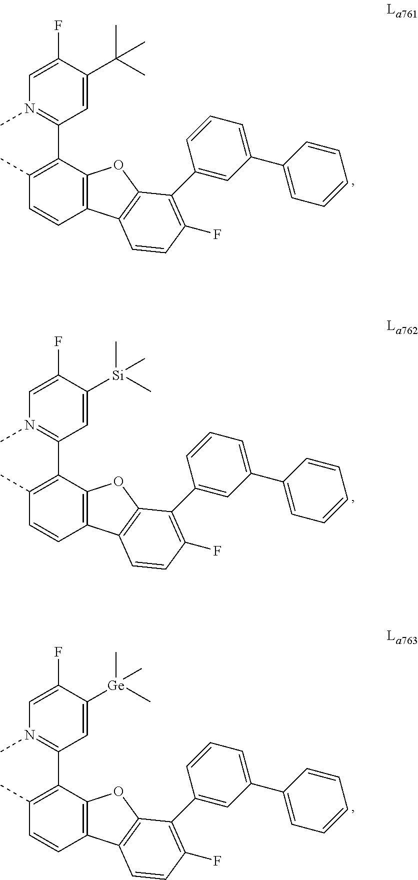 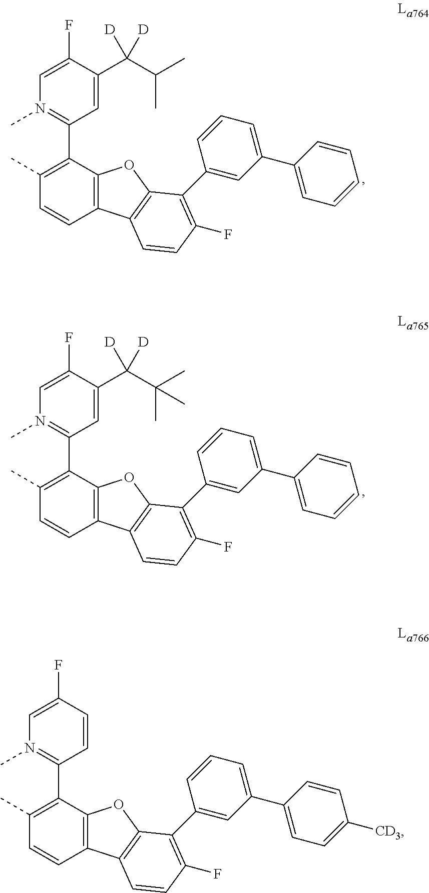 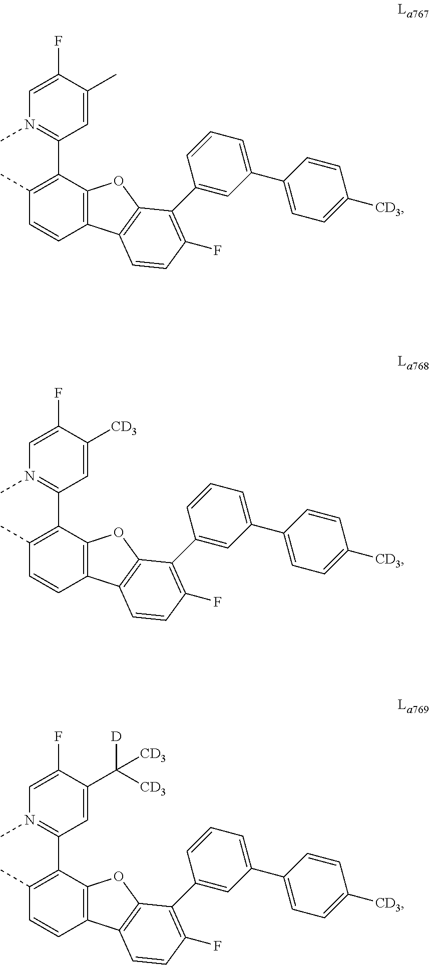 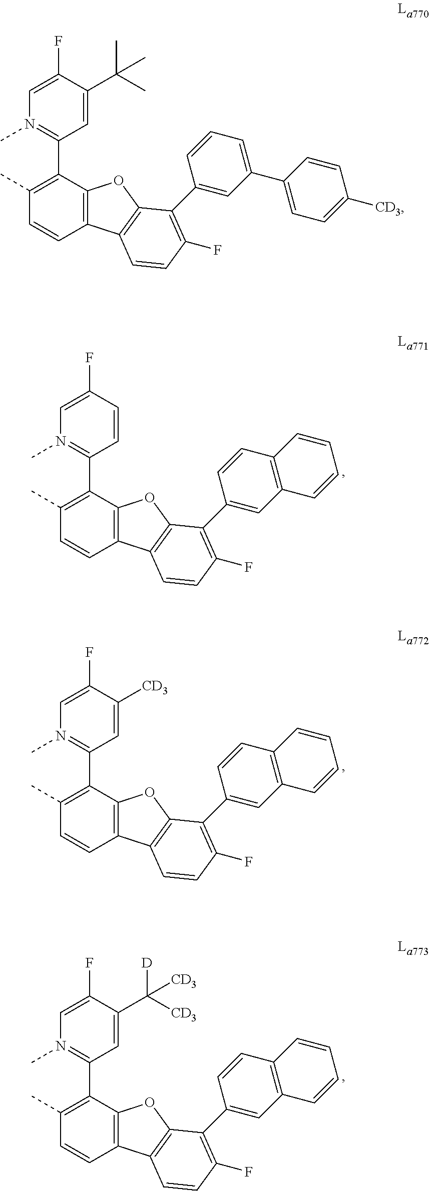 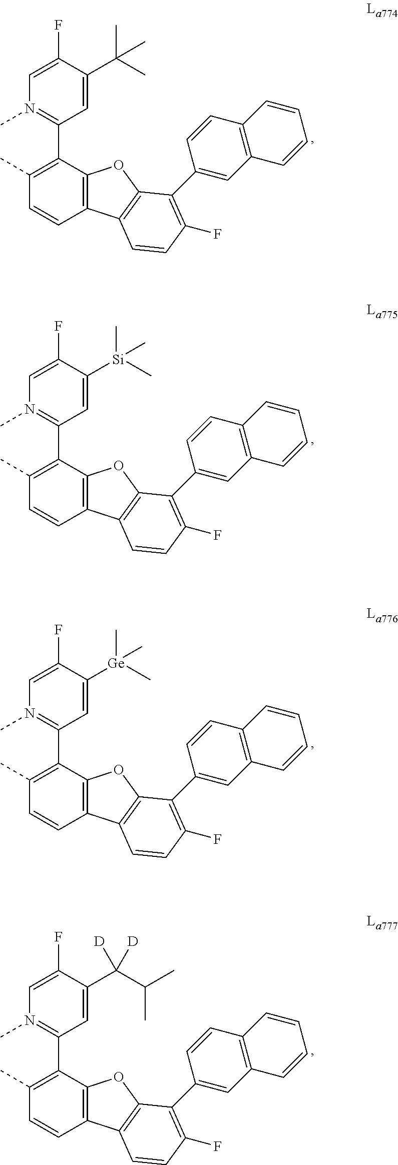 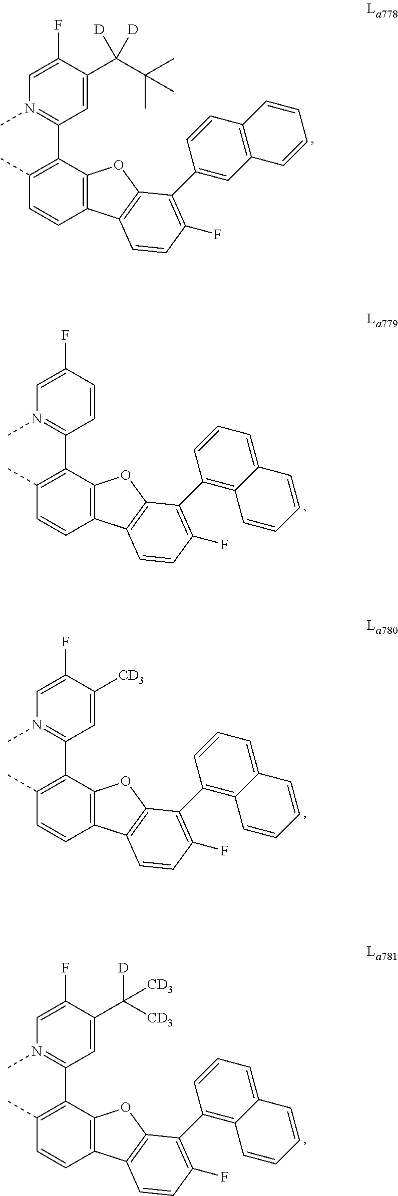 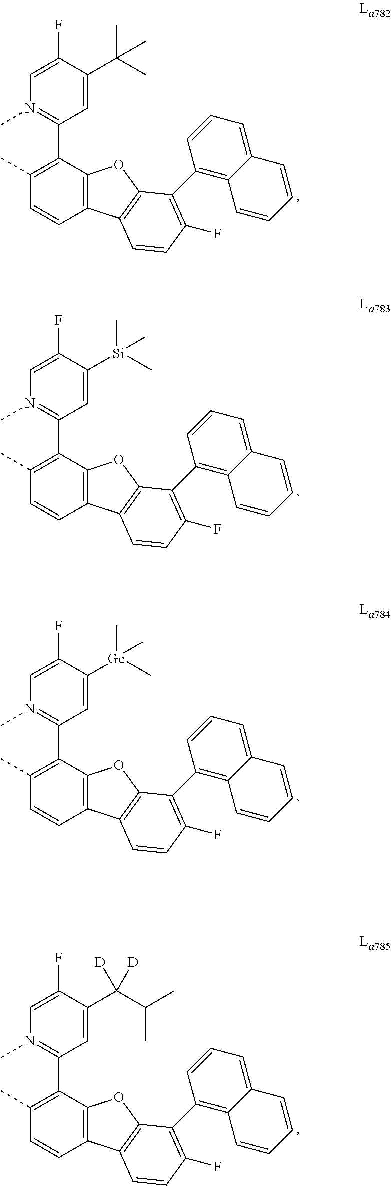 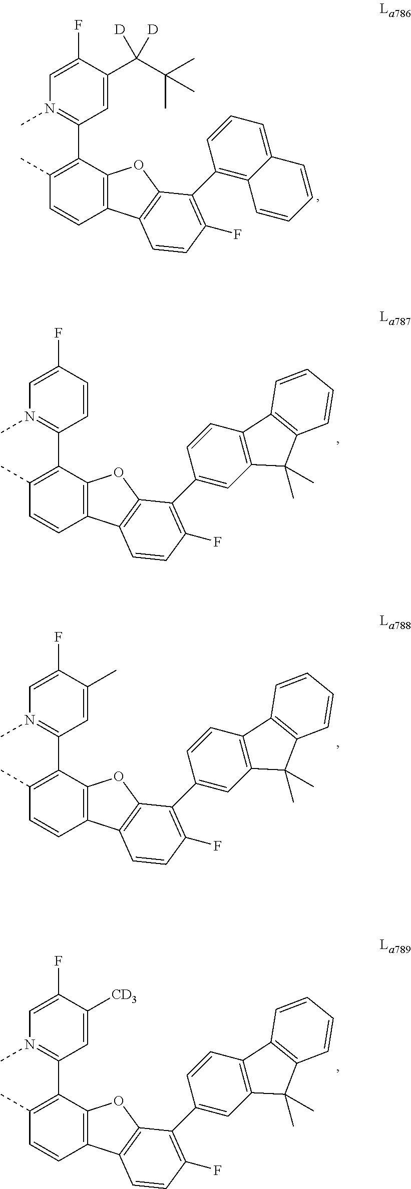 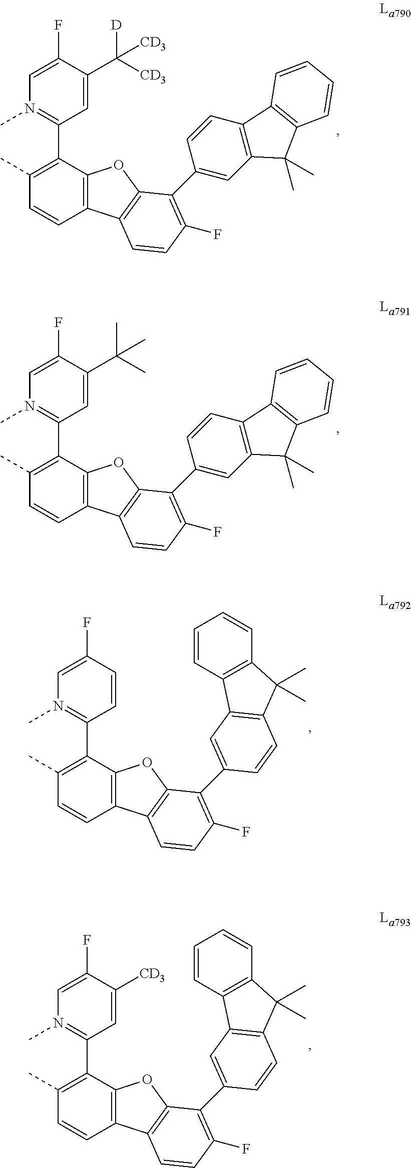 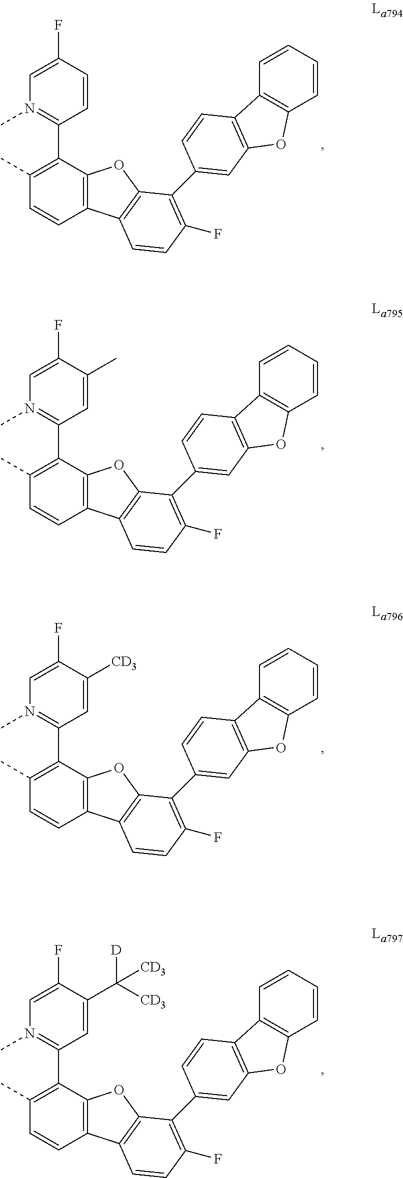 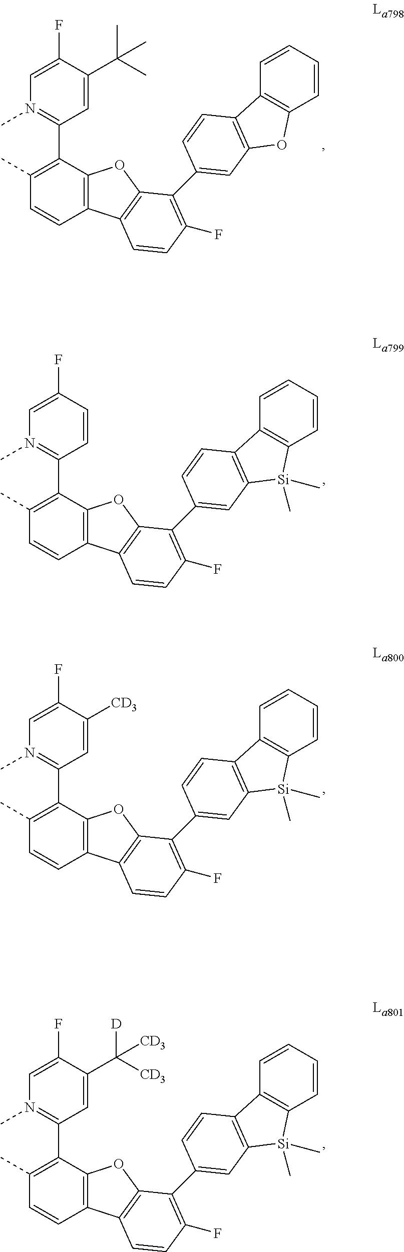 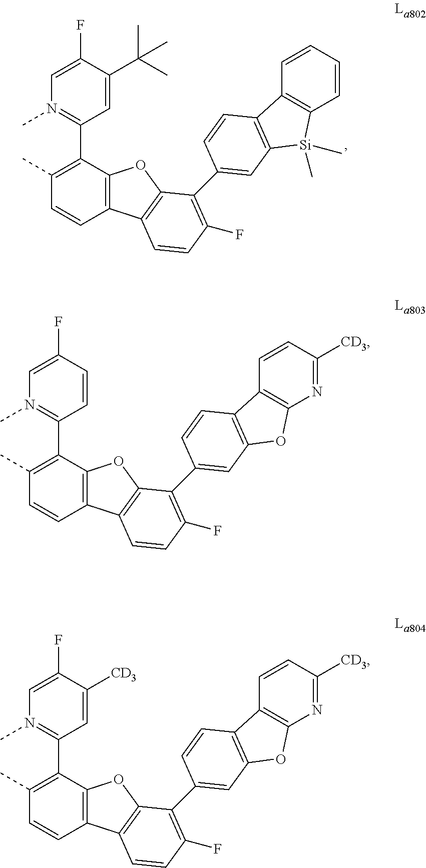 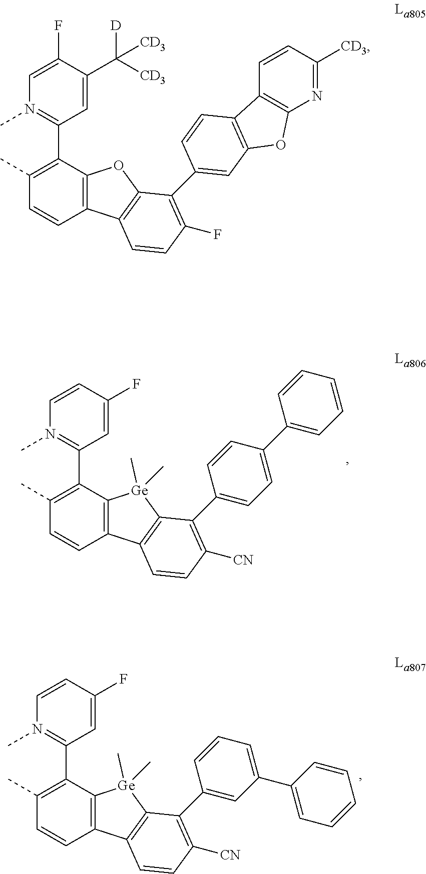 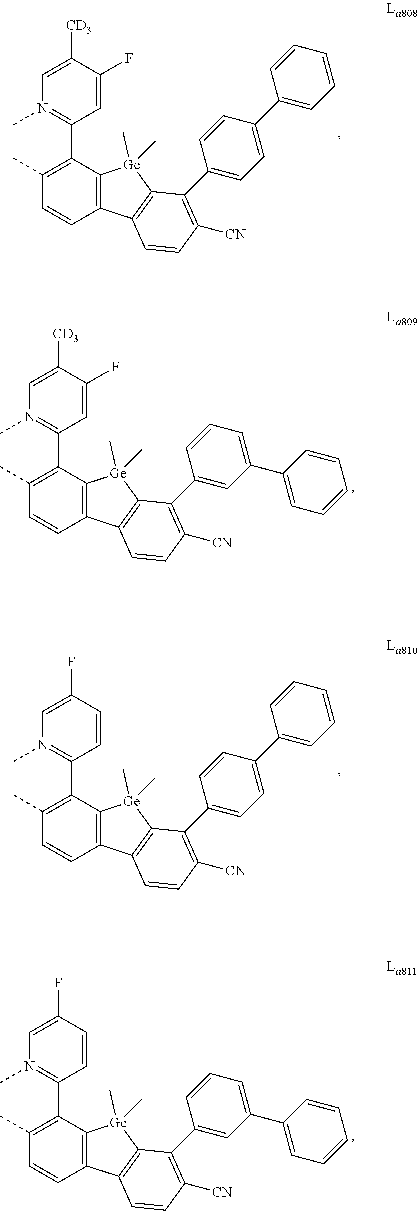 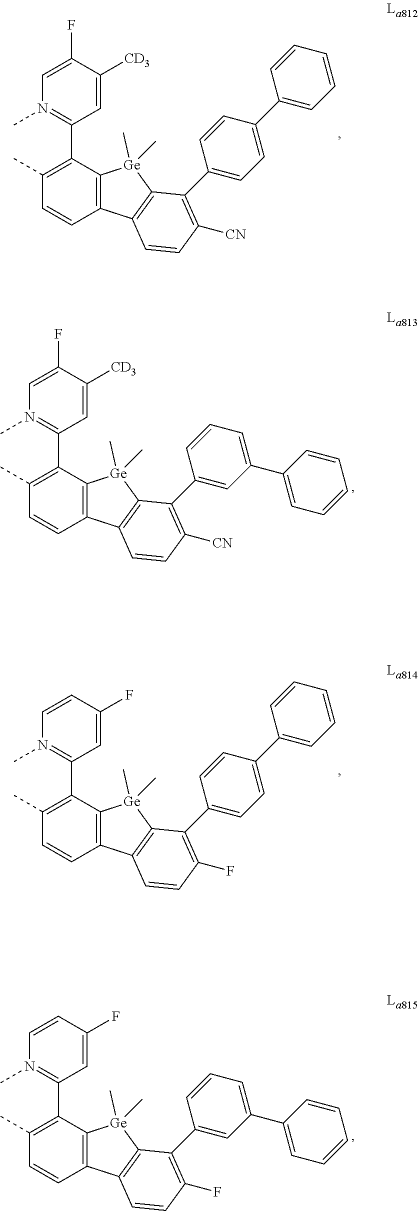 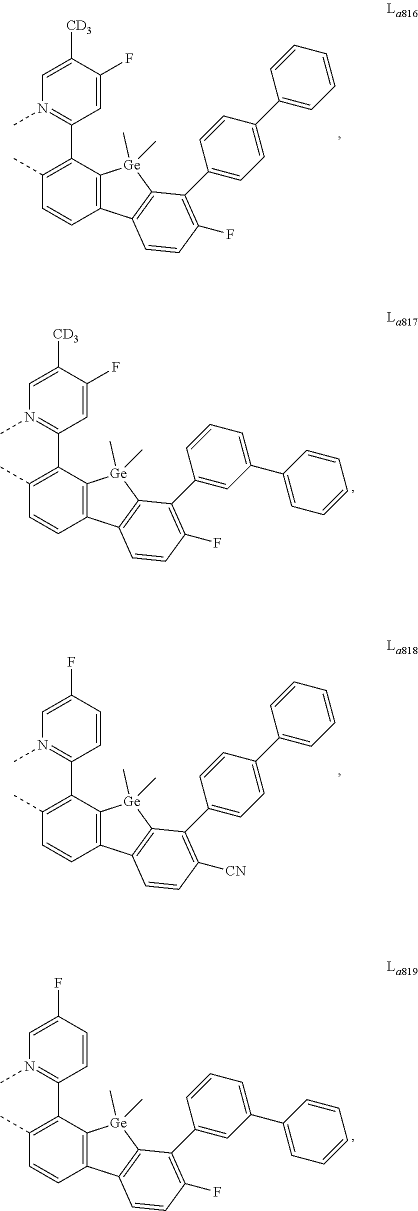 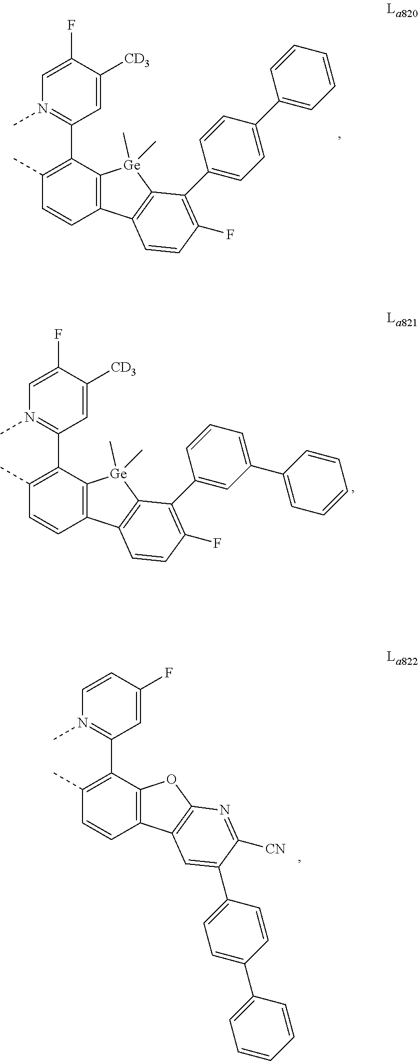 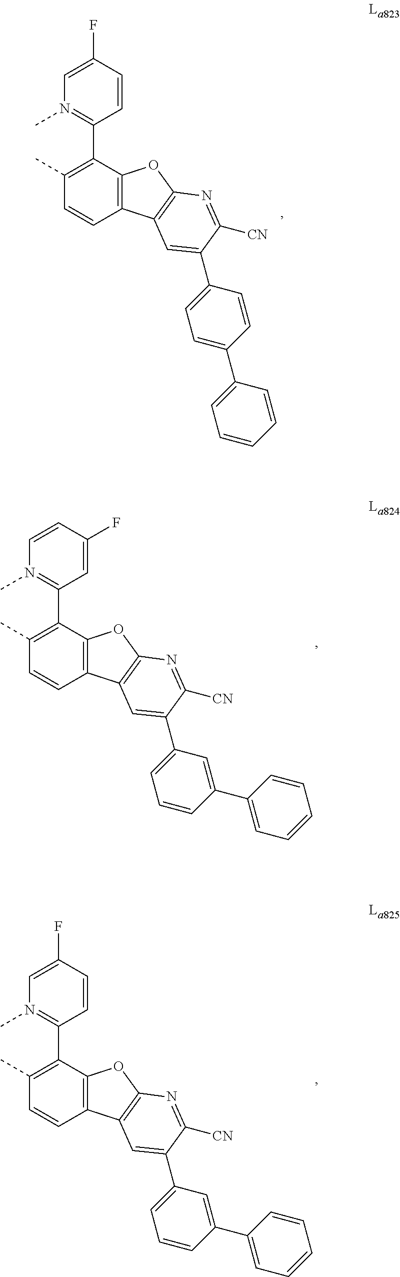 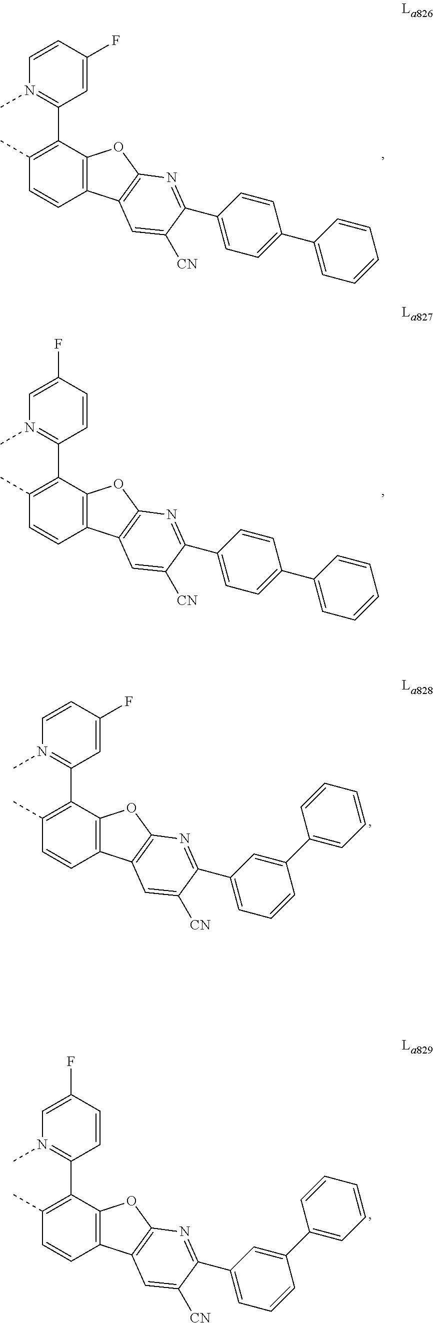 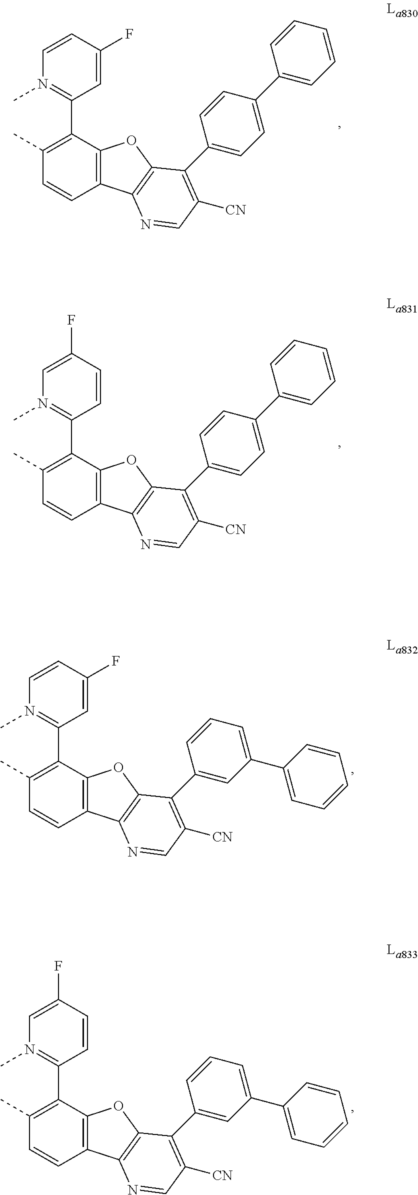 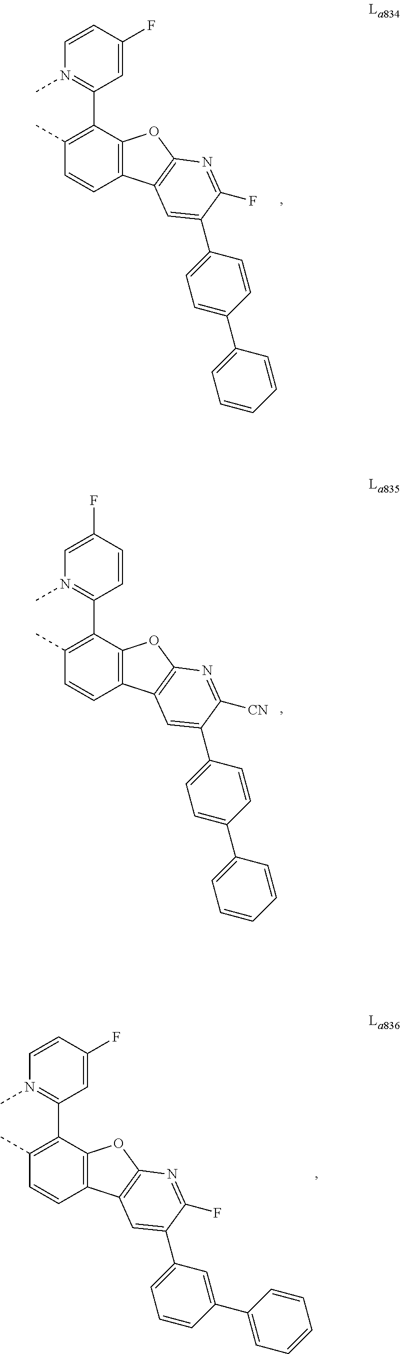 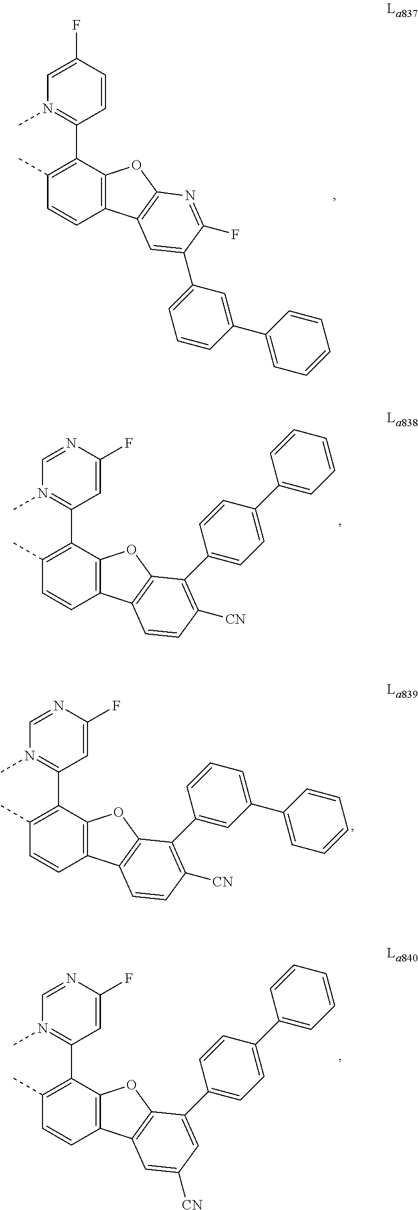 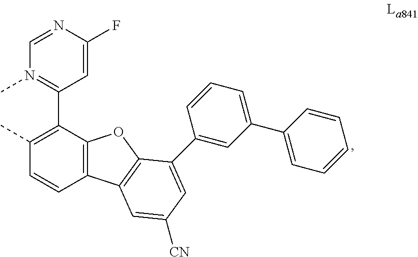 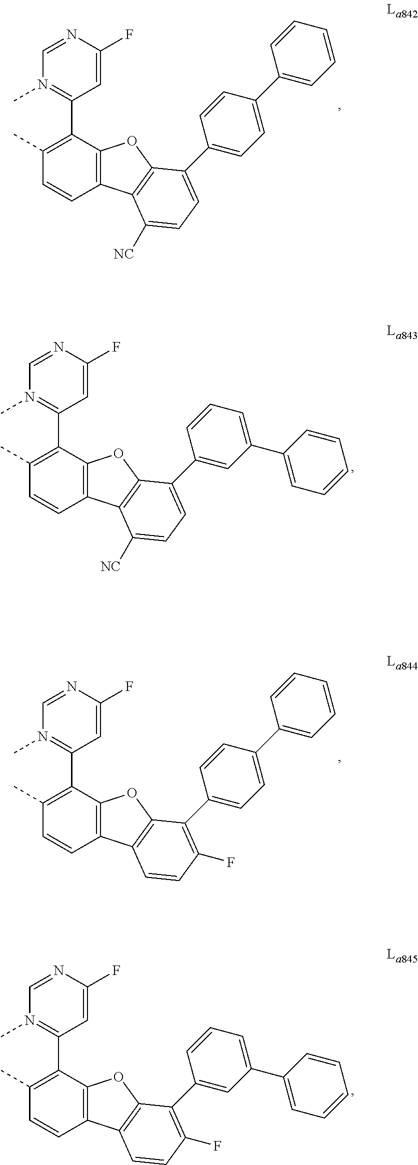 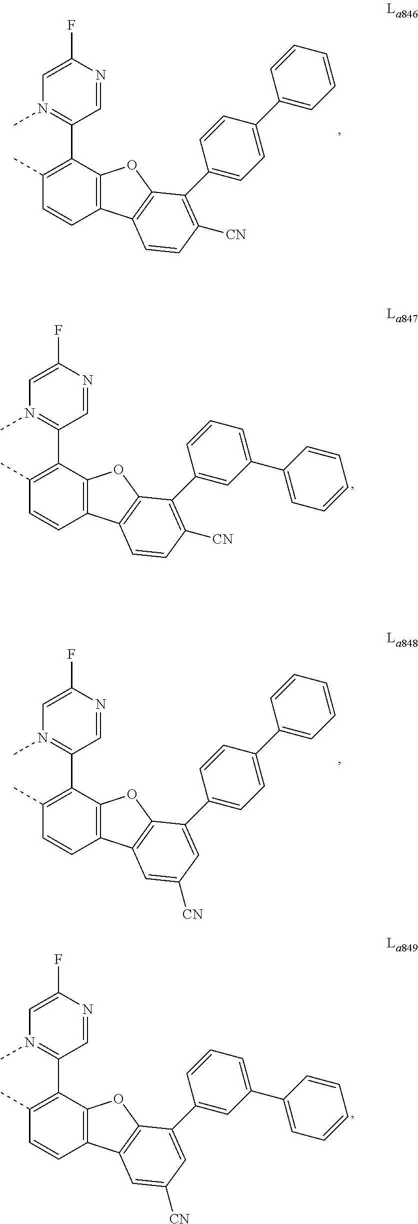 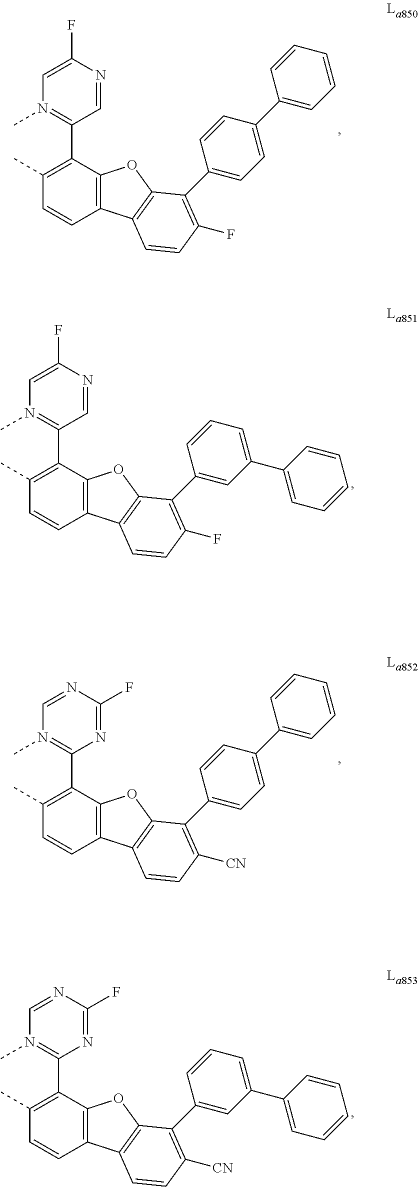 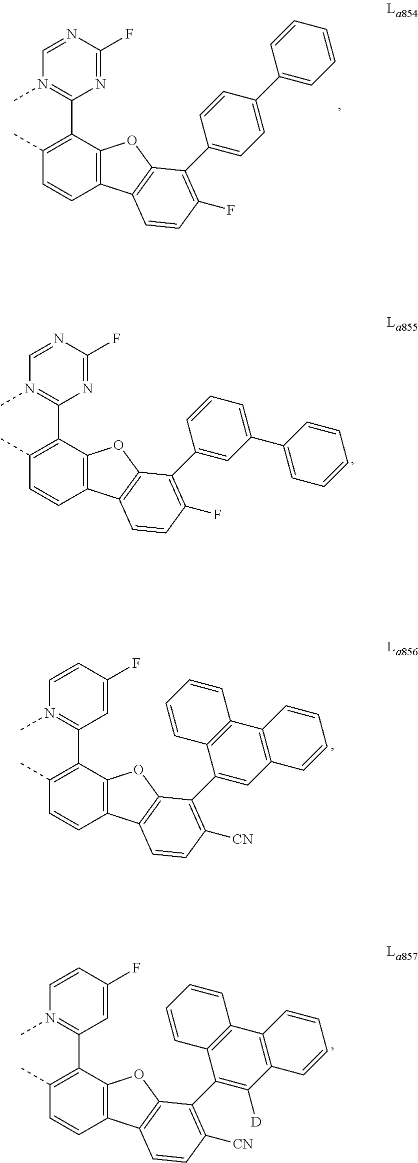 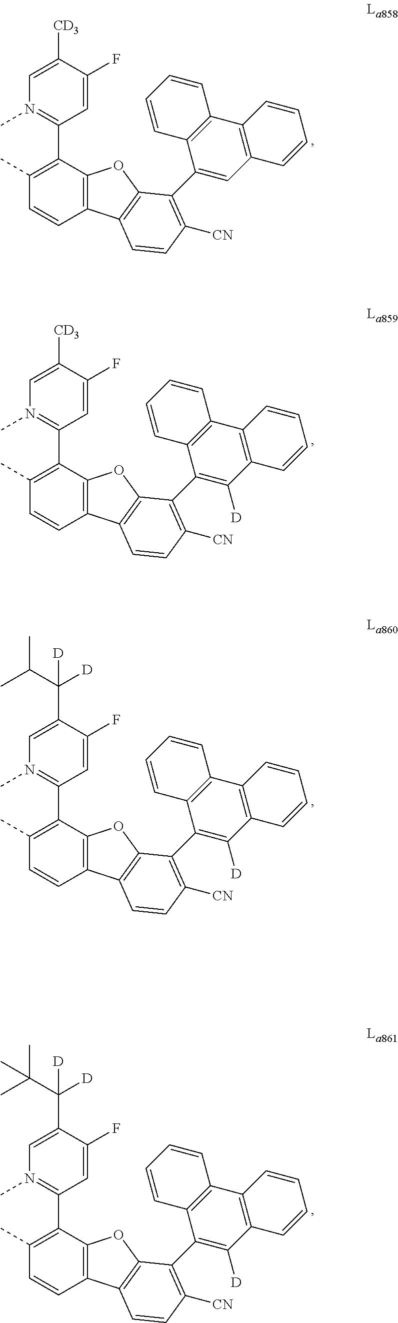 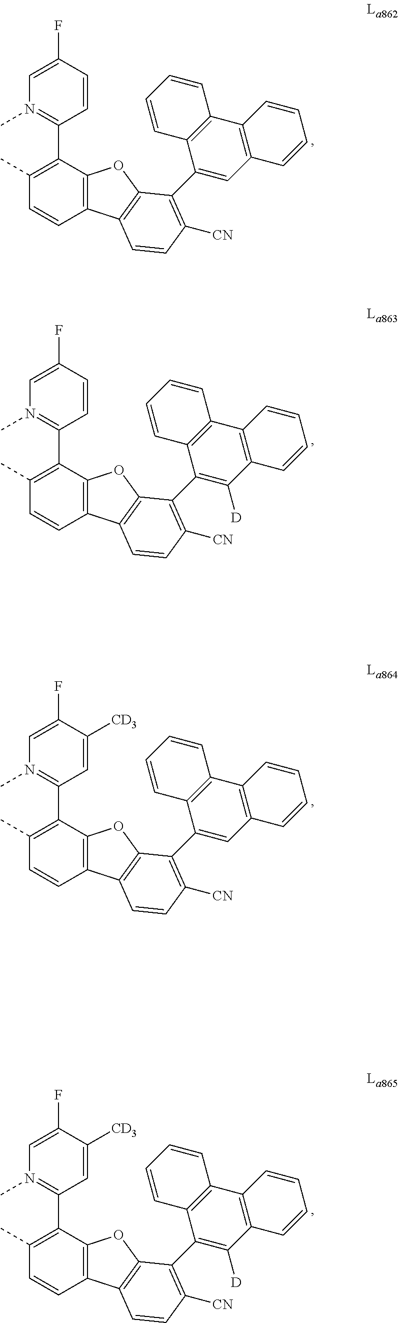 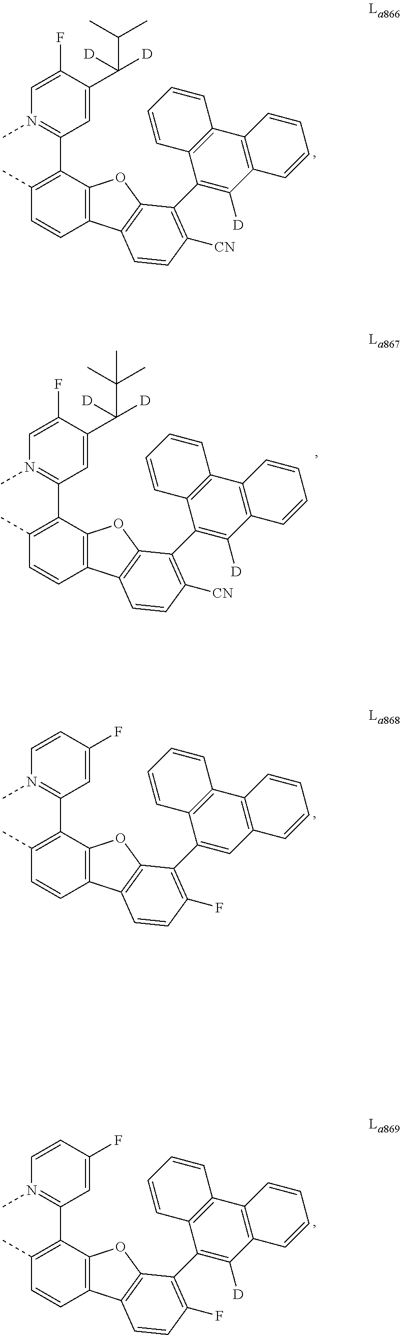 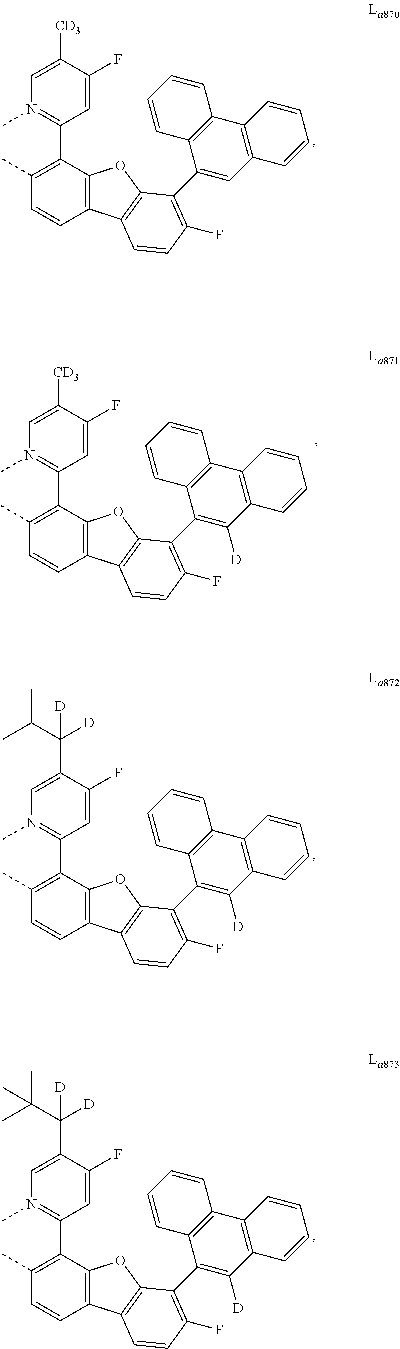 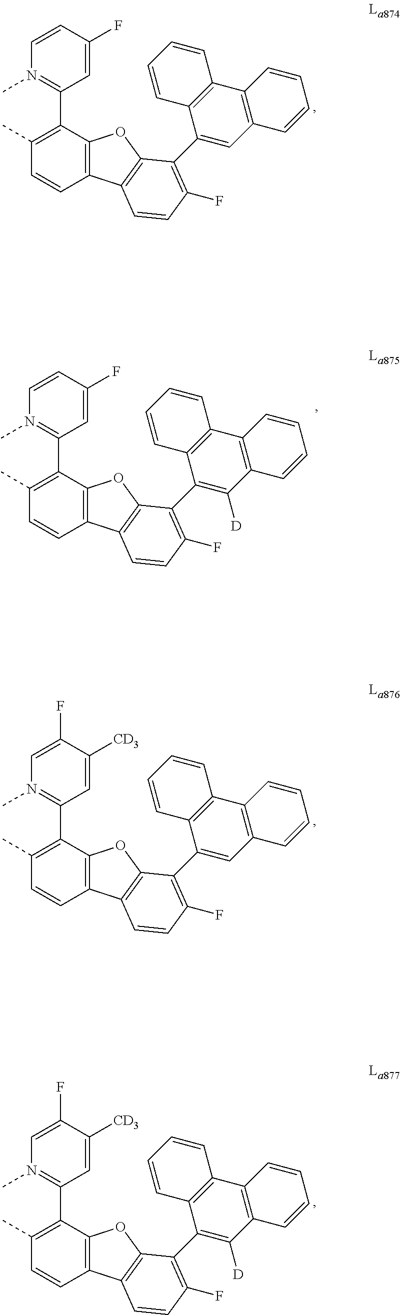 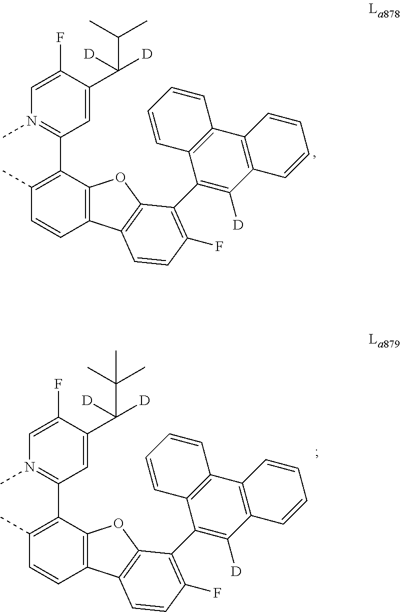
wherein optionally, hydrogens in Lₐ₁ to Lₐ₈₇₉ can be partially or fully deuterated.

18. The metal complex according to claim 3, wherein L_{b} is, at each occurrence identically or differently, selected from the group consisting of: 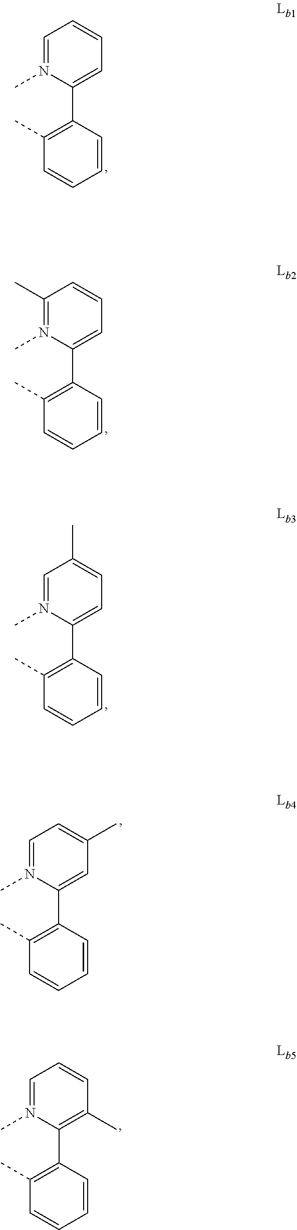 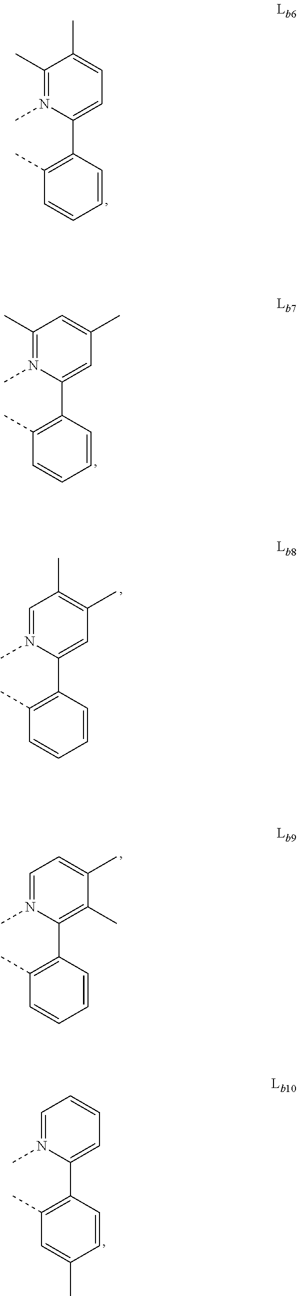 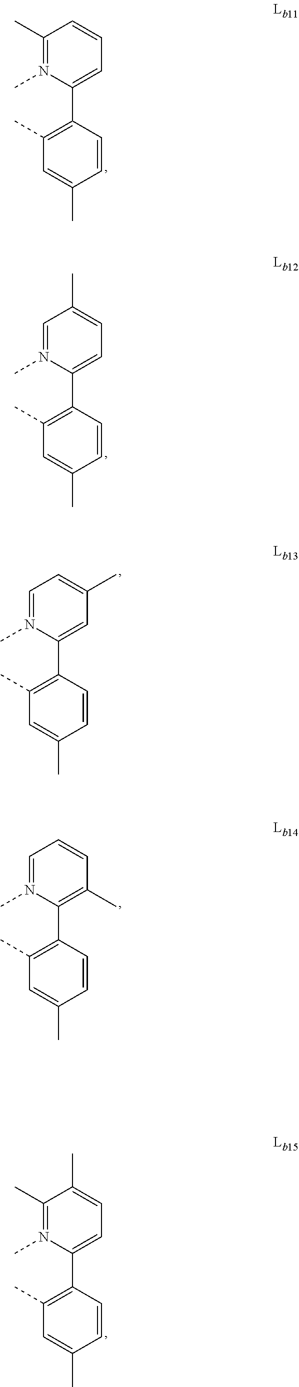 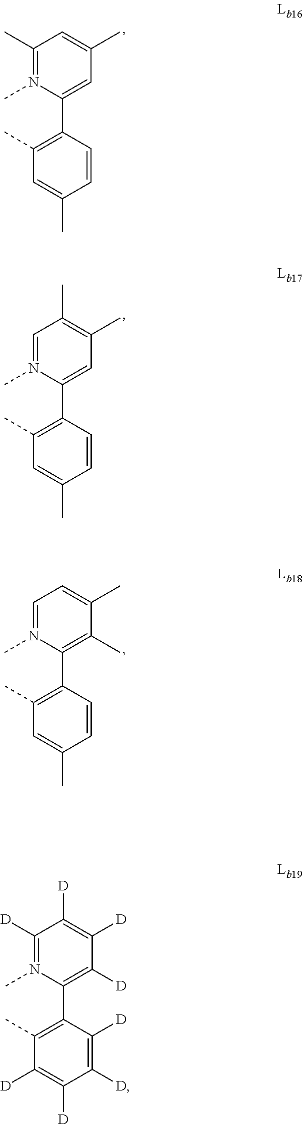 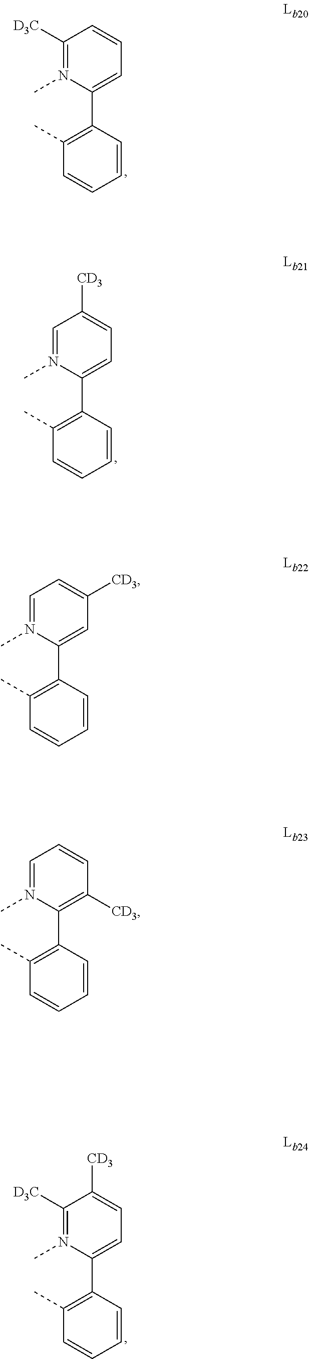 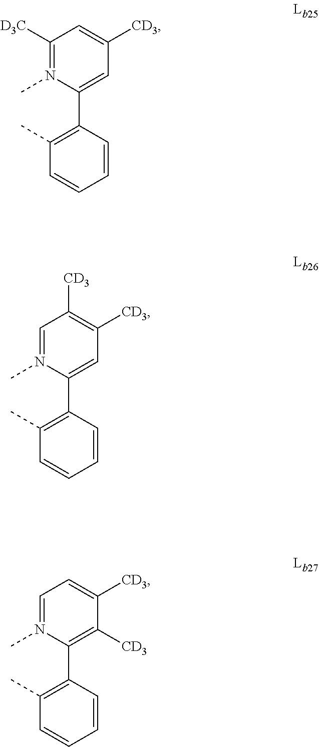 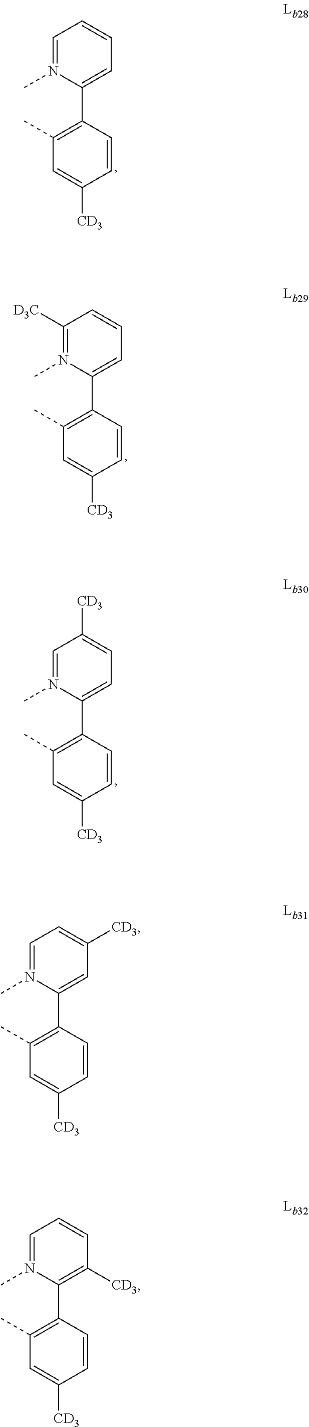 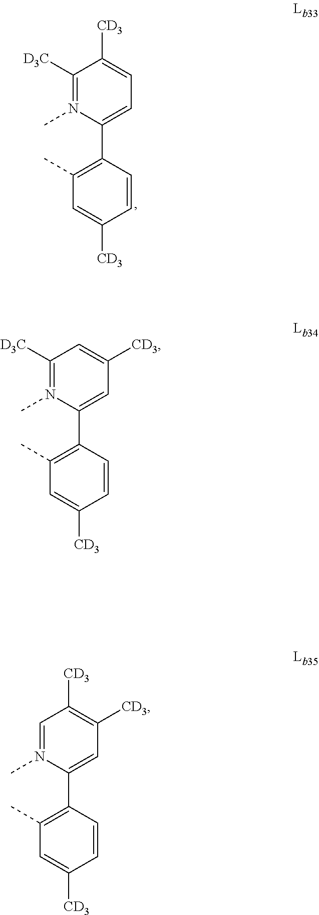 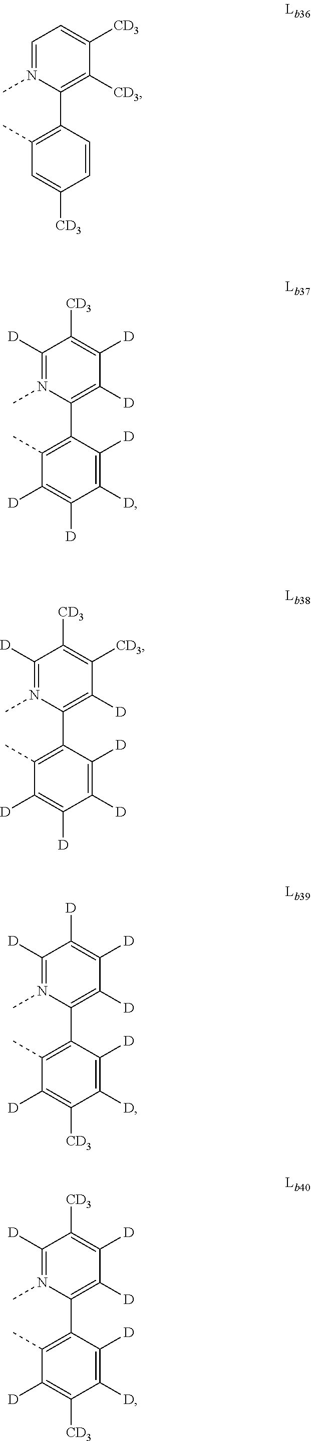 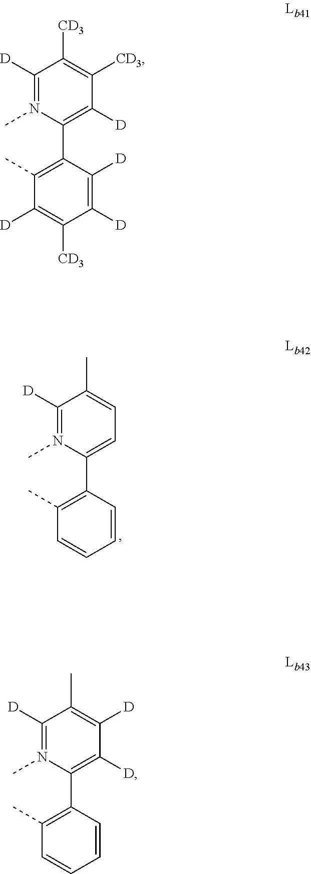 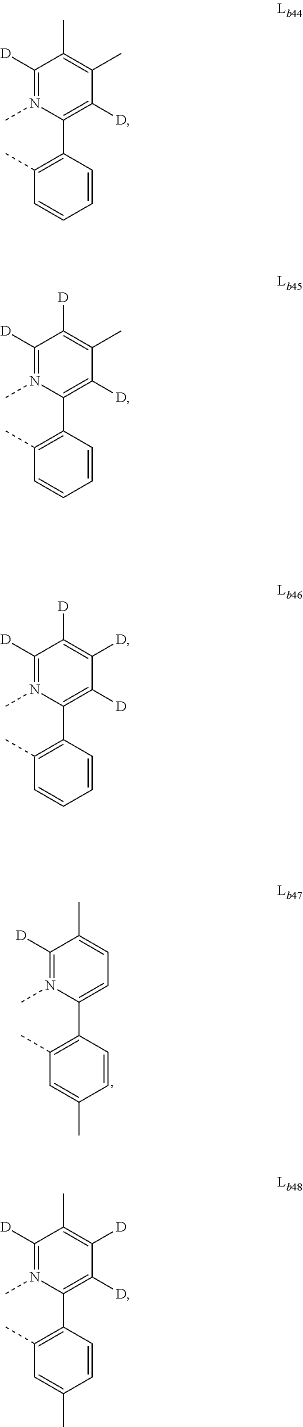 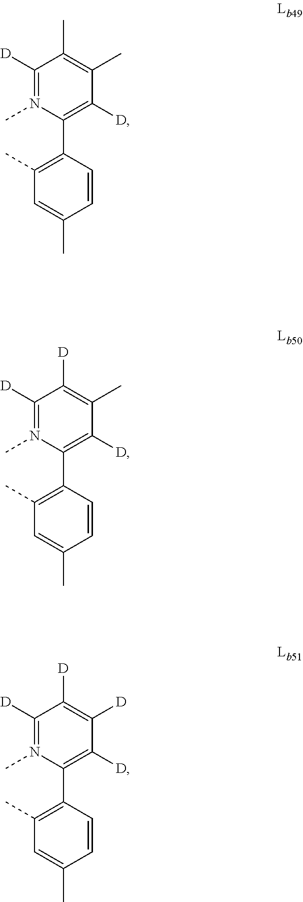 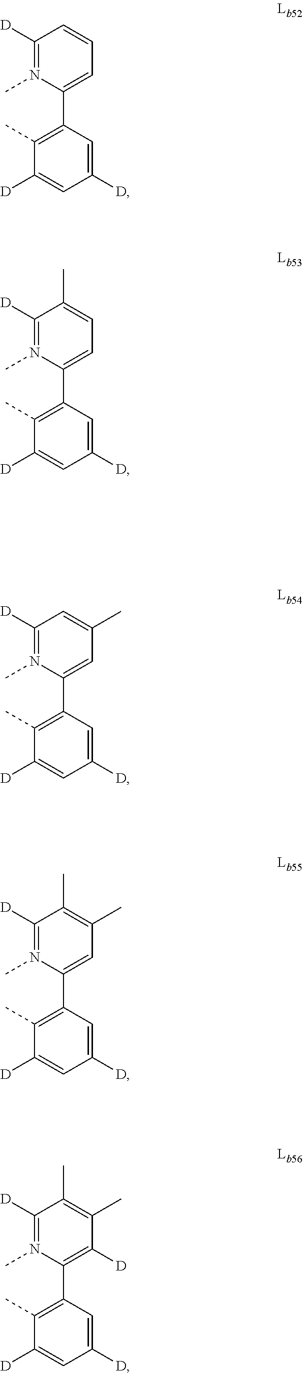 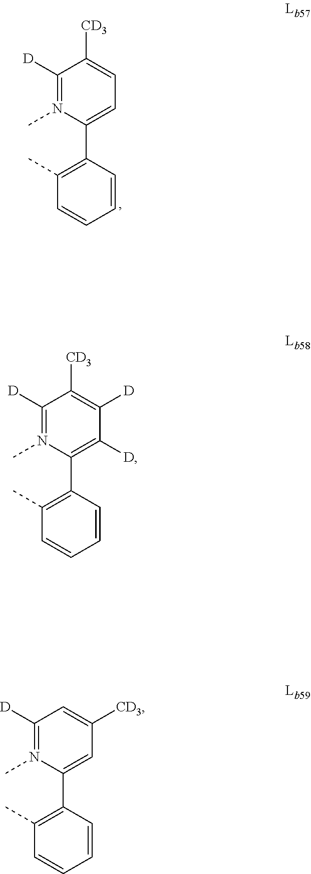 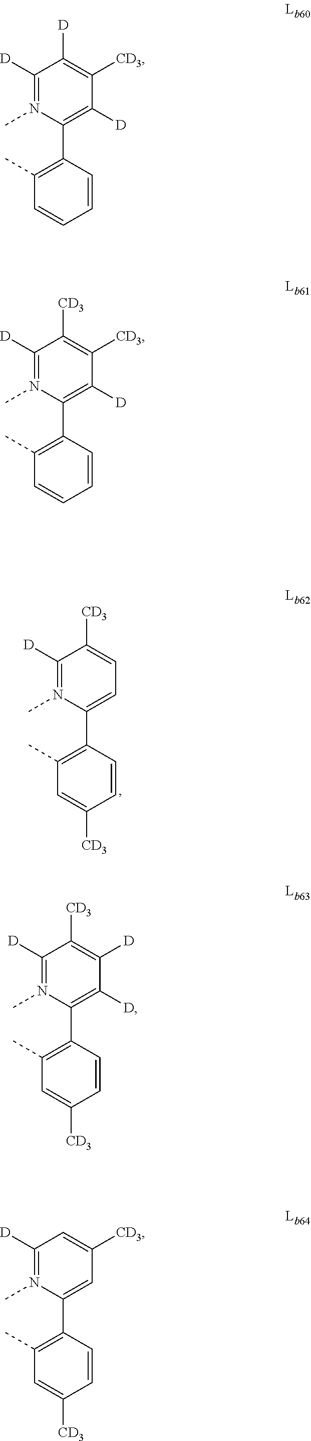 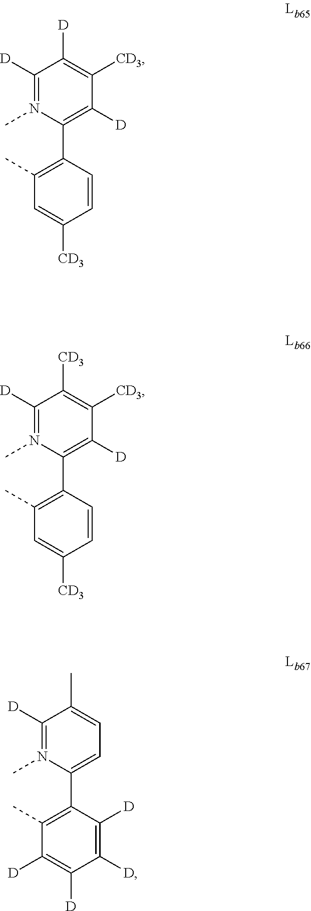 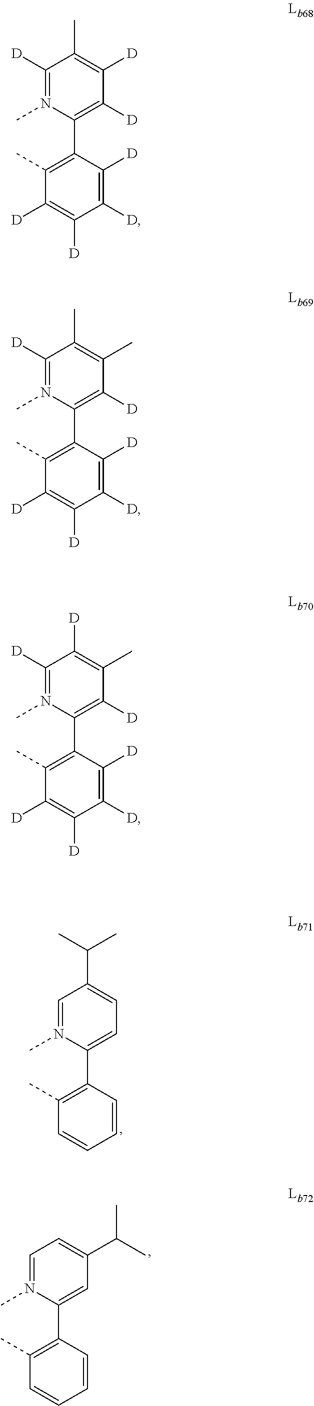 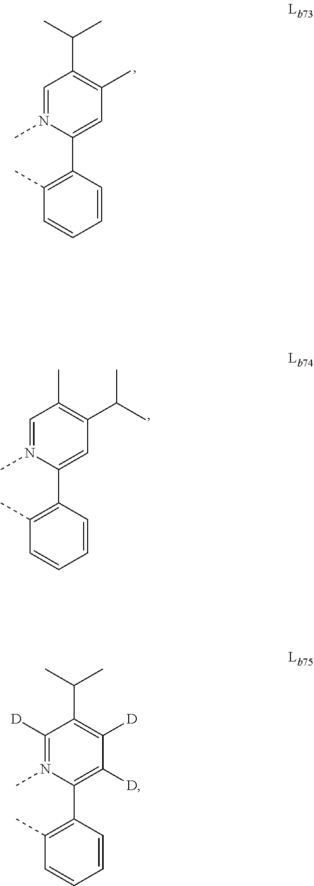 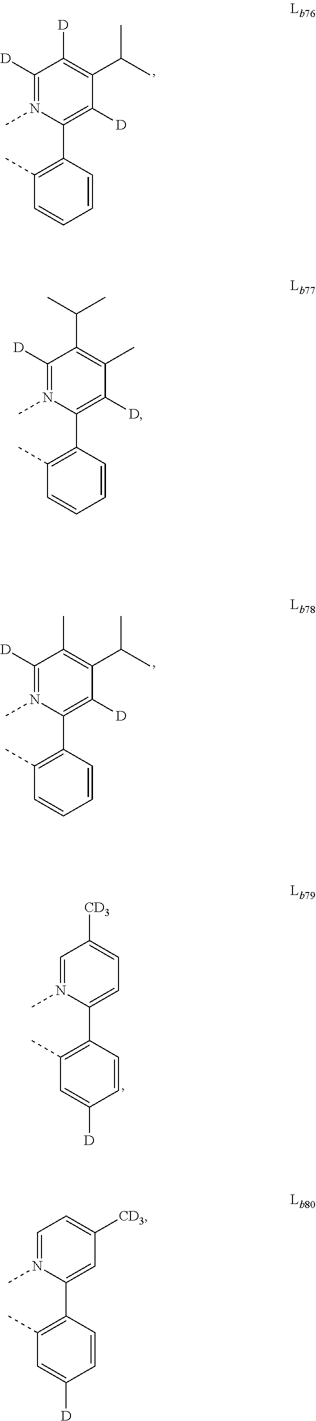 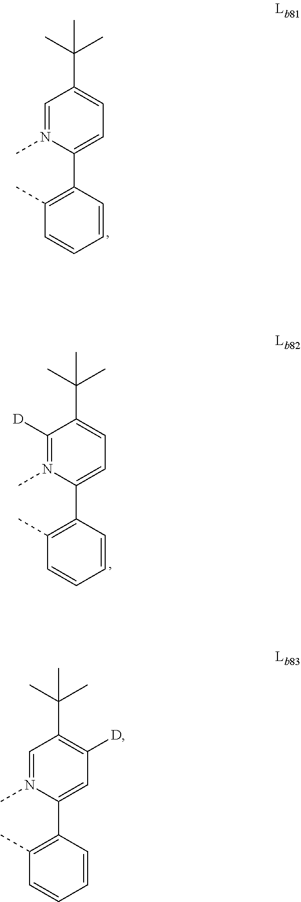 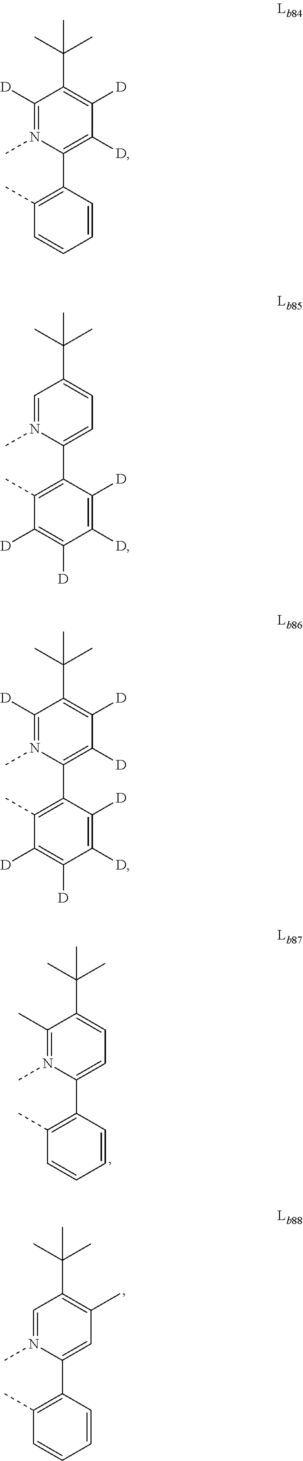 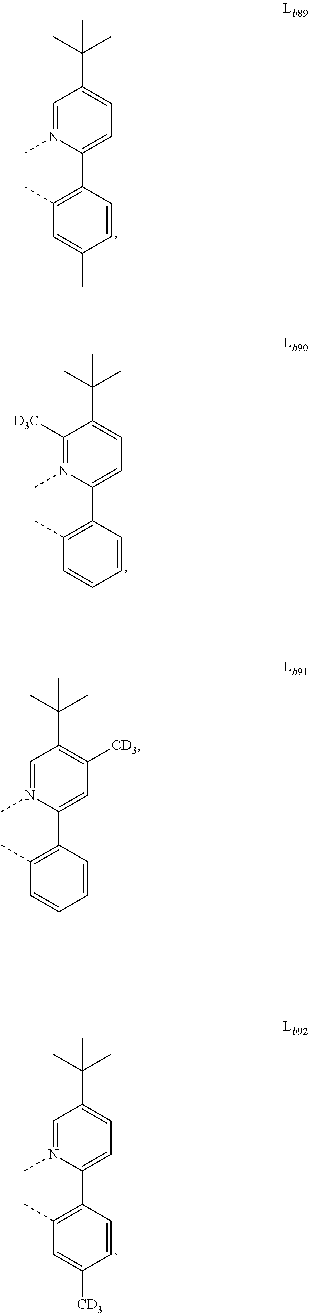 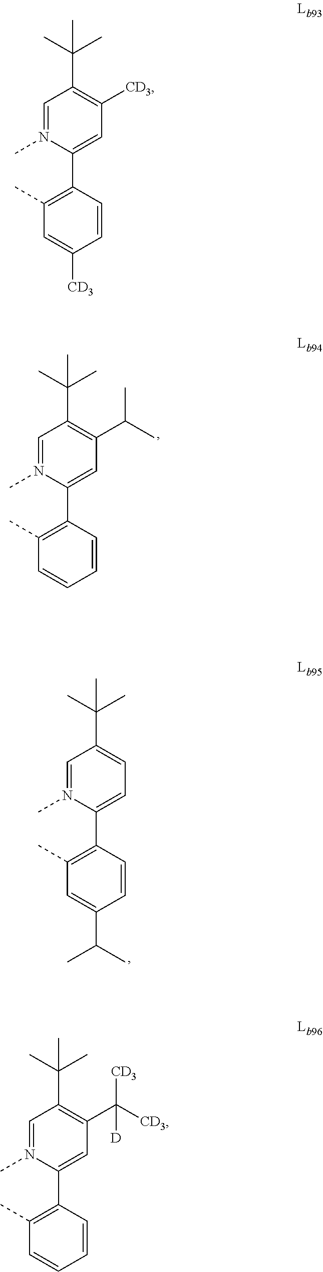 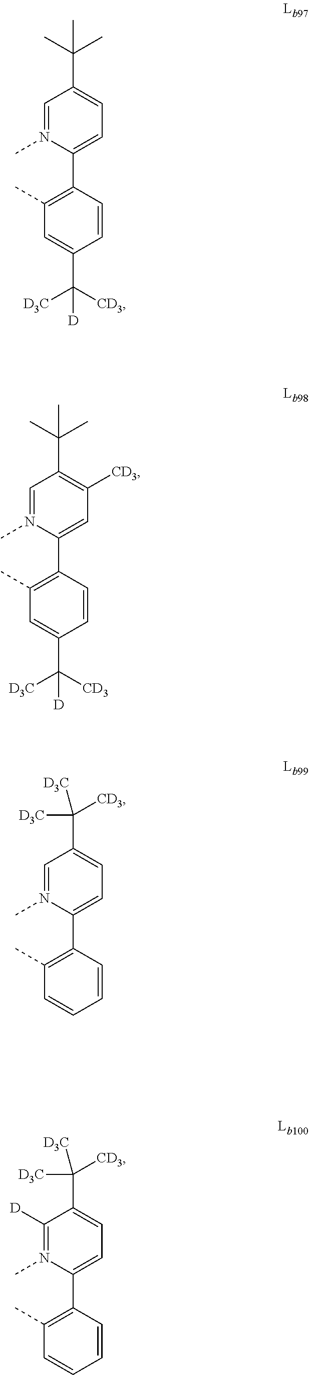 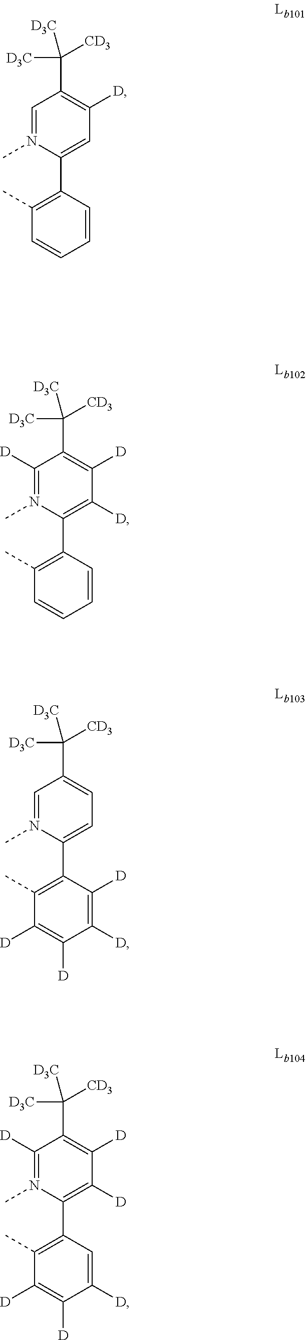 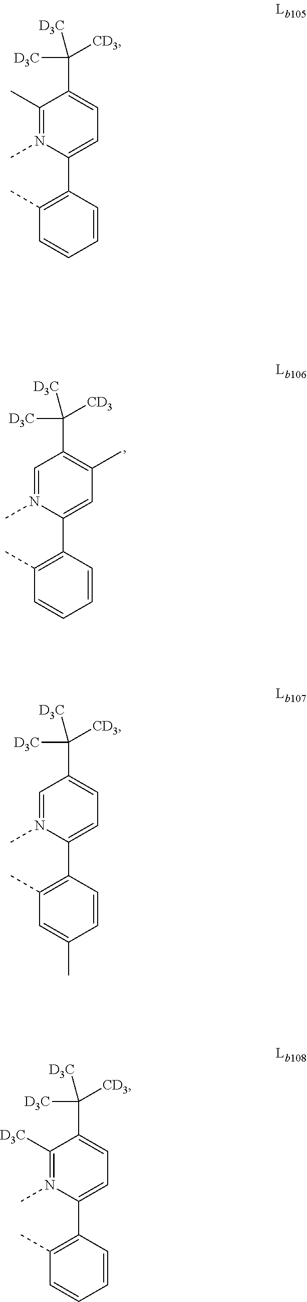 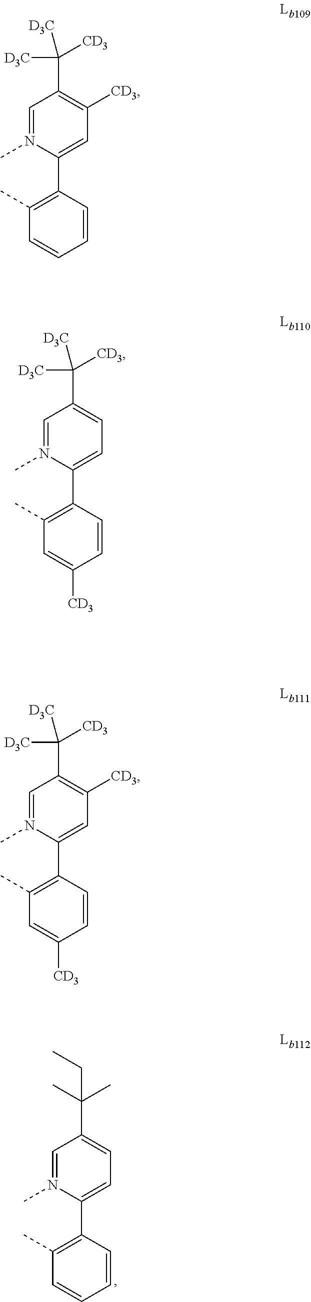 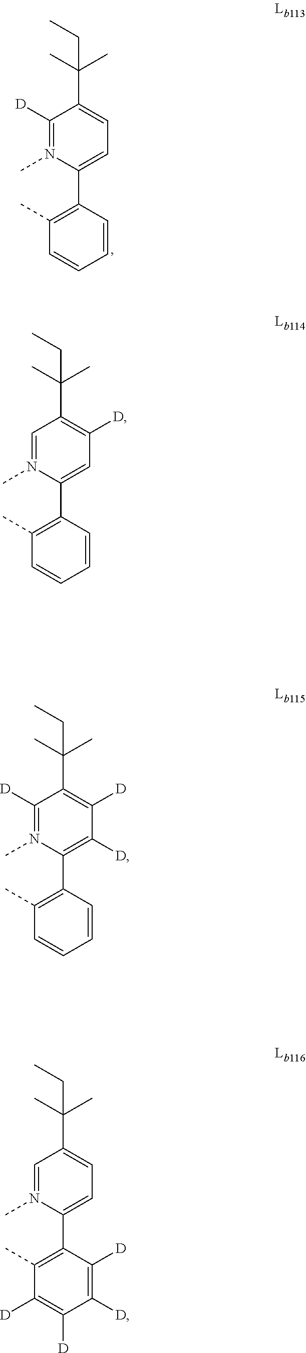 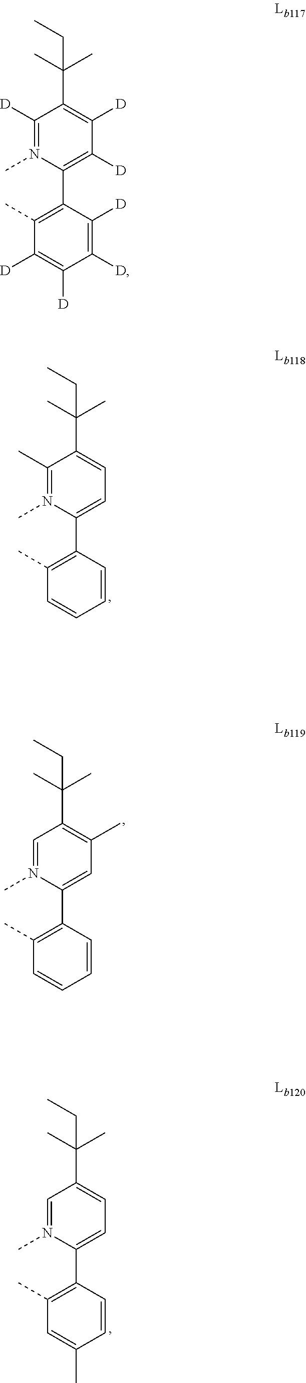 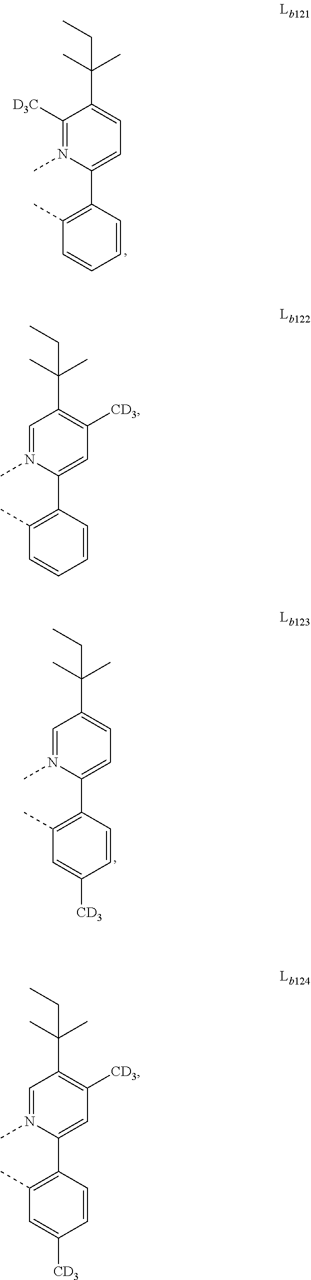 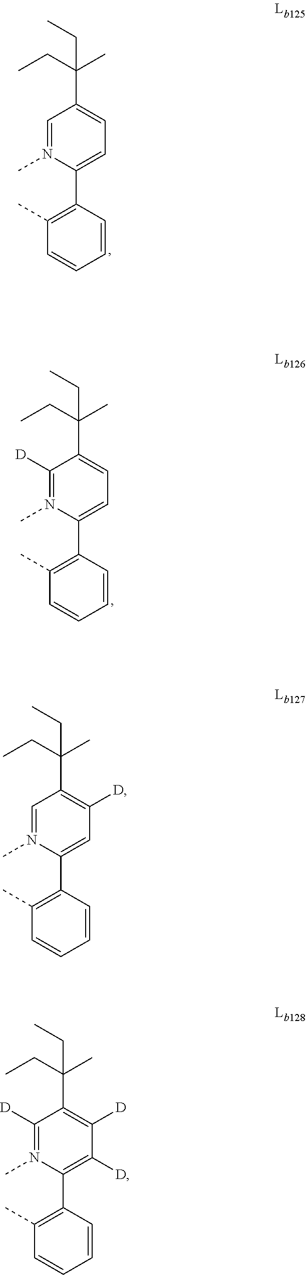 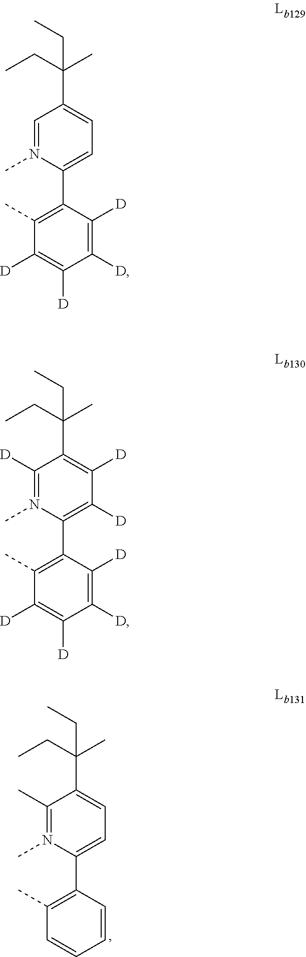 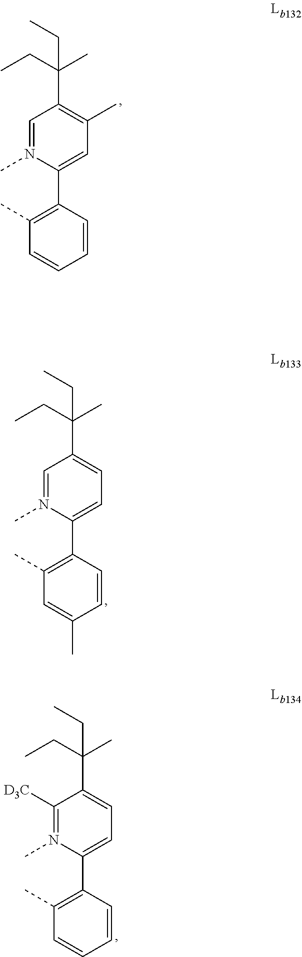 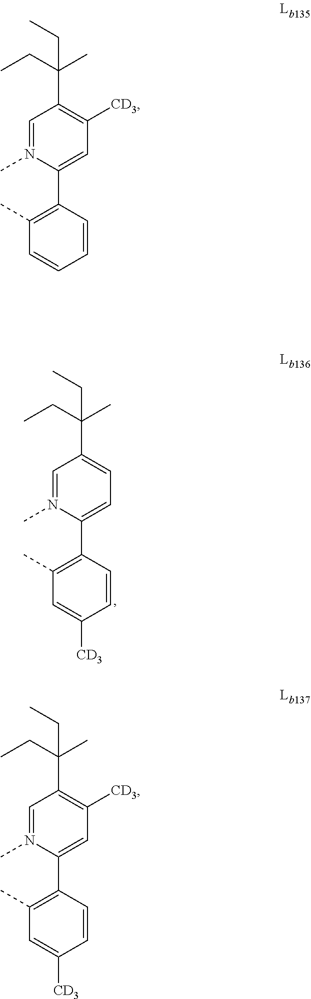 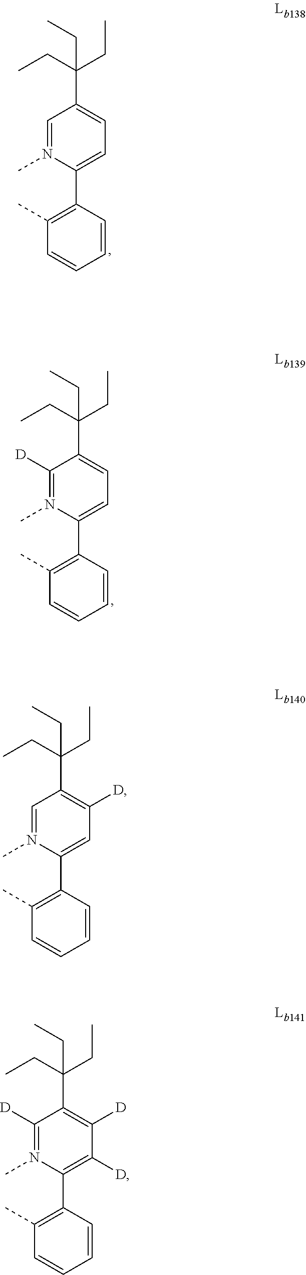 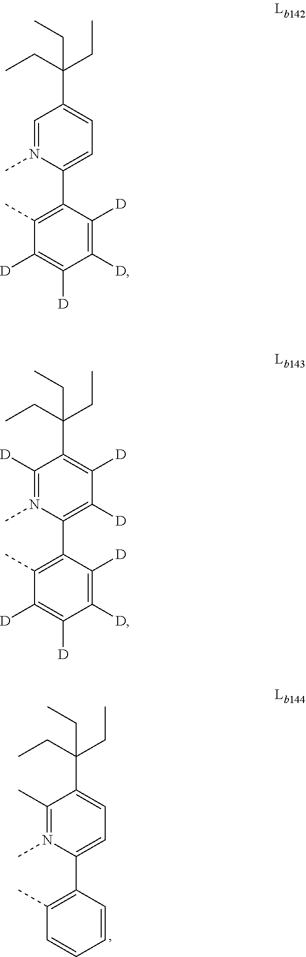 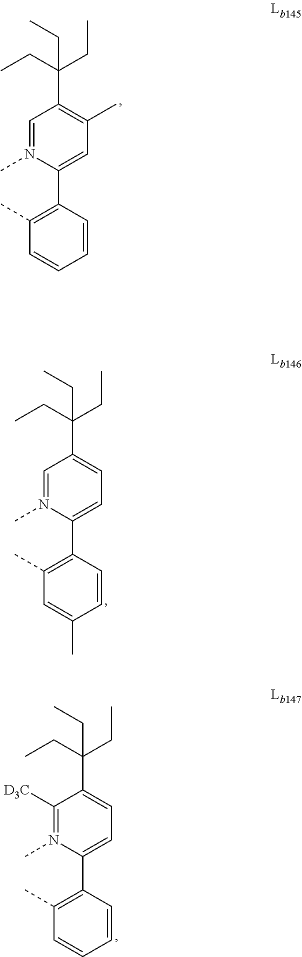 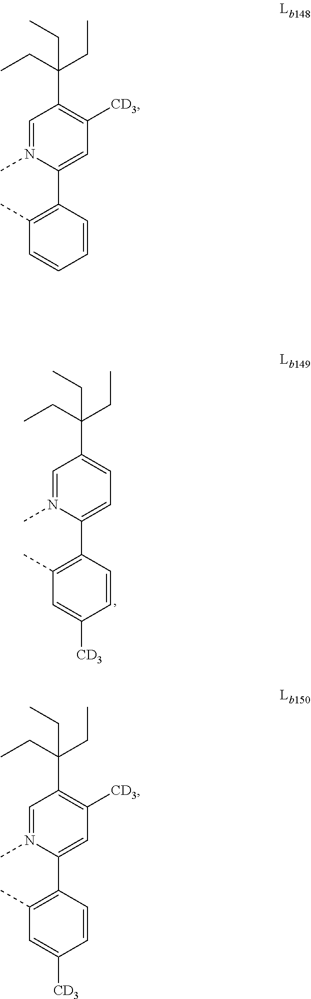 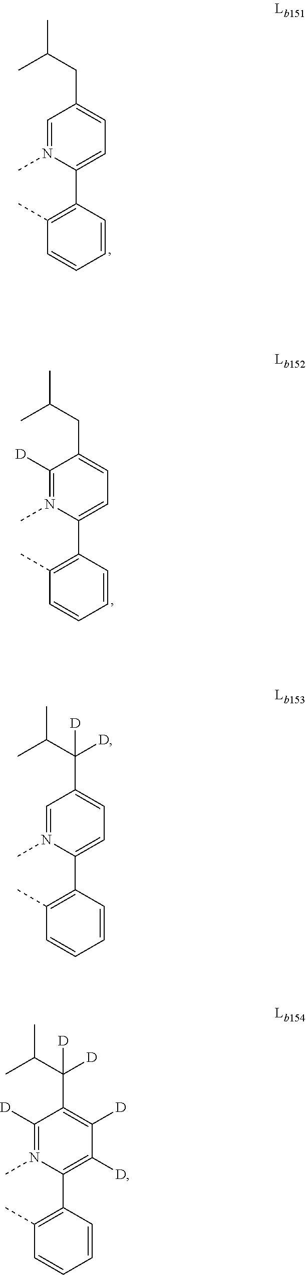 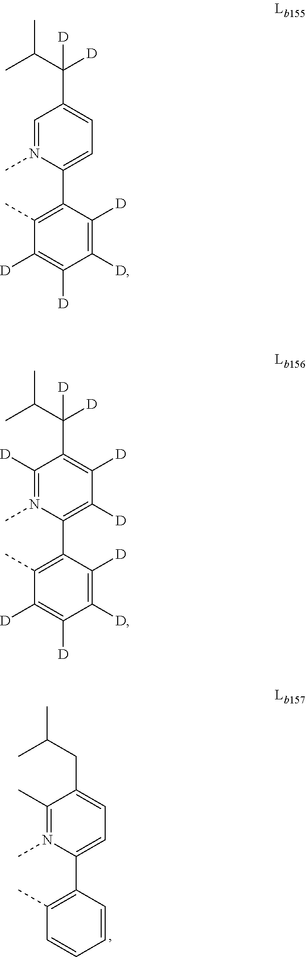 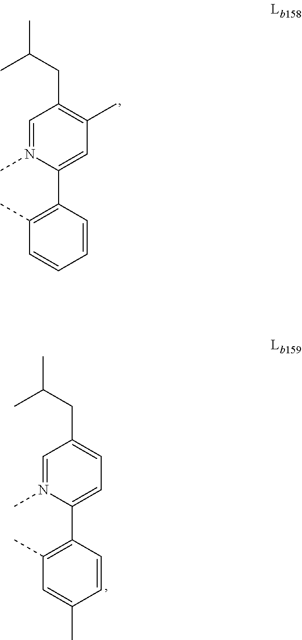 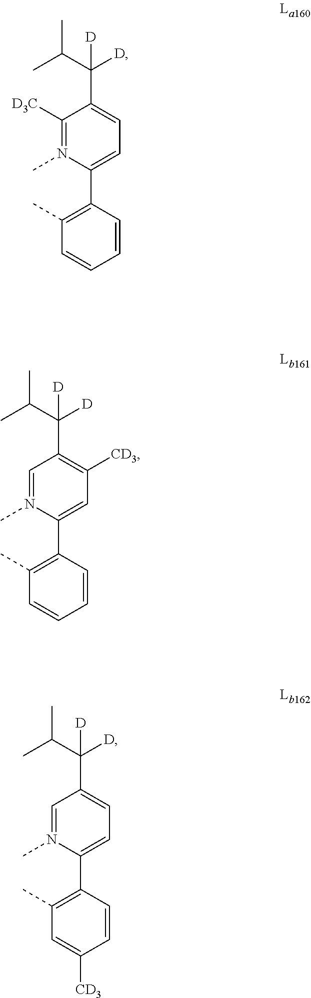 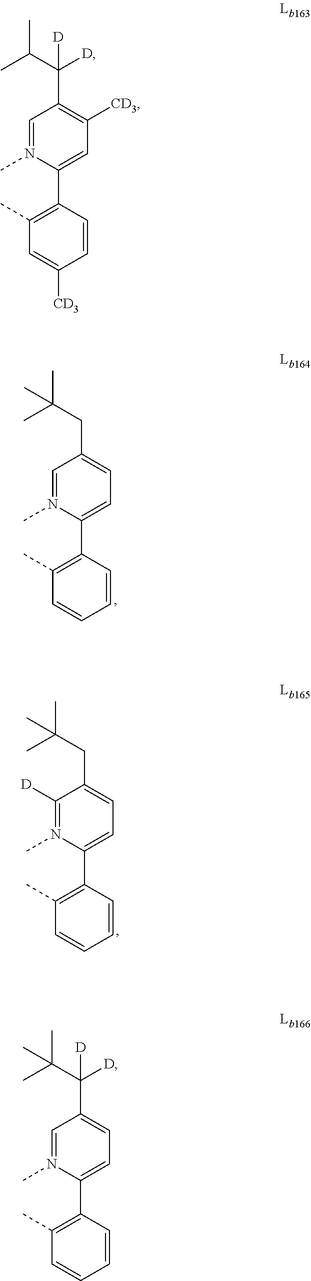 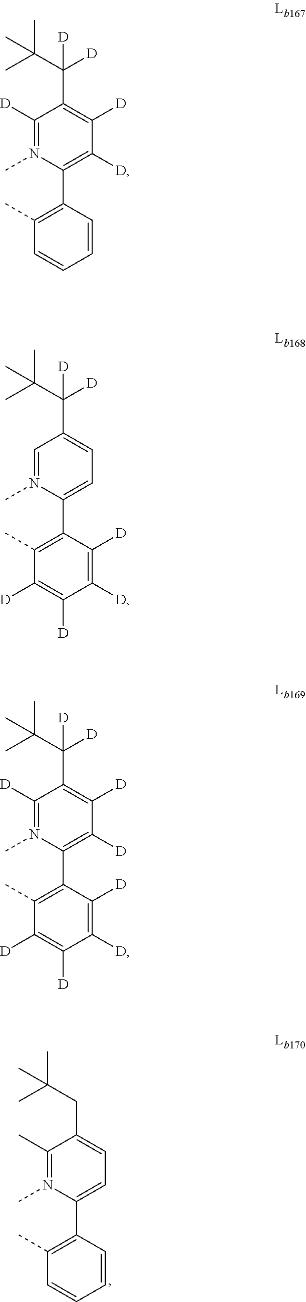 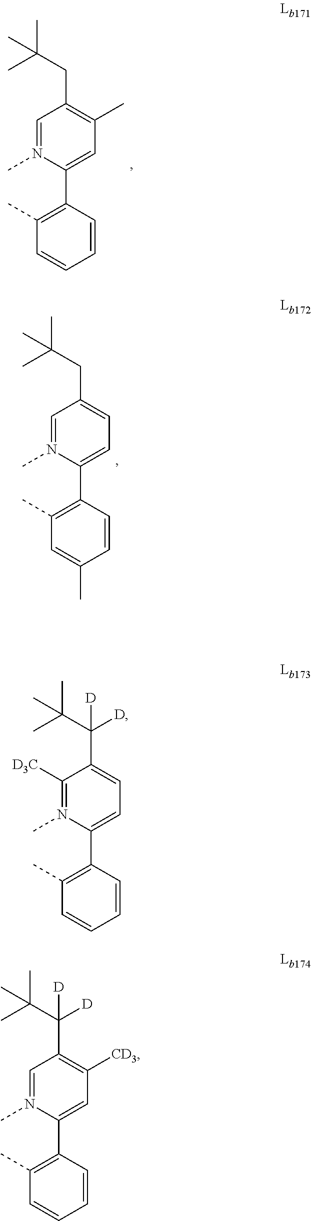 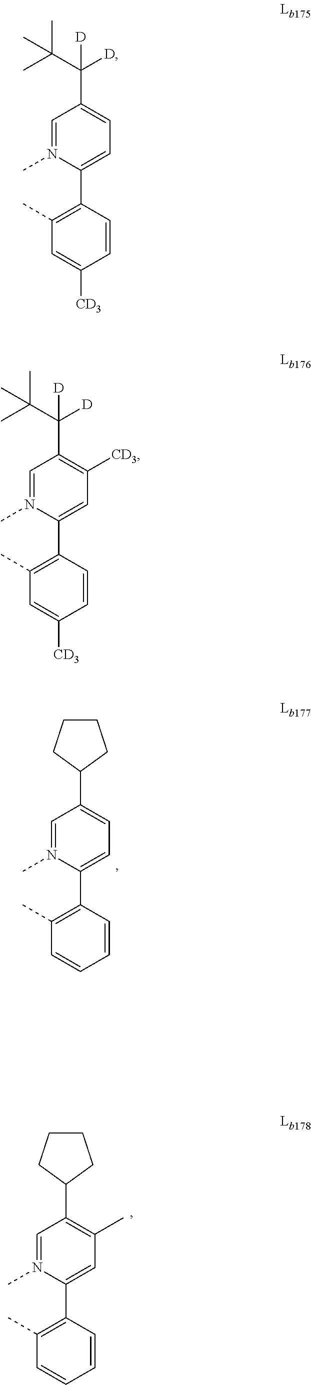 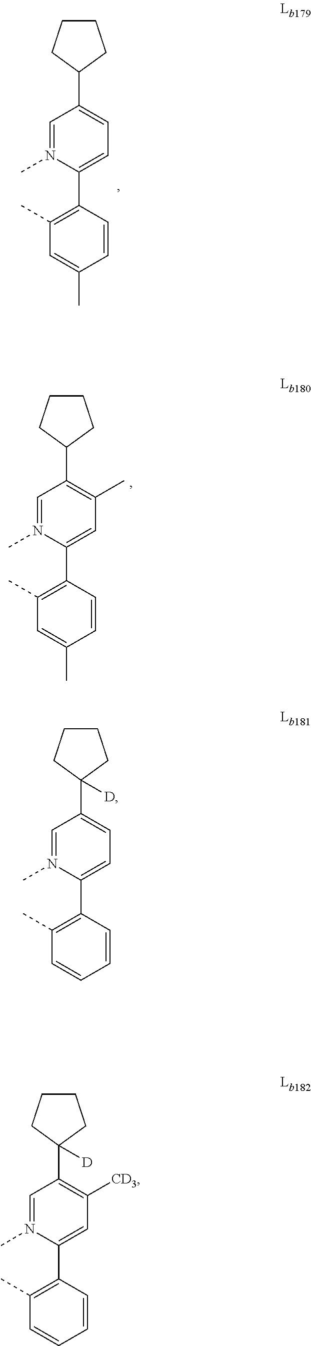 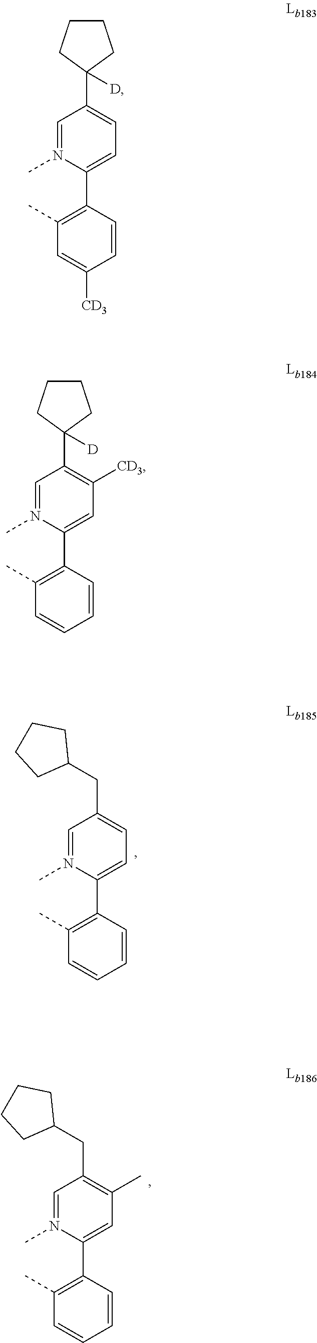 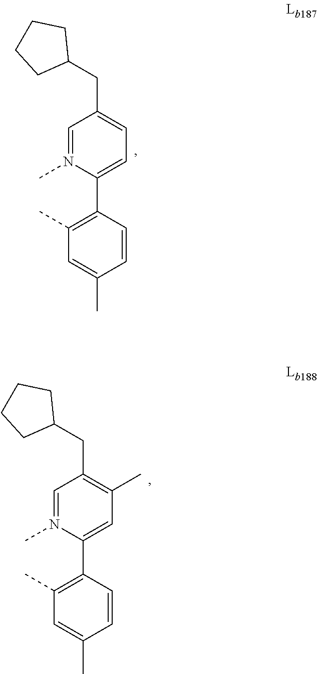 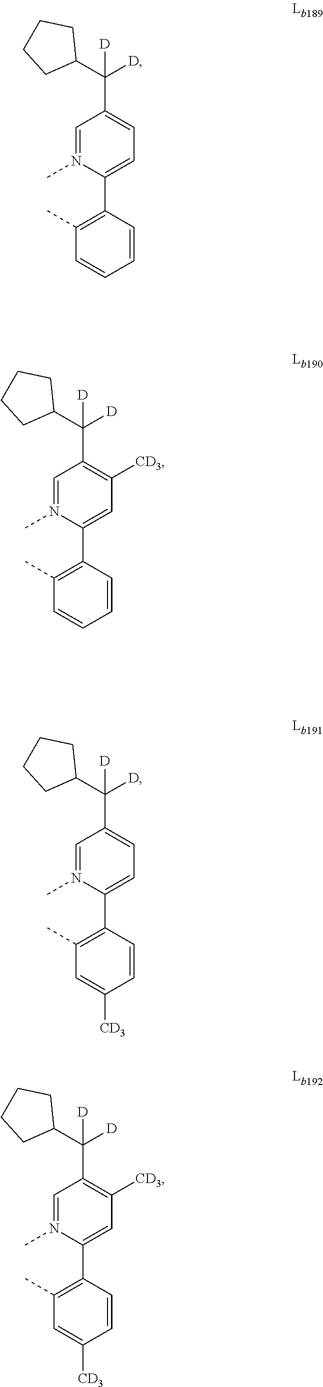 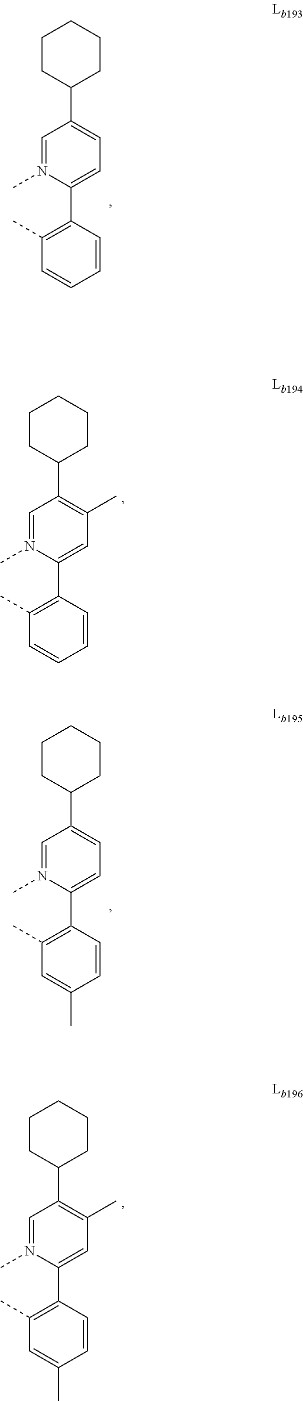 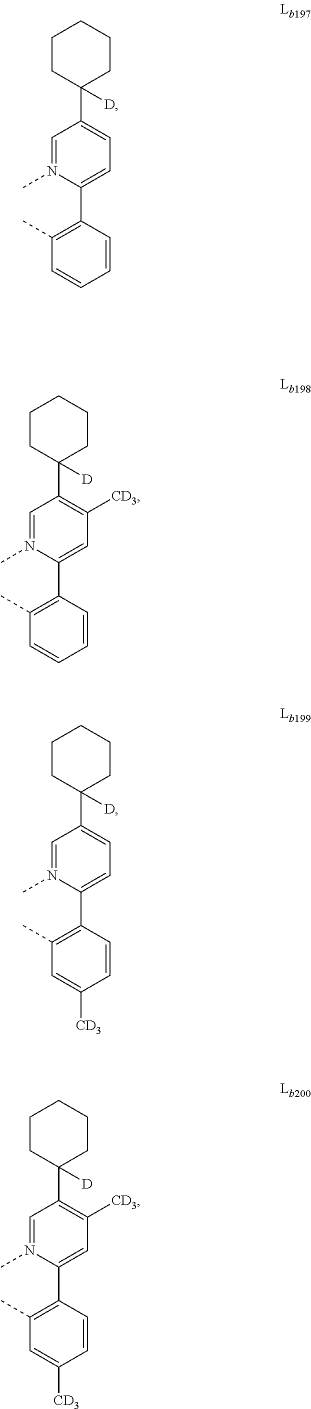 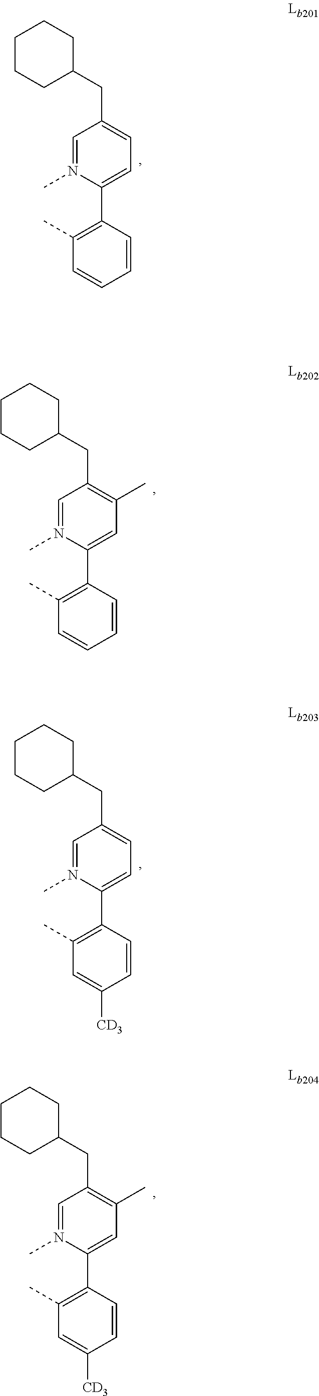 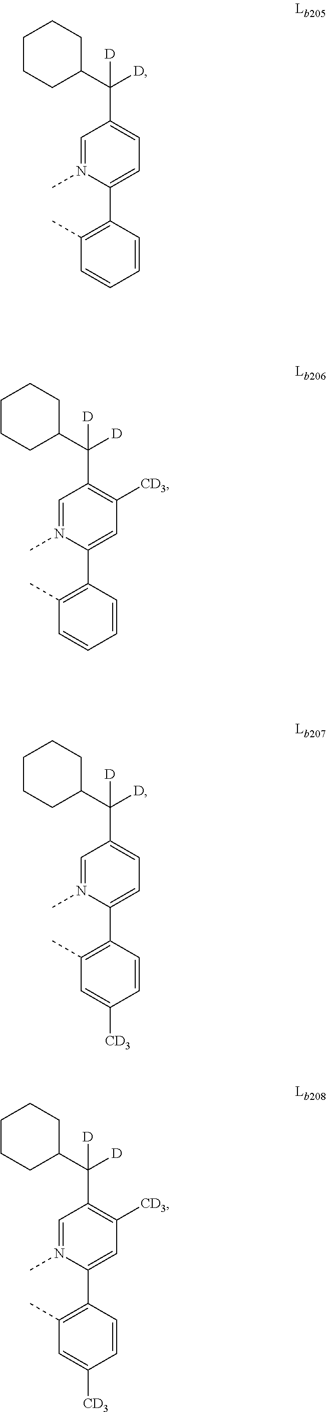 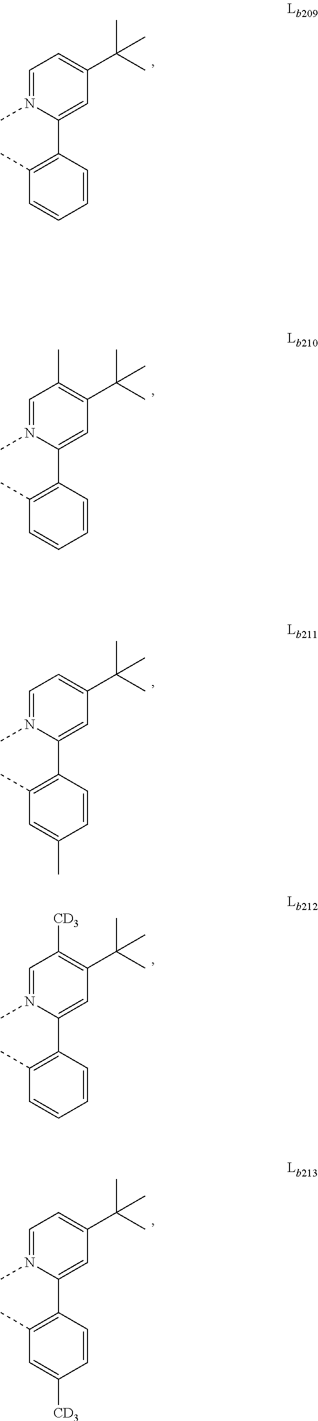 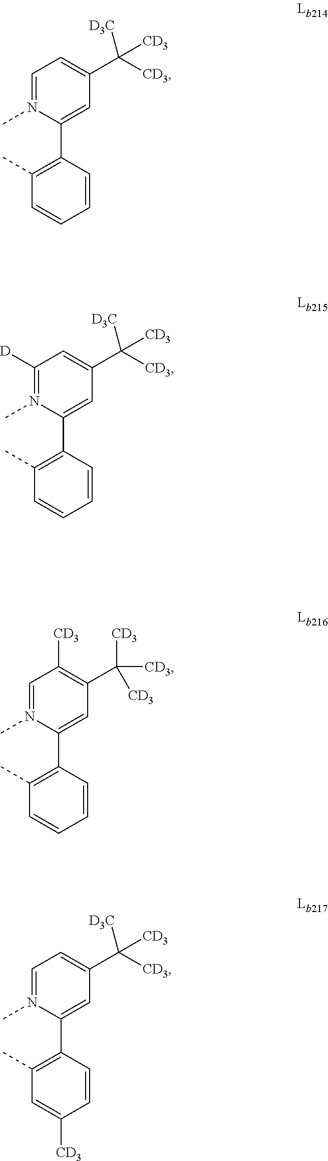 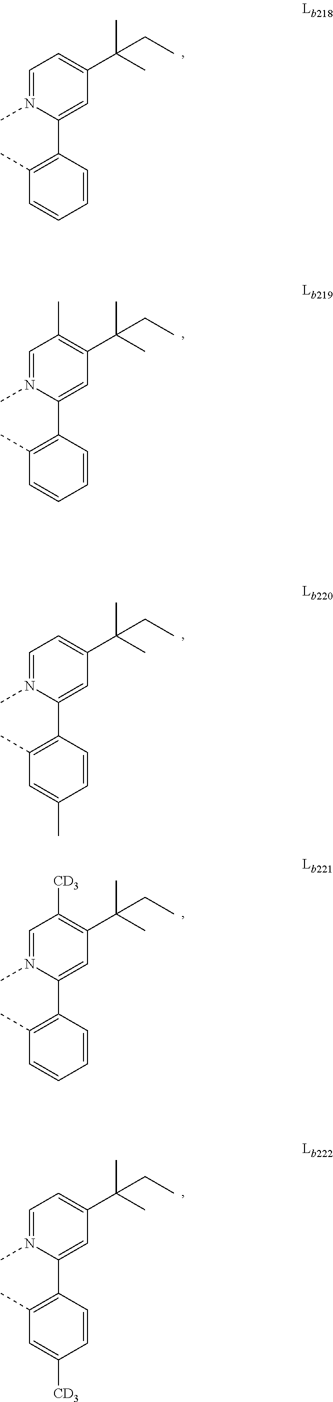 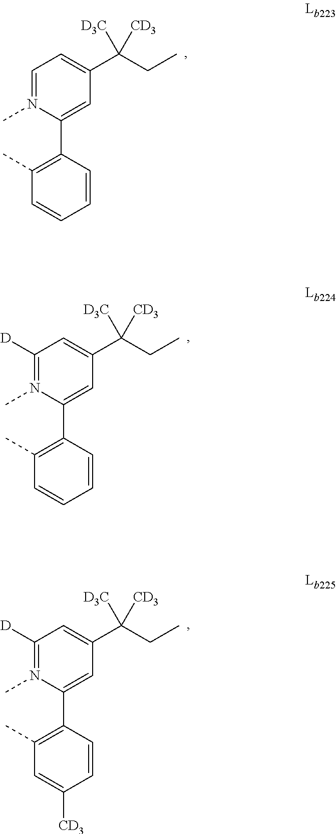 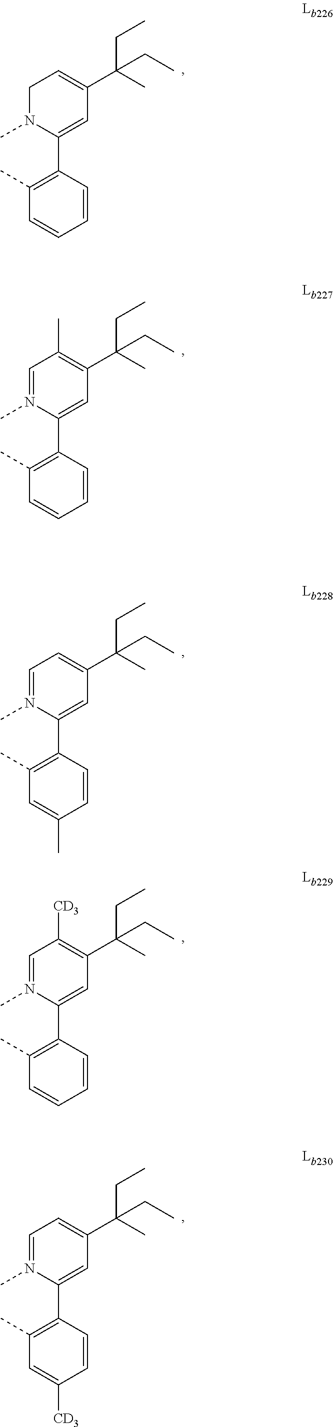 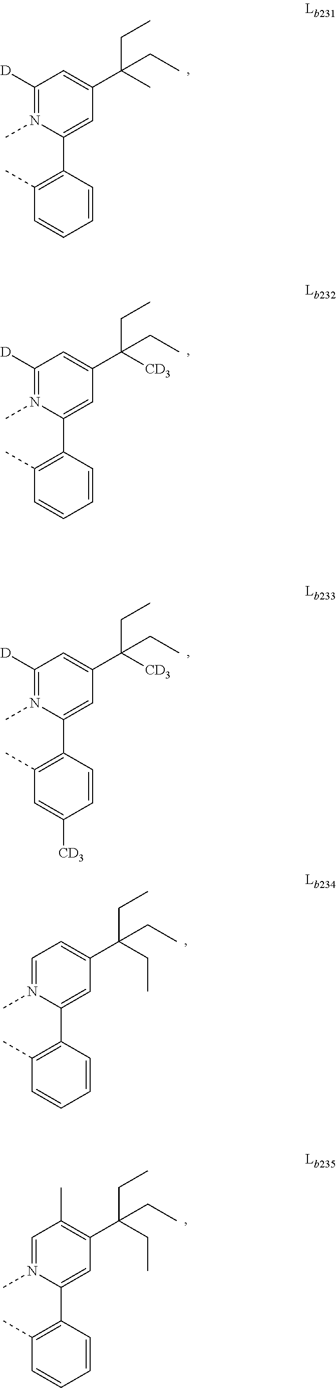 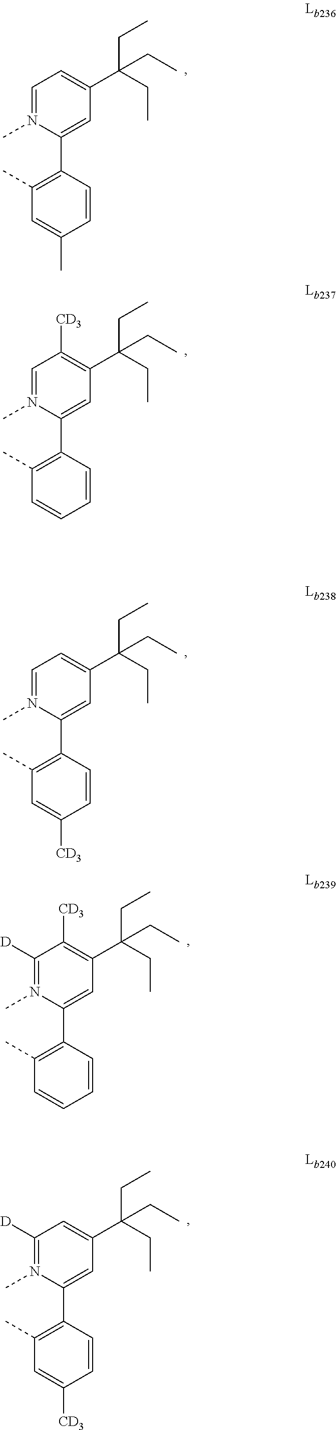 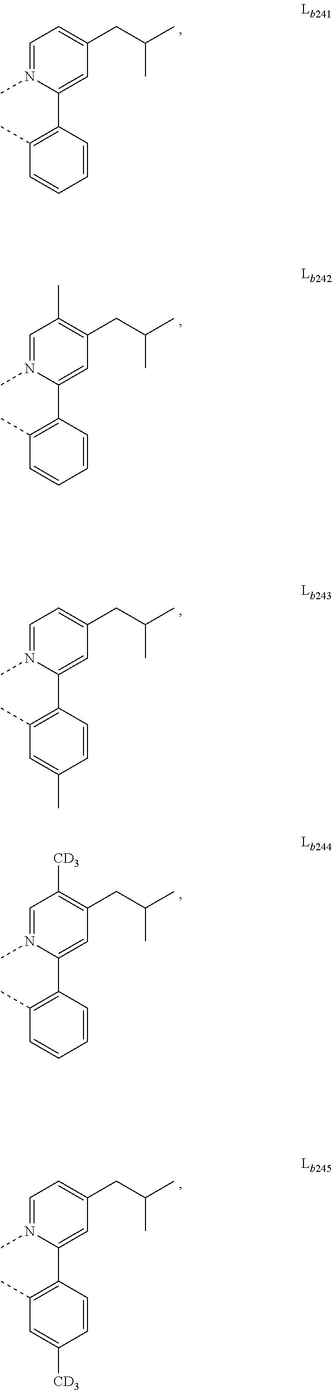 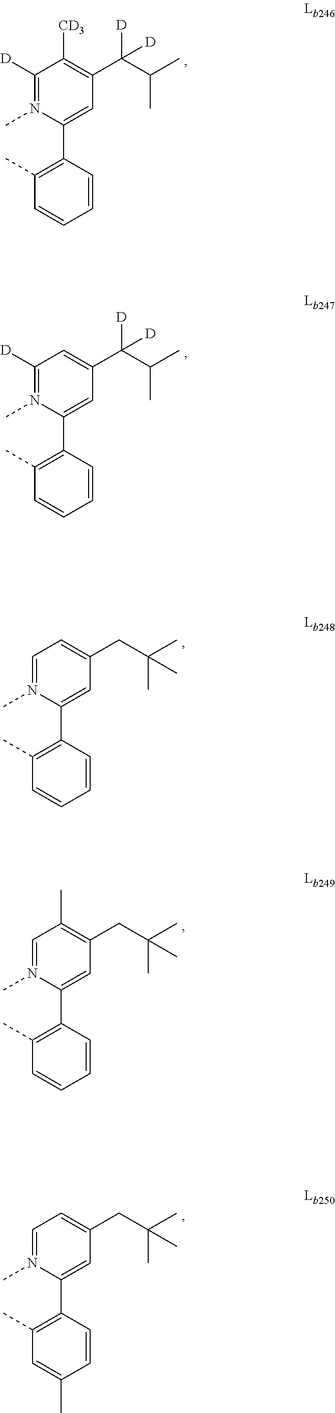 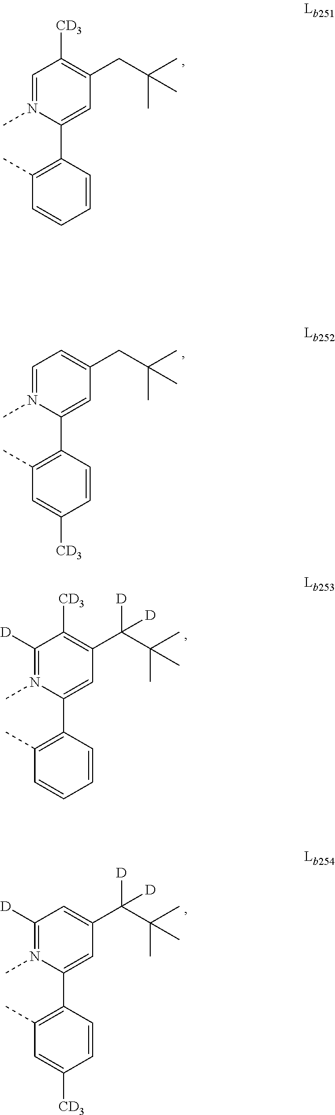 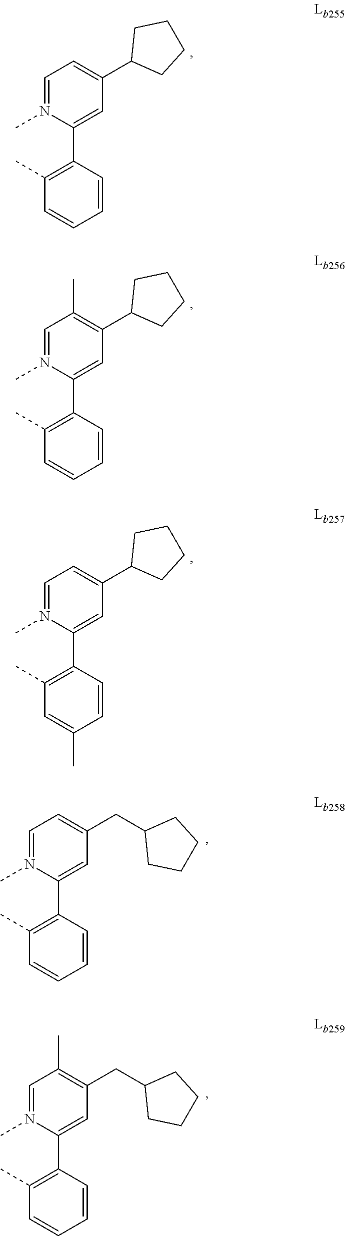 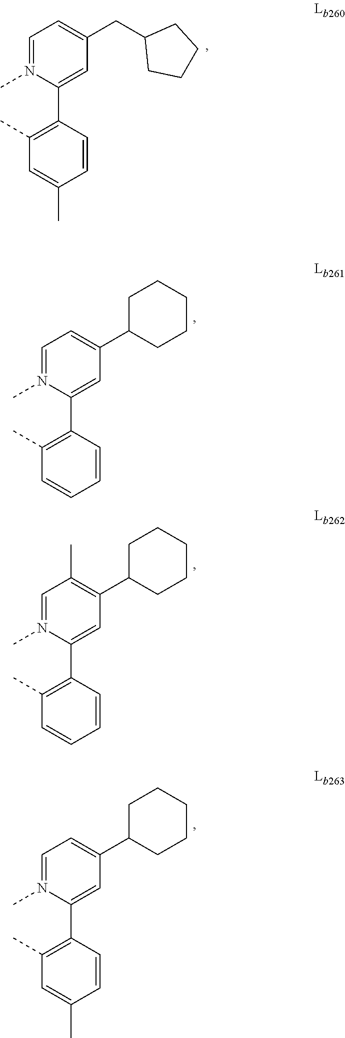 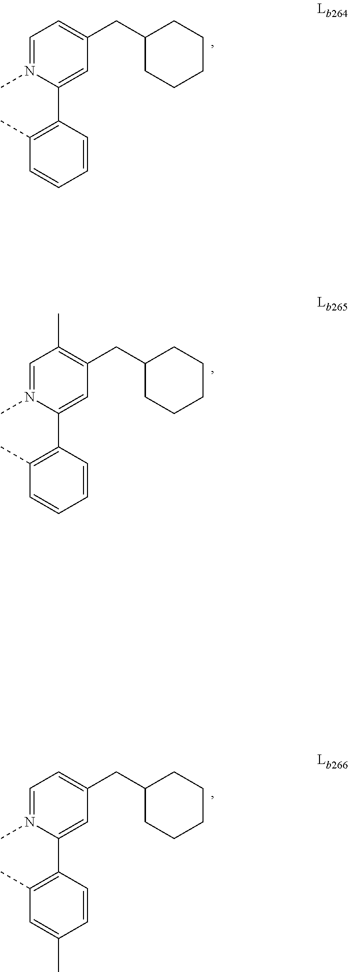 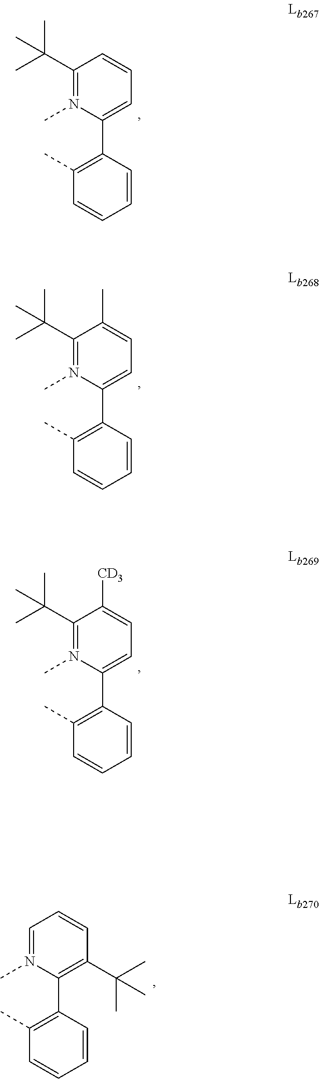 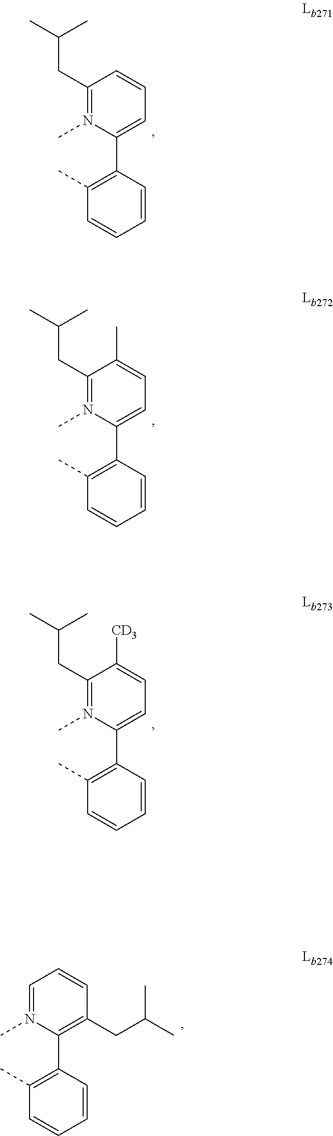 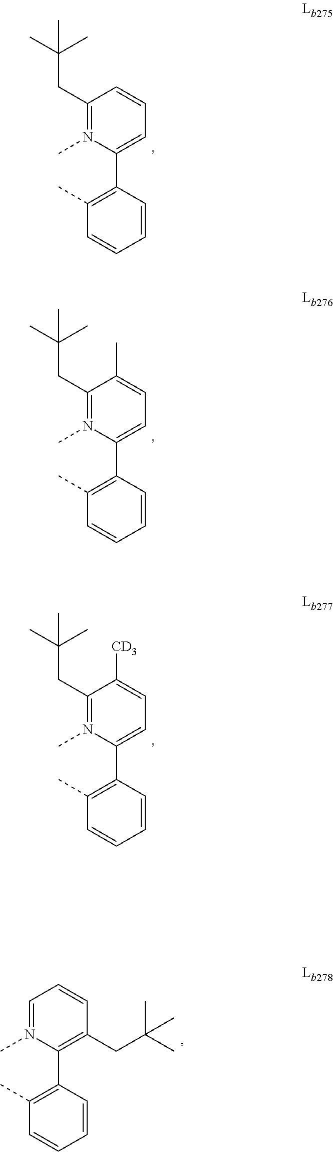 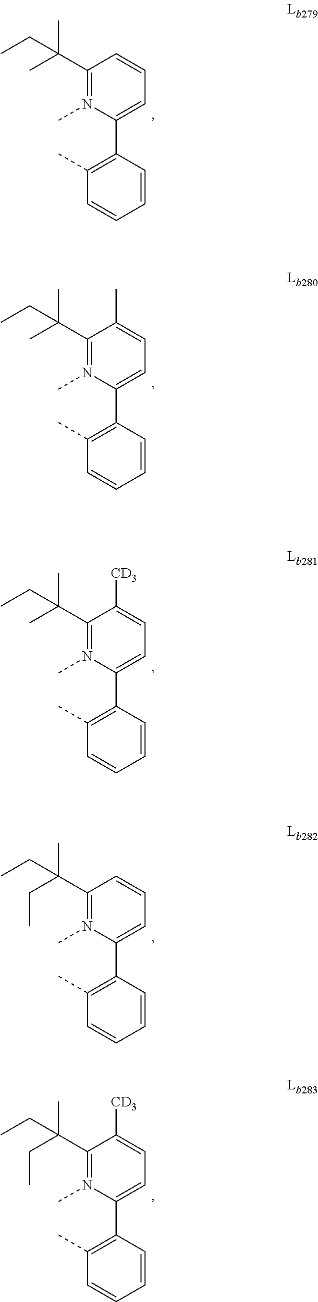 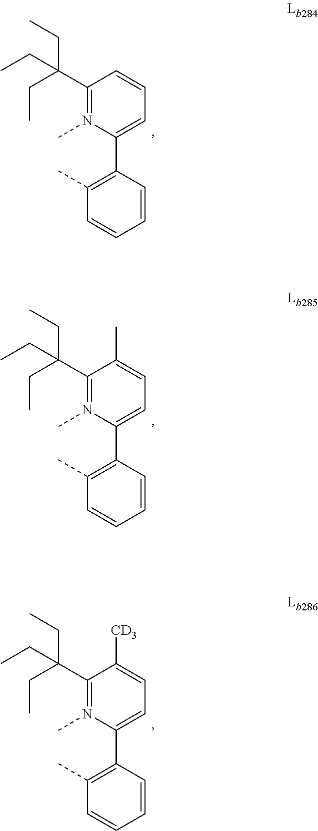 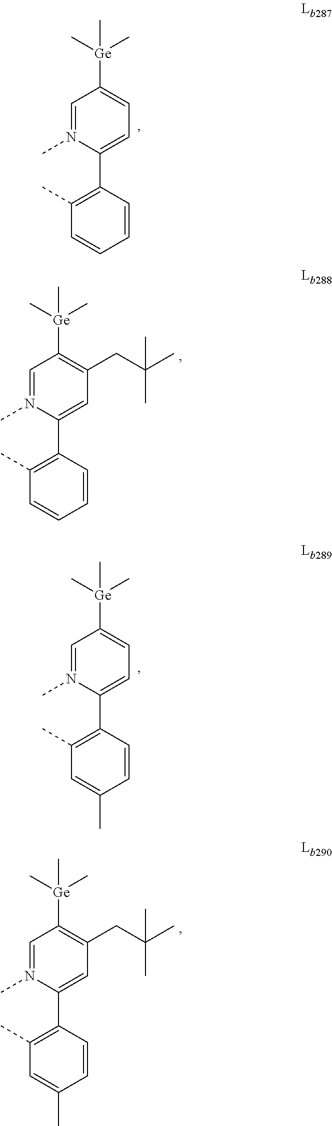 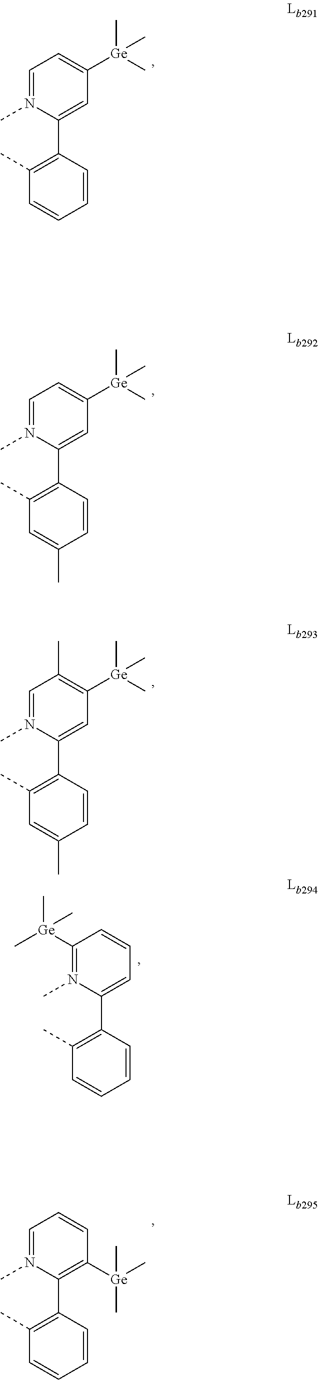 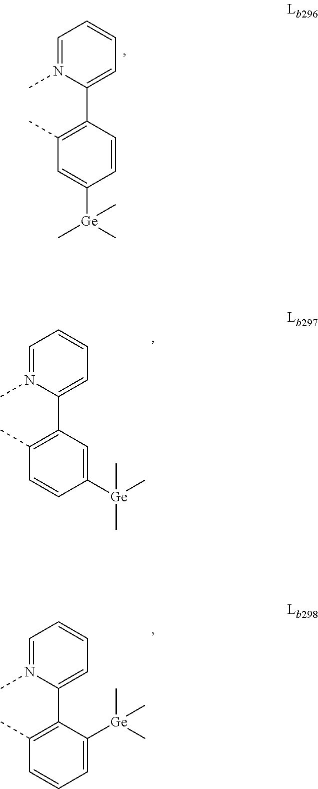 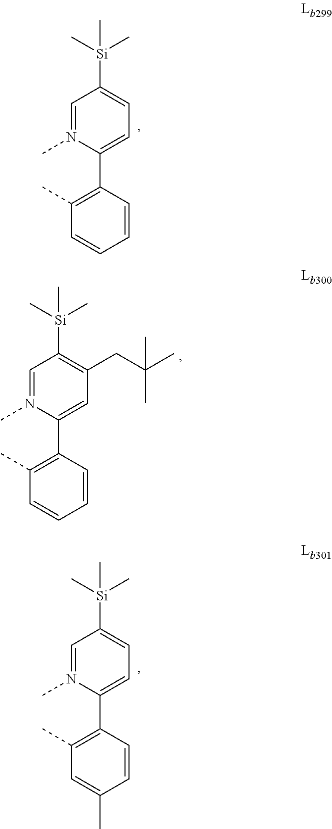 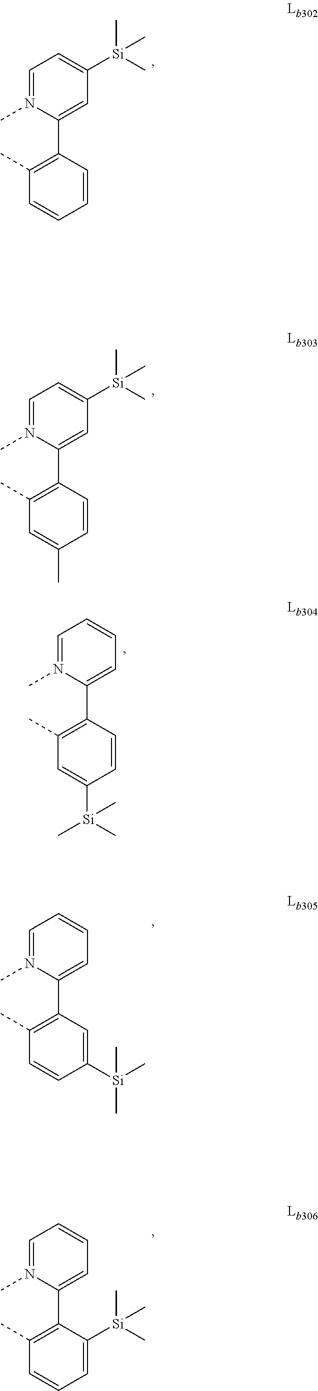 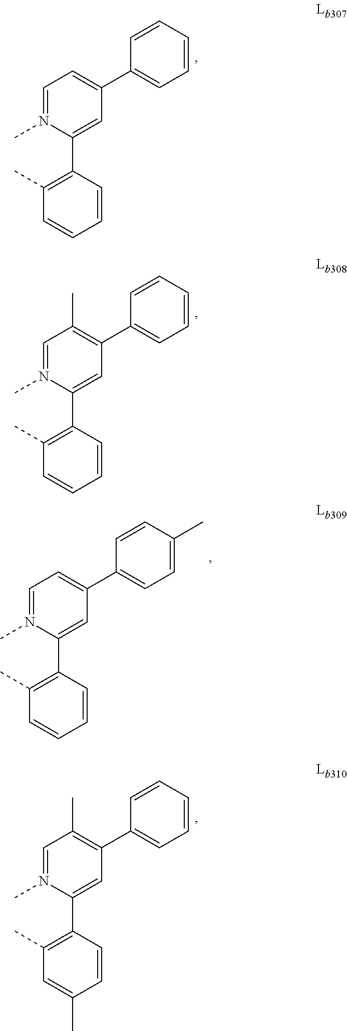 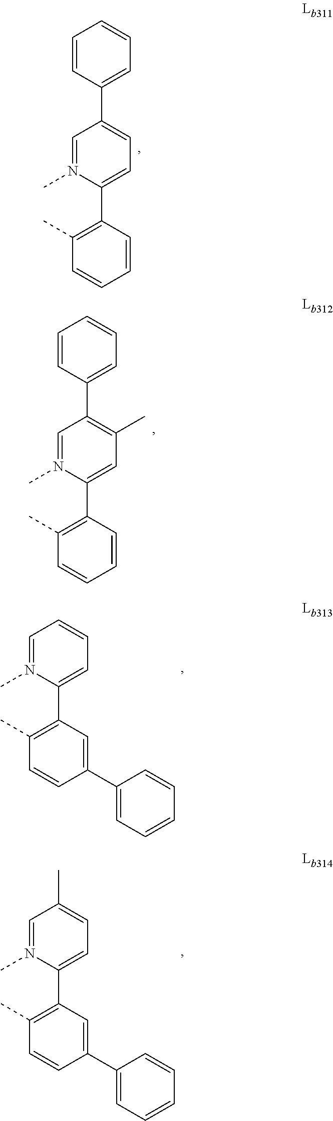 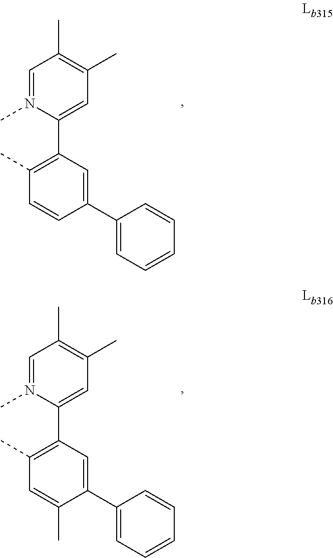 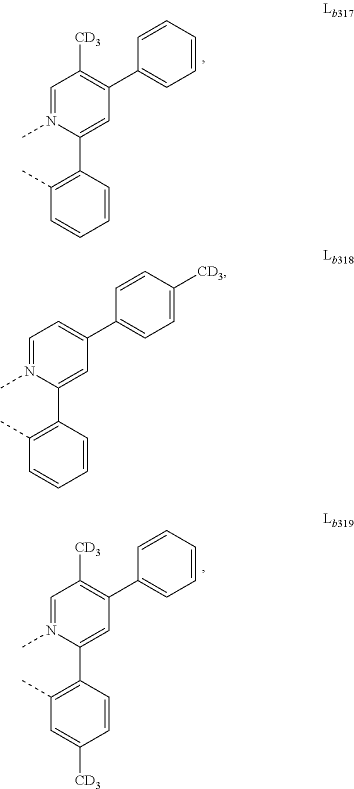 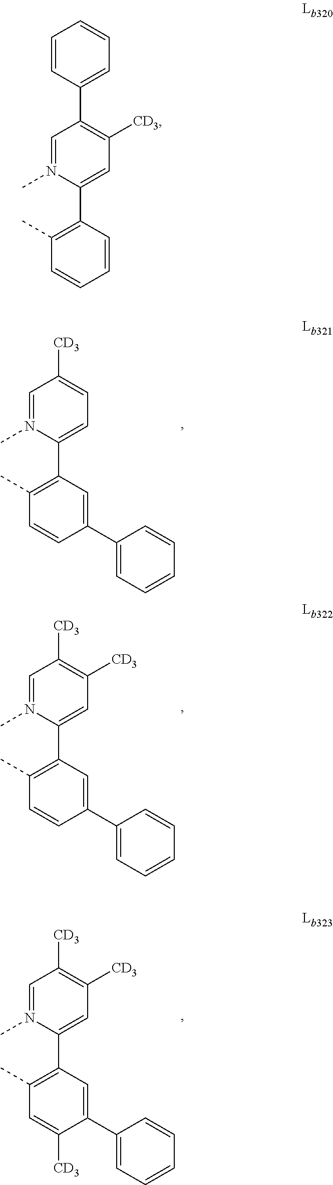 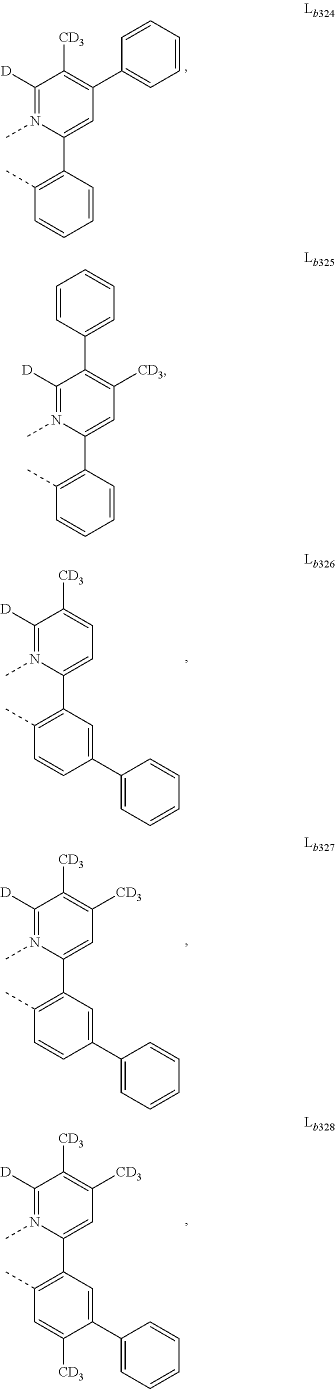 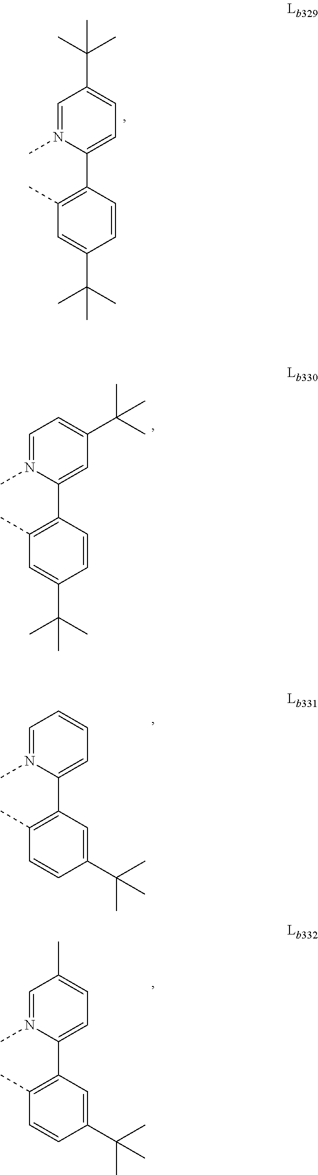 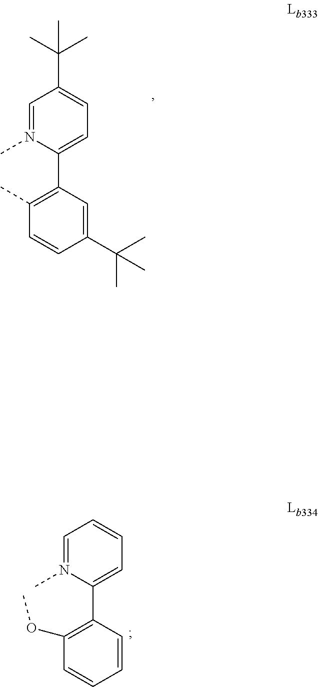
wherein optionally, hydrogen atoms in L_{b1} to L_{b334} can be partially or fully deuterated.

19. The metal complex according to claim 3, wherein the metal complex has a structure of IrLₐ(L_{b})₂, wherein two L_{b} are the same or different, Lₐ is selected from any one of the group consisting of Lₐ₁ to Lₐ₈₇₉, and L_{b} is selected from any one or two of the group consisting of L_{b1} to L_{b334};
preferably, the metal complex is selected from the group consisting of Metal Complex 1 to Metal Complex 396, wherein Metal Complex 1 to Metal Complex 396 have the structure of IrLₐ(L_{b})₂, wherein the two L_{b} are the same and Lₐ and L_{b} correspond to structures shown in the following table, respectively:

| Metal | | | Metal | | | Metal | | |
|---|---|---|---|---|---|---|---|---|
| Complex | Lₐ | L_{b} | Complex | Lₐ | L_{b} | Complex | Lₐ | L_{b} |
| 1 | Lₐ₁ | L_{b1} | 2 | Lₐ₄ | L_{b1} | 3 | Lₐ₆ | L_{b1} |
| 4 | Lₐ₇ | L_{b1} | 5 | Lₐ₆ | L_{b1} | 6 | Lₐ₃₈ | L_{b1} |
| 7 | Lₐ₇₆ | L_{b1} | 8 | Lₐ₇₉ | L_{b1} | 9 | Lₐ₁₀₄ | L_{b1} |
| 10 | Lₐ₁₀₇ | L_{b1} | 11 | Lₐ₁₁₆ | L_{b1} | 12 | Lₐ₁₂₈ | L_{b1} |
| 13 | Lₐ₁₄₀ | L_{b1} | 14 | Lₐ₁₄₈ | L_{b1} | 15 | Lₐ₁₆₄ | L_{b1} |
| 16 | Lₐ₁₈₀ | L_{b1} | 17 | Lₐ₁₈₈ | L_{b1} | 18 | Lₐ₂₈₀ | L_{b1} |
| 19 | Lₐ₂₈₃ | L_{b1} | 20 | Lₐ₃₅₃ | L_{b1} | 21 | Lₐ₃₈₀ | L_{b1} |
| 22 | Lₐ₄₂₄ | L_{b1} | 23 | Lₐ₄₃₆ | L_{b1} | 24 | Lₐ₆₂₁ | L_{b1} |
| 25 | Lₐ₆₂₄ | L_{b1} | 26 | Lₐ₆₂₇ | L_{b1} | 27 | Lₐ₆₆₀ | L_{b1} |
| 28 | Lₐ₆₉₁ | L_{b1} | 29 | Lₐ₇₀₀ | L_{b1} | 30 | Lₐ₇₀₈ | L_{b1} |
| 31 | Lₐ₇₂₆ | L_{b1} | 32 | Lₐ₇₅₉ | L_{b1} | 33 | Lₐ₇₇₂ | L_{b1} |
| 34 | Lₐ₁ | L_{b3} | 35 | Lₐ₄ | L_{b3} | 36 | Lₐ₆ | L_{b3} |
| 37 | Lₐ₇ | L_{b3} | 38 | Lₐ₆ | L_{b3} | 39 | Lₐ₃₈ | L_{b3} |
| 40 | Lₐ₇₆ | L_{b3} | 41 | Lₐ₇₉ | L_{b3} | 42 | Lₐ₁₀₄ | L_{b3} |
| 43 | Lₐ₁₀₇ | L_{b3} | 44 | Lₐ₁₁₆ | L_{b3} | 45 | Lₐ₁₂₈ | L_{b3} |
| 46 | Lₐ₁₄₀ | L_{b3} | 47 | Lₐ₁₄₈ | L_{b3} | 48 | Lₐ₁₆₄ | L_{b3} |
| 49 | Lₐ₁₈₀ | L_{b3} | 50 | Lₐ₁₈₈ | L_{b3} | 51 | Lₐ₂₈₀ | L_{b3} |
| 52 | Lₐ₂₈₃ | L_{b3} | 53 | Lₐ₃₅₃ | L_{b3} | 54 | Lₐ₃₈₀ | L_{b3} |
| 55 | Lₐ₄₂₄ | L_{b3} | 56 | Lₐ₄₃₆ | L_{b3} | 57 | Lₐ₆₂₁ | L_{b3} |
| 58 | Lₐ₆₂₄ | L_{b3} | 59 | Lₐ₆₂₇ | L_{b3} | 60 | Lₐ₆₆₀ | L_{b3} |
| 61 | Lₐ₆₉₁ | L_{b3} | 62 | Lₐ₇₀₀ | L_{b3} | 63 | Lₐ₇₀₈ | L_{b3} |
| 64 | Lₐ₇₂₆ | L_{b3} | 65 | Lₐ₇₅₉ | L_{b3} | 66 | Lₐ₇₇₂ | L_{b3} |
| 67 | Lₐ₁ | L_{b8} | 68 | Lₐ₄ | L_{b8} | 69 | Lₐ₆ | L_{b8} |
| 70 | Lₐ₇ | L_{b8} | 71 | Lₐ₆ | L_{b8} | 72 | Lₐ₃₈ | L_{b8} |
| 73 | Lₐ₇₆ | L_{b8} | 74 | Lₐ₇₉ | L_{b8} | 75 | Lₐ₁₀₄ | L_{b8} |
| 76 | Lₐ₁₀₇ | L_{b8} | 77 | Lₐ₁₁₆ | L_{b8} | 78 | Lₐ₁₂₈ | L_{b8} |
| 79 | Lₐ₁₄₀ | L_{b8} | 80 | Lₐ₁₄₈ | L_{b8} | 81 | Lₐ₁₆₄ | L_{b8} |
| 82 | Lₐ₁₈₀ | L_{b8} | 83 | Lₐ₁₈₈ | L_{b8} | 84 | Lₐ₂₈₀ | L_{b8} |
| 85 | Lₐ₂₈₃ | L_{b8} | 86 | Lₐ₃₅₃ | L_{b8} | 87 | Lₐ₃₈₀ | L_{b8} |
| 88 | Lₐ₄₂₄ | L_{b8} | 89 | Lₐ₄₃₆ | L_{b8} | 90 | Lₐ₆₂₁ | L_{b8} |
| 91 | Lₐ₆₂₄ | L_{b8} | 92 | Lₐ₆₂₇ | L_{b8} | 93 | Lₐ₆₆₀ | L_{b8} |
| 94 | Lₐ₆₉₁ | L_{b8} | 95 | Lₐ₇₀₀ | L_{b8} | 96 | Lₐ₇₀₈ | L_{b8} |
| 97 | Lₐ₇₂₆ | L_{b8} | 98 | Lₐ₇₅₉ | L_{b8} | 99 | Lₐ₇₇₂ | L_{b8} |
| 100 | Lₐ₁ | L_{b73} | 101 | Lₐ₄ | L_{b73} | 102 | Lₐ₆ | L_{b73} |
| 103 | Lₐ₇ | L_{b73} | 104 | Lₐ₆ | L_{b73} | 105 | Lₐ₃₈ | L_{b73} |
| 106 | Lₐ₇₆ | L_{b73} | 107 | Lₐ₇₉ | L_{b73} | 108 | Lₐ₁₀₄ | L_{b73} |
| 109 | Lₐ₁₀₇ | L_{b73} | 110 | Lₐ₁₁₆ | L_{b73} | 111 | Lₐ₁₂₈ | L_{b73} |
| 112 | Lₐ₁₄₀ | L_{b73} | 113 | Lₐ₁₄₈ | L_{b73} | 114 | Lₐ₁₆₄ | L_{b73} |
| 115 | Lₐ₁₈₀ | L_{b73} | 116 | Lₐ₁₈₈ | L_{b73} | 117 | Lₐ₂₈₀ | L_{b73} |
| 118 | Lₐ₂₈₃ | L_{b73} | 119 | Lₐ₃₅₃ | L_{b73} | 120 | Lₐ₃₈₀ | L_{b73} |
| 121 | Lₐ₄₂₄ | L_{b73} | 122 | Lₐ₄₃₆ | L_{b73} | 123 | Lₐ₆₂₁ | L_{b73} |
| 124 | Lₐ₆₂₄ | L_{b73} | 125 | Lₐ₆₂₇ | L_{b73} | 126 | Lₐ₆₆₀ | L_{b73} |
| 127 | Lₐ₆₉₁ | L_{b73} | 128 | Lₐ₇₀₀ | L_{b73} | 129 | Lₐ₇₀₈ | L_{b73} |
| 130 | Lₐ₇₂₆ | L_{b73} | 131 | Lₐ₇₅₉ | L_{b73} | 132 | Lₐ₇₇₂ | L_{b73} |
| 133 | Lₐ₁ | L_{b81} | 134 | Lₐ₄ | L_{b81} | 135 | Lₐ₆ | L_{b81} |
| 136 | Lₐ₇ | L_{b81} | 137 | Lₐ₆ | L_{b81} | 138 | Lₐ₃₈ | L_{b81} |
| 139 | Lₐ₇₆ | L_{b81} | 140 | Lₐ₇₉ | L_{b81} | 141 | Lₐ₁₀₄ | L_{b81} |
| 142 | Lₐ₁₀₇ | L_{b81} | 143 | Lₐ₁₁₆ | L_{b81} | 144 | Lₐ₁₂₈ | L_{b81} |
| 145 | Lₐ₁₄₀ | L_{b81} | 146 | Lₐ₁₄₈ | L_{b81} | 147 | Lₐ₁₆₄ | L_{b81} |
| 148 | Lₐ₁₈₈ | L_{b81} | 149 | Lₐ₂₇₇ | L_{b81} | 150 | Lₐ₂₈₀ | L_{b81} |
| 151 | Lₐ₂₈₃ | L_{b81} | 152 | Lₐ₃₅₃ | L_{b81} | 153 | Lₐ₃₈₀ | L_{b81} |
| 154 | Lₐ₄₂₄ | L_{b81} | 155 | Lₐ₄₃₆ | L_{b81} | 156 | Lₐ₆₂₁ | L_{b81} |
| 157 | Lₐ₆₂₄ | L_{b81} | 158 | Lₐ₆₂₇ | L_{b81} | 159 | Lₐ₆₆₀ | L_{b81} |
| 160 | Lₐ₆₉₁ | L_{b81} | 161 | Lₐ₇₀₀ | L_{b81} | 162 | Lₐ₇₀₈ | L_{b81} |
| 163 | Lₐ₇₂₆ | L_{b81} | 164 | Lₐ₇₅₉ | L_{b81} | 165 | Lₐ₇₇₂ | L_{b81} |
| 166 | Lₐ₁ | L_{b84} | 167 | Lₐ₄ | L_{b84} | 168 | Lₐ₆ | L_{b84} |
| 169 | Lₐ₇ | L_{b84} | 170 | Lₐ₆ | L_{b84} | 171 | Lₐ₃₈ | L_{b84} |
| 172 | Lₐ₇₆ | L_{b84} | 173 | Lₐ₇₉ | L_{b84} | 174 | Lₐ₁₀₄ | L_{b84} |
| 175 | Lₐ₁₀₇ | L_{b84} | 176 | Lₐ₁₁₆ | L_{b84} | 177 | Lₐ₁₂₈ | L_{b84} |
| 178 | Lₐ₁₄₀ | L_{b84} | 179 | Lₐ₁₄₈ | L_{b84} | 180 | Lₐ₁₆₄ | L_{b84} |
| 181 | Lₐ₁₈₀ | L_{b84} | 182 | Lₐ₁₈₈ | L_{b84} | 183 | Lₐ₂₈₀ | L_{b84} |
| 184 | Lₐ₂₈₃ | L_{b84} | 185 | Lₐ₃₅₃ | L_{b84} | 186 | Lₐ₃₈₀ | L_{b84} |
| 187 | Lₐ₄₂₄ | L_{b84} | 188 | Lₐ₄₃₆ | L_{b84} | 189 | Lₐ₆₂₁ | L_{b84} |
| 190 | Lₐ₆₂₄ | L_{b84} | 191 | Lₐ₆₂₇ | L_{b84} | 192 | Lₐ₆₆₀ | L_{b84} |
| 193 | Lₐ₆₉₁ | L_{b84} | 194 | Lₐ₇₀₀ | L_{b84} | 195 | Lₐ₇₀₈ | L_{b84} |
| 196 | Lₐ₇₂₆ | L_{b84} | 197 | Lₐ₇₅₉ | L_{b84} | 198 | Lₐ₇₇₂ | L_{b84} |
| 199 | Lₐ₁ | L_{b88} | 200 | Lₐ₄ | L_{b88} | 201 | Lₐ₆ | L_{b88} |
| 202 | Lₐ₇ | L_{b88} | 203 | Lₐ₆ | L_{b88} | 204 | Lₐ₃₈ | L_{b88} |
| 205 | Lₐ₇₆ | L_{b88} | 206 | Lₐ₇₉ | L_{b88} | 207 | Lₐ₁₀₄ | L_{b88} |
| 208 | Lₐ₁₀₇ | L_{b88} | 209 | Lₐ₁₁₆ | L_{b88} | 210 | Lₐ₁₂₈ | L_{b88} |
| 211 | Lₐ₁₄₀ | L_{b88} | 212 | Lₐ₁₄₈ | L_{b88} | 213 | Lₐ₁₆₄ | L_{b88} |
| 214 | Lₐ₁₈₀ | L_{b88} | 215 | Lₐ₁₈₈ | L_{b88} | 216 | Lₐ₂₈₀ | L_{b88} |
| 217 | Lₐ₂₈₃ | L_{b88} | 218 | Lₐ₃₅₃ | L_{b88} | 219 | Lₐ₃₈₀ | L_{b88} |
| 220 | Lₐ₄₂₄ | L_{b88} | 221 | Lₐ₄₃₆ | L_{b88} | 222 | Lₐ₆₂₁ | L_{b88} |
| 223 | Lₐ₆₂₄ | L_{b88} | 224 | Lₐ₆₂₇ | L_{b88} | 225 | Lₐ₆₆₀ | L_{b88} |
| 226 | Lₐ₆₉₁ | L_{b88} | 227 | Lₐ₇₀₀ | L_{b88} | 228 | Lₐ₇₀₈ | L_{b88} |
| 229 | Lₐ₇₂₆ | L_{b88} | 230 | Lₐ₇₅₉ | L_{b88} | 231 | Lₐ₇₇₂ | L_{b88} |
| 232 | Lₐ₁ | L_{b112} | 233 | Lₐ₄ | L_{b112} | 234 | Lₐ₆ | L_{b112} |
| 235 | Lₐ₇ | L_{b112} | 236 | Lₐ₆ | L_{b112} | 237 | Lₐ₃₈ | L_{b112} |
| 238 | Lₐ₇₆ | L_{b112} | 239 | Lₐ₇₉ | L_{b112} | 240 | Lₐ₁₀₄ | L_{b112} |
| 241 | Lₐ₁₀₇ | L_{b112} | 242 | Lₐ₁₁₆ | L_{b112} | 243 | Lₐ₁₂₈ | L_{b112} |
| 244 | Lₐ₁₄₀ | L_{b112} | 245 | Lₐ₁₄₈ | L_{b112} | 246 | Lₐ₁₆₄ | L_{b112} |
| 247 | Lₐ₁₈₀ | L_{b112} | 248 | Lₐ₁₈₈ | L_{b112} | 249 | Lₐ₂₈₀ | L_{b112} |
| 250 | Lₐ₂₈₃ | L_{b112} | 251 | Lₐ₃₅₃ | L_{b112} | 252 | Lₐ₃₈₀ | L_{b112} |
| 253 | Lₐ₄₂₄ | L_{b112} | 254 | Lₐ₄₃₆ | L_{b112} | 255 | Lₐ₆₂₁ | L_{b112} |
| 256 | Lₐ₆₂₄ | L_{b112} | 257 | Lₐ₆₂₇ | L_{b112} | 258 | Lₐ₆₆₀ | L_{b112} |
| 259 | Lₐ₆₉₁ | L_{b112} | 260 | Lₐ₇₀₀ | L_{b112} | 261 | Lₐ₇₀₈ | L_{b112} |
| 262 | Lₐ₇₂₆ | L_{b112} | 263 | Lₐ₇₅₉ | L_{b112} | 264 | Lₐ₇₇₂ | L_{b112} |
| 265 | Lₐ₁ | L_{b164} | 266 | Lₐ₄ | L_{b164} | 267 | Lₐ₆ | L_{b164} |
| 268 | Lₐ₇ | L_{b164} | 269 | Lₐ₆ | L_{b164} | 270 | Lₐ₃₈ | L_{b164} |
| 271 | Lₐ₇₆ | L_{b164} | 272 | Lₐ₇₉ | L_{b164} | 273 | Lₐ₁₀₄ | L_{b164} |
| 274 | Lₐ₁₀₇ | L_{b164} | 275 | Lₐ₁₁₆ | L_{b164} | 276 | Lₐ₁₂₈ | L_{b164} |
| 277 | Lₐ₁₄₀ | L_{b164} | 278 | Lₐ₁₄₈ | L_{b164} | 279 | Lₐ₁₆₄ | L_{b164} |
| 280 | Lₐ₁₈₀ | L_{b164} | 281 | Lₐ₁₈₈ | L_{b164} | 282 | Lₐ₂₈₀ | L_{b164} |
| 283 | Lₐ₂₈₃ | L_{b164} | 284 | Lₐ₃₅₃ | L_{b164} | 285 | Lₐ₃₈₀ | L_{b164} |
| 286 | Lₐ₄₂₄ | L_{b164} | 287 | Lₐ₄₃₆ | L_{b164} | 288 | Lₐ₆₂₁ | L_{b164} |
| 289 | Lₐ₆₂₄ | L_{b164} | 290 | Lₐ₆₂₇ | L_{b164} | 291 | Lₐ₆₆₀ | L_{b164} |
| 292 | Lₐ₆₉₁ | L_{b164} | 293 | Lₐ₇₀₀ | L_{b164} | 294 | Lₐ₇₀₈ | L_{b164} |
| 295 | Lₐ₇₂₆ | L_{b164} | 296 | Lₐ₇₅₉ | L_{b164} | 297 | Lₐ₇₇₂ | L_{b164} |
| 298 | Lₐ₁ | L_{b209} | 299 | Lₐ₄ | L_{b209} | 300 | Lₐ₆ | L_{b209} |
| 301 | Lₐ₇ | L_{b209} | 302 | Lₐ₆ | L_{b209} | 303 | Lₐ₃₈ | L_{b209} |
| 304 | Lₐ₇₆ | L_{b209} | 305 | Lₐ₇₉ | L_{b209} | 306 | Lₐ₁₀₄ | L_{b209} |
| 307 | Lₐ₁₀₇ | L_{b209} | 308 | Lₐ₁₁₆ | L_{b209} | 309 | Lₐ₁₂₈ | L_{b209} |
| 310 | Lₐ₁₄₀ | L_{b209} | 311 | Lₐ₁₄₈ | L_{b209} | 312 | Lₐ₁₆₄ | L_{b209} |
| 313 | Lₐ₁₈₀ | L_{b209} | 314 | Lₐ₁₈₈ | L_{b209} | 315 | Lₐ₂₈₀ | L_{b209} |
| 316 | Lₐ₂₈₃ | L_{b209} | 317 | Lₐ₃₅₃ | L_{b209} | 318 | Lₐ₃₈₀ | L_{b209} |
| 319 | Lₐ₄₂₄ | L_{b209} | 320 | Lₐ₄₃₆ | L_{b209} | 321 | Lₐ₆₂₁ | L_{b209} |
| 322 | Lₐ₆₂₄ | L_{b209} | 323 | Lₐ₆₂₇ | L_{b209} | 324 | Lₐ₆₆₀ | L_{b209} |
| 325 | Lₐ₆₉₁ | L_{b209} | 326 | Lₐ₇₀₀ | L_{b209} | 327 | Lₐ₇₀₈ | L_{b209} |
| 328 | Lₐ₇₂₆ | L_{b209} | 329 | Lₐ₇₅₉ | L_{b209} | 330 | Lₐ₇₇₂ | L_{b209} |
| 331 | Lₐ₁ | L_{b329} | 332 | Lₐ₄ | L_{b329} | 333 | Lₐ₆ | L_{b329} |
| 334 | Lₐ₇ | L_{b329} | 335 | Lₐ₆ | L_{b329} | 336 | Lₐ₃₈ | L_{b329} |
| 337 | Lₐ₇₆ | L_{b329} | 338 | Lₐ₇₉ | L_{b329} | 339 | Lₐ₁₀₄ | L_{b329} |
| 340 | Lₐ₁₀₇ | L_{b329} | 341 | Lₐ₁₁₆ | L_{b329} | 342 | Lₐ₁₂₈ | L_{b329} |
| 343 | Lₐ₁₄₀ | L_{b329} | 344 | Lₐ₁₄₈ | L_{b329} | 345 | Lₐ₁₆₄ | L_{b329} |
| 346 | Lₐ₁₈₀ | L_{b329} | 347 | Lₐ₁₈₈ | L_{b329} | 348 | Lₐ₂₈₀ | L_{b329} |
| 349 | Lₐ₂₈₃ | L_{b329} | 350 | Lₐ₃₅₃ | L_{b329} | 351 | Lₐ₃₈₀ | L_{b329} |
| 352 | Lₐ₄₂₄ | L_{b329} | 353 | Lₐ₄₃₆ | L_{b329} | 354 | Lₐ₆₂₁ | L_{b329} |
| 355 | Lₐ₆₂₄ | L_{b329} | 356 | Lₐ₆₂₇ | L_{b329} | 357 | Lₐ₆₆₀ | L_{b329} |
| 358 | Lₐ₆₉₁ | L_{b329} | 359 | Lₐ₇₀₀ | L_{b329} | 360 | Lₐ₇₀₈ | L_{b329} |
| 362 | Lₐ₇₂₆ | L_{b329} | 362 | Lₐ₇₅₉ | L_{b329} | 363 | Lₐ₇₇₂ | L_{b329} |
| 364 | Lₐ₁ | L_{b333} | 365 | Lₐ₄ | L_{b333} | 366 | Lₐ₆ | L_{b333} |
| 367 | Lₐ₇ | L_{b333} | 368 | Lₐ₆ | L_{b333} | 369 | Lₐ₃₈ | L_{b333} |
| 370 | Lₐ₇₆ | L_{b333} | 371 | Lₐ₇₉ | L_{b333} | 372 | Lₐ₁₀₄ | L_{b333} |
| 373 | Lₐ₁₀₇ | L_{b333} | 374 | Lₐ₁₁₆ | L_{b333} | 375 | Lₐ₁₂₈ | L_{b333} |
| 376 | Lₐ₁₄₀ | L_{b333} | 377 | Lₐ₁₄₈ | L_{b333} | 378 | Lₐ₁₆₄ | L_{b333} |
| 379 | Lₐ₁₈₀ | L_{b333} | 380 | Lₐ₁₈₈ | L_{b333} | 381 | Lₐ₂₈₀ | L_{b333} |
| 382 | Lₐ₂₈₃ | L_{b333} | 383 | Lₐ₃₅₃ | L_{b333} | 384 | Lₐ₃₈₀ | L_{b333} |
| 385 | Lₐ₄₂₄ | L_{b333} | 386 | Lₐ₄₃₆ | L_{b333} | 387 | Lₐ₆₂₁ | L_{b333} |
| 388 | Lₐ₆₂₄ | L_{b333} | 389 | Lₐ₆₂₇ | L_{b333} | 390 | Lₐ₆₆₀ | L_{b333} |
| 391 | Lₐ₆₉₁ | L_{b333} | 392 | Lₐ₇₀₀ | L_{b333} | 393 | Lₐ₇₀₈ | L_{b333} |
| 394 | Lₐ₇₂₆ | L_{b333} | 395 | Lₐ₇₅₉ | L_{b333} | 396 | Lₐ₇₇₂ | L_{b333}. |

20. An electroluminescent device, comprising:
an anode,
a cathode and
an organic layer disposed between the anode and the cathode, wherein at least one layer of the organic layer comprises the metal complex according to claim 1.

21. The electroluminescent device according to claim 20, wherein the organic layer comprising the metal complex is a light-emitting layer.

22. The electroluminescent device according to claim 21, wherein the light-emitting layer further comprises a first host compound;
preferably, the light-emitting layer further comprises a second host compound;
more preferably, at least one of the first host compound and the second host compound comprises at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene and combinations thereof.

23. The electroluminescent device according to claim 22, wherein the metal complex is doped in the first host compound and the second host compound, and the weight of the metal complex accounts for 1% to 30% of the total weight of the light-emitting layer;
preferably, the weight of the metal complex accounts for 3% to 13% of the total weight of the light-emitting layer.

24. A compound combination, comprising the metal complex according to claim 1.
